(19) United States
(12) Patent Application Publication
(10) Pub. No.: US 2022/0384741 A1
(43) Pub. Date: Dec. 1, 2022

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Wei Cai, Beijing (CN); Ming Sang, Beijing (CN); Zhen Wang, Beijing (CN); Hongbo Li, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 17/659,967

(22) Filed: Apr. 20, 2022

(30) Foreign Application Priority Data
Apr. 21, 2021 (CN) 202110423792.3

(51) Int. Cl. H01L 51/00; C07F 15/00; C09K 11/06

(52) U.S. Cl. CPC H01L 51/0085; C07F 15/0033; C09K 11/06; H01L 51/5012

(57) ABSTRACT

Provided are an organic electroluminescent material and a device thereof. The organic electroluminescent material is a metal complex comprising a ligand Lₐ having a structure of Formula 1. The metal complex may be used as a light-emitting material in an electroluminescent device. These new compounds may be applied to electroluminescent devices and can exhibit better performance, achieve higher device efficiency, and significantly improve the overall performance of the devices. Further provided are an electroluminescent device comprising the metal complex and a compound combination comprising the metal complex.

### CROSS-REFERENCE TO RELATED APPLICATION(S)

This application claims priority to Chinese Patent Application No. CN 202110423792.3 filed on Apr. 21, 2021, the disclosure of which is incorporated herein by reference in its entirety.

### TECHNICAL FIELD

The present disclosure relates to compounds for organic electronic devices such as organic light-emitting devices. More particularly, the present disclosure relates to a metal complex including a ligand Lₐ having a structure of Formula 1 and an electroluminescent device and compound combination including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US2013119354A1 discloses an iridium complex having the following structure:

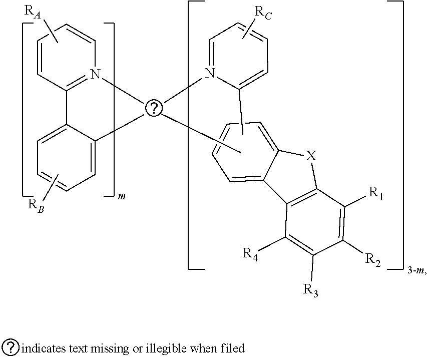

wherein R₁ to R₄ are selected from hydrogen, deuterium, alkyl, cycloalkyl, aryl or heteroaryl. The effect of R₁ including cyano substituted has neither disclosed nor taught.

US20200287144A1 discloses a metal complex including ligands having the following structures:

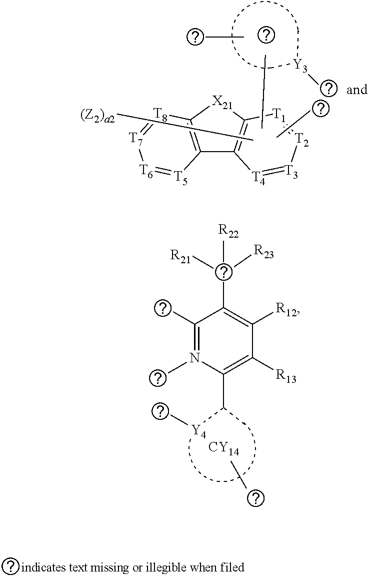

and wherein X₁ is selected from silyl or germanyl. An iridium complex is further disclosed which has a structure represented by the following general formula:

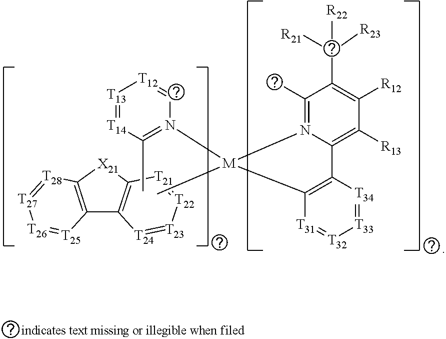

The disclosed specific structures include

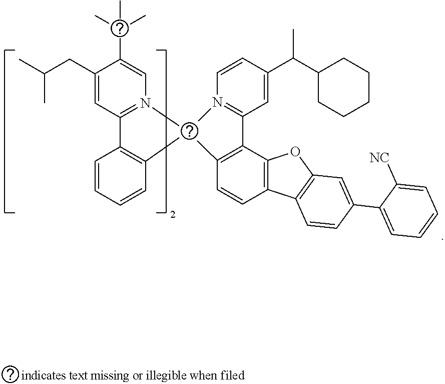

This application focuses on the effect of substituent containing silyl or germanyl at a particular position of the metal complex on device performance and has neither disclosed nor taught an effect of a CN-containing substituent introduced at a particular position of the metal complex on the device performance.

### SUMMARY

The present disclosure aims to provide a series of metal complexes each comprising a ligand Lₐ having a structure of Formula 1 to solve at least part of the above-mentioned problems.

According to an embodiment of the present disclosure, disclosed is a metal complex comprising a metal M and a ligand Lₐ coordinated to the metal M, wherein the metal M is selected from a metal with a relative atomic mass greater than 40, and the ligand Lₐ has a structure represented by Formula 1:

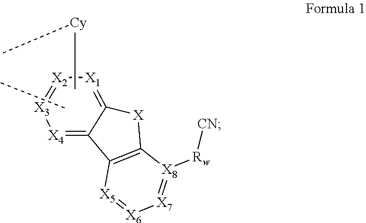

wherein in Formula 1,

Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;

X is selected from the group consisting of O, S, Se, NR′, CR′R′, SiR′R′ and GeR′R′, wherein when two R′ are present at the same time, the two R′ are the same or different;

X₁ to X₄ are, at each occurrence identically or differently, selected from C, CRₓ or N, and at least one of X₁ to X₄ is C and joined to the Cy;

X₅ to X₇ are, at each occurrence identically or differently, selected from CRₓ or N;

X₈ is selected from C;

X₁, X₂, X₃ or X₄ is joined to the metal M by a metal-carbon bond or a metal-nitrogen bond;

R′ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof; and

adjacent substituents R′, R_{w}, Rₓ can be optionally joined to form a ring.

According to another embodiment of the present disclosure, further disclosed is an electroluminescent device, the electroluminescent device comprises:

an anode,

a cathode, and

an organic layer disposed between the anode and the cathode, wherein the organic layer comprises the metal complex in the preceding embodiment.

According to another embodiment of the present disclosure, further disclosed is a compound combination comprising the metal complex in the preceding embodiment.

The series of metal complexes each comprising the ligand Lₐ having the structure of Formula 1, disclosed by the present disclosure, may be used as light-emitting materials in electroluminescent devices. These novel metal complexes may be applied to the electroluminescent devices and can improve device efficiency and significantly improve the overall performance of the devices.

### BRIEF DESCRIPTION OF DRAWINGS

FIG. 1 is a schematic diagram of an electroluminescent device that may contain a metal complex and a compound combination disclosed herein.

FIG. 2 is a schematic diagram of another electroluminescent device that may contain a metal complex and a compound combination disclosed herein.

### DETAILED DESCRIPTION

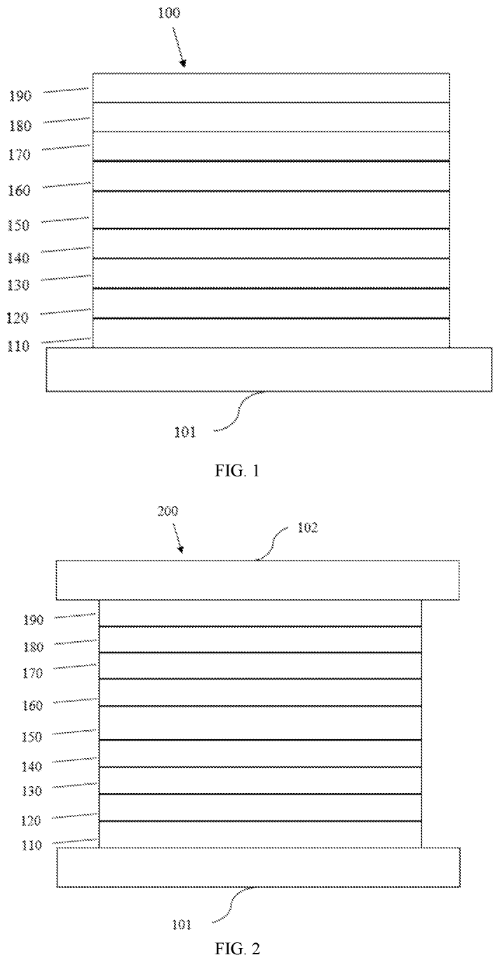

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (Δ_{ES-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Alkylthio—as used herein, is represented by —S-alkyl, —S-cycloalkyl, —S-heteroalkyl or —S-heterocyclic group. Examples and preferred examples of alkyl, cycloalkyl, heteroalkyl and heterocyclic groups are the same as those described above. Alkylthio groups may be those having 1 to 20 carbon atoms, preferably those having 1 to 6 carbon atoms. Examples of alkylthio groups include methylthio, ethylthio, propylthio, butylthio, pentylthio, hexylthio, cyclopropylthio, cyclobutylthio, cyclopentylthio, cyclohexylthio, tetrahydrofurylthio, tetrahydropyranylthio, methylthiopropylthio, ethylthioethylthio, methylthiomethylthio and ethylthiomethylthio. Additionally, the alkylthio group may be optionally substituted.

Arylthio—as used herein, is represented by —S-aryl or —S-heteroaryl. Examples and preferred examples of aryl and heteroaryl are the same as those described above. Arylthio groups may be those having 6 to 30 carbon atoms, preferably those having 6 to 20 carbon atoms. Examples of arylthio groups include phenylthio, biphenylthio and naphthylthio. Additionally, the arylthio group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

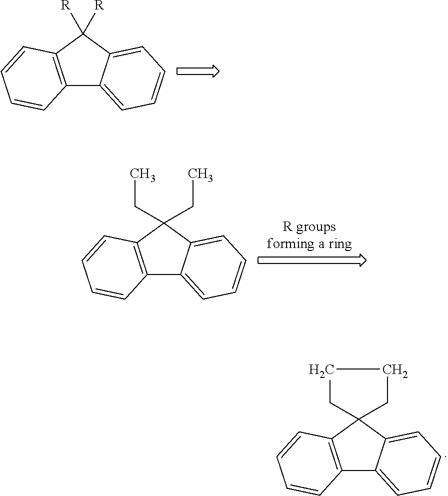

The expression that adjacent substituents can be optionally joined to form a ring is also intended to mean that two substituents bonded to carbon atoms which are directly bonded to each other are joined to each other via a chemical bond to form a ring, which can be exemplified by the following formula:

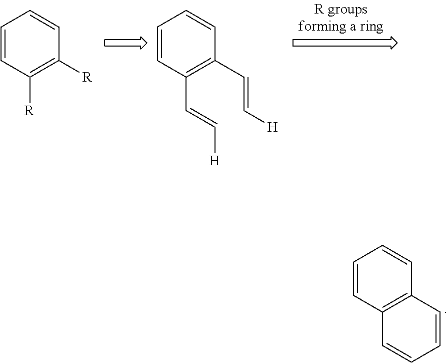

The expression that adjacent substituents can be optionally joined to form a ring is also intended to mean that two substituents bonded to a further distant carbon atom are joined to each other via a chemical bond to form a ring, which can be exemplified by the following formula:

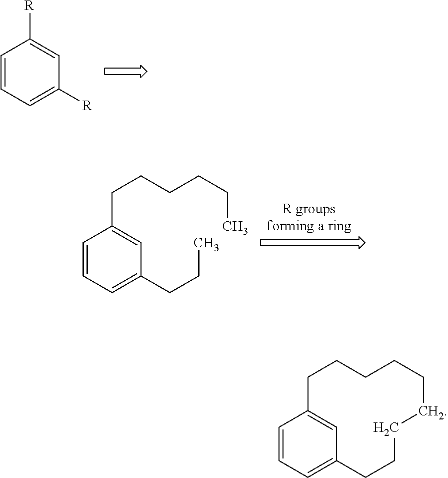

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

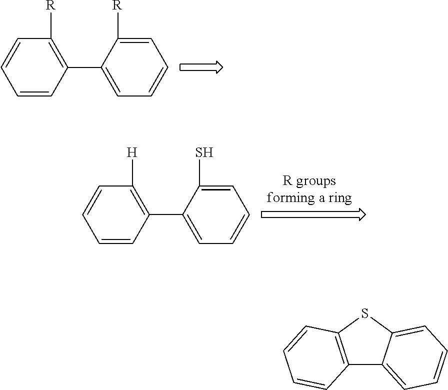

According to an embodiment of the present disclosure, disclosed is a metal complex comprising a metal M and a ligand Lₐ coordinated to the metal M, wherein the metal M is selected from a metal with a relative atomic mass greater than 40, and the ligand Lₐ has a structure represented by Formula 1:

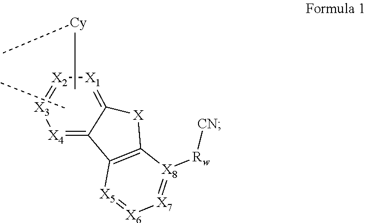

wherein in Formula 1,

Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;

X is selected from the group consisting of O, S, Se, NR′, CR′R′, SiR′R′ and GeR′R′, wherein when two R′ are present at the same time, the two R′ are the same or different;

X₁ to X₄ are, at each occurrence identically or differently, selected from C, CRₓ or N, and at least one of X₁ to X₄ is C and joined to the Cy;

X₅ to X₇ are, at each occurrence identically or differently, selected from CRₓ or N;

X₈ is selected from C;

X₁, X₂, X₃ or X₄ is joined to the metal M by a metal-carbon bond or a metal-nitrogen bond;

R′ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof; and

adjacent substituents R′, R_{w}, Rₓ can be optionally joined to form a ring.

In the present disclosure, the expression that “adjacent substituents R′, R_{w}, Rₓ can be optionally joined to form a ring” is intended to mean that any one or more of groups of adjacent substituents, such as two substituents R′, two substituents Rₓ, substituents R′ and Rₓ and substituents R_{w} and Rₓ, can be joined to form a ring. Obviously, it is possible that none of these substituents are joined to form a ring.

According to an embodiment of the present disclosure, Cy is any structure selected from the group consisting of:

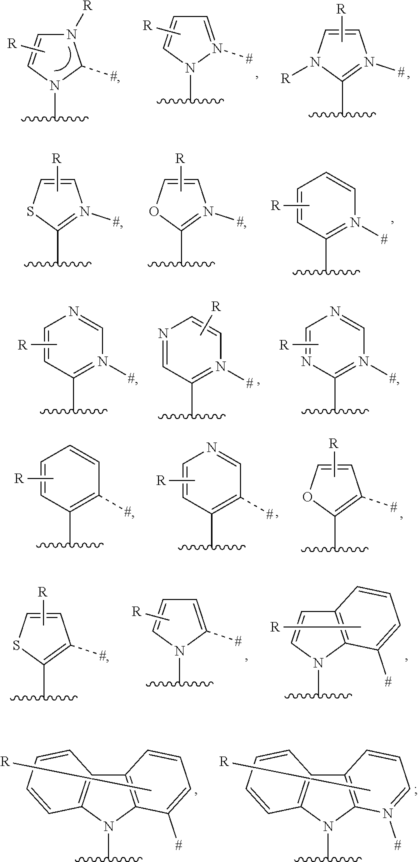

wherein

R represents, at each occurrence identically or differently, mono-substitution, multiple substitutions or non-substitution; and when multiple R are present at the same time in any structure, the multiple R are the same or different;

R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

two adjacent substituents R can be optionally joined to form a ring; and

wherein “#” represents a position where Cy is joined to the metal M, and

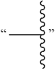

represents a position where Cy is joined to X₁, X₂, X₃ or X₄.

In the present disclosure, the expression that “two adjacent substituents R can be optionally joined to form a ring” is intended to mean that any one or more of groups of any two adjacent substituents R can be joined to form a ring. Obviously, it is possible that none of these substituents are joined to form a ring.

According to an embodiment of the present disclosure, Lₐ is, at each occurrence identically or differently, selected from the group consisting of:

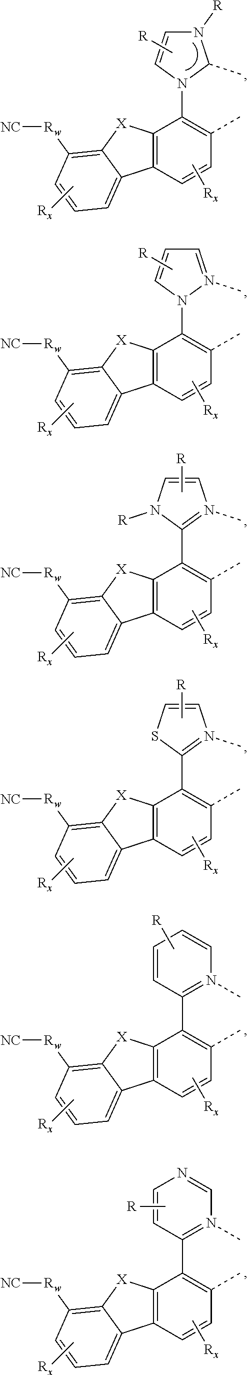

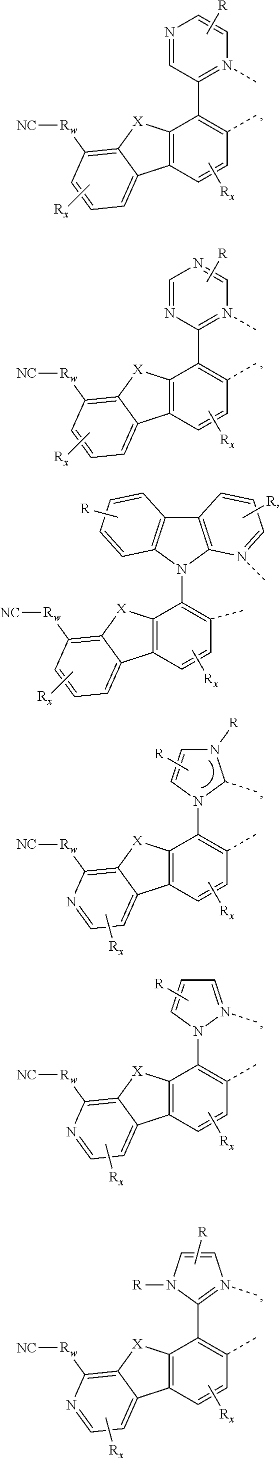

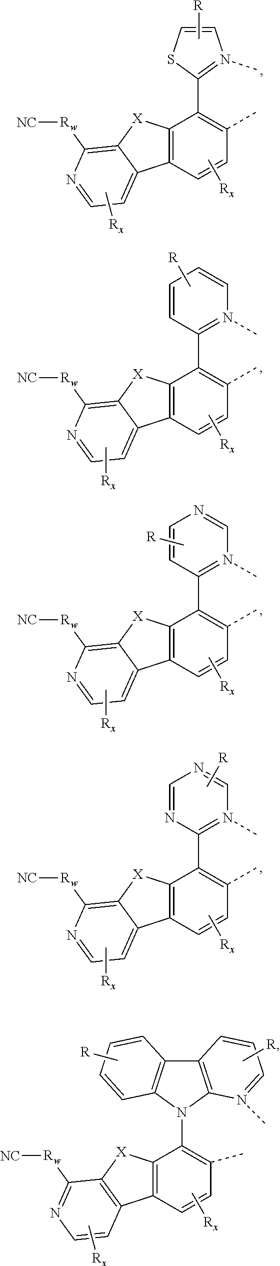

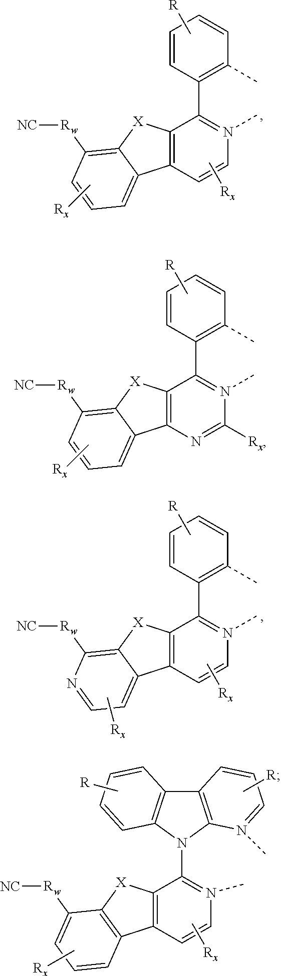

wherein

X is selected from the group consisting of O, S, Se, NR′, CR′R′, SiR′R′ and GeR′R′; wherein when two R′ are present at the same time, the two R′ are the same or different;

R and Rₓ represent, at each occurrence identically or differently, mono-substitution, multiple substitutions or non-substitution;

R and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof; and

adjacent substituents R, R′, R_{w} and Rₓ can be optionally joined to form a ring.

In the present disclosure, the expression that “adjacent substituents R, R′, R_{w} and Rₓ can be optionally joined to form a ring” is intended to mean that any one or more of groups of adjacent substituents, such as two substituents R, two substituents R′, two substituents Rₓ, substituents R′ and Rₓ and substituents R_{w} and Rₓ, can be joined to form a ring. Obviously, it is possible that none of these substituents are joined to form a ring.

According to an embodiment of the present disclosure, the metal complex has a general formula of M(Lₐ)ₘ(L_{b})ₙ(L_{c})_{q};

wherein

M is, at each occurrence identically or differently, selected from the group consisting of Cu, Ag, Au, Ru, Rh, Pd, Os, Ir and Pt;

Lₐ, L_{b} and L_{c} are a first ligand, a second ligand and a third ligand coordinated to the metal M, respectively, and L_{c} is the same as or different from Lₐ or L_{b}; wherein Lₐ, L_{b} and L_{c} can be optionally joined to form a multidentate ligand; for example, any two of Lₐ, L_{b} and L_{c} may be joined to form a tetradentate ligand; in another example, Lₐ, L_{b} and L_{c} may be joined to each other to form a hexadentate ligand; in another example, none of Lₐ, L_{b} and L_{c} are joined so that no multidentate ligand is formed;

m is selected from 1, 2 or 3, n is selected from 0, 1 or 2, q is selected from 0, 1 or 2, and m+n+q equals an oxidation state of the metal M; wherein when m is greater than or equal to 2, multiple Lₐ are the same or different; when n is equal to 2, two L_{b} are the same or different; when q is equal to 2, two L_{c} are the same or different;

L_{b} and L_{c} are, at each occurrence identically or differently, selected from a structure represented by any one of the group consisting of:

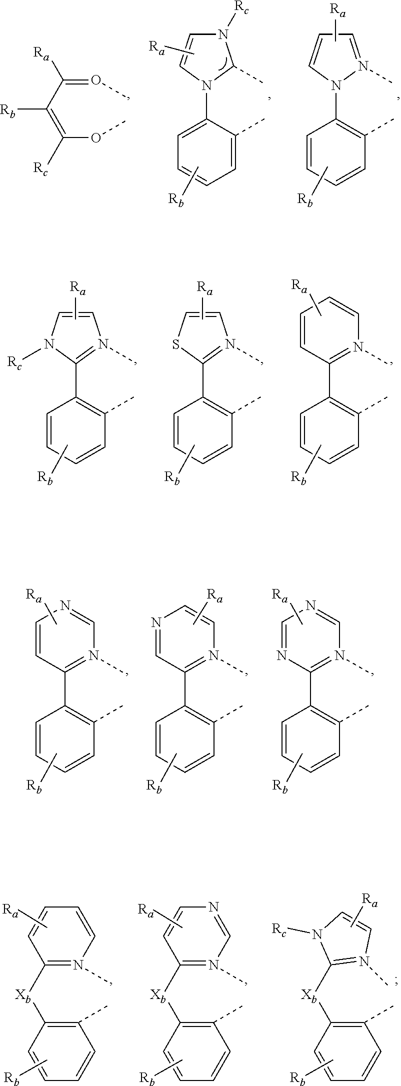

wherein

Rₐ and R_{b} represent, at each occurrence identically or differently, mono-substitution, multiple substitutions or non-substitution;

X_{b} is, at each occurrence identically or differently, selected from the group consisting of O, S, Se, NR_{N1} and CR_{C1}R_{C2};

Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and

adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and Rₑ, substituents R_{b} and Rₑ, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2} and substituents R_{C1} and R_{C2}, can be joined to form a ring. Obviously, it is possible that none of these substituents are joined to form a ring.

According to an embodiment of the present disclosure, wherein, the metal M is, at each occurrence identically or differently, selected from the group consisting of Cu, Ag, Au, Ru, Rh, Pd, Os, Ir and Pt.

According to an embodiment of the present disclosure, wherein, the metal M is, at each occurrence identically or differently, selected from Pt or Ir.

According to an embodiment of the present disclosure, wherein, the metal complex Ir(Lₐ)ₘ(L_{b})₃₋ₘ has a structure represented by Formula 3:

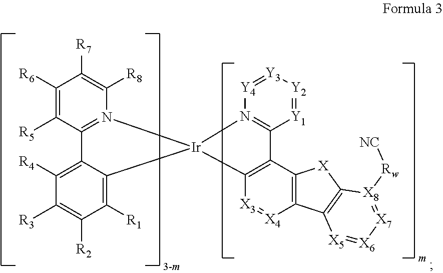

wherein

X is selected from the group consisting of O, S, Se, NR′, CR′R′, SiR′R′ and GeR′R′, wherein when two R′ are present at the same time, the two R′ are the same or different;

m is selected from 1, 2 or 3; when m is selected from 1, two L_{b} are the same or different; when m is selected from 2 or 3, multiple Lₐ are the same or different;

Y₁ to Y₄ are, at each occurrence identically or differently, selected from CR_{y} or N;

X₃ to X₇ are, at each occurrence identically or differently, selected from CRₓ or N;

X₈ is selected from C;

R′, R_{y} and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof;

adjacent substituents R′, R_{w}, Rₓ and R_{y} can be optionally joined to form a ring; and

adjacent substituents R₁ to R₈ can be optionally joined to form a ring.

In the present disclosure, the expression that “adjacent substituents R′, R_{w}, Rₓ and R_{y} can be optionally joined to form a ring” is intended to mean that any one or at least two of groups of adjacent substituents, such as two substituents R′, two substituents Rₓ, two substituents R_{y} and substituents R_{w} and Rₓ, can be joined to form a ring. Obviously, it is possible that none of these substituents are joined to form a ring.

In the present disclosure, the expression that “adjacent substituents R₁ to R₈ can be optionally joined to form a ring” is intended to mean that any one or at least two of groups of adjacent substituents, such as adjacent substituents R₁ and R₂, adjacent substituents R₃ and R₂, adjacent substituents R₃ and R₄, adjacent substituents R₅ and R₄, adjacent substituents R₅ and R₆, adjacent substituents R₇ and R₆ and adjacent substituents R₇ and R₈, can be joined to form a ring. Obviously, it is possible that none of these substituents are joined to form a ring.

According to an embodiment of the present disclosure, wherein, the metal complex Ir(Lₐ)ₘ(L_{b})₃₋ₘ has a structure represented by Formula 3A:

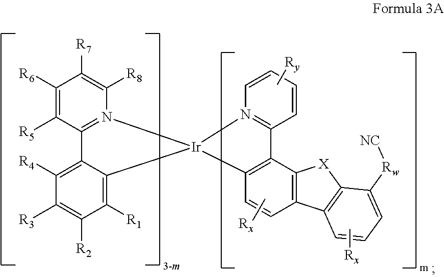

wherein

m is selected from 1, 2 or 3; when m is selected from 1, two L_{b} are the same or different; when m is selected from 2 or 3, multiple Lₐ are the same or different;

X is selected from the group consisting of O, S, Se, NR′, CR′R′, SiR′R′ and GeR′R′, wherein when two R′ are present at the same time, the two R′ are the same or different;

Rₓ and R_{y} represent, at each occurrence identically or differently, mono-substitution, multiple substitutions or non-substitution;

R′, R_{y} and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof;

adjacent substituents R′, R_{w}, Rₓ and R_{y} can be optionally joined to form a ring; and

adjacent substituents R₁ to R₈ can be optionally joined to form a ring.

According to an embodiment of the present disclosure, wherein, X is selected from O or S.

According to an embodiment of the present disclosure, wherein, X is O.

According to an embodiment of the present disclosure, wherein, X₁ to X₇ are, at each occurrence identically or differently, selected from C or CRₓ.

According to an embodiment of the present disclosure, wherein, at least one of X₁ to X₇ is N, for example, one of X₁ to X₇ is N or two of X₁ to X₇ are N.

According to an embodiment of the present disclosure, in Formula 3, X₃ to X₇ are, at each occurrence identically or differently, selected from CRₓ.

According to an embodiment of the present disclosure, in Formula 3, at least one of X₃ to X₇ is N, for example, one of X₃ to X₇ is N or two of X₃ to X₇ are N.

According to an embodiment of the present disclosure, wherein, Y₁ to Y₄ are, at each occurrence identically or differently, selected from CR_{y}.

According to an embodiment of the present disclosure, wherein, at least one of Y₁ to Y₄ is N, for example, one of Y₁ to Y₄ is N or two of Y₁ to Y₄ are N.

According to an embodiment of the present disclosure, wherein, at least one of X₃ to X₇ is selected from CRₓ, and the Rₓ is cyano.

According to an embodiment of the present disclosure, at least one of X₅ to X₇ is selected from CRₓ, and the Rₓ is cyano.

According to an embodiment of the present disclosure, wherein, X₇ is CRₓ, and the Rₓ is cyano.

According to an embodiment of the present disclosure, wherein, Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano and combinations thereof.

According to an embodiment of the present disclosure, wherein, Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, cyano and combinations thereof.

According to an embodiment of the present disclosure, wherein, Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, cyano and combinations thereof.

According to an embodiment of the present disclosure, wherein, at least one Rₓ is selected from the group consisting of: deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, cyano and combinations thereof.

According to an embodiment of the present disclosure, wherein, at least one Rₓ is selected from the group consisting of: deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, cyano and combinations thereof.

According to an embodiment of the present disclosure, wherein, R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted arylene having 6 to 30 carbon atoms, substituted or unsubstituted heteroarylene having 3 to 30 carbon atoms and combinations thereof.

According to an embodiment of the present disclosure, wherein, R_{w} is, at each occurrence identically or differently, selected from the group consisting of: substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms and combinations thereof.

According to an embodiment of the present disclosure, wherein, R_{w} is, at each occurrence identically or differently, selected from arylene having 6 to 30 carbon atoms.

According to an embodiment of the present disclosure, wherein, R_{w} is, at each occurrence identically or differently, selected from the group consisting of: substituted or unsubstituted arylene having 6 to 12 carbon atoms and substituted or unsubstituted heteroarylene having 3 to 12 carbon atoms.

According to an embodiment of the present disclosure, wherein, R_{w} is, at each occurrence identically or differently, selected from the group consisting of: cyclopentylene, cyclohexylene, phenylene, pyridylene, pyrimidinylene, triazinylene, naphthylene, phenanthrylene, anthrylene, fluorenylidene, silafluorenylidene, quinolylene, isoquinolylene, dithiophenylene, difurylene, benzofurylene, benzothienylene, dibenzofurylene, dibenzothienylene, triphenylenylene, carbazolylene, azacarbazolylene, azafluorenylidene, azasilafluorenylidene, azadibenzofurylene, azadibenzothienylene and combinations thereof; optionally, hydrogens in the above groups are partially or fully deuterated.

According to an embodiment of the present disclosure, wherein, R_{w} is, at each occurrence identically or differently, selected from the group consisting of A-1 to A-194, wherein the specific structures of A-1 to A-194 are referred to claim 10.

According to an embodiment of the present disclosure, wherein, hydrogens in A-1 to A-194 can be partially or fully deuterated, and the specific structures of A-1 to A-194 are referred to claim 10.

According to an embodiment of the present disclosure, wherein, in Formula 3 and Formula 3A, R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, wherein, in Formula 3 and Formula 3A, R_{y} is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 11 carbon atoms, substituted or unsubstituted alkylsilyl having 3 to 6 carbon atoms, cyano and combinations thereof.

According to an embodiment of the present disclosure, wherein, in Formula 3, R_{y} is, at each occurrence identically or differently, selected from the group consisting of: hydrogen, deuterium, fluorine, substituted or unsubstituted alkyl having 1 to 6 carbon atoms and substituted or unsubstituted aryl having 6 to 12 carbon atoms.

According to an embodiment of the present disclosure, wherein, in Formula 3 and Formula 3A, R_{y} is, at each occurrence identically or differently, selected from the group consisting of: hydrogen, deuterium, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl and combinations thereof.

According to an embodiment of the present disclosure, wherein, in Formula 3 and Formula 3A, at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein, in Formula 3 and Formula 3A, at least one or at least two of R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₅ to R₈ is at least 4.

According to an embodiment of the present disclosure, wherein, in Formula 3 and Formula 3A, at least one or at least two of R₆ and R₇ are selected from substituted or unsubstituted alkyl having 1 to 20 carbon atoms, substituted or unsubstituted cycloalkyl having 3 to 20 ring carbon atoms or a combination thereof, and the total number of carbon atoms in both of R₆ and R₇ is at least 4.

According to an embodiment of the present disclosure, wherein, in Formula 3 and Formula 3A, R₇ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, wherein, in Formula 3 and Formula 3A, R₇ is selected from substituted or unsubstituted alkyl having 4 to 20 carbon atoms, substituted or unsubstituted cycloalkyl having 4 to 20 ring carbon atoms or a combination thereof.

According to an embodiment of the present disclosure, wherein, in Formula 3 and Formula 3A, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein, in Formula 3 and Formula 3A, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, wherein, in Formula 3 and Formula 3A, at least one, at least two, at least three or all of R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof.

According to an embodiment of the present disclosure, wherein, R′ is selected from substituted or unsubstituted alkyl having 1 to 20 carbon atoms or substituted or unsubstituted cycloalkyl having 3 to 20 ring carbon atoms.

According to an embodiment of the present disclosure, wherein, R′ is selected from methyl or deuterated methyl.

According to an embodiment of the present disclosure, wherein, Lₐ is, at each occurrence identically or differently, selected from the group consisting of Lₐ₁ to Lₐ₇₇₀, wherein the specific structures of Lₐ₁ to Lₐ₇₇₀ are referred to claim 14.

According to an embodiment of the present disclosure, wherein, hydrogens in the structures of Lₐ₁ to Lₐ₇₇₀ can be partially or fully deuterated, wherein the specific structures of Lₐ₁ to Lₐ₇₇₀ are referred to claim 14.

According to an embodiment of the present disclosure, wherein, L_{b} is, at each occurrence identically or differently, selected from the group consisting of L_{b1} to L_{b329}, wherein the specific structures of L_{b1} to L_{b329} are referred to claim 15.

According to an embodiment of the present disclosure, wherein, hydrogens in the structures of L_{b1} to L_{b329} can be partially or fully deuterated, wherein the specific structures of L_{b1} to L_{b329} are referred to claim 15.

According to an embodiment of the present disclosure, wherein, L_{c} is, at each occurrence identically or differently, selected from the group consisting of L_{c1} to L_{c360}, wherein the specific structures of L_{c1} to L_{c360} are referred to claim 16.

According to an embodiment of the present disclosure, wherein, the metal complex has a structure of Ir(Lₐ)₂(L_{b}), wherein Lₐ is, at each occurrence identically or differently, selected from any one or any two of the group consisting of Lₐ₁ to Lₐ₇₇₀ and L_{b} is selected from any one of the group consisting of L_{b1} to L_{b329}, wherein the specific structures of Lₐ₁ to Lₐ₇₇₀ are referred to claim 14 and the specific structures of L_{b1} to L_{b329} are referred to claim 15.

According to an embodiment of the present disclosure, wherein, the metal complex has a structure of Ir(Lₐ)(L_{b})₂, wherein Lₐ is, at each occurrence identically or differently, selected from any one of the group consisting of Lₐ₁ to Lₐ₇₇₀ and L_{b} is selected from any one or any two of the group consisting of L_{b1} to L_{b329}, wherein the specific structures of Lₐ₁ to Lₐ₇₇₀ are referred to claim 14 and the specific structures of L_{b1} to L_{b329} are referred to claim 15.

According to one embodiment of the present disclosure, wherein, the metal complex has a structure of Ir(Lₐ)₃, wherein Lₐ is, at each occurrence identically or differently, selected from any one or any two or any three of the group consisting of Lₐ₁ to Lₐ₇₇₀, wherein the specific structures of Lₐ₁ to Lₐ₇₇₀ are referred to claim 14.

According to an embodiment of the present disclosure, wherein, the metal complex has a structure of Ir(Lₐ)₂(L_{c}), wherein Lₐ is, at each occurrence identically or differently, selected from any one or any two of the group consisting of Lₐ₁ to Lₐ₇₇₀ and L_{c} is selected from any one of the group consisting of L_{c1} to L_{c360}, wherein the specific structures of Lₐ₁ to Lₐ₇₇₀ are referred to claim 14 and the specific structures of L_{c1} to L_{c360} are referred to claim 16.

According to an embodiment of the present disclosure, wherein, the metal complex has a structure of Ir(Lₐ)(L_{c})₂, wherein Lₐ is, at each occurrence identically or differently, selected from any one of the group consisting of Lₐ₁ to Lₐ₇₇₀ and L_{c} is selected from any one or any two of the group consisting of L_{c1} to L_{c360}, wherein the specific structures of Lₐ₁ to Lₐ₇₇₀ are referred to claim 14 and the specific structures of L_{c1} to L_{c360} are referred to claim 16.

According to an embodiment of the present disclosure, wherein, the metal complex has a structure of Ir(Lₐ)(L_{b})(L_{c}), wherein Lₐ is, at each occurrence identically or differently, selected from any one of the group consisting of Lₐ₁ to Lₐ₇₇₀, L_{b} is selected from any one of the group consisting of L_{b1} to L_{b329}, and L_{c} is selected from any one of the group consisting of L_{c1} to L_{c360}, wherein the specific structures of Lₐ₁ to Lₐ₇₇₀ are referred to claim 14, the specific structures of L_{b1} to L_{b329} are referred to claim 15, and the specific structures of L_{c1} to L_{c360} are referred to claim 16.

According to an embodiment of the present disclosure, wherein, the metal complex is selected from the group consisting of Metal Complex 1 to Metal Complex 1578, wherein the specific structures of Metal Complex 1 to Metal Complex 1578 are referred to claim 17.

According to an embodiment of the present disclosure, wherein, hydrogens in the structures of Metal Complex 1 to Metal Complex 1578 can be partially or fully deuterated, wherein the specific structures of Metal Complex 1 to Metal Complex 1578 are referred to claim 17.

According to an embodiment of the present disclosure, disclosed is an electroluminescent device. The electroluminescent device comprises:

an anode,

a cathode, and

an organic layer disposed between the anode and the cathode, wherein the organic layer comprises the metal complex in any one of the preceding embodiments.

According to an embodiment of the present disclosure, in the electroluminescent device, the organic layer comprising the metal complex is a light-emitting layer.

According to an embodiment of the present disclosure, wherein the electroluminescent device emits green light.

According to an embodiment of the present disclosure, wherein the electroluminescent device emits white light.

According to an embodiment of the present disclosure, in the electroluminescent device, the light-emitting layer comprises a first host compound.

According to an embodiment of the present disclosure, in the electroluminescent device, the light-emitting layer comprises a first host compound and a second host compound.

According to an embodiment of the present disclosure, in the electroluminescent device, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, wherein, the first host compound has a structure represented by Formula 4:

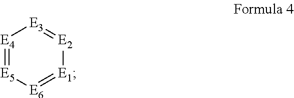

wherein

E₁ to E₆ are, at each occurrence identically or differently, selected from C, CRₑ or N, at least two of E₁ to E₆ are N, and at least one of E₁ to E₆ is C and joined to Formula A;

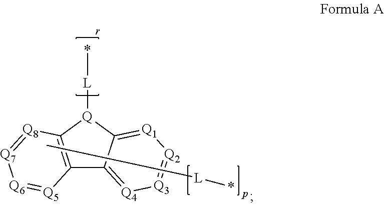

wherein

Q is, at each occurrence identically or differently, selected from the group consisting of O, S, Se, N, NR′″, CR′″R′″, SiR′″R′″, GeR′″R′″ and R′″C═CR′″; when two R′″ are present at the same time, the two R′″ may be the same or different;

p is 0 or 1; r is 0 or 1;

when Q is selected from N, p is 0 and r is 1;

when Q is selected from the group consisting of O, S, Se, NR′″, CR′″R′″, SiR′″R′″, GeR′″R′″ and R′″C═CR′″, p is 1 and r is 0;

L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;

Q₁ to Q₈ are, at each occurrence identically or differently, selected from C, CR_{q} or N;

Rₑ, R′″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

“*” represents a position where Formula A is joined to Formula 4; and

adjacent substituents Rₑ, R′″, R_{q} can be optionally joined to form a ring.

In the present disclosure, the expression that “adjacent substituents Rₑ, R′″, R_{q} can be optionally joined to form a ring” is intended to mean that any one or at least two of groups of adjacent substituents, such as two substituents Rₑ, two substituents R′″, two substituents R_{q} and substituents R′″ and R_{q}, can be joined to form a ring. Obviously, it is possible that none of these substituents are joined to form a ring.

According to an embodiment of the present disclosure, wherein, Q is, at each occurrence identically or differently, selected from O, S, N or NR′″.

According to an embodiment of the present disclosure, wherein, E₁ to E₆ are, at each occurrence identically or differently, selected from C, CRₑ or N, three of E₁ to E₆ are N, at least one of E₁ to E₆ is CRₑ, and Rₑ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof.

According to an embodiment of the present disclosure, wherein, E₁ to E₆ are, at each occurrence identically or differently, selected from C, CRₑ or N, three of E₁ to E₆ are N, at least one of E₁ to E₆ is CRₑ, and Rₑ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylene, substituted or unsubstituted fluorenyl, substituted or unsubstituted dibenzofuryl, substituted or unsubstituted dibenzothienyl, substituted or unsubstituted carbazolyl or a combination thereof.

According to an embodiment of the present disclosure, wherein Rₑ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof.

According to an embodiment of the present disclosure, wherein Rₑ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylene, substituted or unsubstituted fluorenyl, substituted or unsubstituted dibenzofuryl, substituted or unsubstituted dibenzothienyl, substituted or unsubstituted carbazolyl or a combination thereof.

According to an embodiment of the present disclosure, wherein, at least one or at least two of Q₁ to Q₈ are selected from CR_{q}, and R_{q} is selected from substituted or unsubstituted aryl having 6 to 30 carbon atoms, substituted or unsubstituted heteroaryl having 5 to 30 carbon atoms or a combination thereof.

According to an embodiment of the present disclosure, wherein, at least one or at least two of Q₁ to Q₈ are selected from CR_{q}, and R_{q} is selected from substituted or unsubstituted phenyl, substituted or unsubstituted naphthyl, substituted or unsubstituted biphenyl, substituted or unsubstituted terphenyl, substituted or unsubstituted pyridyl or a combination thereof.

According to an embodiment of the present disclosure, wherein R′″ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof.

According to an embodiment of the present disclosure, wherein R′″ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylene, substituted or unsubstituted fluorenyl, substituted or unsubstituted dibenzofuryl, substituted or unsubstituted dibenzothienyl, substituted or unsubstituted carbazolyl or a combination thereof.

According to an embodiment of the present disclosure, wherein L is, at each occurrence identically or differently, selected from a single bond, substituted or unsubstituted arylene having 6 to 20 carbon atoms, substituted or unsubstituted heteroarylene having 3 to 20 carbon atoms or a combination thereof.

According to an embodiment of the present disclosure, wherein L is, at each occurrence identically or differently, selected from a single bond, substituted or unsubstituted phenylene, substituted or unsubstituted biphenylene, substituted or unsubstituted carbazolylene, substituted or unsubstituted dibenzofurylene, substituted or unsubstituted dibenzothienylene or substituted or unsubstituted fluorenylidene.

According to an embodiment of the present disclosure, L is, at each occurrence identically or differently, selected from a single bond, substituted or unsubstituted phenylene or substituted or unsubstituted biphenylene.

According to an embodiment of the present disclosure, the first host compound is selected from the group consisting of H-1 to H-243, wherein the specific structures of H-1 to H-243 are referred to claim 23.

According to an embodiment of the present disclosure, in the electroluminescent device, the second host compound has a structure represented by Formula 5:

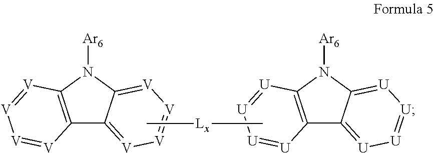

wherein

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;

V is, at each occurrence identically or differently, selected from C, CRᵥ or N, and at least one of V is C and joined to Lₓ;

U is, at each occurrence identically or differently, selected from C, CRᵤ or N, and at least one of U is C and joined to Lₓ;

Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Ar₆ is, at each occurrence identically or differently, selected from substituted or unsubstituted aryl having 6 to 30 carbon atoms, substituted or unsubstituted heteroaryl having 3 to 30 carbon atoms or a combination thereof; and

adjacent substituents Rᵥ and Rᵤ can be optionally joined to form a ring.

In this embodiment, the expression that “adjacent substituents Rᵥ and Rᵤ can be optionally joined to form a ring” is intended to mean that any one or more of groups of adjacent substituents, such as two substituents Rᵥ, two substituents Rᵤ, and substituents Rᵥ and Rᵤ, can be joined to form a ring. Obviously, it is possible that none of these substituents are joined to form a ring.

According to an embodiment of the present disclosure, in the electroluminescent device, the second host compound has a structure represented by one of Formula 5-a to Formula 5-j:

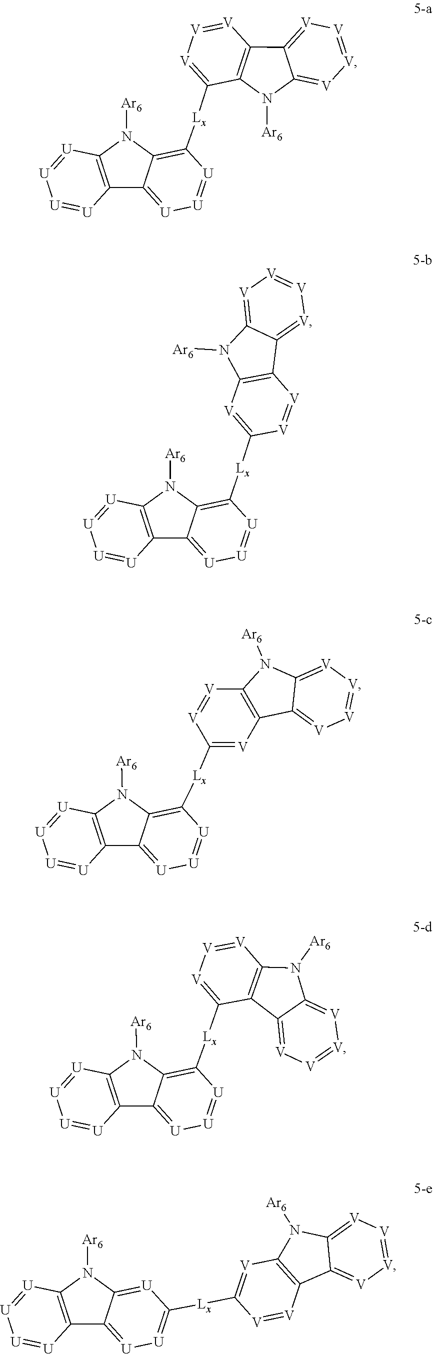

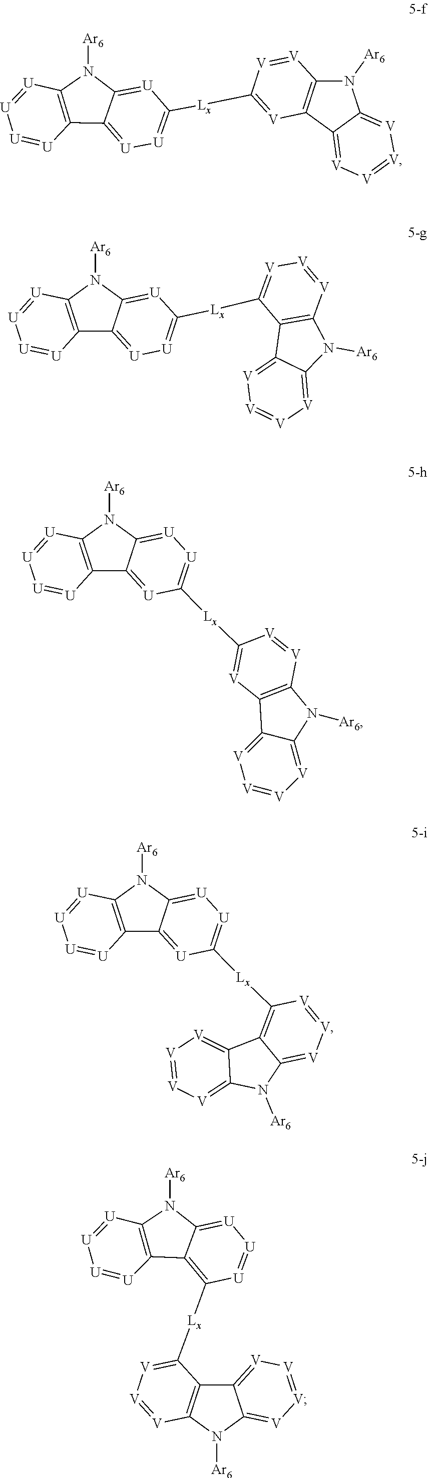

wherein

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;

V is, at each occurrence identically or differently, selected from CRᵥ or N;

U is, at each occurrence identically or differently, selected from CRᵤ or N;

Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Ar₆ is, at each occurrence identically or differently, selected from substituted or unsubstituted aryl having 6 to 30 carbon atoms, substituted or unsubstituted heteroaryl having 3 to 30 carbon atoms or a combination thereof; and

adjacent substituents Rᵥ and Rᵤ can be optionally joined to form a ring.

According to an embodiment of the present disclosure, the second host compound is selected from the group consisting of X-1 to X-150, wherein the specific structures of X-1 to X-150 are referred to claim 25.

According to an embodiment of the present disclosure, in the electroluminescent device, the metal complex is doped in the first host compound and the second host compound, and the weight of the metal complex accounts for 1% to 30% of the total weight of the light-emitting layer.

According to an embodiment of the present disclosure, in the electroluminescent device, the metal complex is doped in the first host compound and the second host compound, and the weight of the metal complex accounts for 3% to 13% of the total weight of the light-emitting layer.

According to another embodiment of the present disclosure, disclosed is a compound combination comprising the metal complex in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### MATERIAL SYNTHESIS EXAMPLE

The method for preparing a compound in the present disclosure is not limited herein. Typically, the following compounds are used as examples without limitations, and synthesis routes and preparation methods thereof are described below.

### Synthesis Example 1: Synthesis of Metal Complex 493

Step 1:

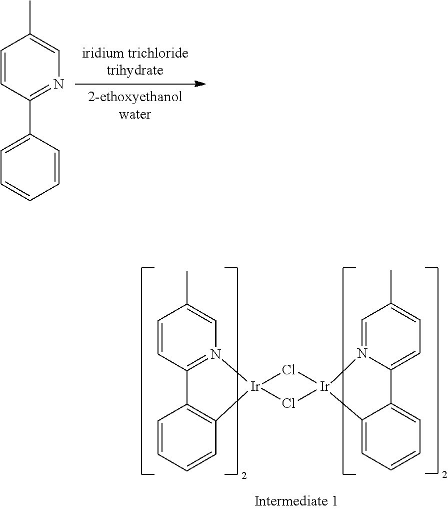

5-Methyl-2-phenylpyridine (10.0 g, 59.2 mmol), iridium trichloride trihydrate (5.0 g, 14.2 mmol), 300 mL of 2-ethoxyethanol and 100 mL of water were sequentially added to a dry 500 mL round-bottom flask, purged with nitrogen three times, and heated and stirred for 24 h at 130° C. under nitrogen protection. The solution was cooled, filtered, washed three times with methanol and n-hexane respectively, and pumped to dryness to obtain 7.5 g of Intermediate 1 as a yellow solid (with a yield of 97%).

Step 2:

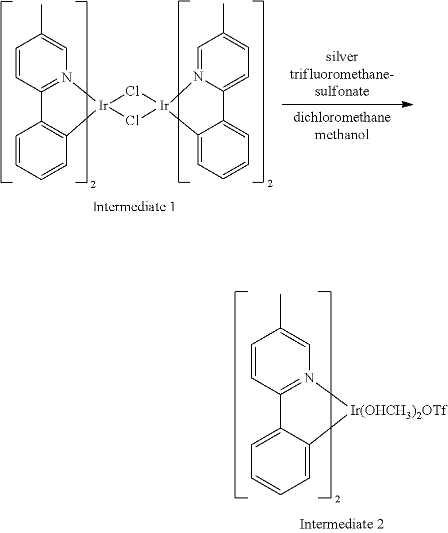

Intermediate 1 (7.5 g, 6.8 mmol), 250 mL of anhydrous dichloromethane, 10 mL of methanol and silver trifluoromethanesulfonate (3.8 g, 14.8 mmol) were sequentially added to a dry 500 mL round-bottom flask, purged with nitrogen three times, and stirred overnight at room temperature under nitrogen protection. The solution was filtered through Celite and washed twice with dichloromethane. The organic phases below were collected and concentrated under reduced pressure to obtain 9.2 g of Intermediate 2 (with a yield of 93%).

Step 3:

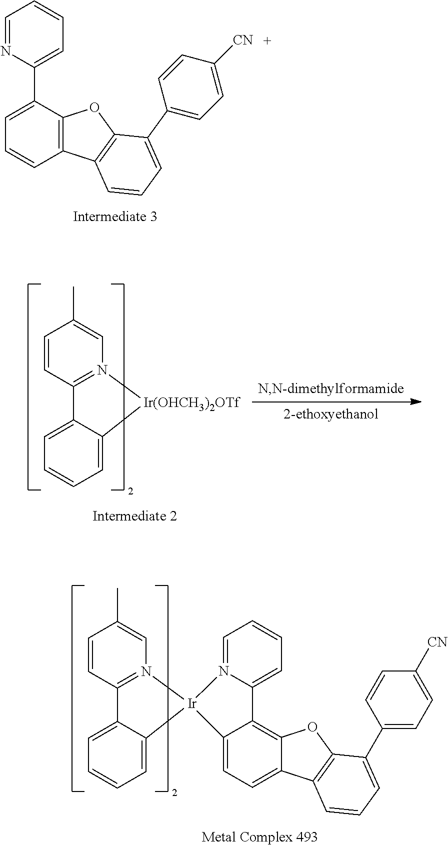

Intermediate 3 (3.0 g, 8.6 mmol), Intermediate 2 (3.7 g, 5.8 mmol), 50 mL of 2-ethoxyethanol and 50 mL of N,N-dimethylformamide were sequentially added to a dry 250 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved in dichloromethane. The organic phases were collected, concentrated under reduced pressure, and purified through column chromatography to obtain Metal Complex 493 as a yellow solid (2.20 g with a yield of 43.4%). The product was confirmed as the target product with a molecular weight of 874.2.

### Synthesis Example 2: Synthesis of Metal Complex 735

Step 1:

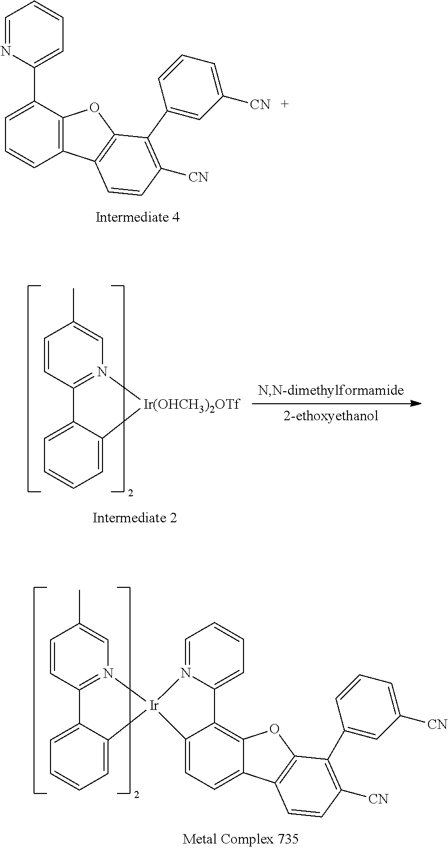

Intermediate 4 (1.5 g, 4.0 mmol), Intermediate 2 (2.1 g, 2.9 mmol), 50 mL of 2-ethoxyethanol and 50 mL of N,N-dimethylformamide were sequentially added to a dry 250 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved in dichloromethane. The organic phases were collected, concentrated under reduced pressure, and purified through column chromatography to obtain Metal Complex 735 as a yellow solid (1.1 g with a yield of 42.6%). The product was confirmed as the target product with a molecular weight of 899.2.

### Synthesis Example 3: Synthesis of Metal Complex 975

Step 1:

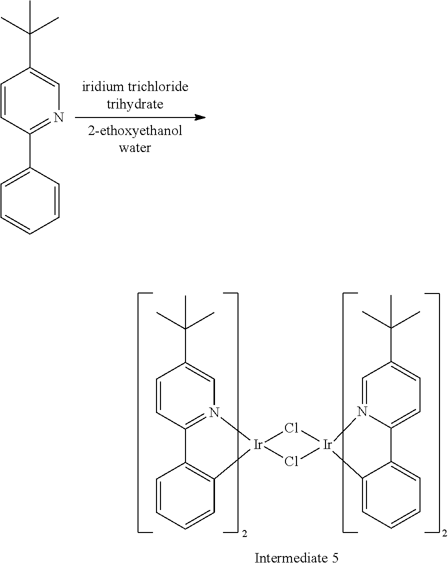

5-T-butyl-2-phenylpyridine (13.2 g, 62.9 mmol), iridium trichloride trihydrate (5.5 g, 15.7 mmol), 300 mL of 2-ethoxyethanol and 100 mL of water were sequentially added to a dry 500 mL round-bottom flask, purged with nitrogen three times, and heated and stirred for 24 h at 130° C. under nitrogen protection. The solution was cooled, filtered, washed three times with methanol and n-hexane respectively, and pumped to dryness to obtain 9.7 g of Intermediate 5 (with a yield of 97%).

Step 2:

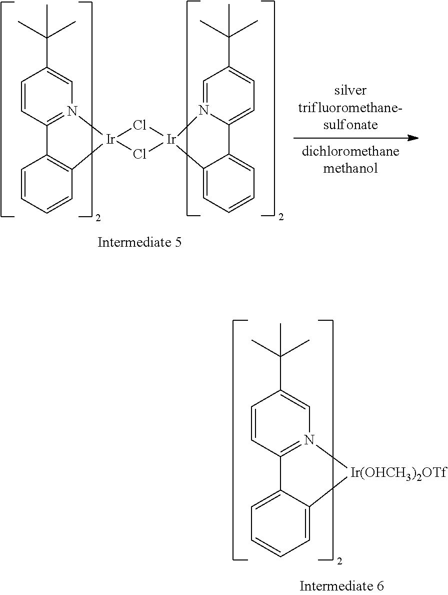

Intermediate 5 (9.7 g, 7.7 mmol), 250 mL of anhydrous dichloromethane, 10 mL of methanol and silver trifluoromethanesulfonate (4.3 g, 16.7 mmol) were sequentially added to a dry 500 mL round-bottom flask, purged with nitrogen three times, and stirred overnight at room temperature under nitrogen protection. The solution was filtered through Celite and washed twice with dichloromethane. The organic phases below were collected and concentrated under reduced pressure to obtain 13.2 g of Intermediate 6 as a yellow solid (with a yield of 93%).

Step 3:

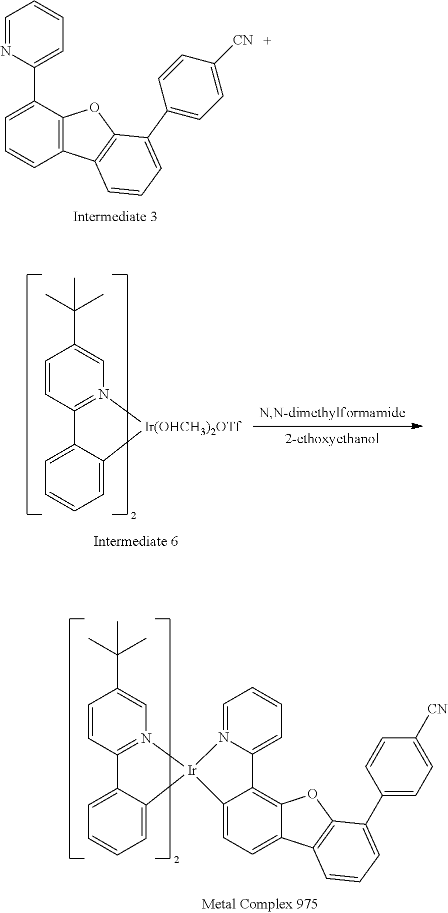

Intermediate 3 (1.2 g, 3.5 mmol), Intermediate 6 (2.0 g, 2.5 mmol), 50 mL of 2-ethoxyethanol and 50 mL of N,N-dimethylformamide were sequentially added to a dry 250 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved in dichloromethane. The organic phases were collected, concentrated under reduced pressure, and purified through column chromatography to obtain Metal Complex 975 as a yellow solid (1.3 g with a yield of 54.3%). The product was confirmed as the target product with a molecular weight of 958.3.

### Synthesis Example 4: Synthesis of Metal Complex 1192

Step 1:

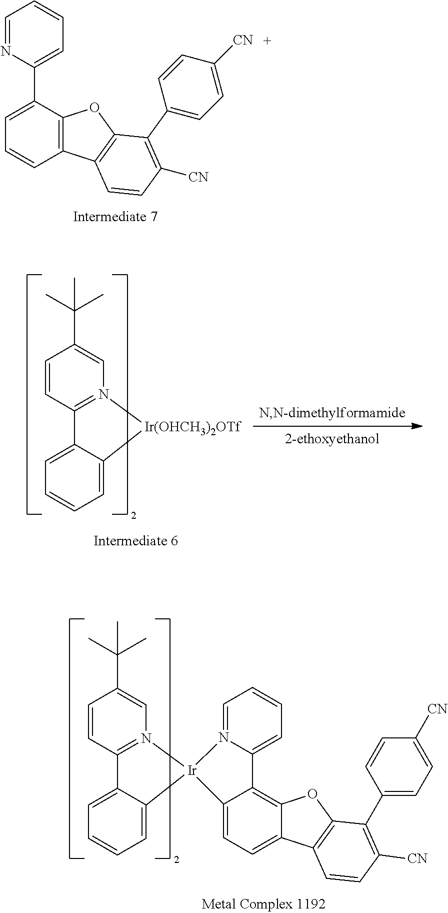

Intermediate 7 (1.5 g, 4.0 mmol), Intermediate 6 (2.2 g, 2.7 mmol), 50 mL of 2-ethoxyethanol and 50 mL of N,N-dimethylformamide were sequentially added to a dry 250 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved in dichloromethane. The organic phases were collected, concentrated under reduced pressure, and purified through column chromatography to obtain Metal Complex 1192 as a yellow solid (1.3 g with a yield of 50.0%). The product was confirmed as the target product with a molecular weight of 983.3.

Those skilled in the art will appreciate that the above preparation methods are merely exemplary. Those skilled in the art can obtain other compound structures of the present disclosure through the modifications of the preparation methods.

### Device Example 1-1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10⁻⁸ torr. Compound HI was used as a hole injection layer (HIL). Compound HT was used as a hole transporting layer (HTL). Compound H1 was used as an electron blocking layer (EBL). Metal Complex 493 of the present disclosure was doped in Compound H1 and Compound H2 as a dopant, and the resulting mixture was deposited for use as an emissive layer (EML). On the EML, Compound HB was used as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited as an electron injection layer with a thickness of 1 nm and Al was deposited as a cathode with a thickness of 120 nm. The device was transferred back to the glovebox and encapsulated with a glass lid to complete the device.

### Device Comparative Example 1-1

The implementation in Device Comparative Example 1-1 was the same as that in Device Example 1-1, except that in the EML, Metal Complex 493 of the present disclosure was replaced with Compound GD1.

### Device Comparative Example 1-2

The implementation in Device Comparative Example 1-2 was the same as that in Device Example 1-1, except that in the EML, Metal Complex 493 of the present disclosure was replaced with Compound GD2.

Detailed structures and thicknesses of layers of the devices are shown in the following table. A layer using more than one material is obtained by doping different compounds at their weight ratio as recorded.

TABLE 1
Device structures in Example 1-1 and Comparative Examples 1-1 and 1-2

| Device ID | HIL | HTL | EBL | EML | HBL | ETL |
|---|---|---|---|---|---|---|
| Example 1-1 | Compound | Compound | Compound | Compound | Compound | Compound |
| | HI | HT | H1 | H1:Compound | HB | ET:Liq (40:60) |
| | (100 Å) | (350 Å) | (50 Å) | H2:Metal | (50 Å) | (350 Å) |
| | | | | Complex | | |
| | | | | 493(63:31:6) | | |
| | | | | (400 Å) | | |
| Comparative | Compound | Compound | Compound | Compound | Compound | Compound |
| Example 1-1 | HI | HT | H1 | H1:Compound | HB | ET:Liq (40:60) |
| | (100 Å) | (350 Å) | (50 Å) | H2:Compound | (50 Å) | (350 Å) |
| | | | | GDI (63:31:6) | | |
| | | | | (400 Å) | | |
| Comparative | Compound | Compound | Compound | Compound | Compound | Compound |
| Example 1-2 | HI | HT | H1 | H1:Compound | HB | ET:Liq (40:60) |
| | (100 Å) | (350 Å) | (50 Å) | H2:Compound | (50 Å) | (350 Å) |
| | | | | GD2 (63:31:6) | | |
| | | | | (400 Å) | | |

The structures of the materials used in the devices are shown as follows:

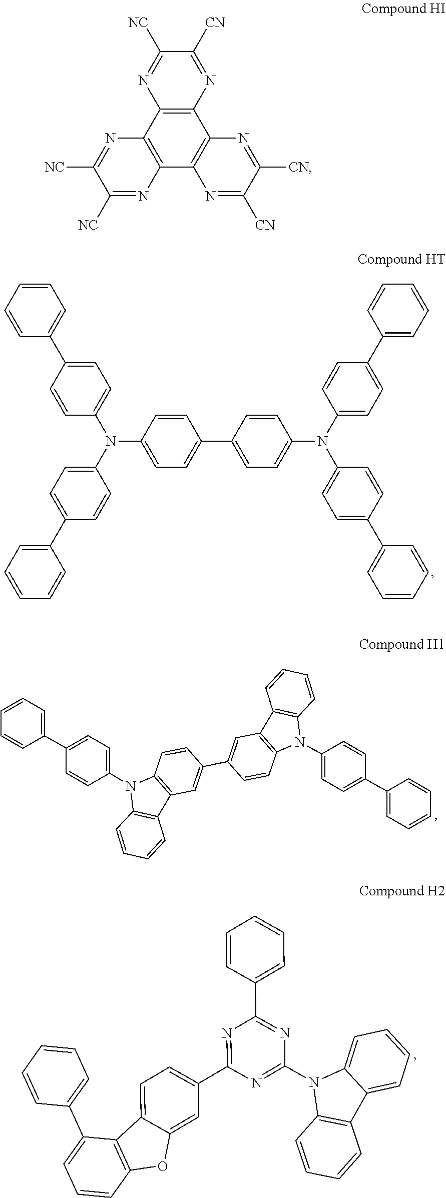 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

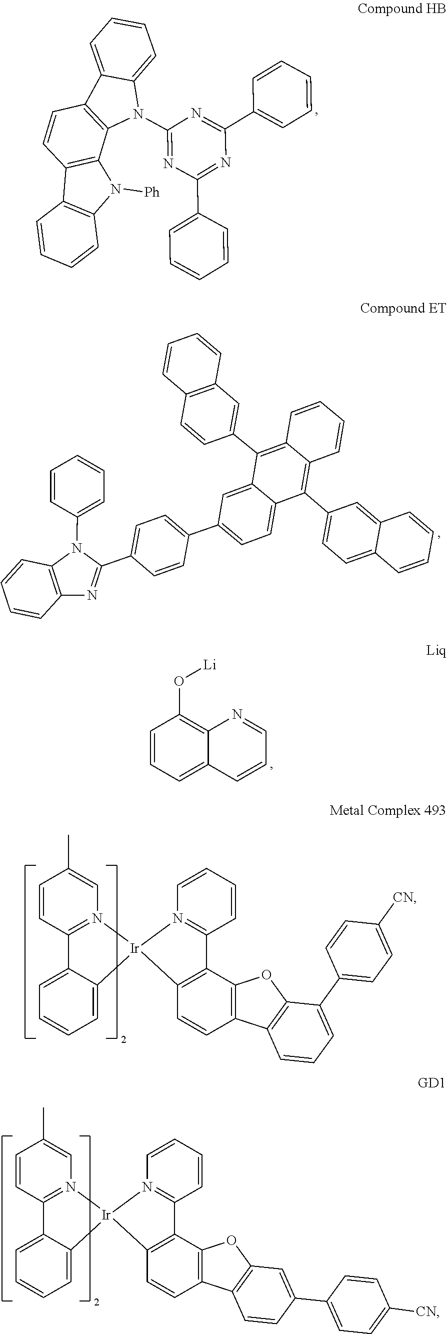

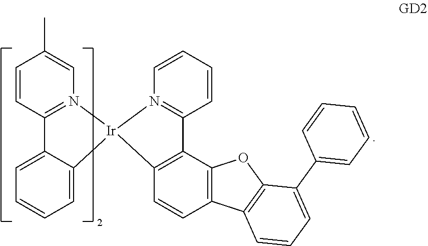

Current-voltage-luminance (IVL) characteristics of the devices were measured. The CIE data, maximum emission wavelength λₘₐₓ, voltage (V), current efficiency (CE) and power efficiency (PE) of each device were measured at 1000 cd/m². Data about external quantum efficiency (EQE) was measured at a constant current of 15 mA/cm². The data was recorded and shown in Table 2.

TABLE 2
Device data of Examples 1-1 and
Comparative Examples 1-1 and 1-2

| | | λₘₐₓ | Voltage | CE | PE | EQE |
|---|---|---|---|---|---|---|
| Device ID | CIE (x, y) | (nm) | (V) | (cd/A) | (lm/W) | (%) |
| Example 1-1 | (0.348, 0.626) | 530 | 2.67 | 104 | 123 | 24.81 |
| Comparative | (0.372, 0.611) | 538 | 2.76 | 104 | 119 | 22.53 |
| Example 1-1 | | | | | | |
| Comparative | (0.352, 0.623) | 528 | 2.84 | 95 | 105 | 22.36 |
| Example 1-2 | | | | | | |

Table 2 shows the device performance of the metal complex of the present disclosure and the comparative compounds. Example 1-1 differs from Comparative Example 1-1 only in that a substituent containing cyano is located at a different position of the ligand Lₐ of the metal complex. Compared with Comparative Example 1-1, Example 1-1 has a slightly reduced driving voltage, slightly improved PE and EQE significantly improved by 10.1%. Example 1-1 differs from Comparative Example 1-2 only in that whether a substituent at position X₈ of the ligand Lₐ of the metal complex contains cyano. Compared with Comparative Example 1-2, Example 1-1 has a device voltage reduced by 0.17 V and CE, PE and EQE that are improved by 9.5%, 17.1% and 11.0%, respectively.

The above data indicates that the metal complex of the present disclosure comprising a substituent containing cyano at a particular position of Lₐ has significantly better device efficiency and performance than the metal complexes in the comparative examples and can significantly improve the overall performance of the device.

### Device Example 2-1

The implementation in Device Example 2-1 was the same as that in Device Example 1-1, except that in the EML, Metal Complex 493 of the present disclosure was replaced with Metal Complex 975 of the present disclosure.

### Device Example 2-2

The implementation in Device Example 2-2 was the same as that in Device Example 1-1, except that in the EML, Metal Complex 493 of the present disclosure was replaced with Metal Complex 1192 of the present disclosure.

### Device Comparative Example 2-1

The implementation in Device Comparative Example 2-1 was the same as that in Device Example 1-1, except that in the EL, Metal Complex 493 of the present disclosure was replaced with Compound GD3.

### Device Comparative Example 2-2

The implementation in Device Comparative Example 2-2 was the same as that in Device Example 1-1, except that in the EL, Metal Complex 493 of the present disclosure was replaced with Compound GD4.

Detailed structures and thicknesses of layers of the devices are shown in the following table. A layer using more than one material is obtained by doping different compounds at their weight ratio as recorded.

TABLE 3
Device structures in Examples 2-1 and 2-2 and Comparative Examples 2-1 and 2-2

| Device ID | HIL | HTL | EBL | EML | HBL | ETL |
|---|---|---|---|---|---|---|
| Example 2-1 | Compound | Compound | Compound | Compound | Compound | Compound |
| | HI | HT | H1 | H1:Compound | HB | ET:Liq (40:60) |
| | (100 Å) | (350 Å) | (50 Å) | H2:Metal | (50 Å) | (350 Å) |
| | | | | Complex 975 | | |
| | | | | (63:31:6) | | |
| | | | | (400 Å) | | |
| Example 2-2 | Compound | Compound | Compound | Compound | Compound | Compound |
| | HI | HT | H1 | H1:Compound | HB | ET:Liq (40:60) |
| | (100 Å) | (350 Å) | (50 Å) | H2:Metal | (50 Å) | (350 Å) |
| | | | | Complex 1192 | | |
| | | | | (63:31:6) | | |
| | | | | (400 Å) | | |
| Comparative | Compound | Compound | Compound | Compound | Compound | Compound |
| Example 2-1 | HI | HT | H1 | H1:Compound | HB | ET:Liq (40:60) |
| | (100 Å) | (350 Å) | (50 Å) | H2:Compound | (50 Å) | (350 Å) |
| | | | | GD3 (63:31:6) | | |
| | | | | (400 Å) | | |
| Comparative | Compound | Compound | Compound | Compound | Compound | Compound |
| Example 2-2 | HI | HT | H1 | H1:Compound | HB | ET:Liq (40:60) |
| | (100 Å) | (350 Å) | (50 Å) | H2:Compound | (50 Å) | (350 Å) |
| | | | | GD4 (63:31:6) | | |
| | | | | (400 Å) | | |

The structures of the new materials used in the devices are shown as follows:

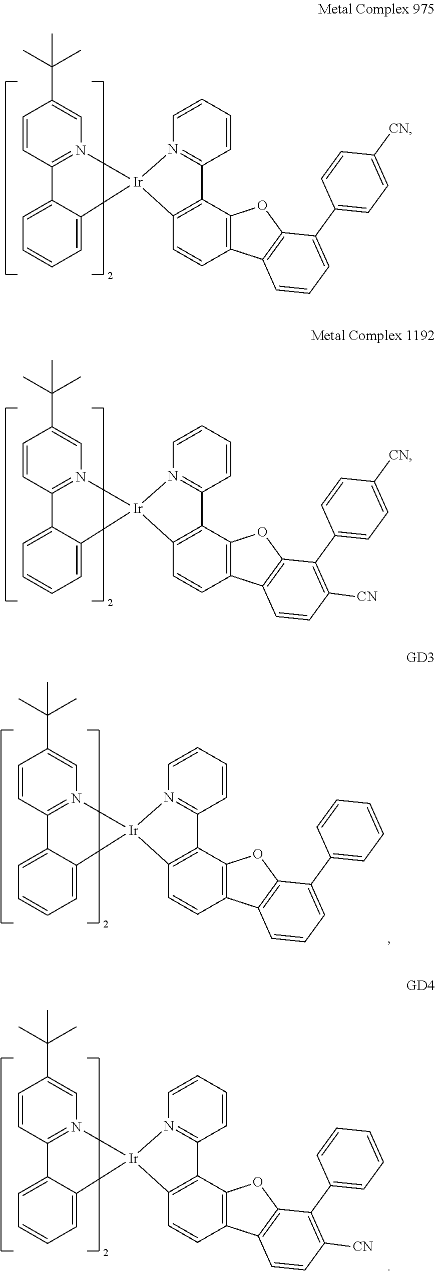

IVL characteristics of the devices were measured. The CIE data, maximum emission wavelength λₘₐₓ, voltage (V), current efficiency (CE), power efficiency (PE) and external quantum efficiency (EQE) of each device were measured at 1000 cd/m². The data was recorded and shown in Table 4.

TABLE 4
Device data of Examples 2-1 and 2-2
and Comparative Examples 2-1 and 2-2

| | | λₘₐₓ | Voltage | CE | PE | EQE |
|---|---|---|---|---|---|---|
| Device ID | CIE (x, y) | (nm) | (V) | (cd/A) | (lm/W) | (%) |
| Example 2-1 | (0.351, 0.625) | 531 | 2.69 | 109 | 127 | 28.07 |
| Comparative | (0.353, 0.623) | 531 | 3.11 | 94 | 95 | 24.33 |
| Example 2-1 | | | | | | |
| Example 2-2 | (0.361, 0.622) | 537 | 2.59 | 112 | 136 | 28.33 |
| Comparative | (0.342, 0.635) | 531 | 2.70 | 104 | 121 | 26.21 |
| Example 2-2 | | | | | | |

Table 4 shows the device performance of the metal complexes of the present disclosure and the comparative compounds. Example 2-1 differs from Comparative Example 2-1 only in that whether the substituent at position X₈ of the ligand Lₐ of the metal complex contains cyano. Example 2-2 differs from Comparative Example 2-2 only in that whether the substituent at position X₈ of the ligand Lₐ of the metal complex contains cyano. Compared with Comparative Example 2-1, Example 2-1 has a driving voltage reduced by 0.42 V and CE, PE and EQE that are significantly improved by 15.9%, 33.7% and 15.4%, respectively. Compared with Comparative Example 2-2, Example 2-2 has a driving voltage reduced by 0.11 V, CE and PE that are both improved by about 5%, and EQE improved by 8.1%.

The above data indicates that the metal complex of the present disclosure comprising a substituent containing cyano at a particular position of Lₐ has significantly better device efficiency and performance than the metal complexes in the comparative examples and can significantly improve the overall performance of the device.

As can be seen from the examples and comparative examples discussed above, the metal complex of the present disclosure comprising the substituent containing cyano at position X₈ of the ligand Lₐ can significantly improve device performance compared with the metal complexes in the comparative examples. The observed advantages of the compounds of the present disclosure are completely unexpected, which is impossible to predict even for a person skilled in the art.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein the metal M is selected from a metal with a relative atomic mass greater than 40, and the ligand Lₐ has a structure represented by Formula 1: 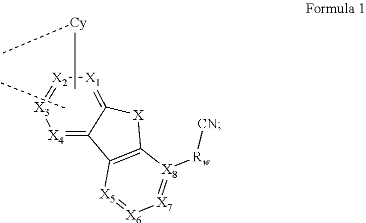
wherein in Formula 1,
Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;
X is selected from the group consisting of O, S, Se, NR′, CR′R′, SiR′R′ and GeR′R′, wherein when two R′ are present at the same time, the two R′ are the same or different;
X₁ to X₄ are, at each occurrence identically or differently, selected from C, CRₓ or N, and at least one of X₁ to X₄ is C and joined to the Cy;
X₅ to X₇ are, at each occurrence identically or differently, selected from CRₓ or N;
X₈ is selected from C;
X₁, X₂, X₃ or X₄ is joined to the metal M by a metal-carbon bond or a metal-nitrogen bond;
R′ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof; and
adjacent substituents R′, R_{w}, Rₓ can be optionally joined to form a ring.

2. The metal complex of claim 1, wherein Cy is any structure selected from the group consisting of: 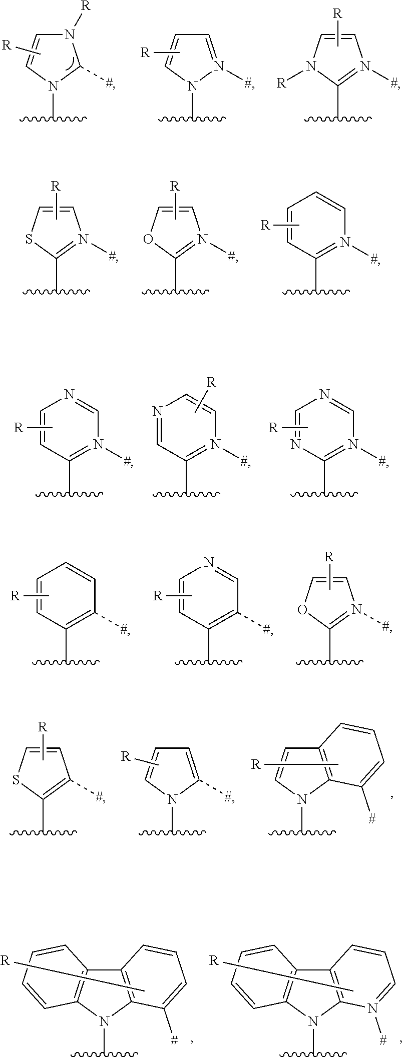
wherein
R represents, at each occurrence identically or differently, mono-substitution, multiple substitutions or non-substitution; and when multiple R are present at the same time in any structure, the multiple R are the same or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
two adjacent substituents R can be optionally joined to form a ring; and
wherein “#” represents a position where Cy is joined to the metal M, and “┤” represents a position where Cy is joined to X₁, X₂, X₃ or X₄.

3. The metal complex of claim 1, wherein the metal complex has a general formula of M(Lₐ)ₘ(L_{b})ₙ(L_{c})_{q};
wherein
M is, at each occurrence identically or differently, selected from the group consisting of Cu, Ag, Au, Ru, Rh, Pd, Os, Ir and Pt; preferably, M is, at each occurrence identically or differently, selected from Pt or Ir;
Lₐ, L_{b} and L_{c} are a first ligand, a second ligand and a third ligand coordinated to the metal M, respectively, and L_{c} is the same as or different from Lₐ or L_{b}; wherein Lₐ, L_{b} and L_{c} can be optionally joined to form a multidentate ligand;
m is selected from 1, 2 or 3, n is selected from 0, 1 or 2, q is selected from 0, 1 or 2, and m+n+q equals an oxidation state of the metal M; wherein when m is greater than or equal to 2, multiple Lₐ are the same or different; when n is equal to 2, two L_{b} are the same or different; when q is equal to 2, two L_{c} are the same or different;
Lₐ is, at each occurrence identically or differently, selected from the group consisting of: 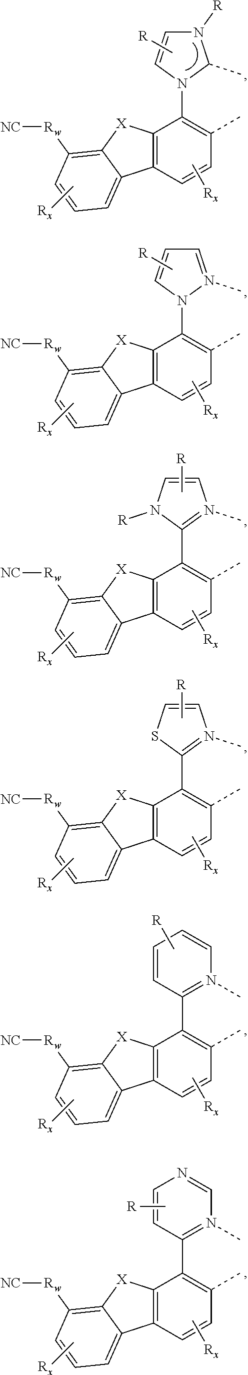 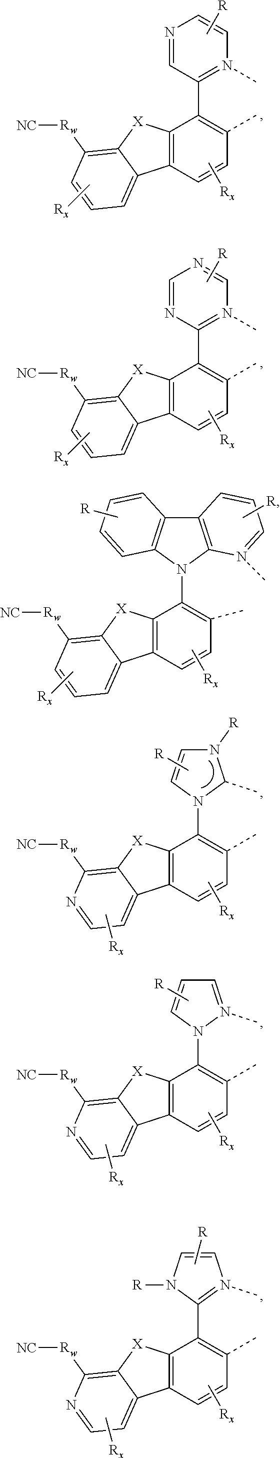 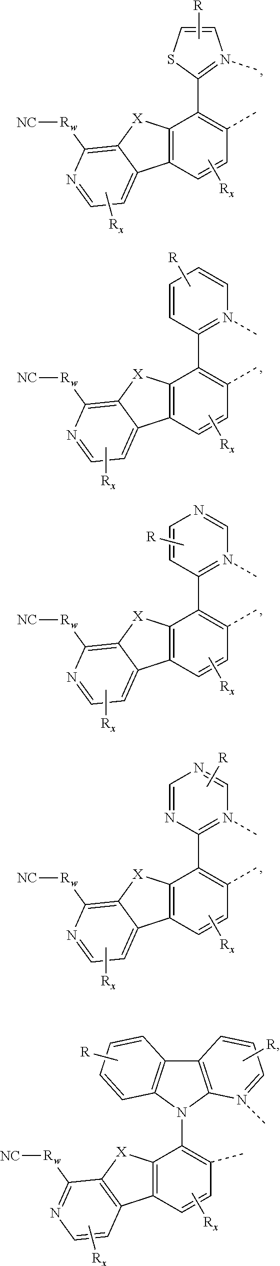 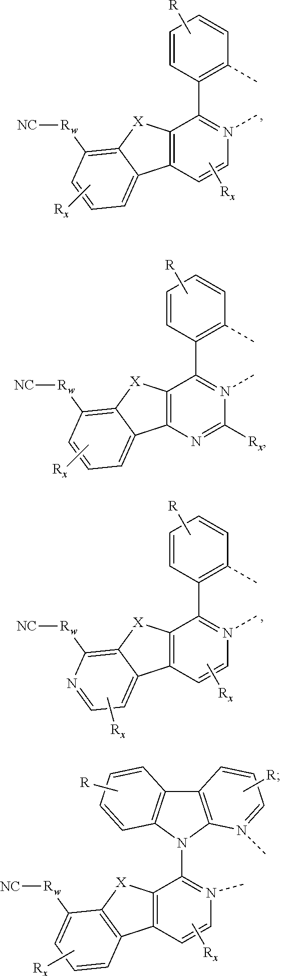
wherein
X is selected from the group consisting of O, S, Se, NR′, CR′R′, SiR′R′ and GeR′R′; wherein when two R′ are present at the same time, the two R′ are the same or different;
R and Rₓ represent, at each occurrence identically or differently, mono-substitution, multiple substitutions or non-substitution;
L_{b} and L_{c} are, at each occurrence identically or differently, selected from a structure represented by any one of the group consisting of: 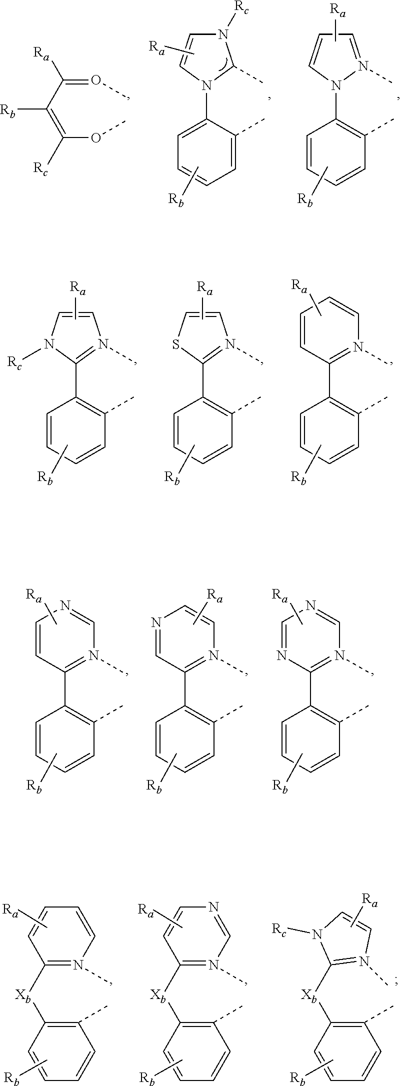
wherein
Rₐ and R_{b} represent, at each occurrence identically or differently, mono-substitution, multiple substitutions or non-substitution;
X_{b} is, at each occurrence identically or differently, selected from the group consisting of O, S, Se, NR_{N1} and CR_{C1}R_{C2};
R, R′, Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof;
adjacent substituents R, R′, R_{w} and Rₓ can be optionally joined to form a ring; and
adjacent substituents Rₐ, R_{b}, R_{c}, R_{N1}, R_{C1}, R_{C2} can be optionally joined to form a ring.

4. The metal complex of claim 1, wherein the metal complex Ir(Lₐ)ₘ(L_{b})₃₋ₘ has a structure represented by Formula 3: 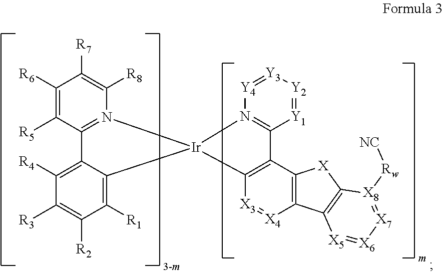
wherein
X is selected from the group consisting of O, S, Se, NR′, CR′R′, SiR′R′ and GeR′R′, wherein when two R′ are present at the same time, the two R′ are the same or different;
m is selected from 1, 2 or 3; when m is selected from 1, two L_{b} are the same or different; when m is selected from 2 or 3, multiple Lₐ are the same or different;
Y₁ to Y₄ are, at each occurrence identically or differently, selected from CR_{y} or N;
X₃ to X₇ are, at each occurrence identically or differently, selected from CRₓ or N;
X₈ is selected from C;
R′, R_{y} and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted alkyleneoxy having 1 to 20 carbon atoms, substituted or unsubstituted aryleneoxy having 6 to 30 carbon atoms, substituted or unsubstituted alkylsulfanylidene having 1 to 20 carbon atoms, substituted or unsubstituted arylsulfanylidene having 6 to 30 carbon atoms, substituted or unsubstituted alkenylene having 2 to 20 carbon atoms, substituted or unsubstituted alkynylene having 2 to 20 carbon atoms, substituted or unsubstituted arylene having 6 to 30 carbon atoms, substituted or unsubstituted heteroarylene having 3 to 30 carbon atoms, substituted or unsubstituted alkylsilylene having 3 to 20 carbon atoms, substituted or unsubstituted arylsilylene having 6 to 20 carbon atoms, substituted or unsubstituted alkylgermanylidene having 3 to 20 carbon atoms, substituted or unsubstituted arylgermanylidene having 6 to 20 carbon atoms and combinations thereof;
adjacent substituents R′, R_{w}, Rₓ and R_{y} can be optionally joined to form a ring; and
adjacent substituents R₁ to R₈ can be optionally joined to form a ring.

5. The metal complex of claim 1, wherein X is selected from O or S.

6. The metal complex of claim 4, wherein X₃ to X₇ are, at each occurrence identically or differently, selected from CRₓ; and/or Y₁ to Y₄ are, at each occurrence identically or differently, selected from CR_{y}.

7. The metal complex of claim 4, wherein at least one of X₃ to X₇ is N, and/or at least one of Y₁ to Y₄ is N.

8. The metal complex of claim 1, wherein Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano and combinations thereof;
preferably, at least one Rₓ is selected from the group consisting of: deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, cyano and combinations thereof;
more preferably, at least one Rₓ is selected from the group consisting of: deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, cyano and combinations thereof.

9. The metal complex of claim 1, wherein R_{w} is, at each occurrence identically or differently, selected from the group consisting of: substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, substituted or unsubstituted arylalkylene having 7 to 30 carbon atoms, substituted or unsubstituted arylene having 6 to 30 carbon atoms, substituted or unsubstituted heteroarylene having 3 to 30 carbon atoms and combinations thereof;
preferably, R_{w} is, at each occurrence identically or differently, selected from the group consisting of: substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms and combinations thereof;
more preferably, R_{w} is, at each occurrence identically or differently, selected from the group consisting of: cyclopentylene, cyclohexylene, phenylene, pyridylene, pyrimidinylene, triazinylene, naphthylene, phenanthrylene, anthrylene, fluorenylidene, silafluorenylidene, quinolylene, isoquinolylene, dithiophenylene, difurylene, benzofurylene, benzothienylene, dibenzofurylene, dibenzothienylene, triphenylenylene, carbazolylene, azacarbazolylene, azafluorenylidene, azasilafluorenylidene, azadibenzofurylene, azadibenzothienylene and combinations thereof; optionally, hydrogens in the above groups are partially or fully deuterated.

10. The metal complex of claim 1, wherein R_{w} is, at each occurrence identically or differently, selected from the group consisting of A-1 to A-194, wherein A-1 to A-194 have the following specific structures: 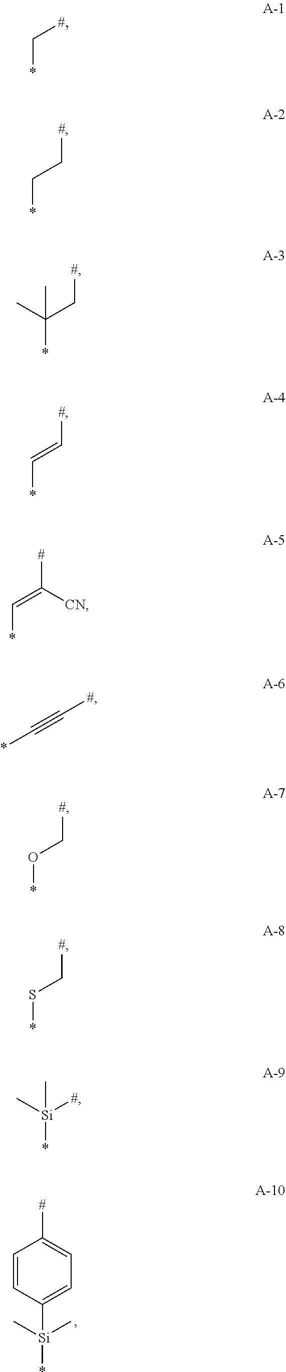 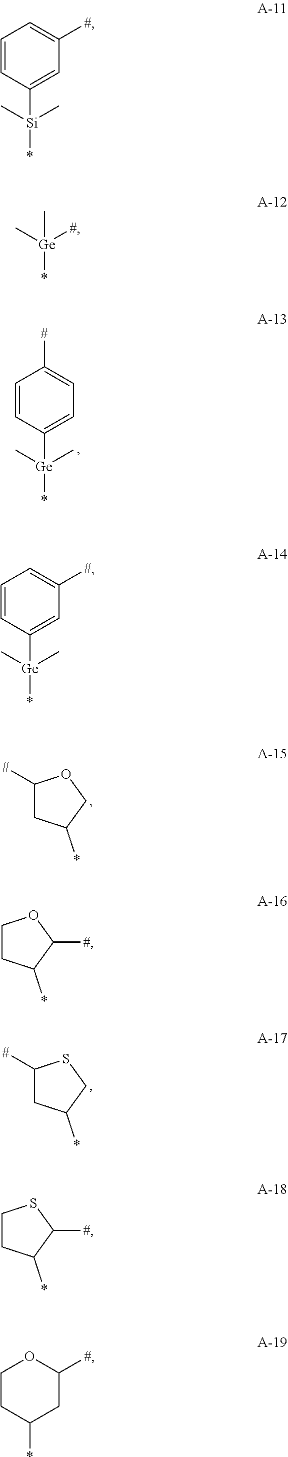 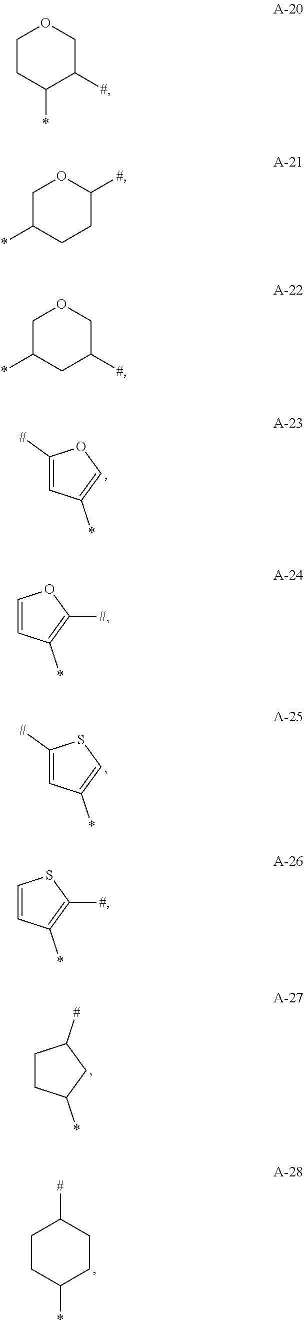 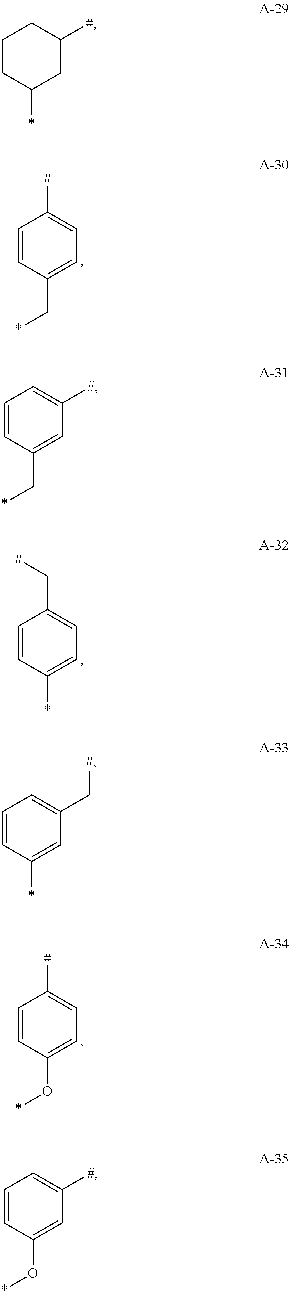 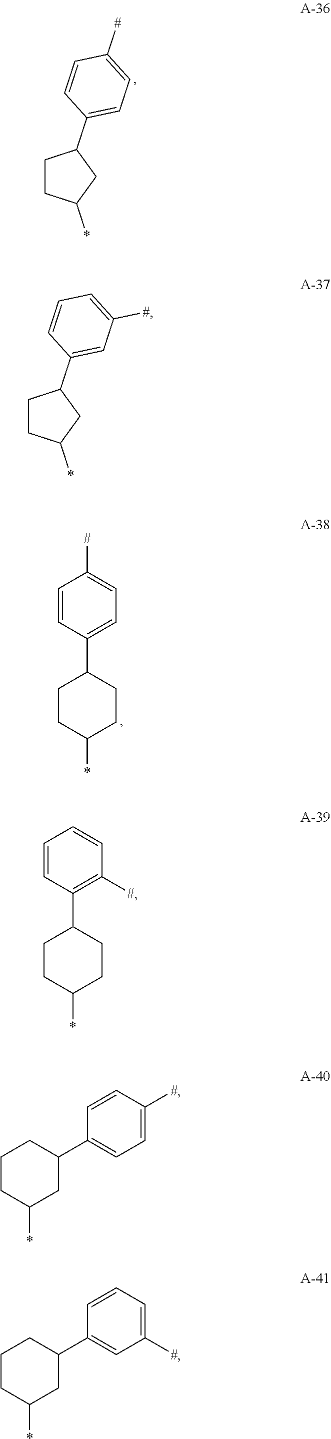 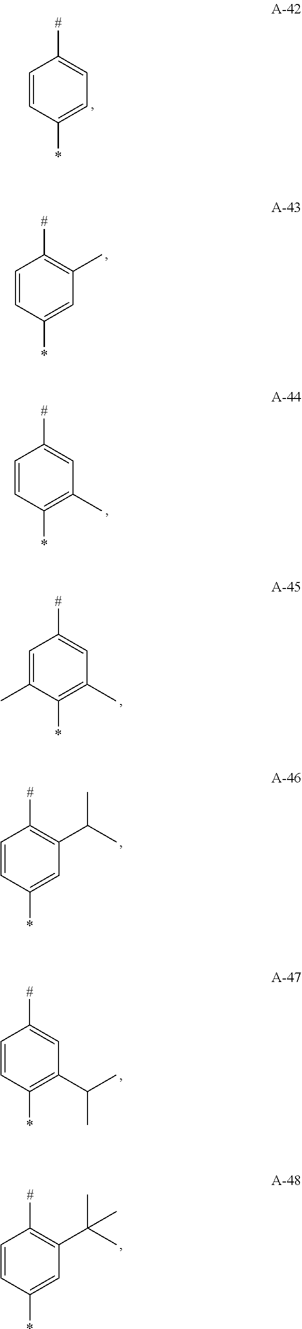 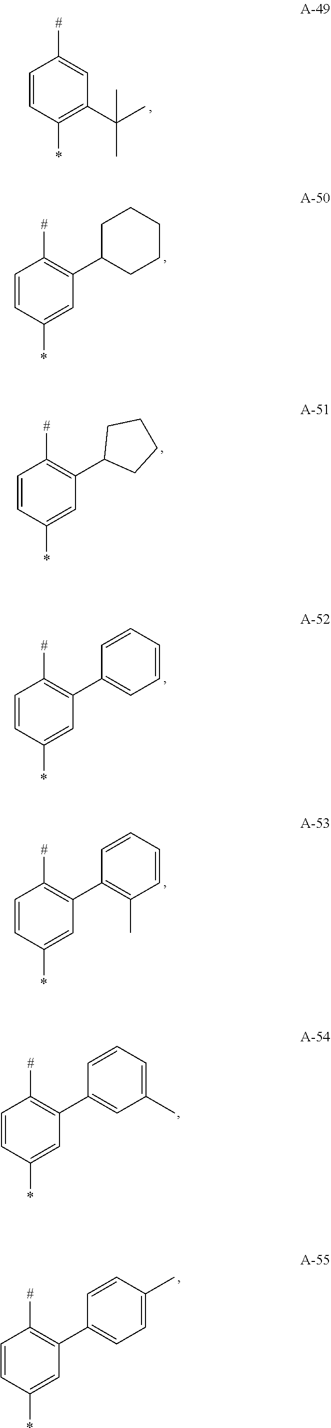 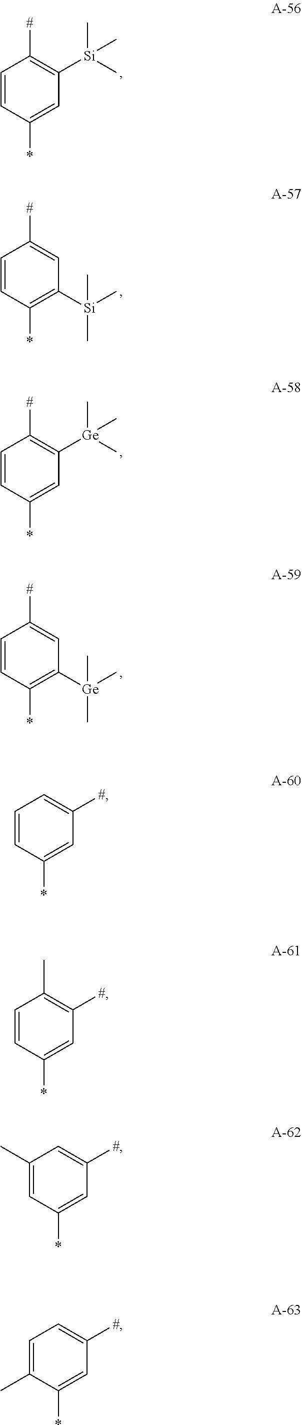 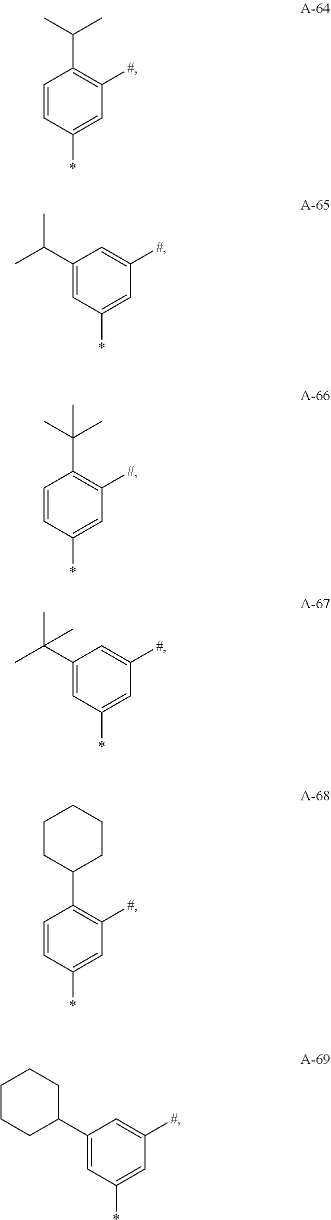 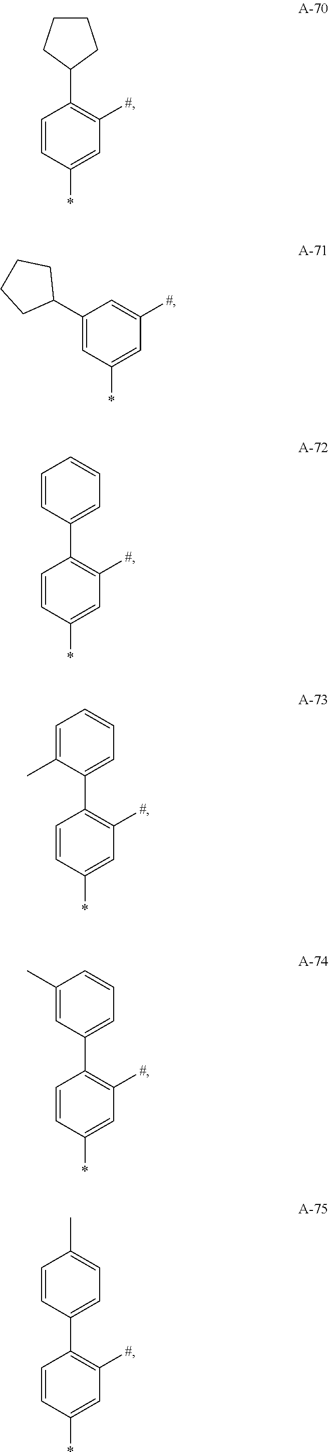 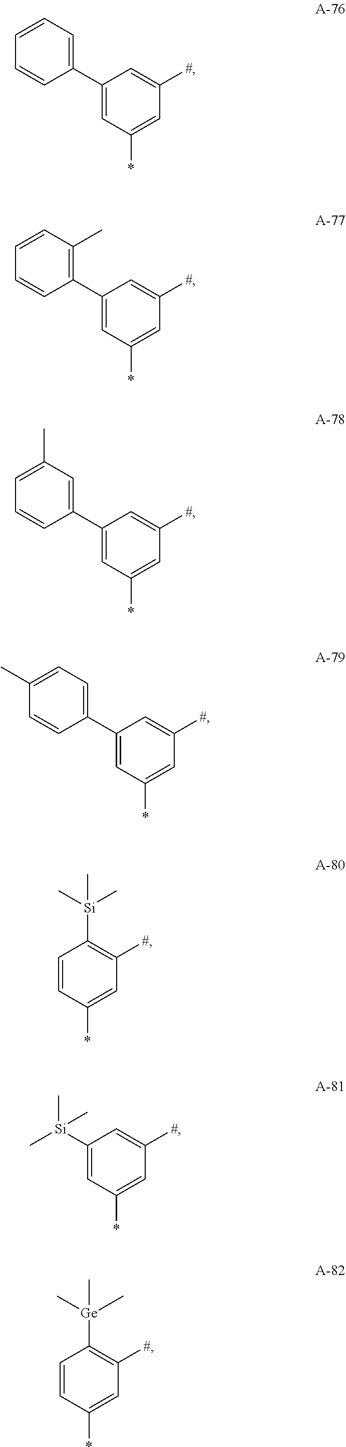 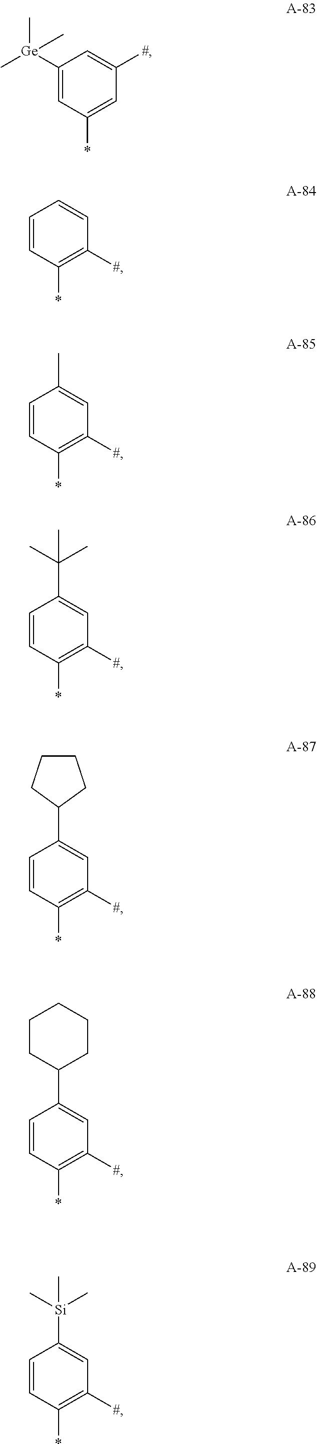 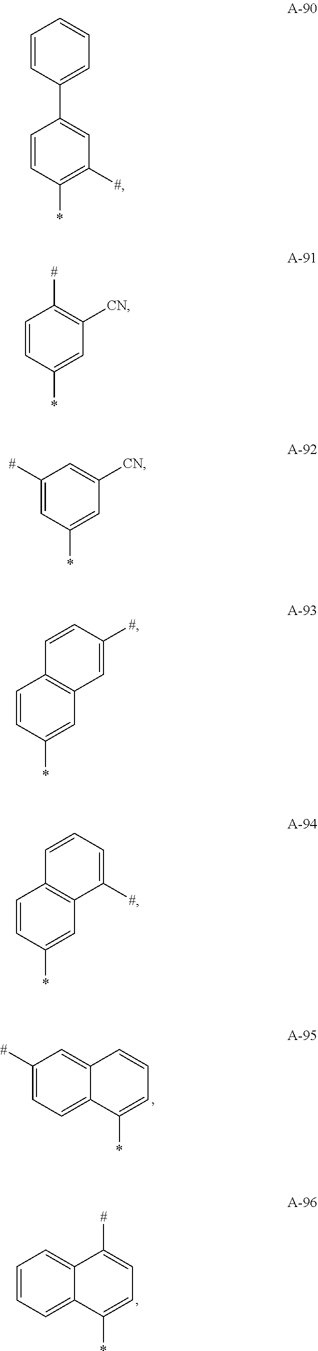 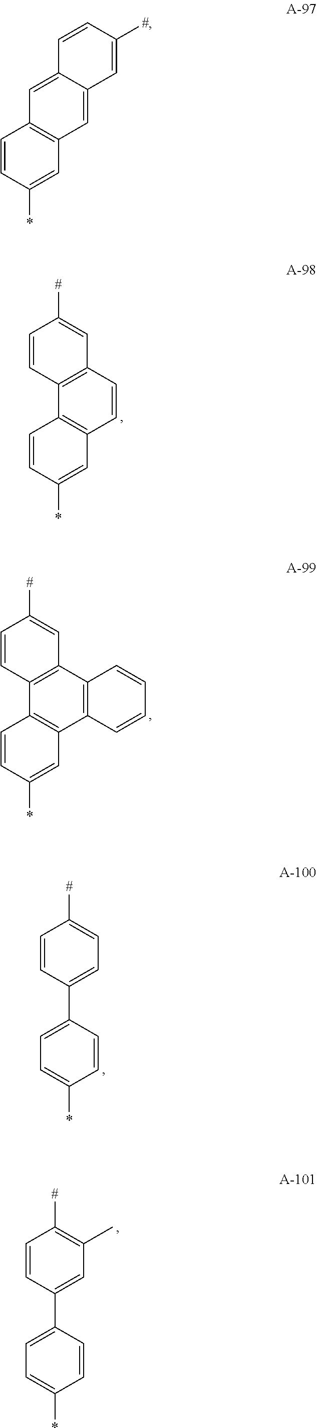 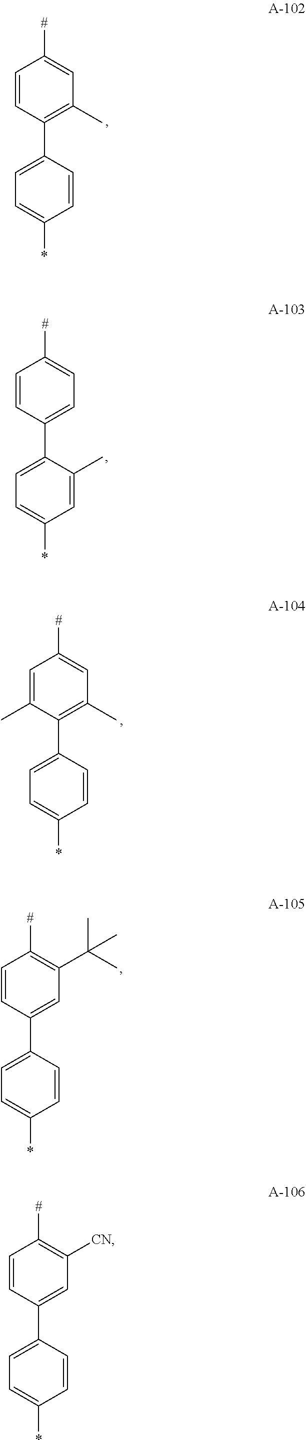 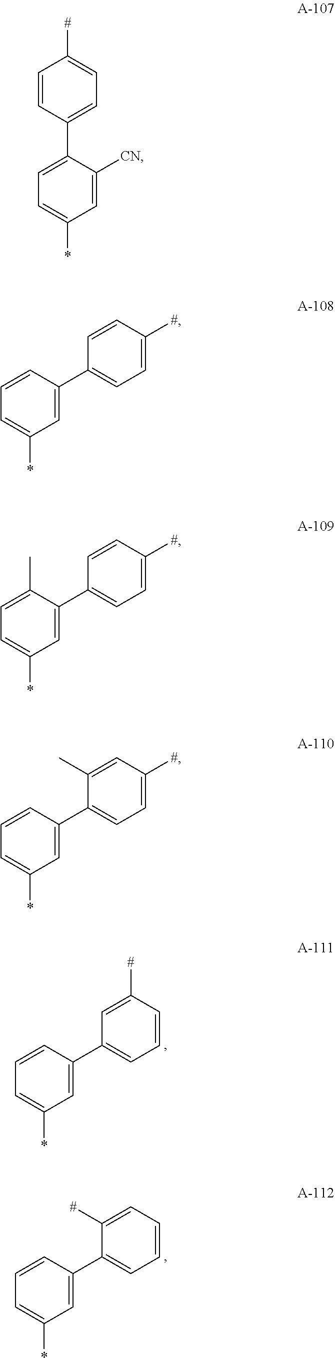 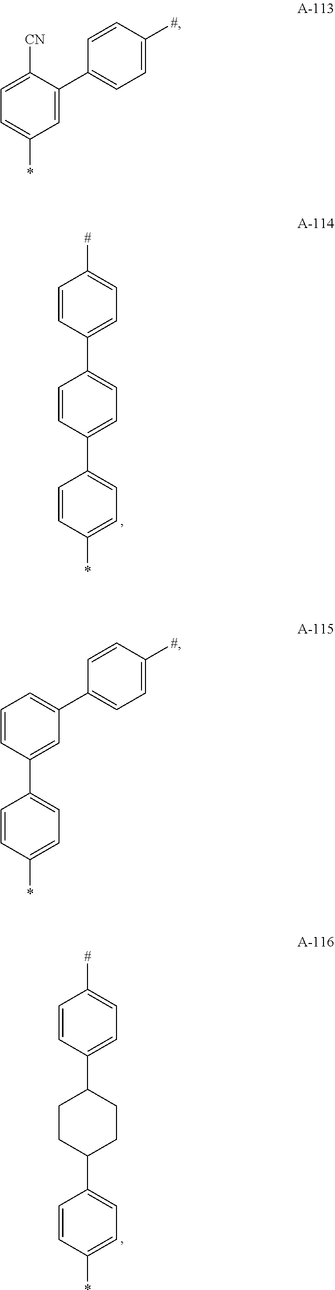 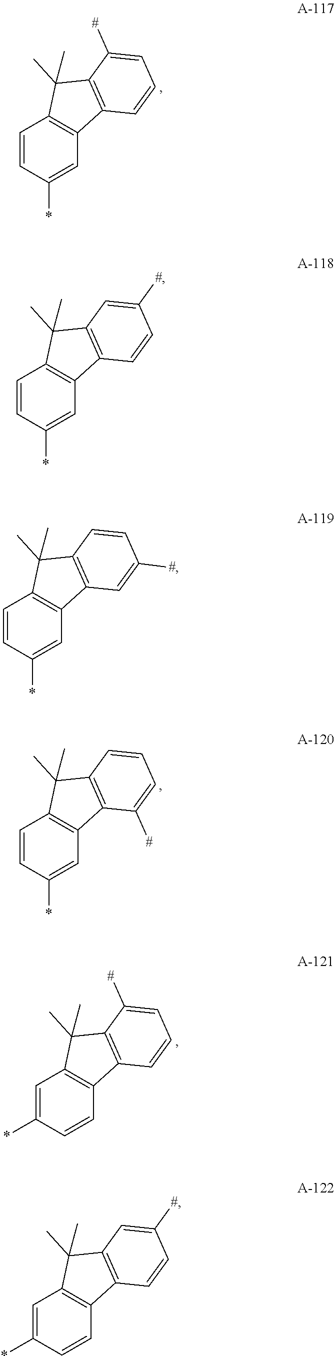 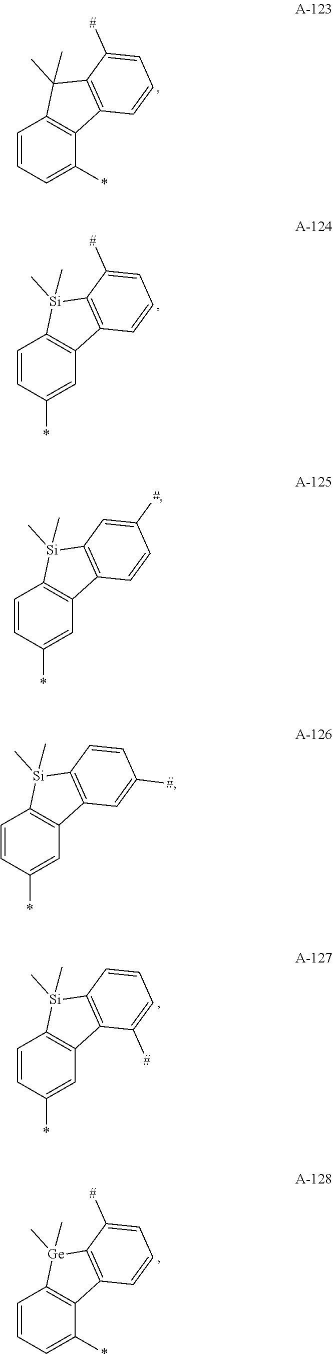 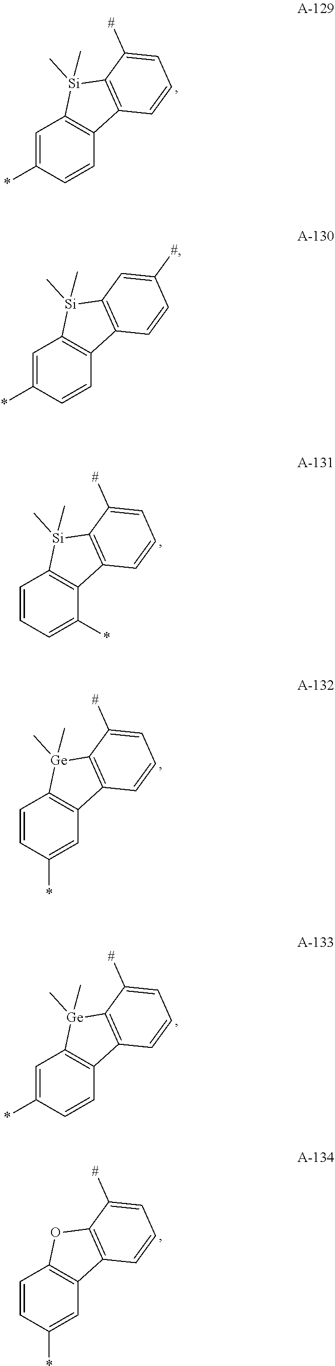 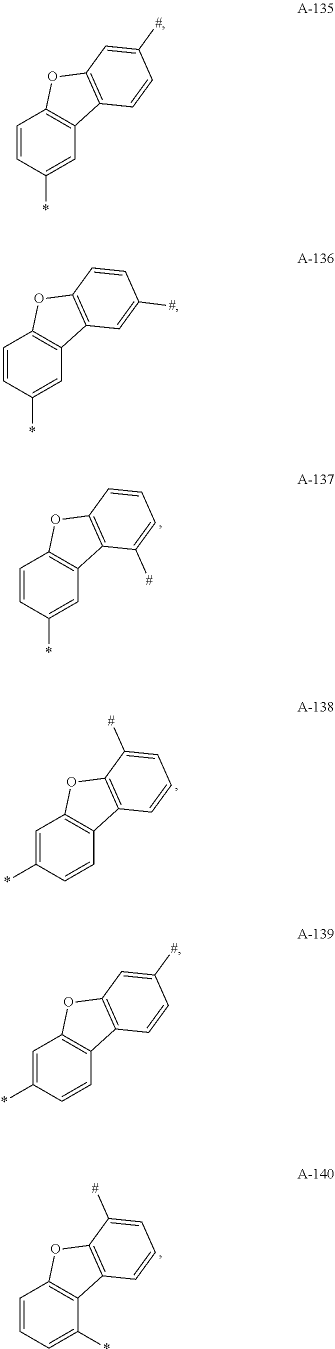 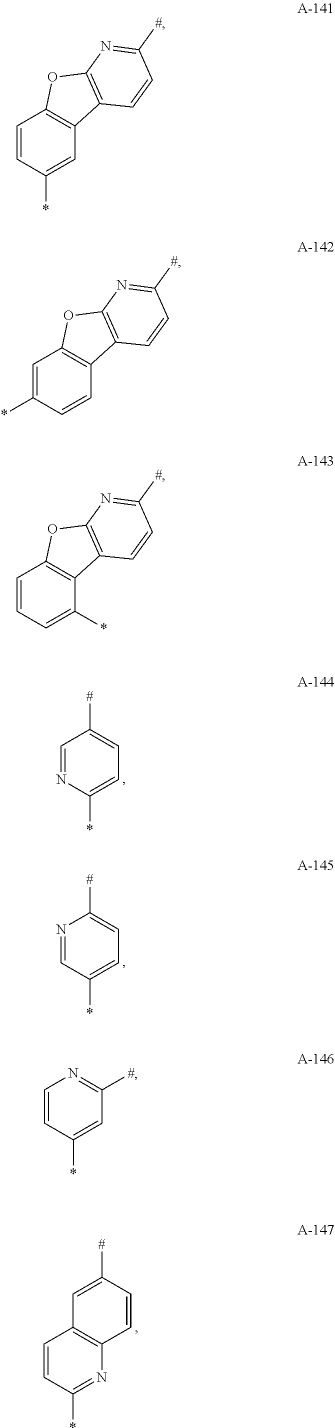 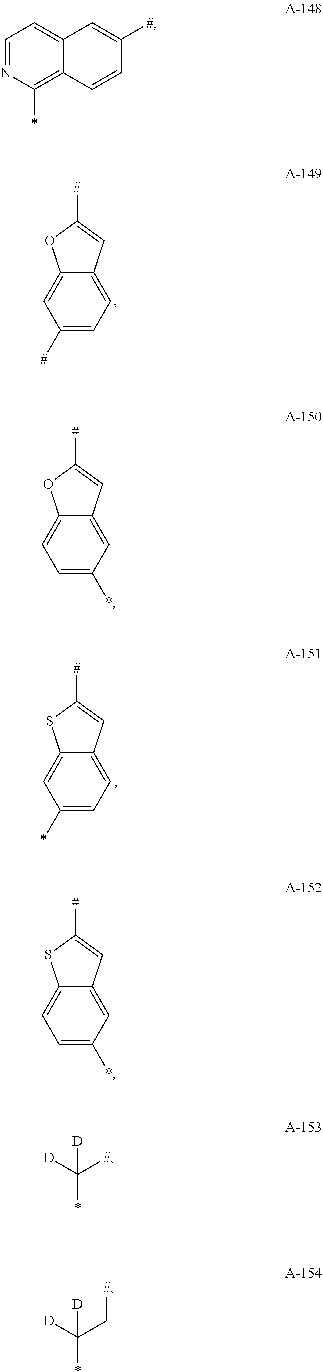 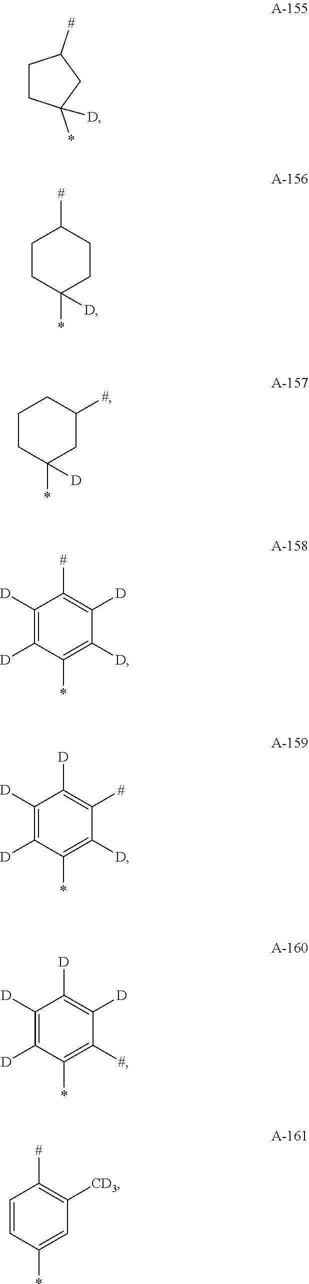 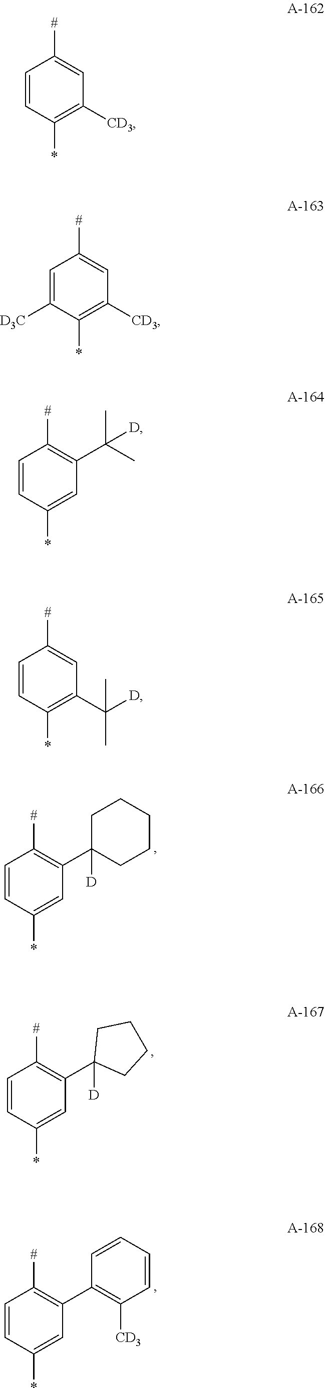 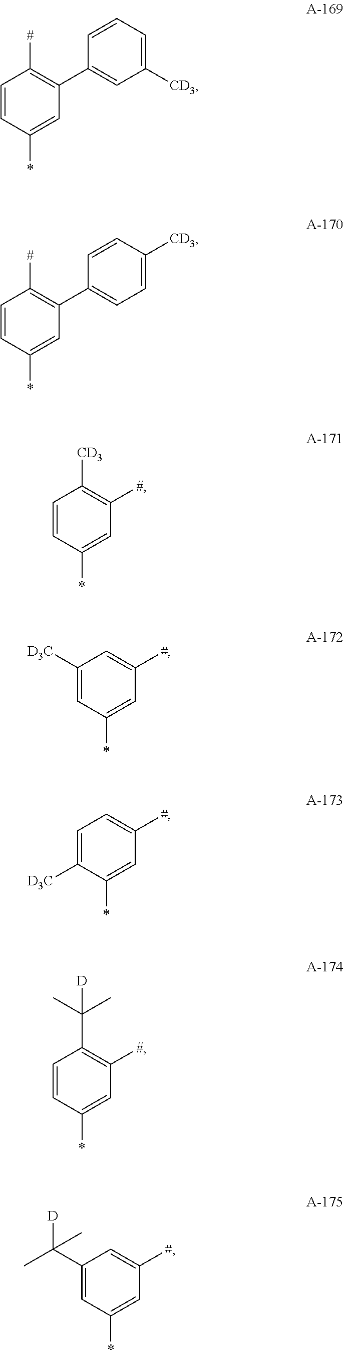 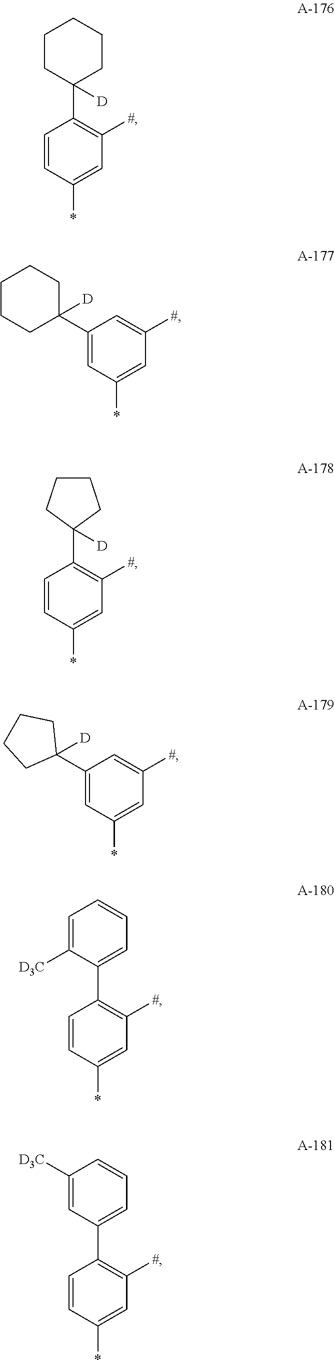 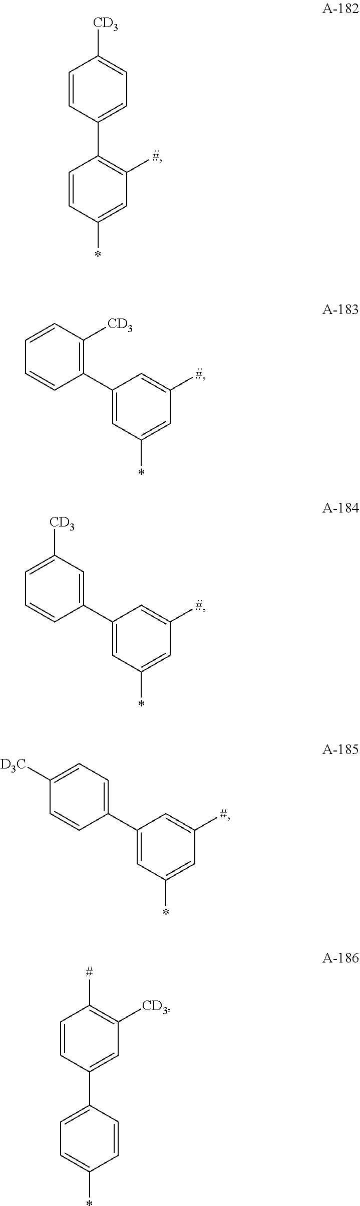 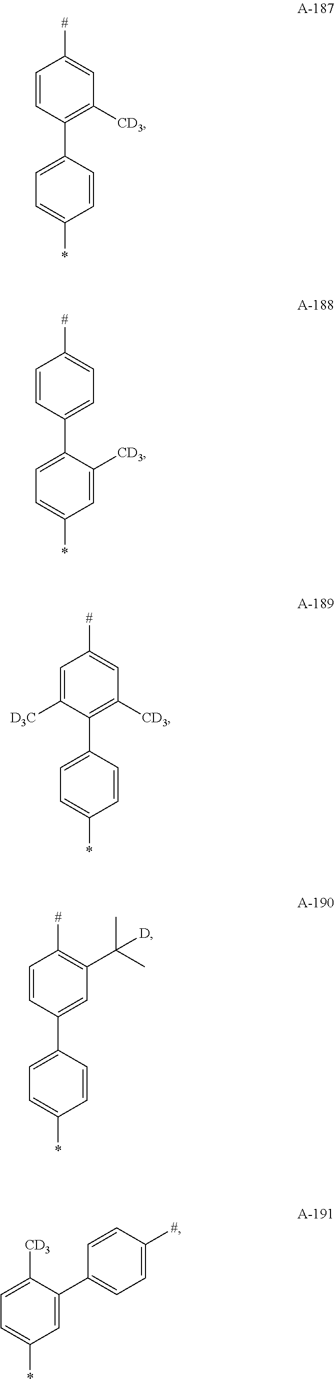 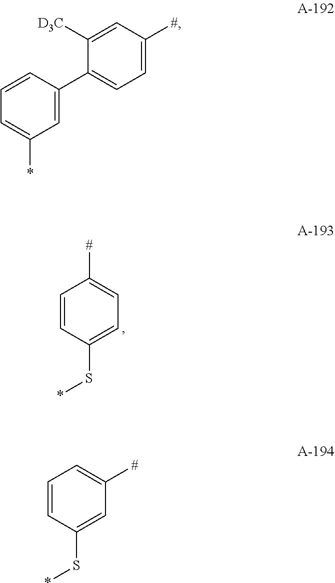
and combinations thereof;
optionally, hydrogens in the above groups can be partially or fully deuterated; wherein “*” represents a position where R_{w} is joined to X₈ and “#” represents a position where R_{w} is joined to “CN”.

11. The metal complex of claim 4, wherein R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
preferably, at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

12. The metal complex of claim 4, wherein at least one or at least two of R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₅ to R₈ is at least 4.

13. The metal complex of claim 4, wherein at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof;
more preferably, at least one, at least two, at least three or all of R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof; optionally, hydrogens in the above groups can be partially or fully deuterated.

14. The metal complex of claim 1, wherein Lₐ is, at each occurrence identically or differently, selected from any one of the group consisting of: 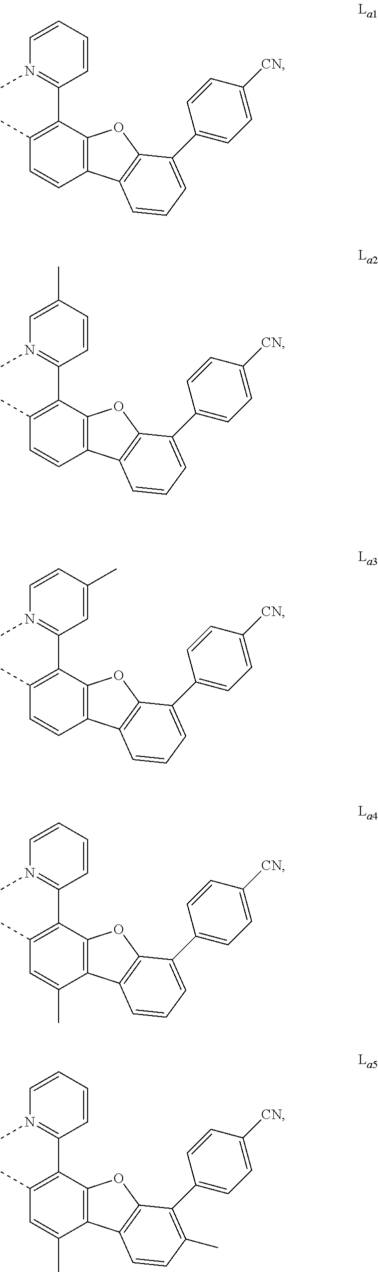 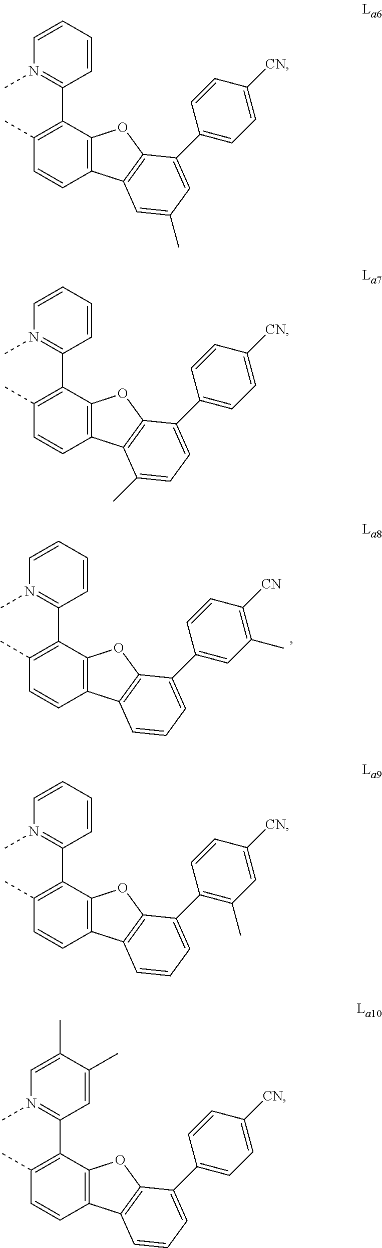 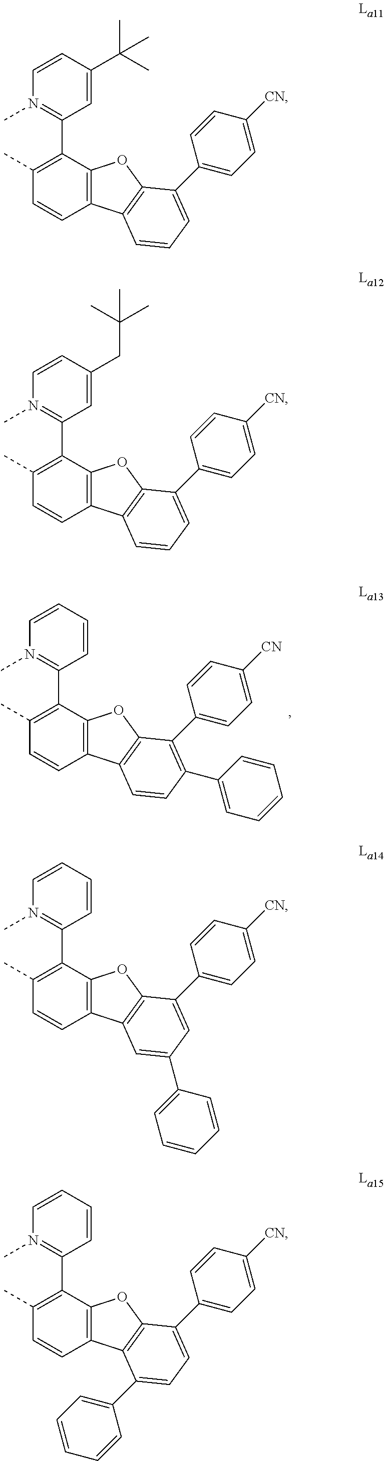 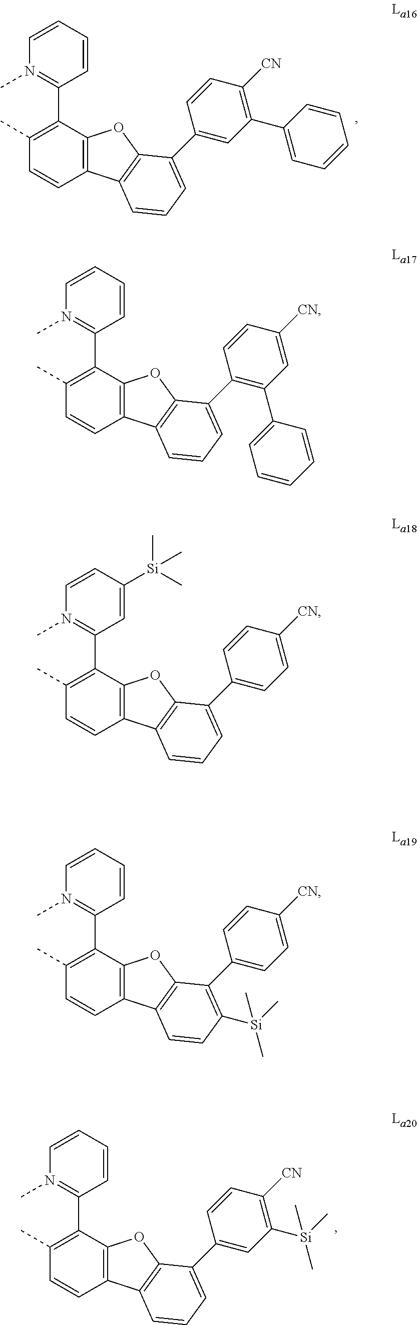 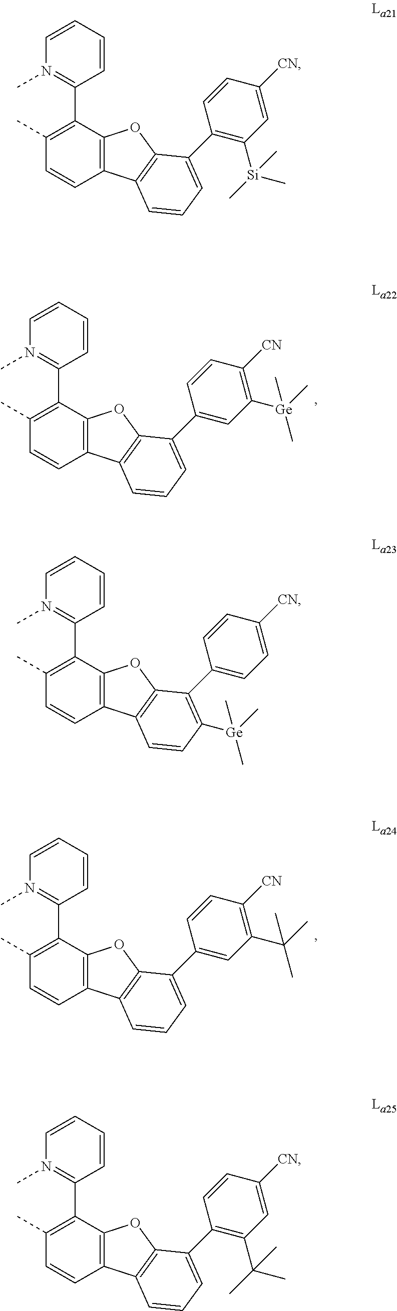 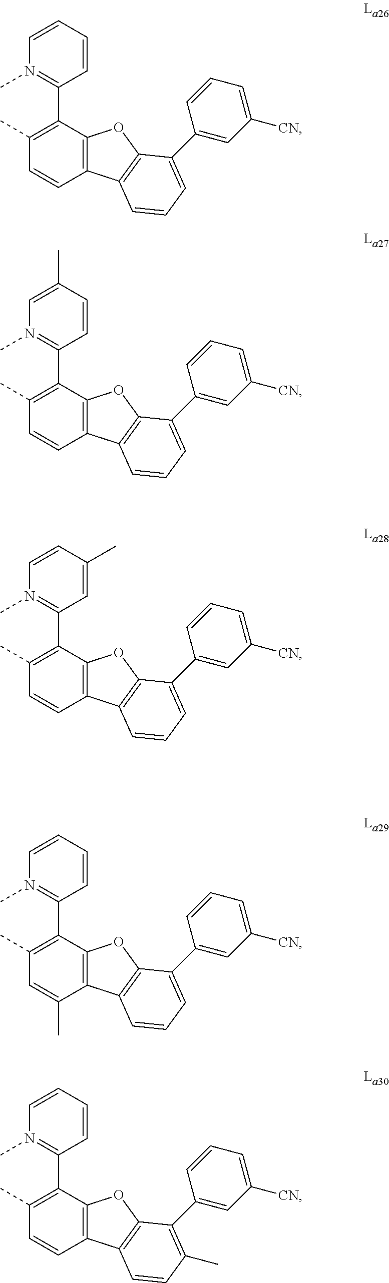 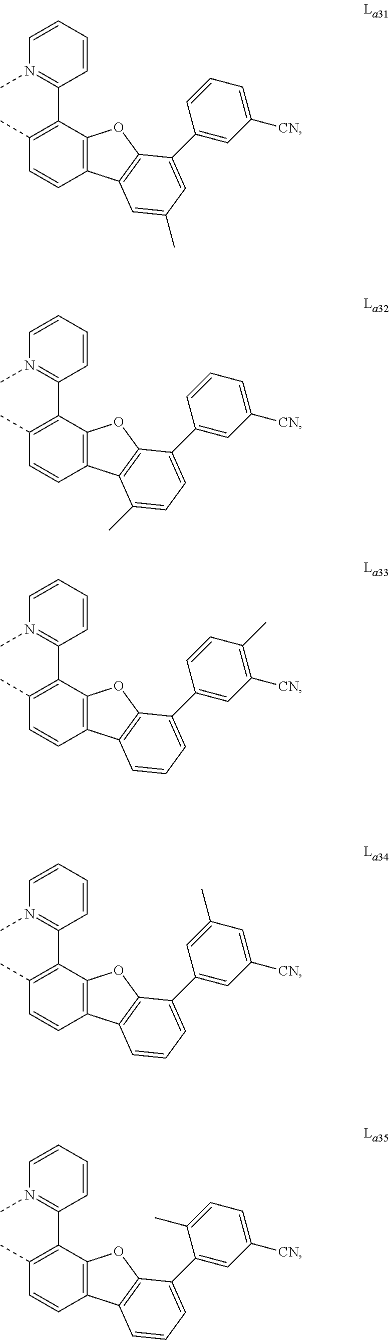 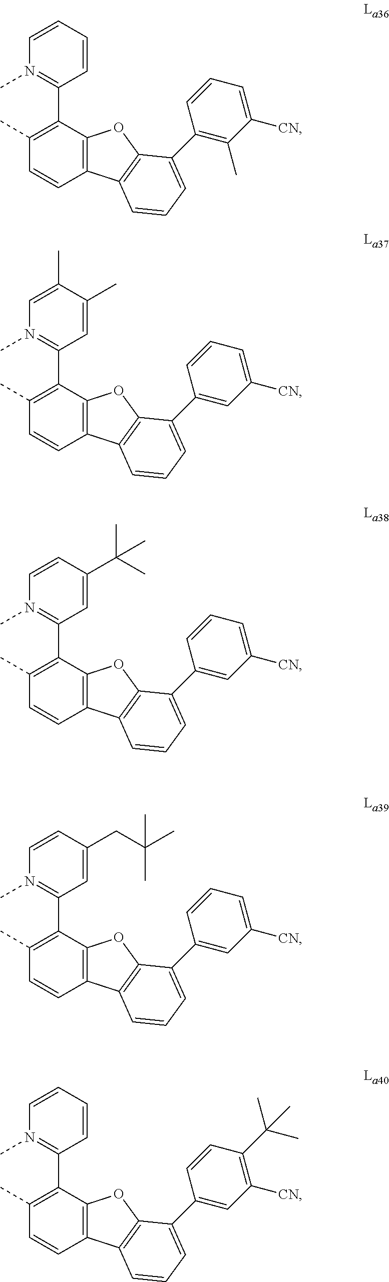 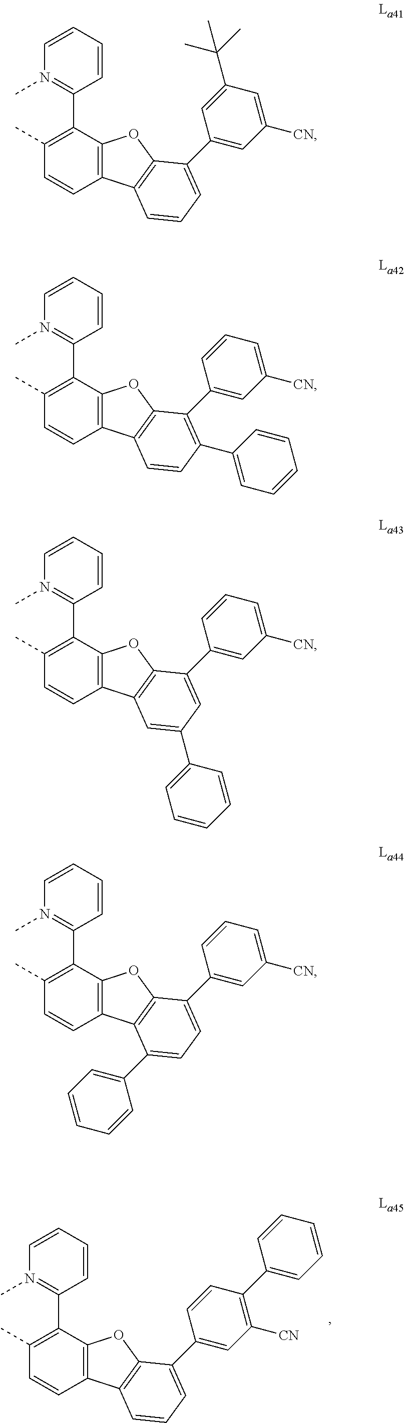 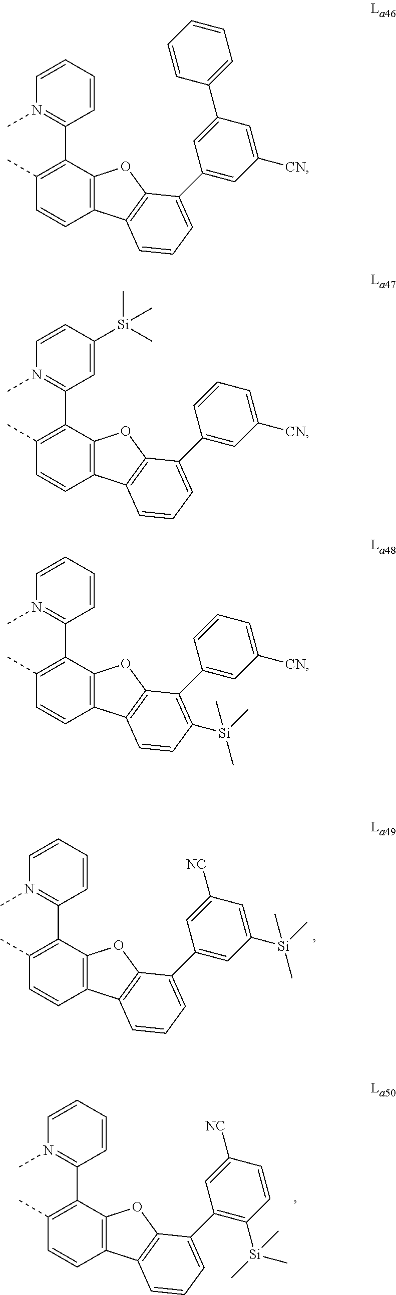 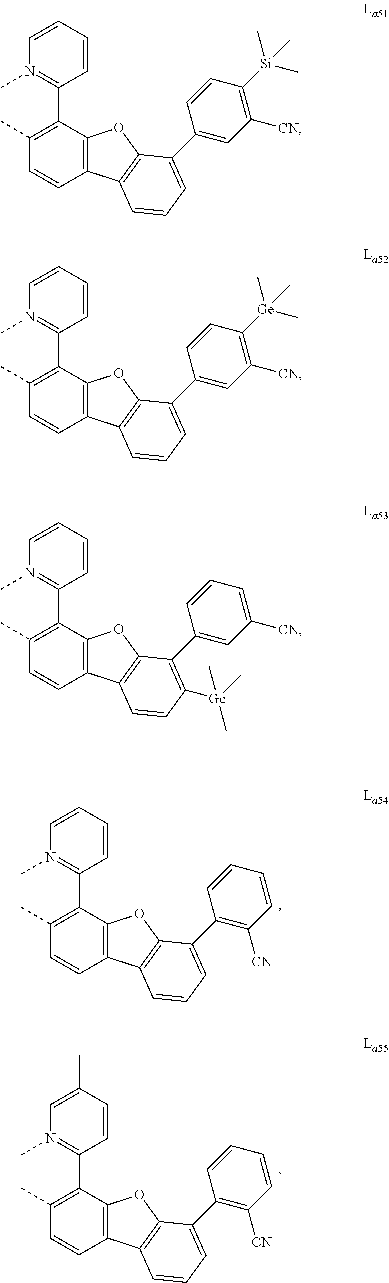 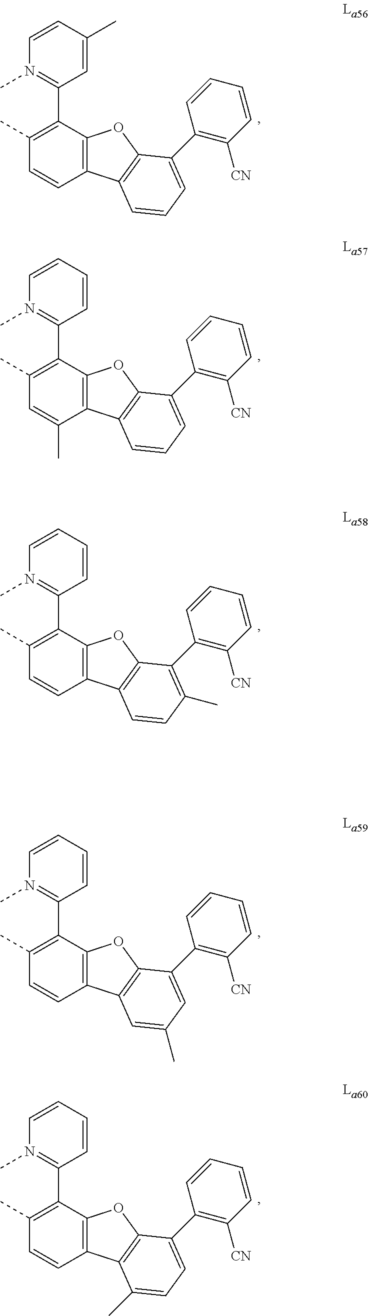 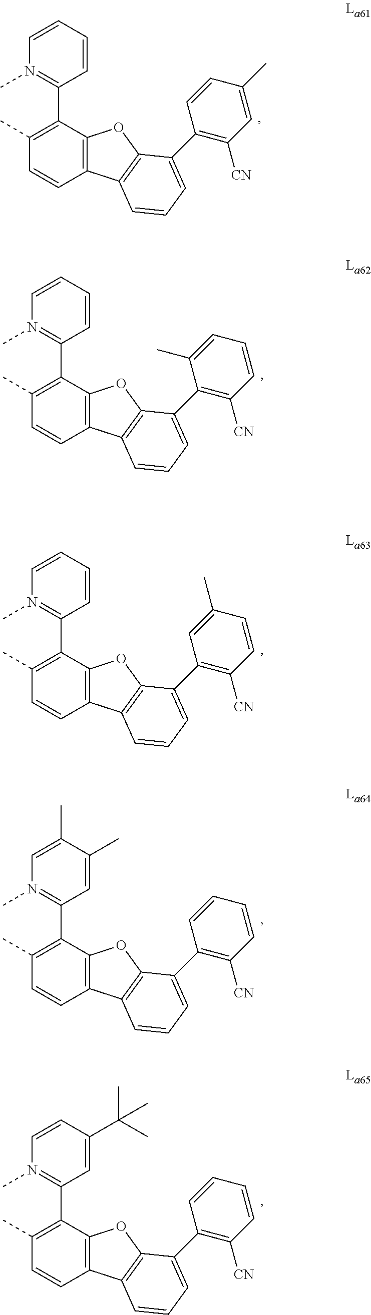 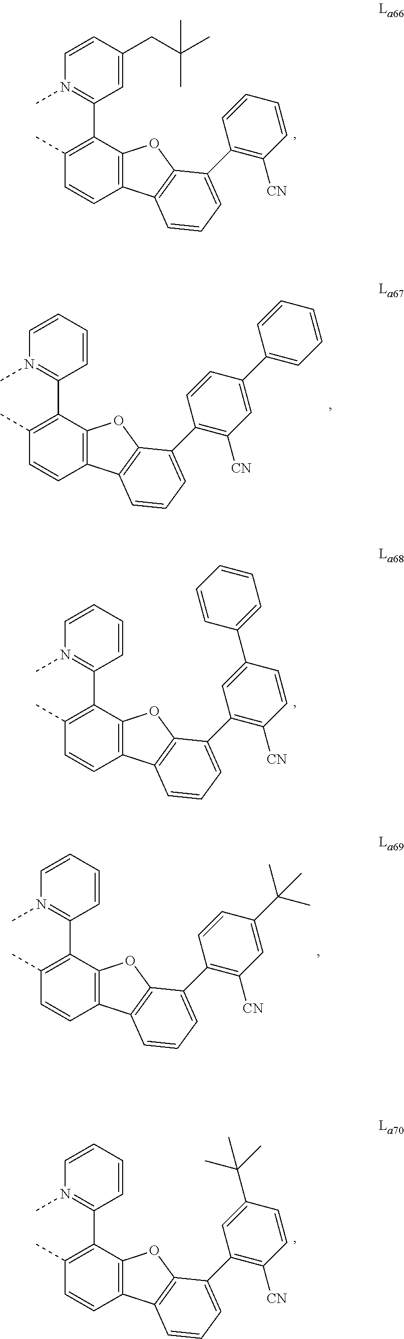 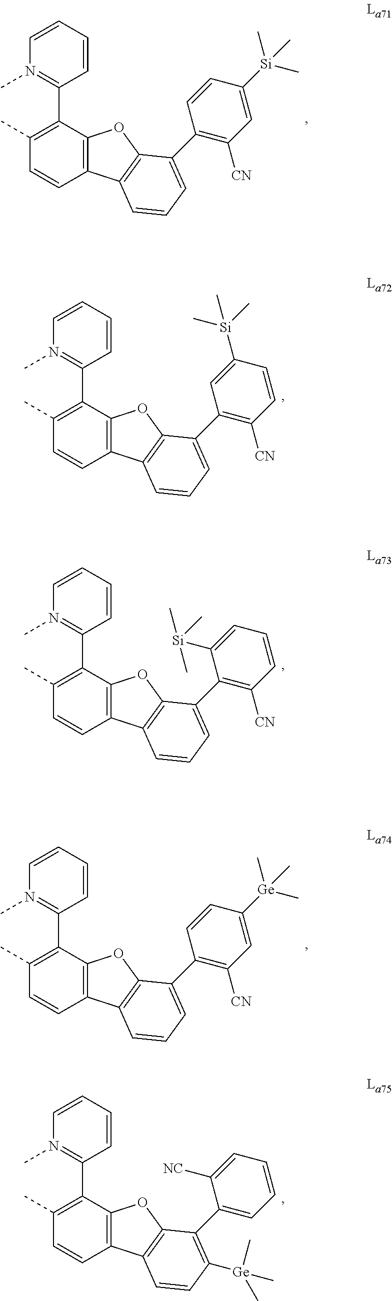 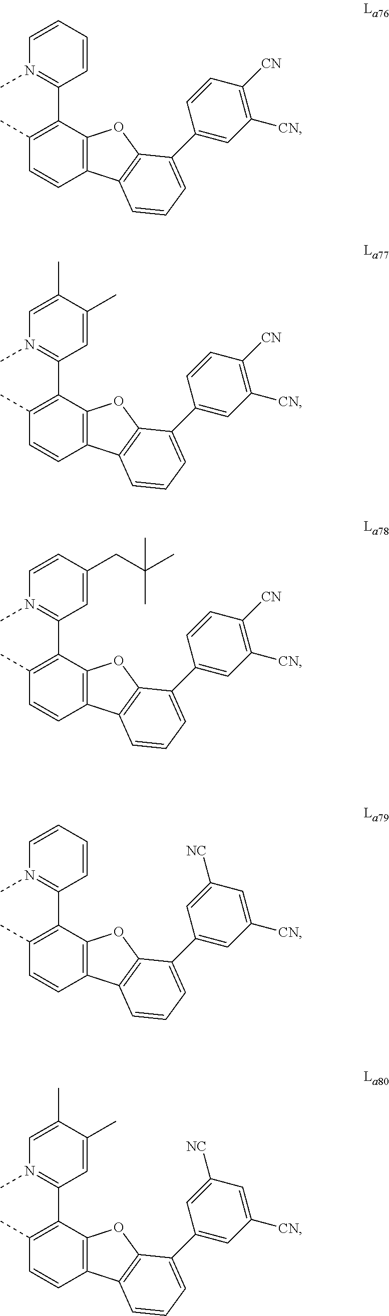 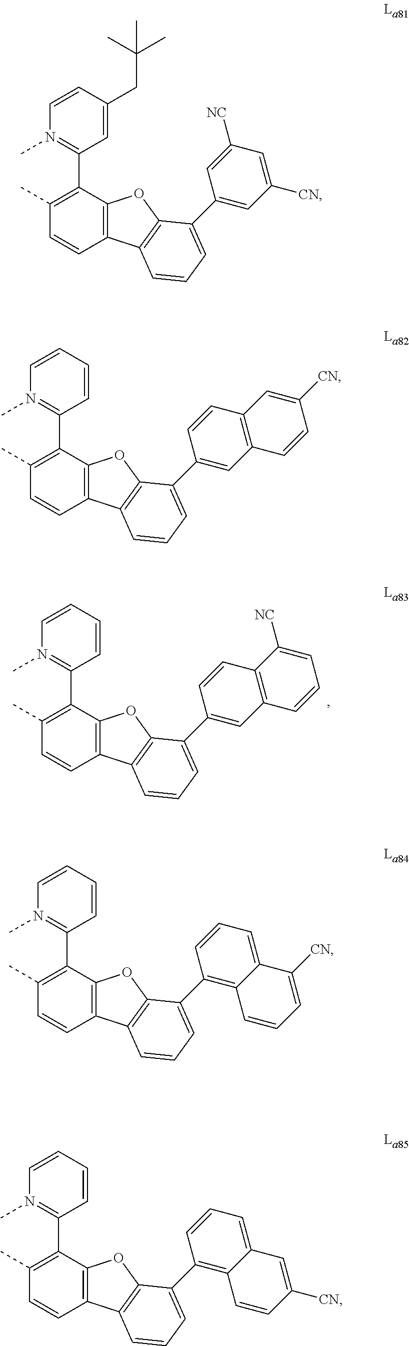 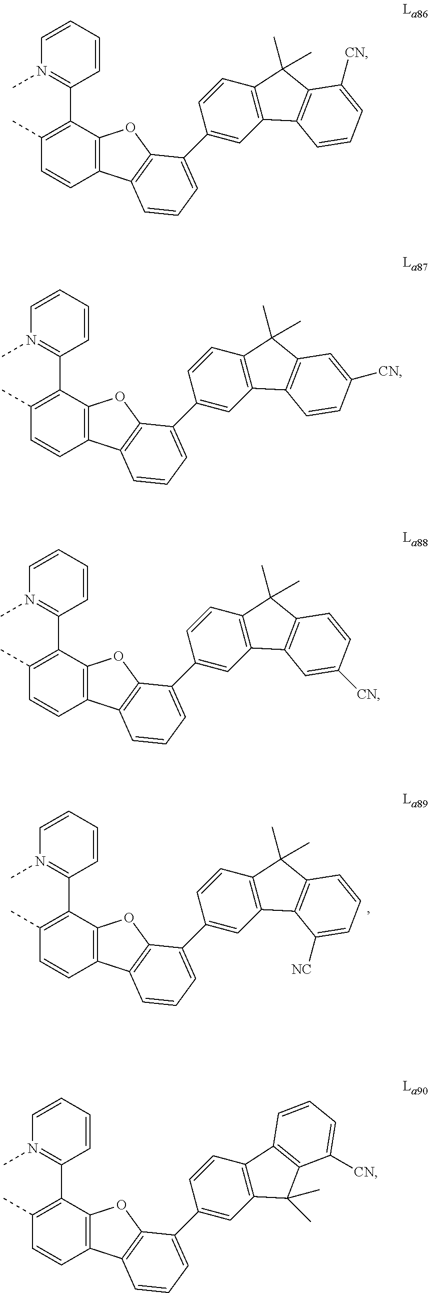 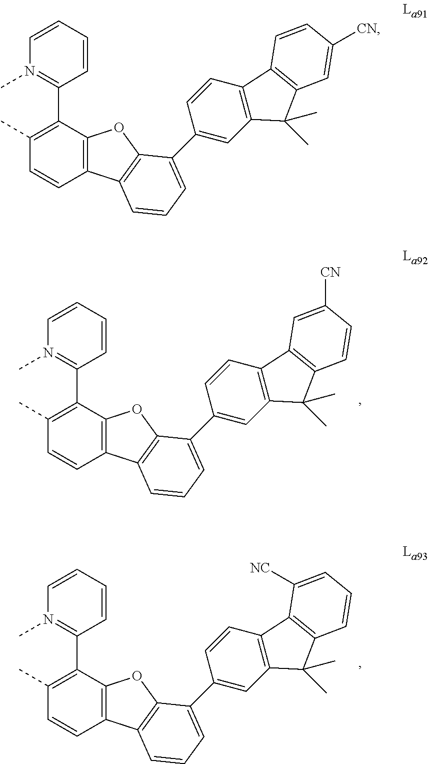 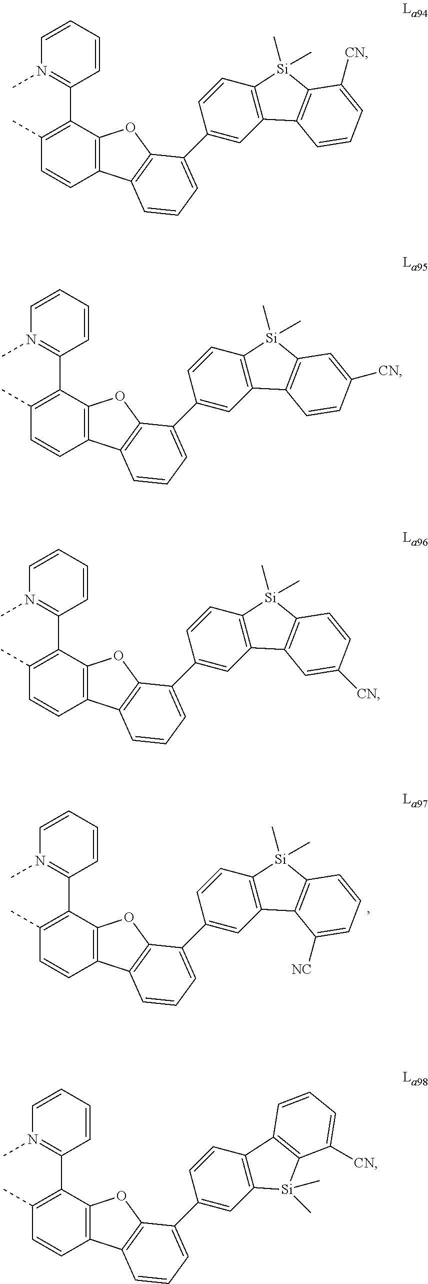 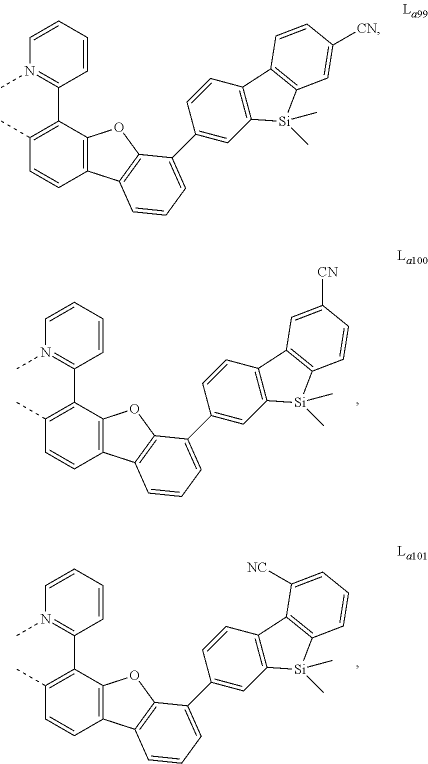 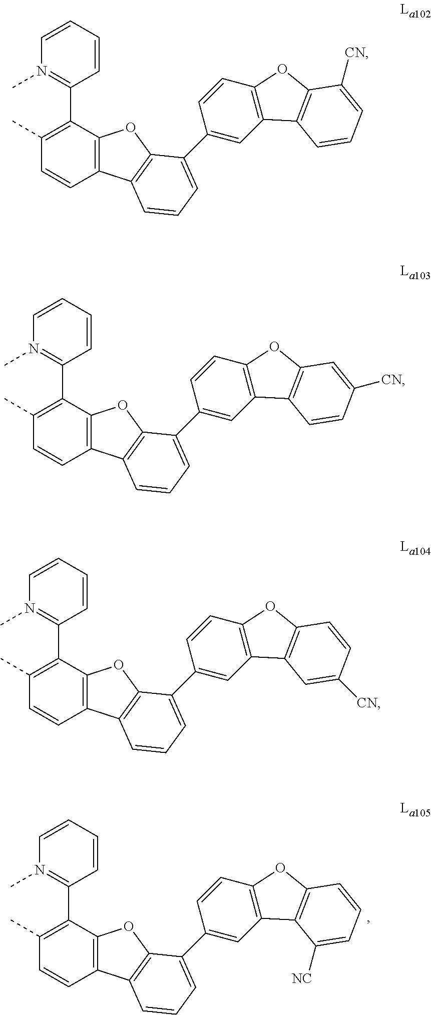 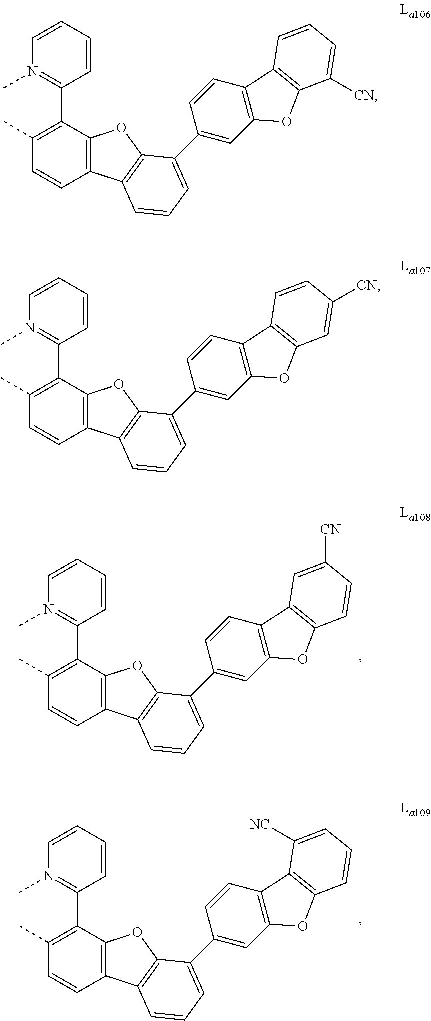 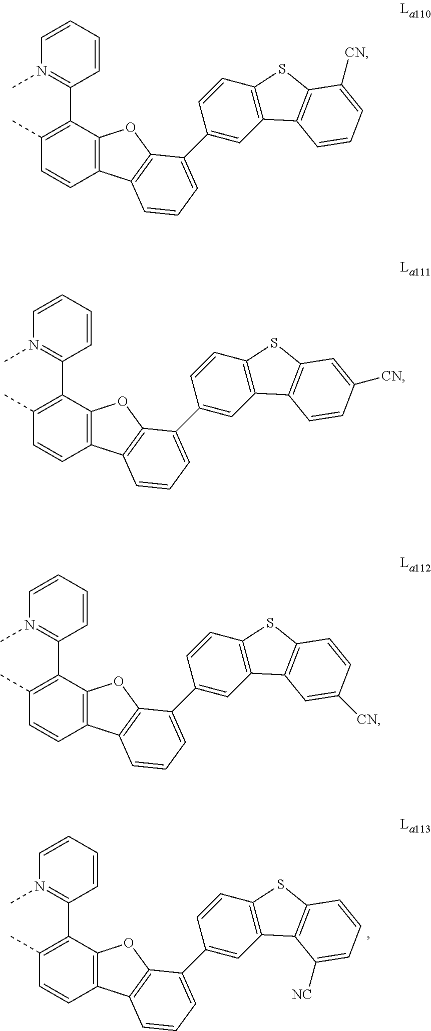 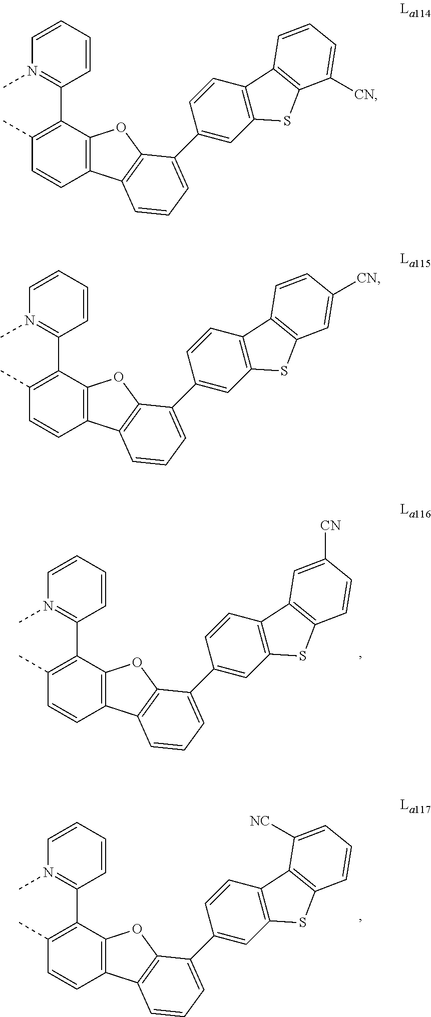 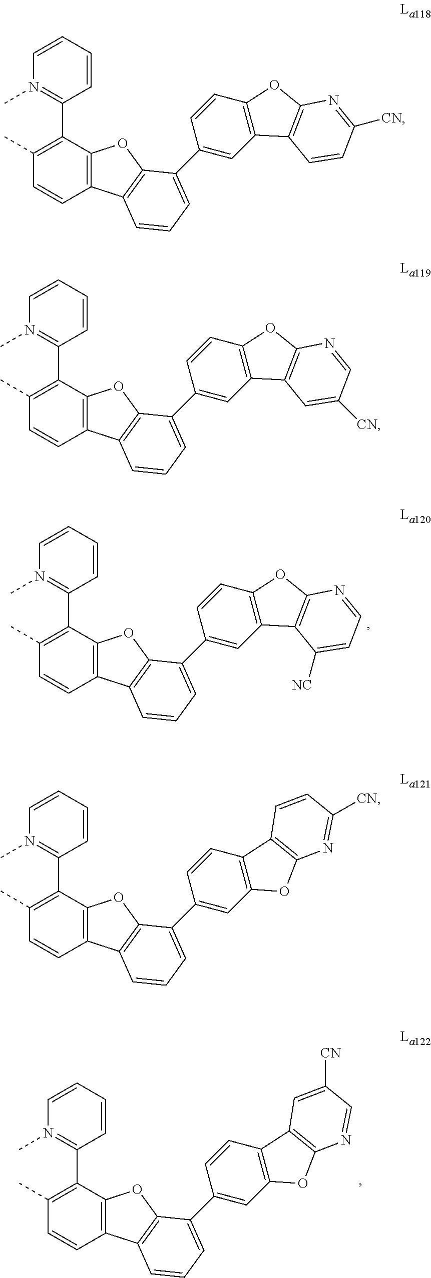 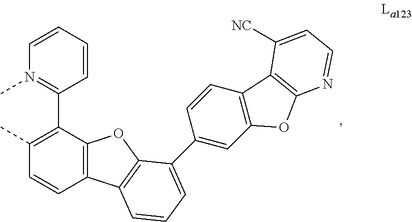 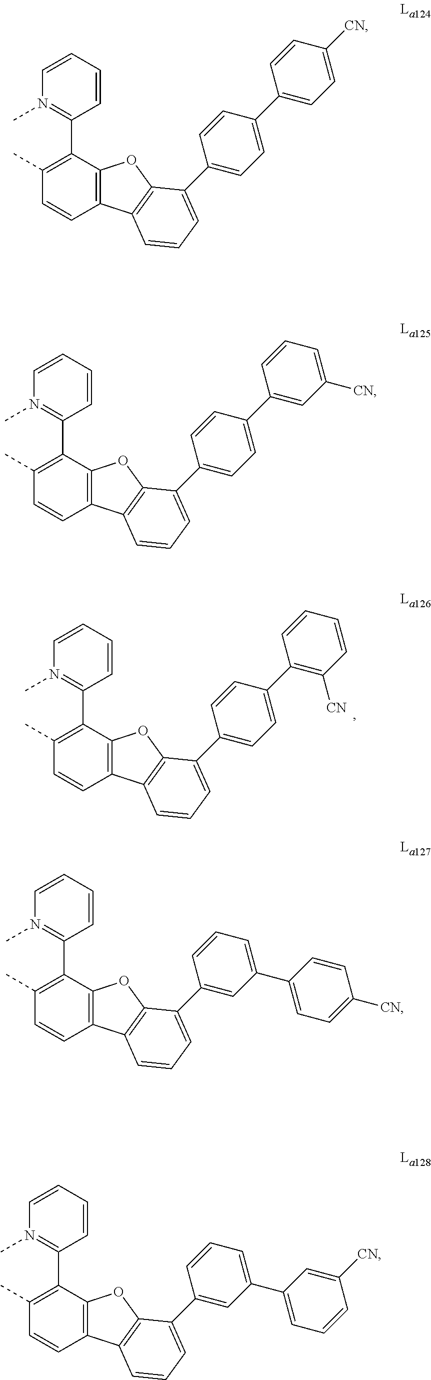 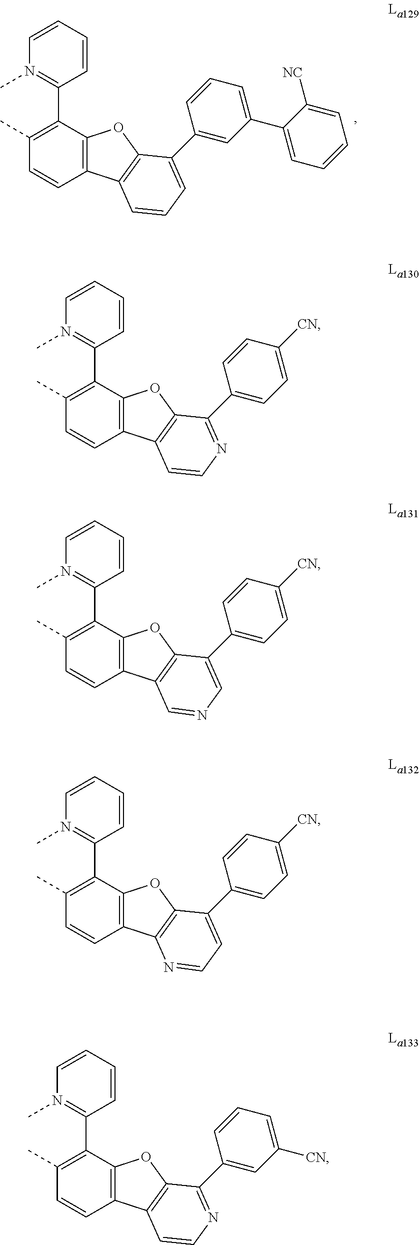 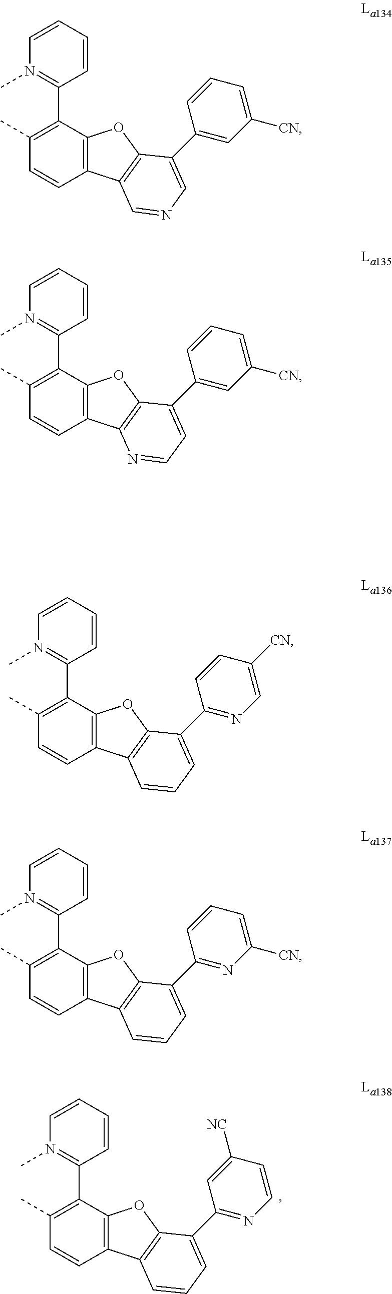 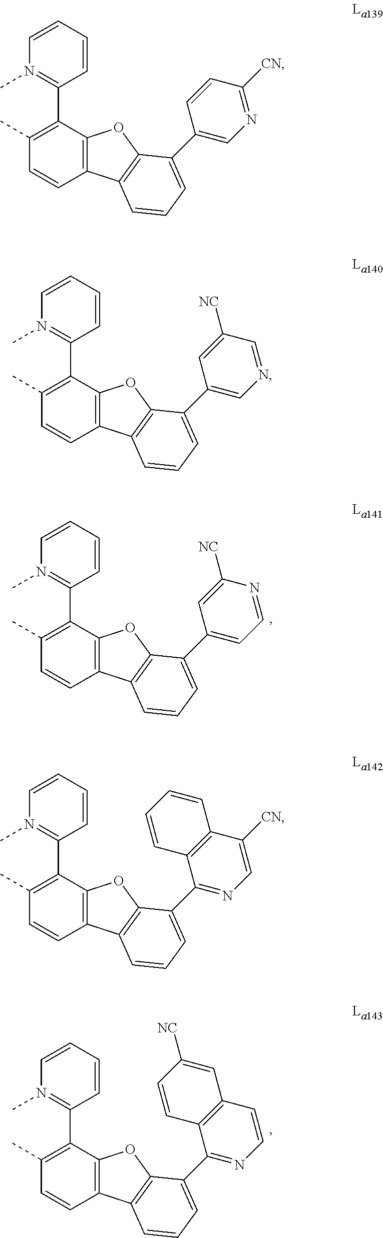 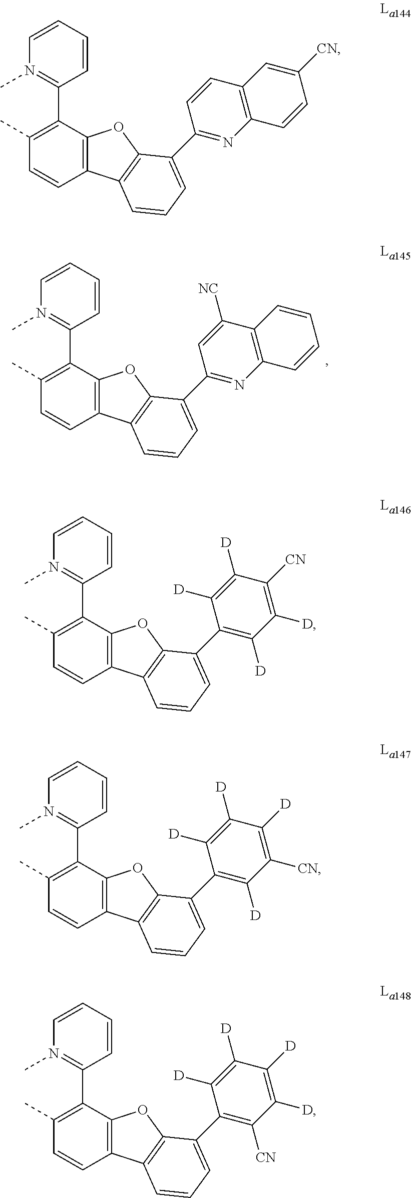 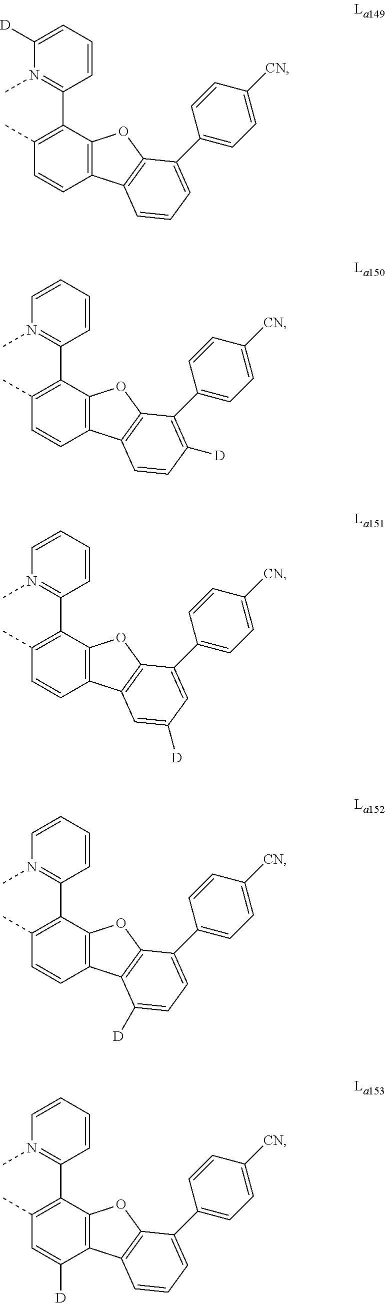 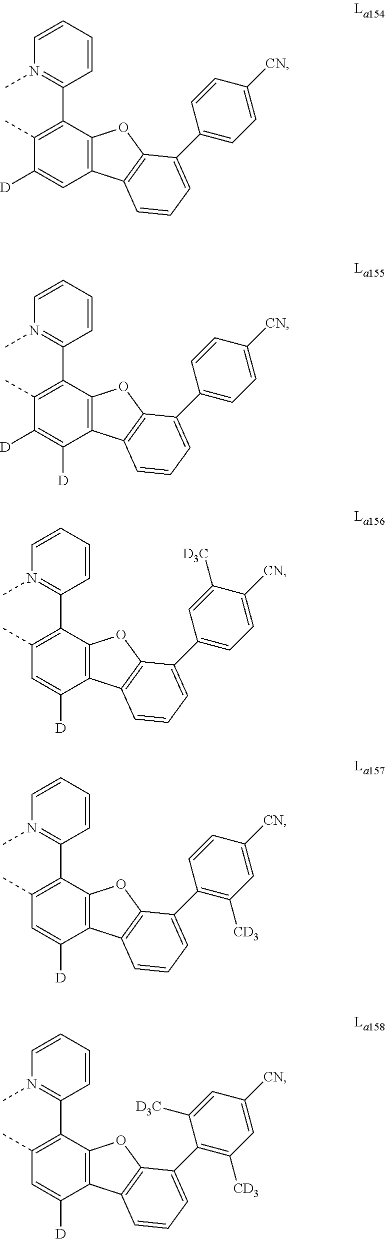 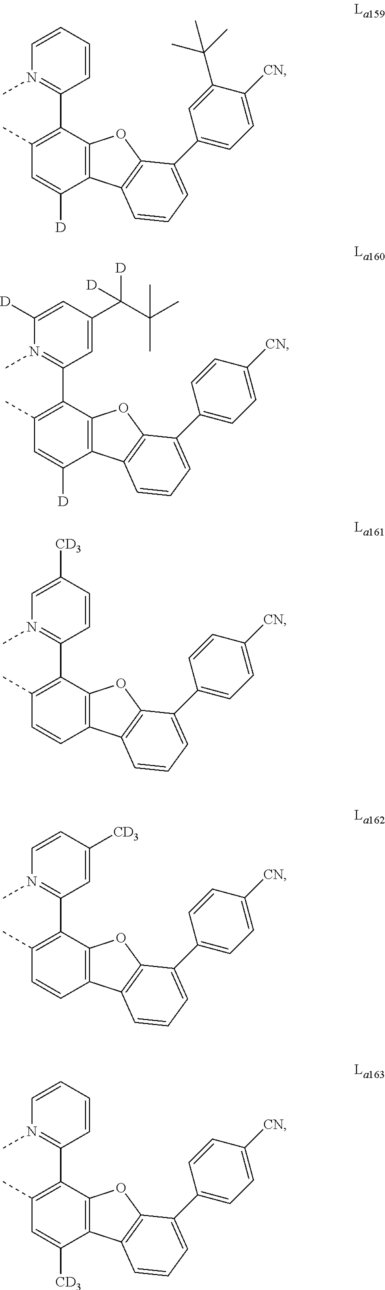 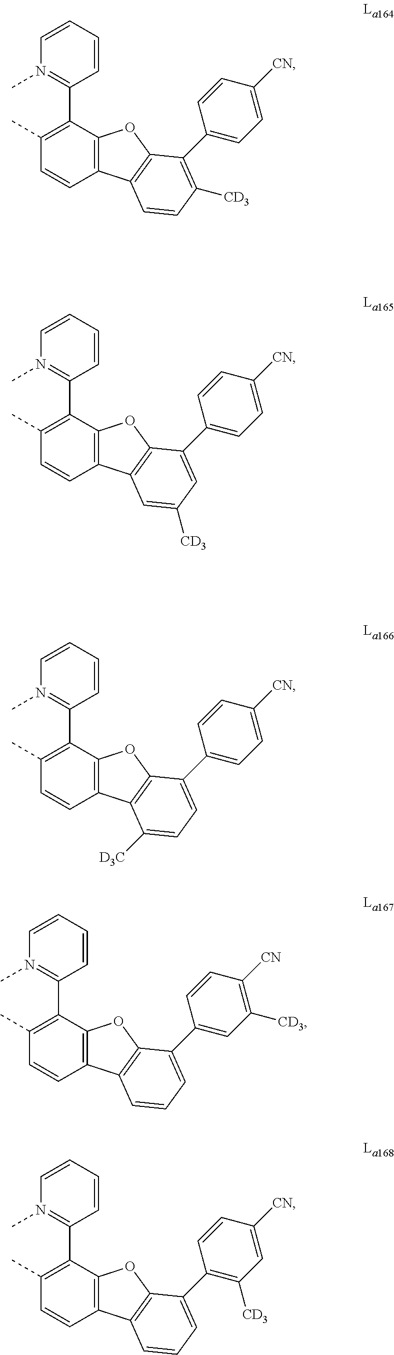 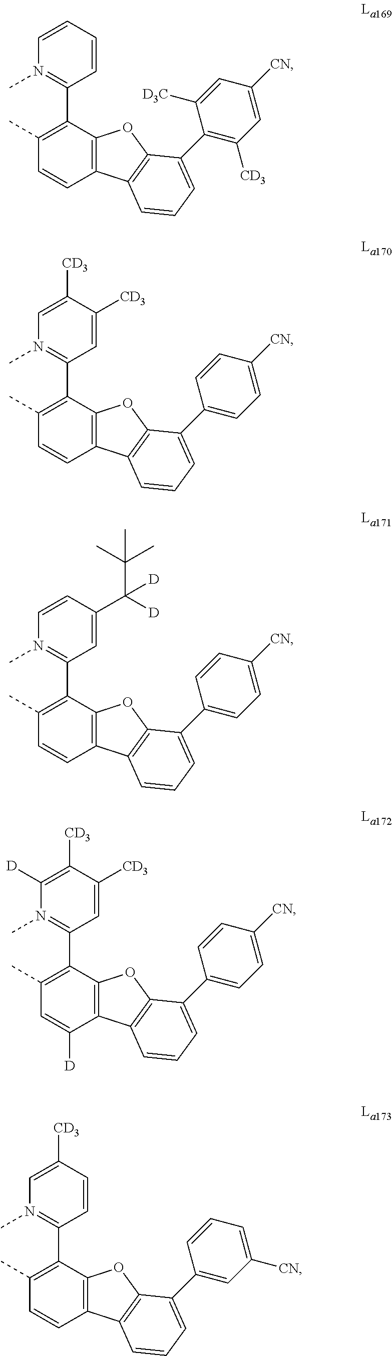 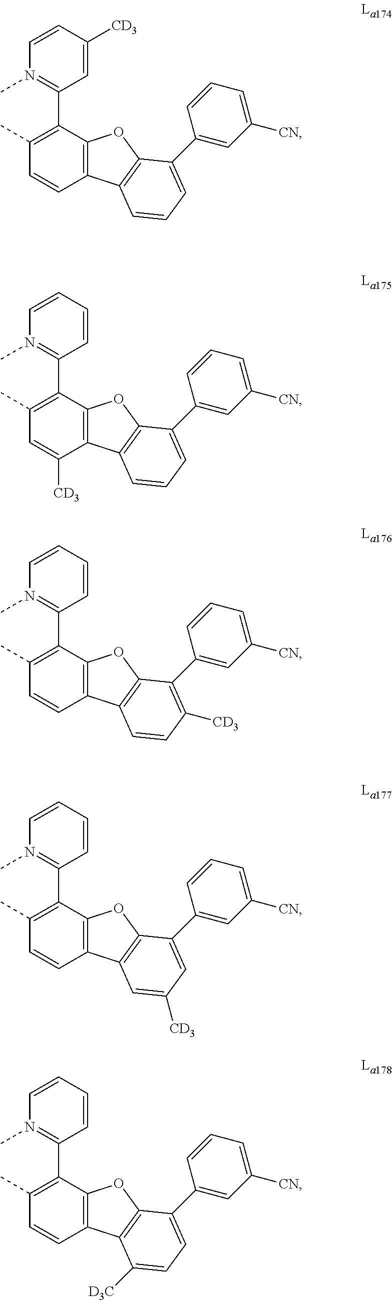 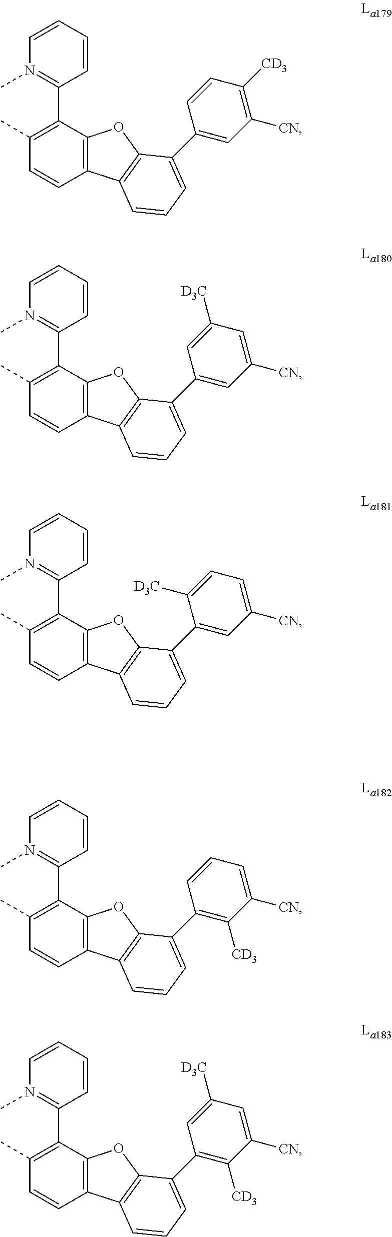 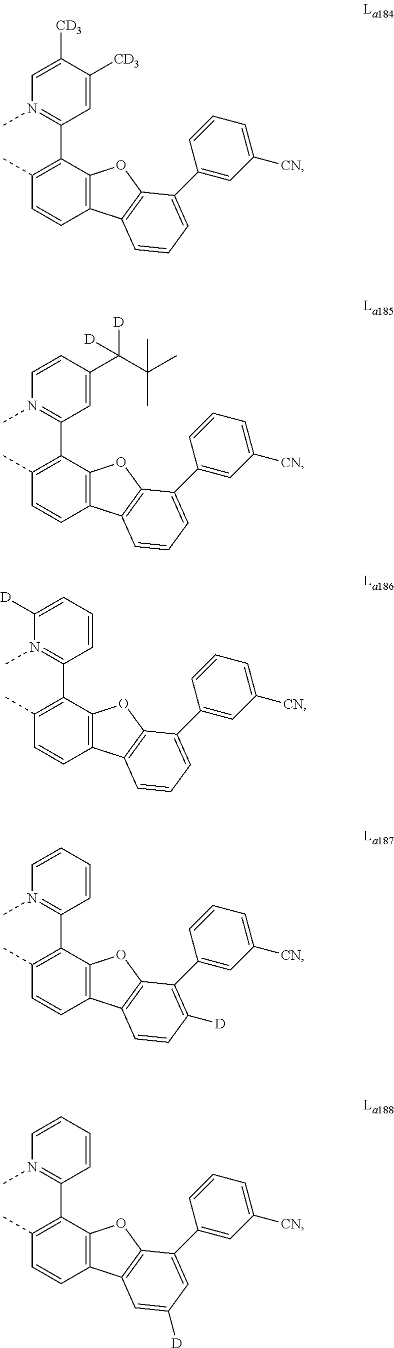 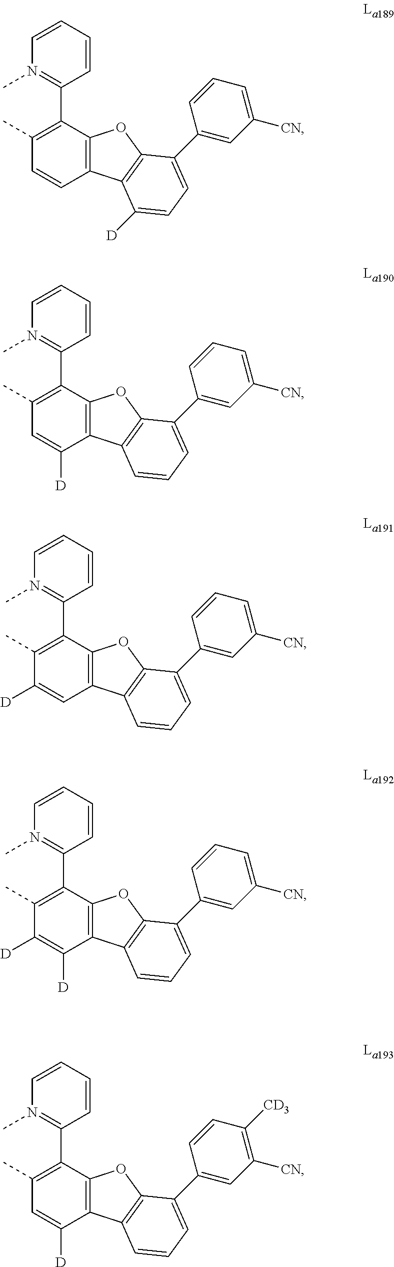 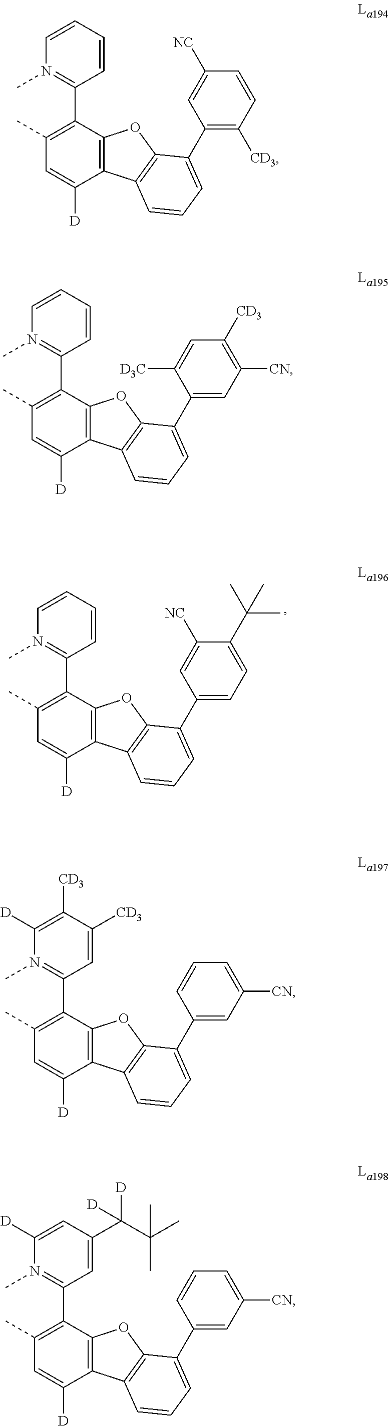 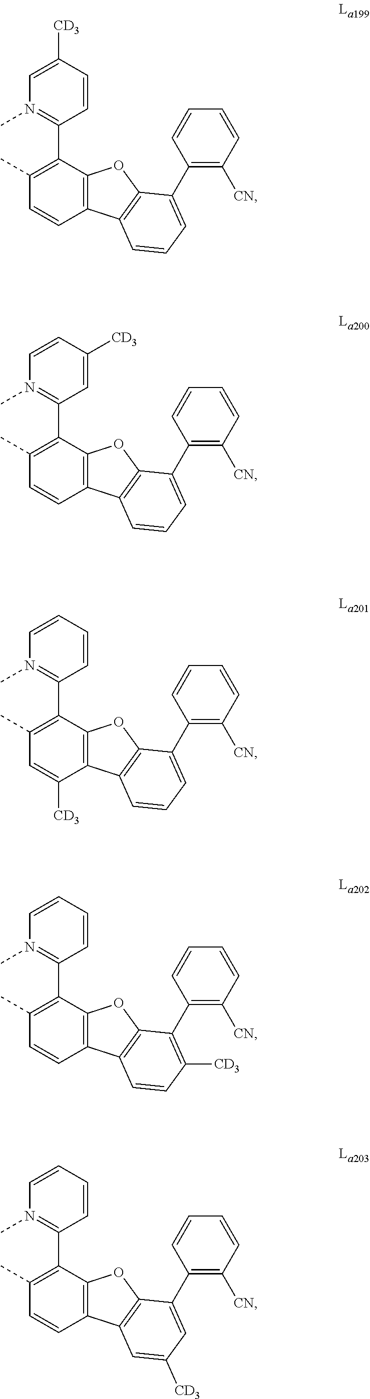 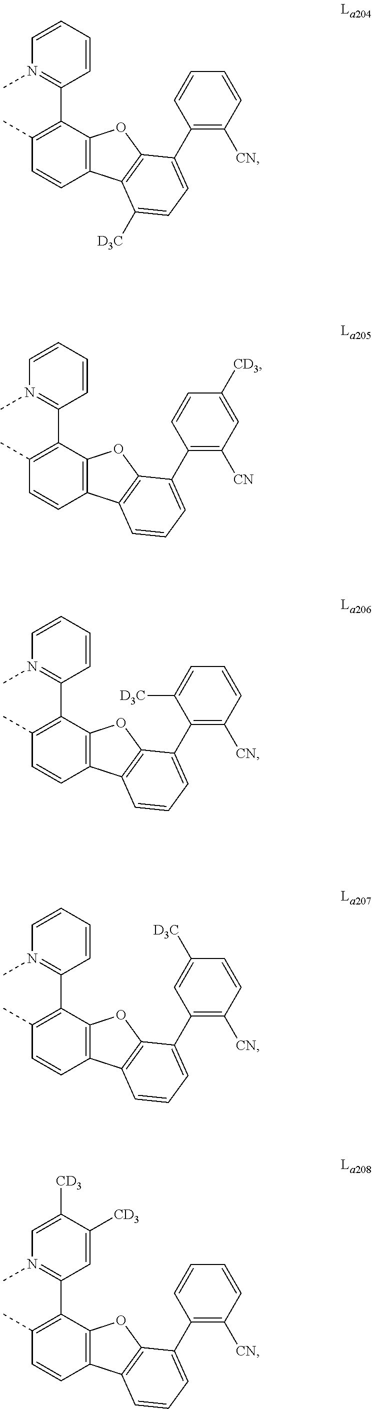 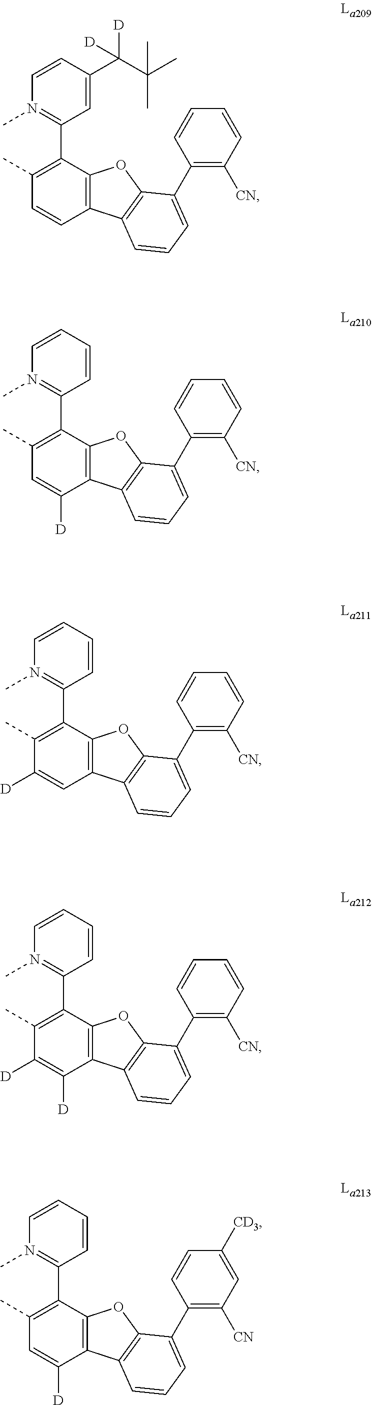 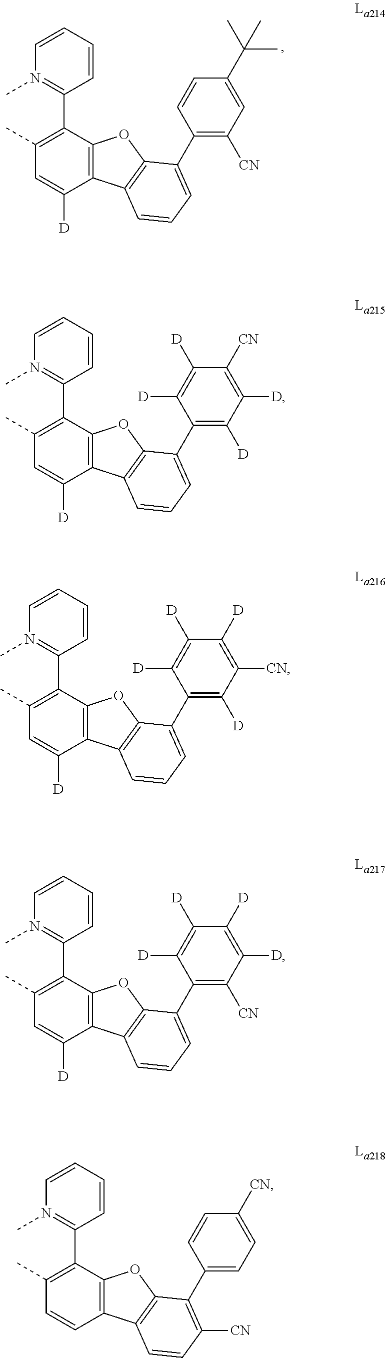 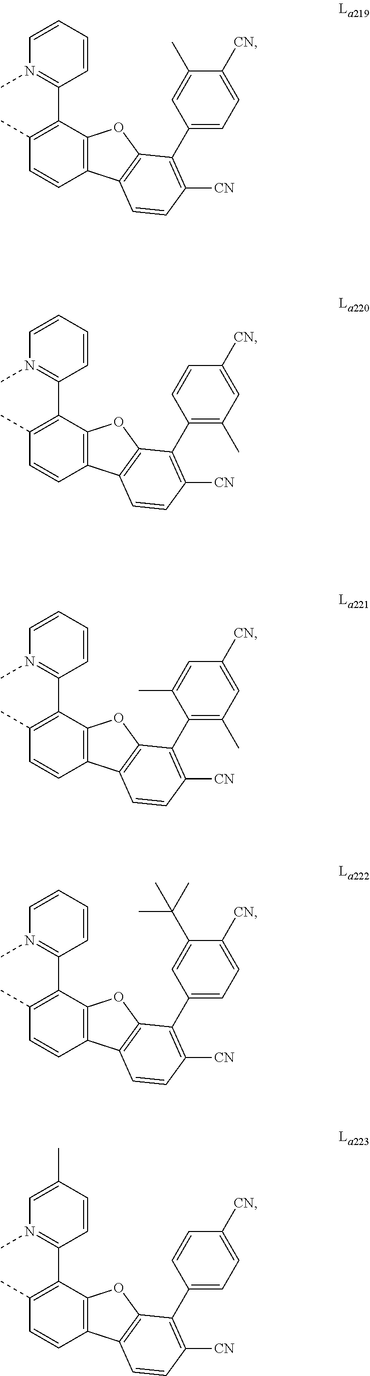 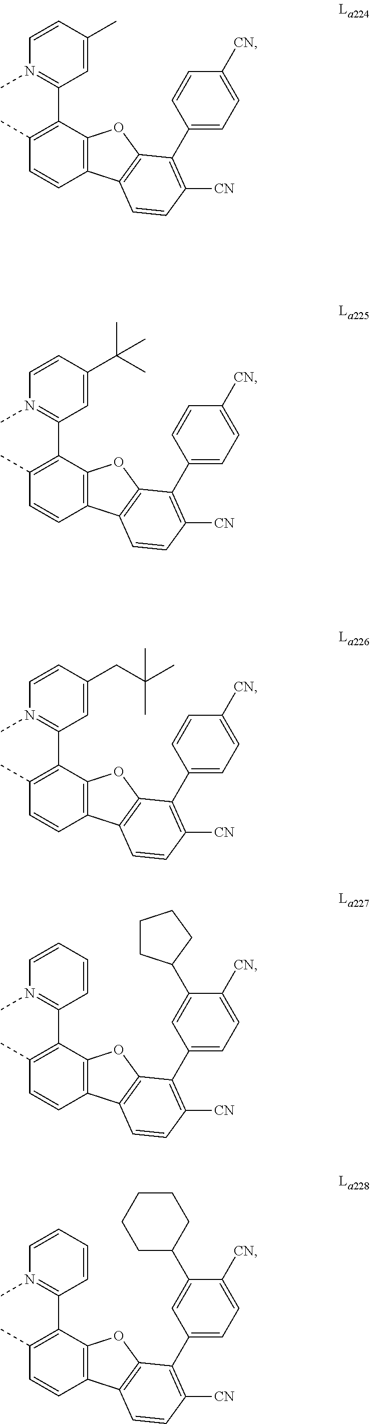 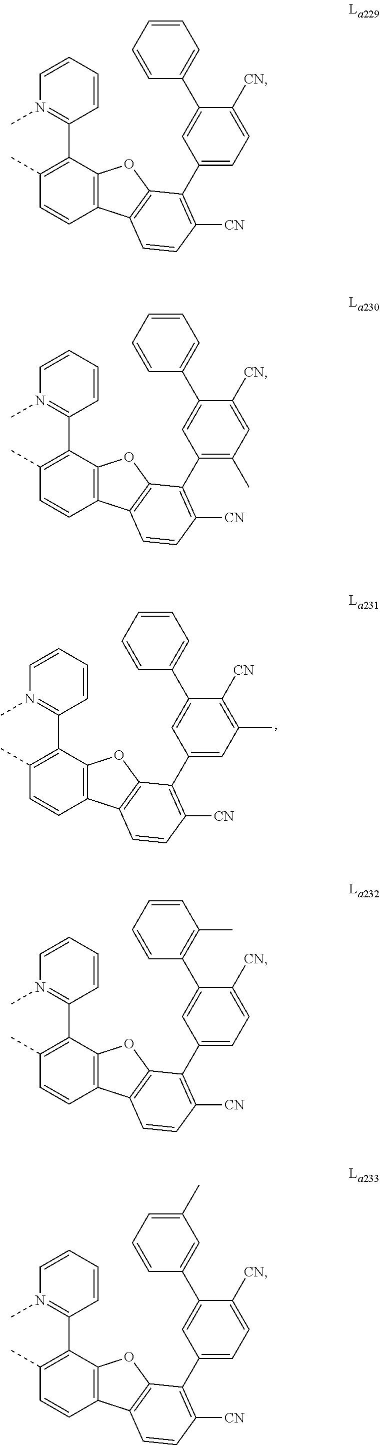 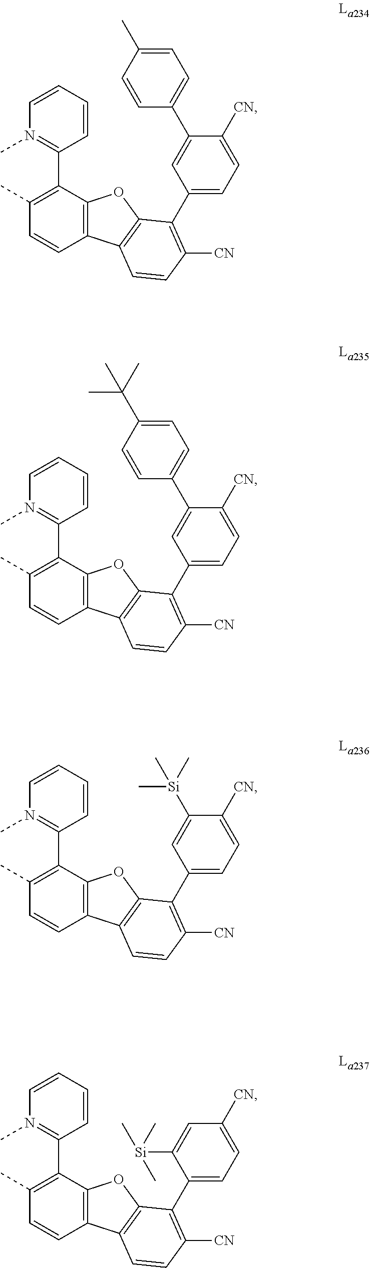 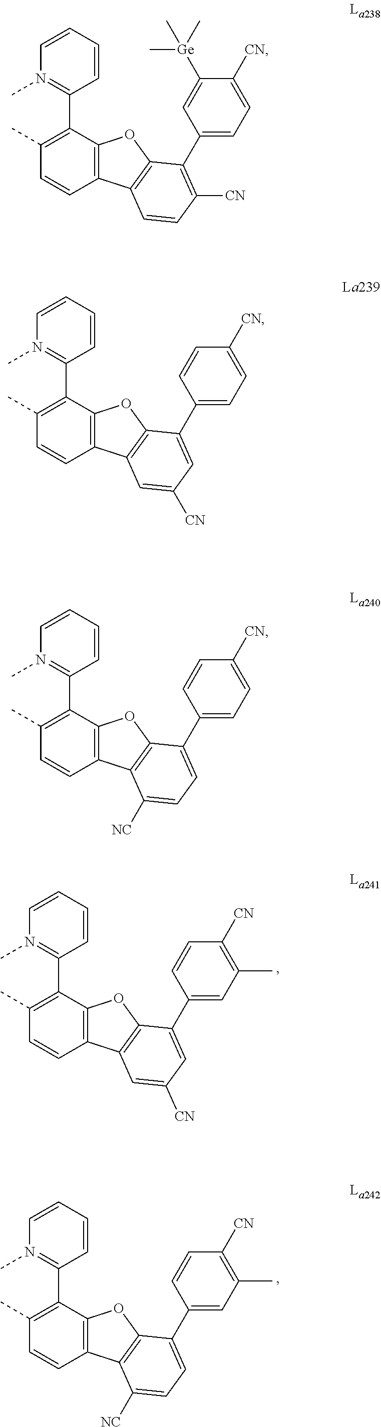 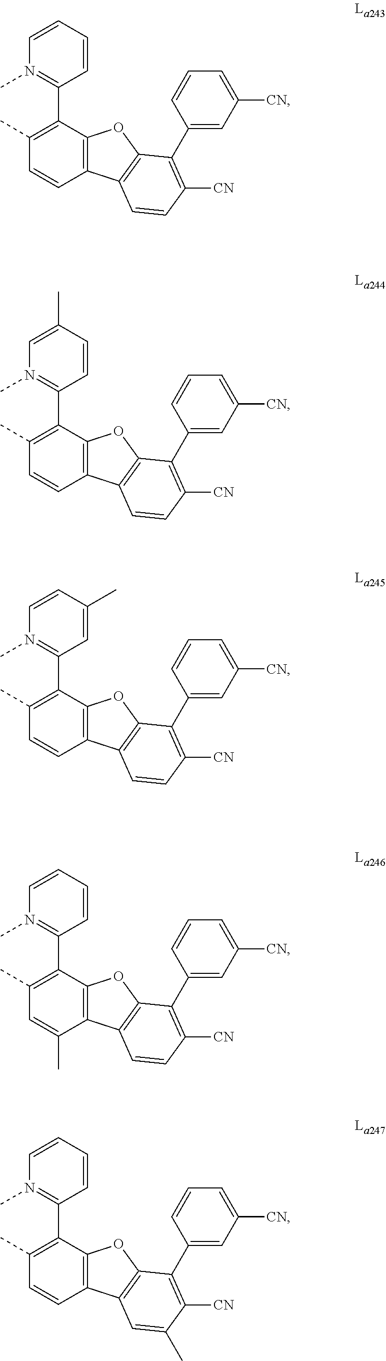 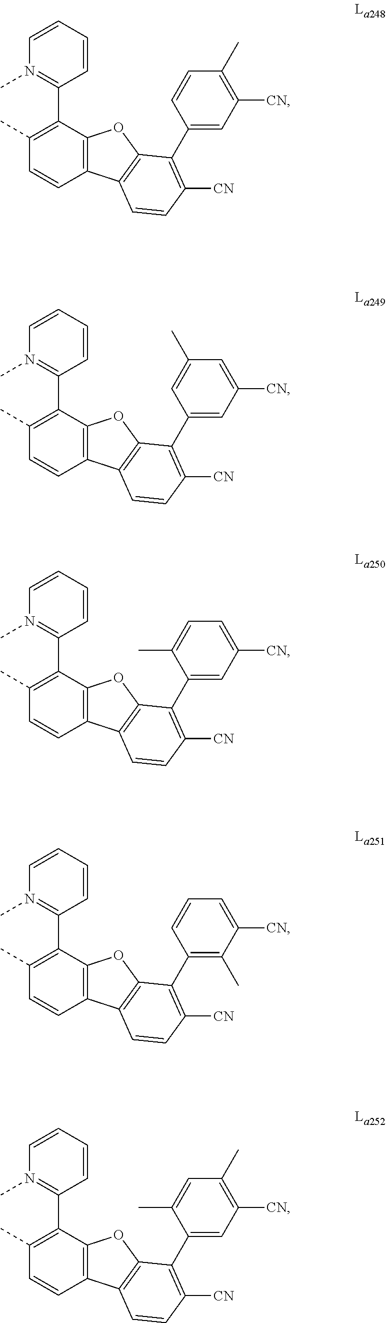 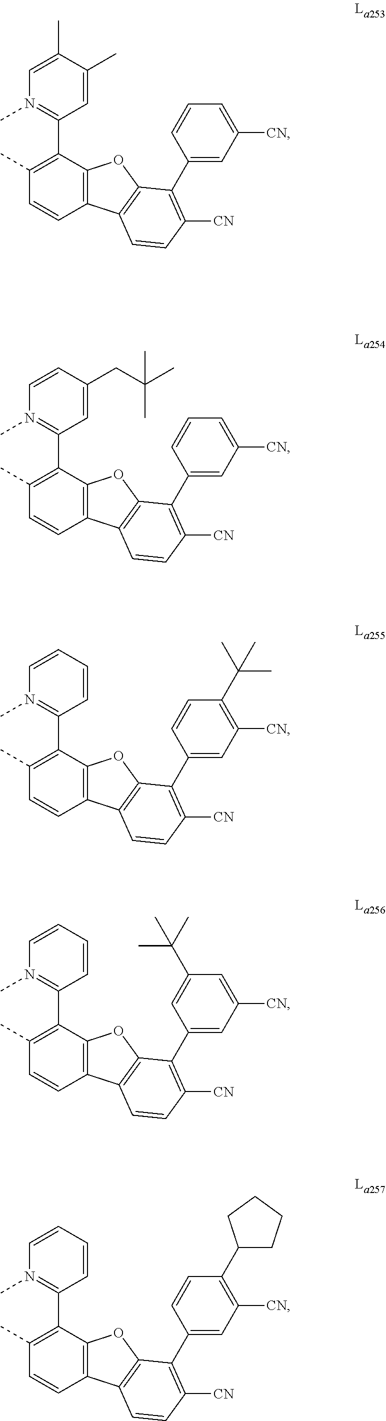 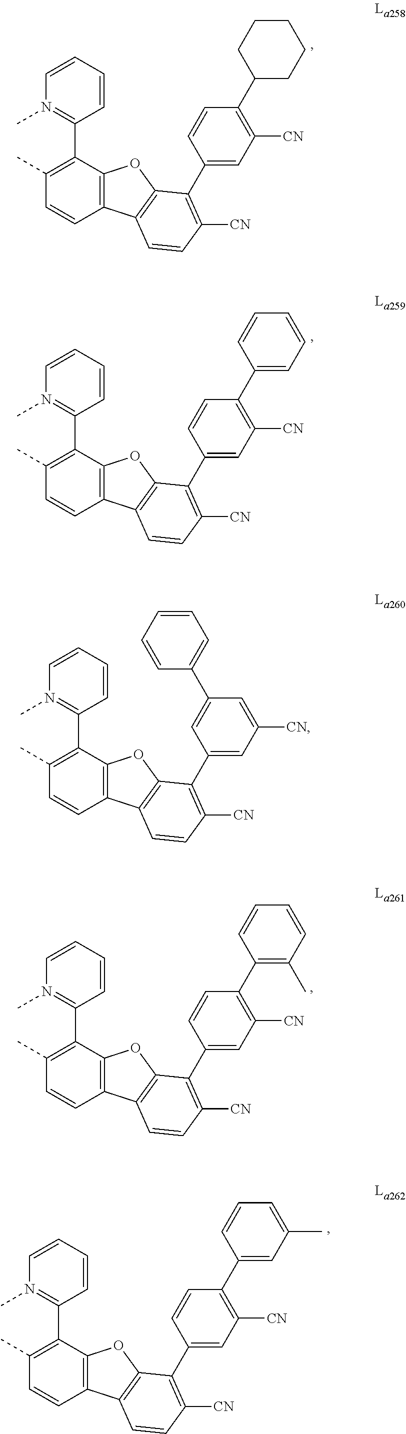 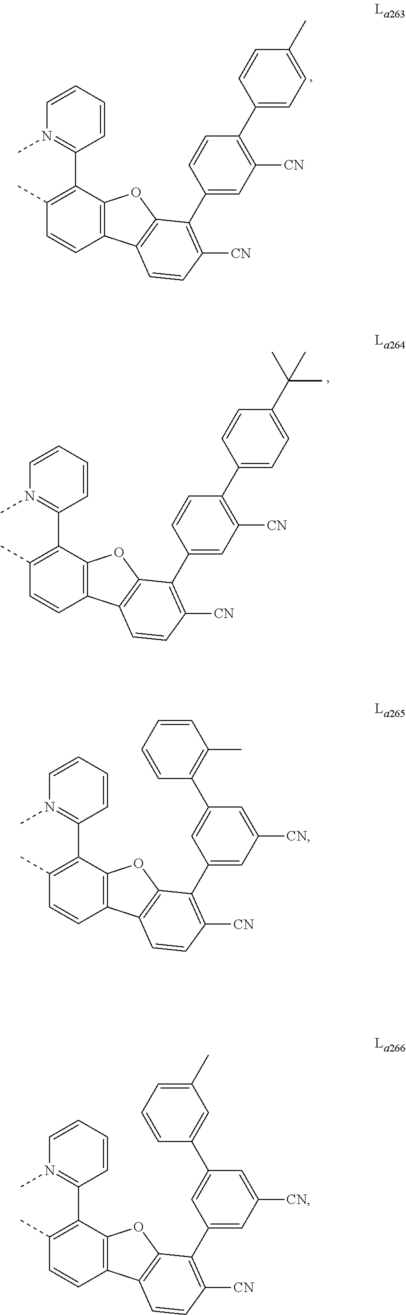 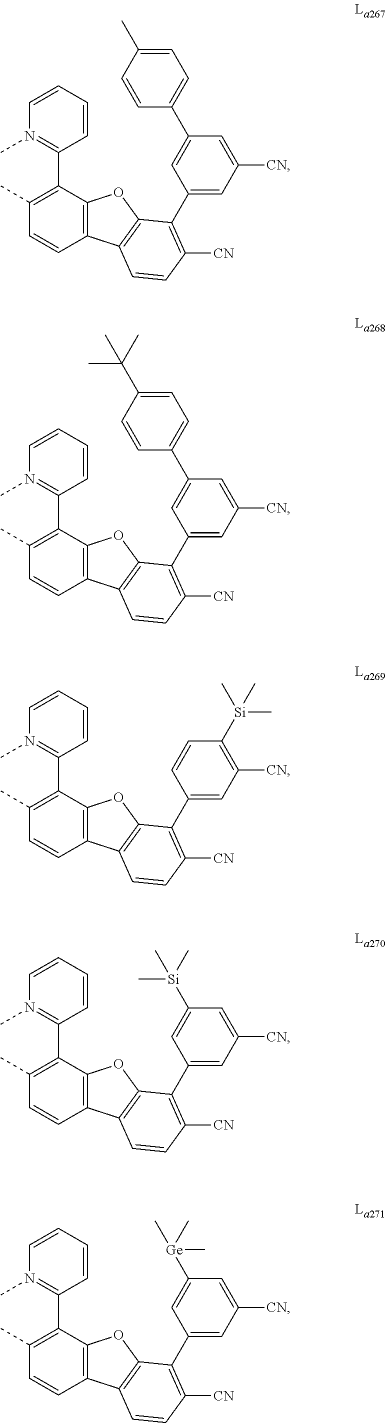 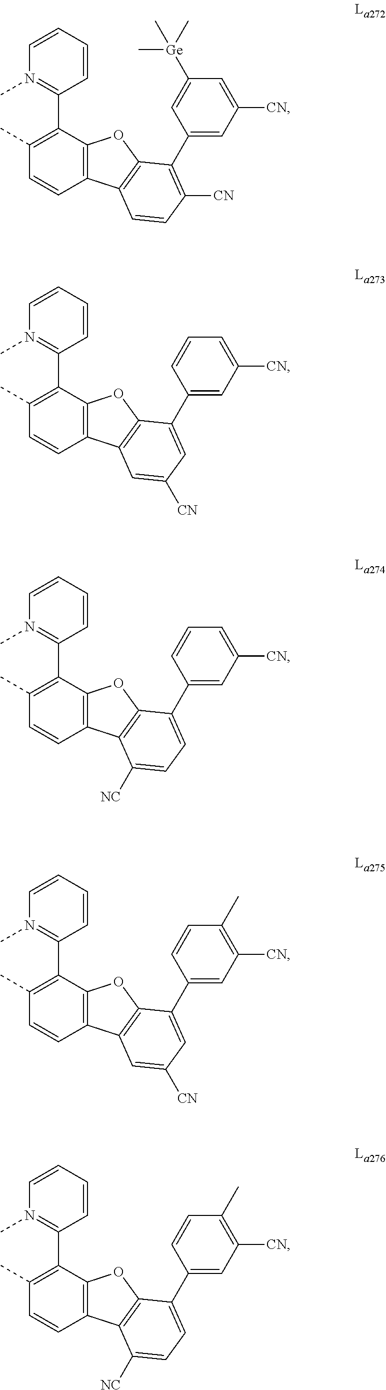 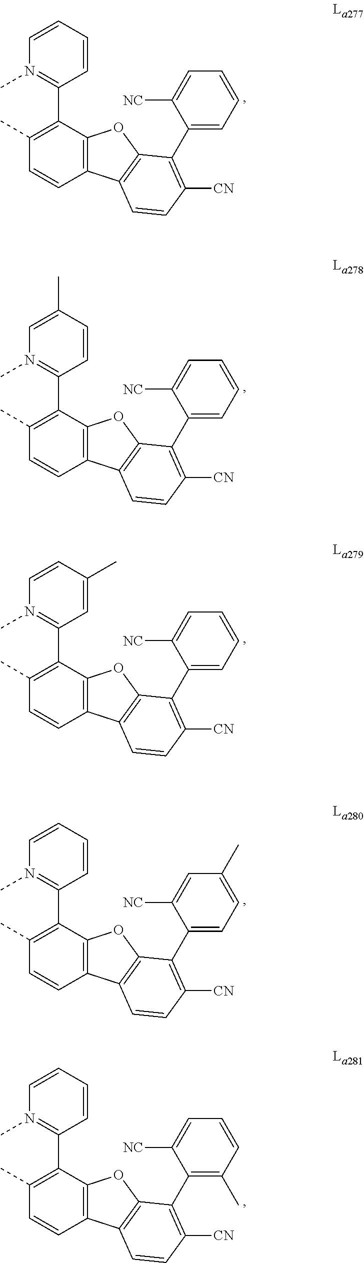 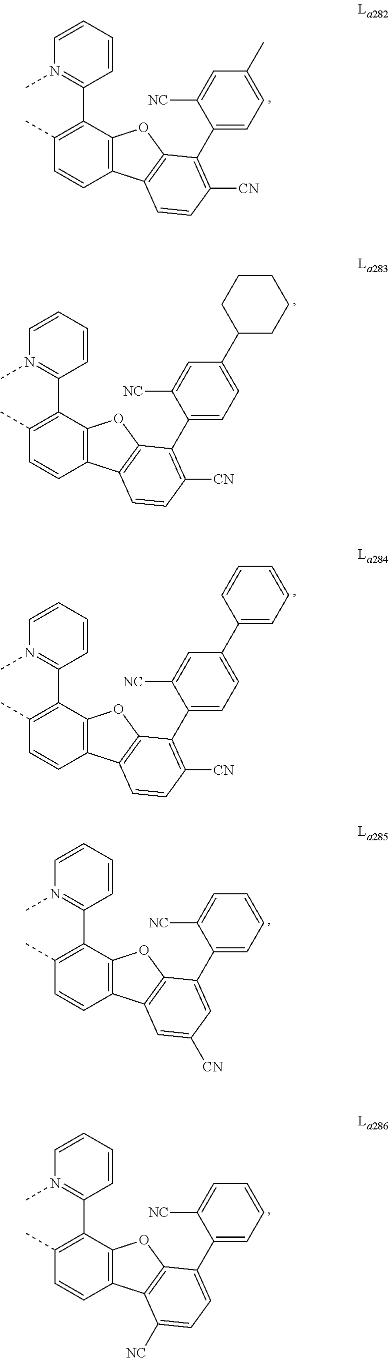 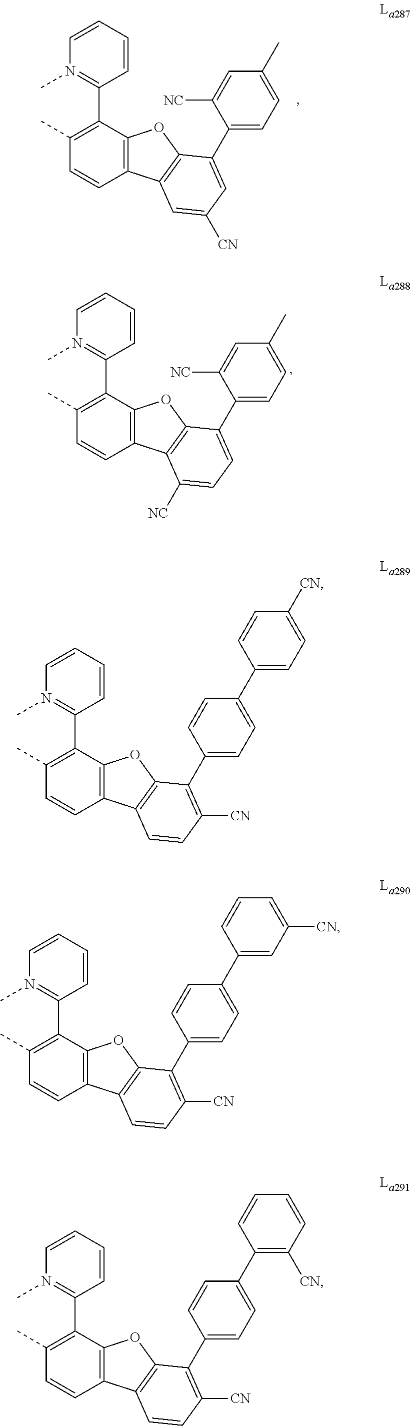 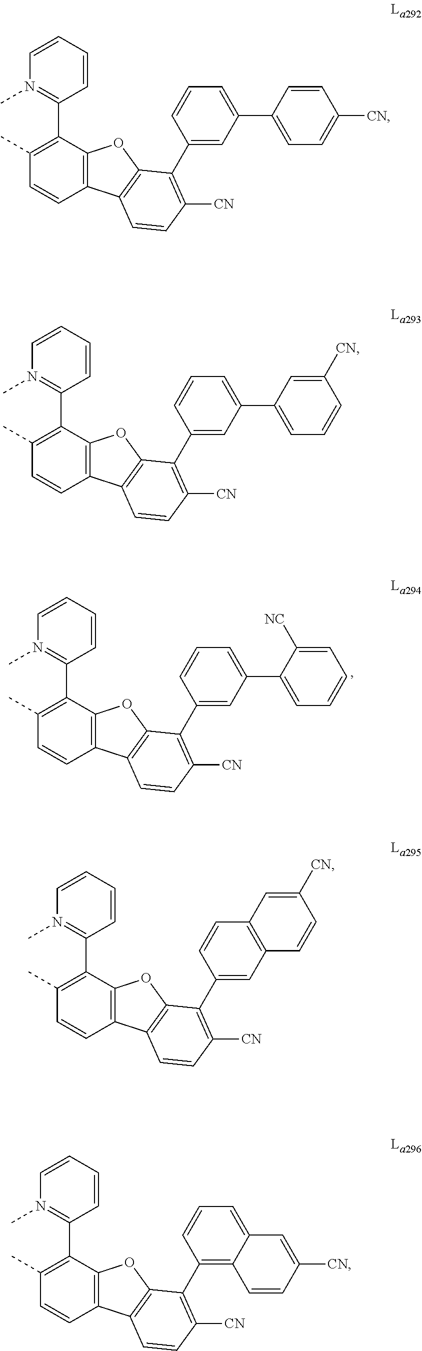 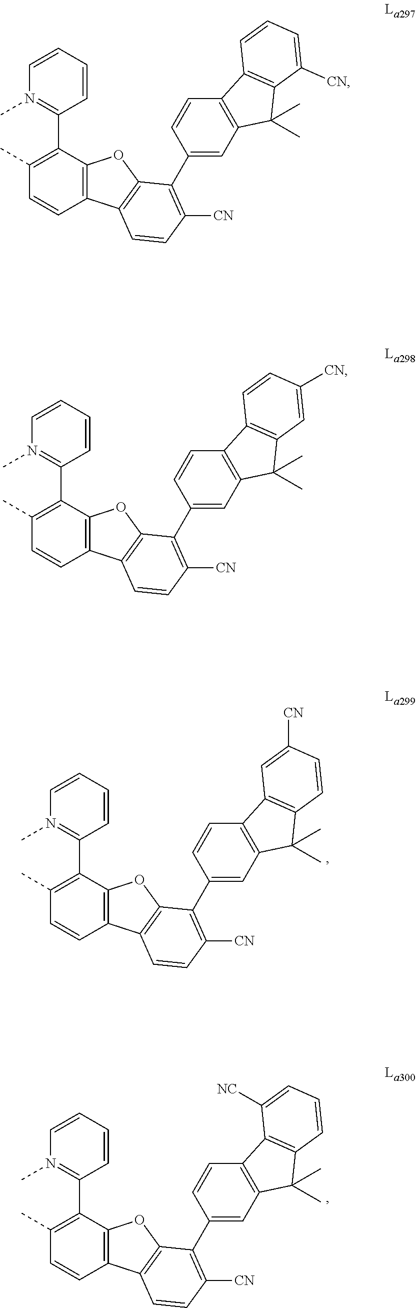 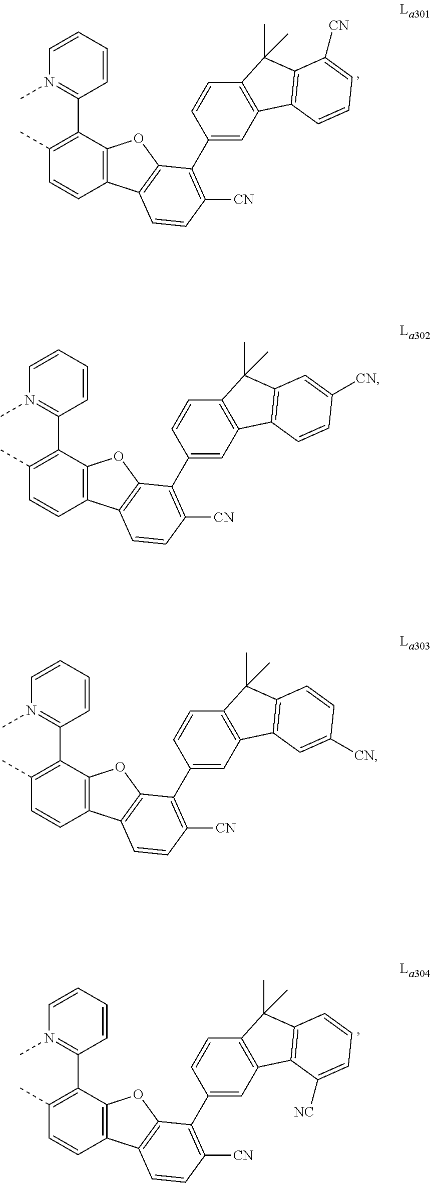 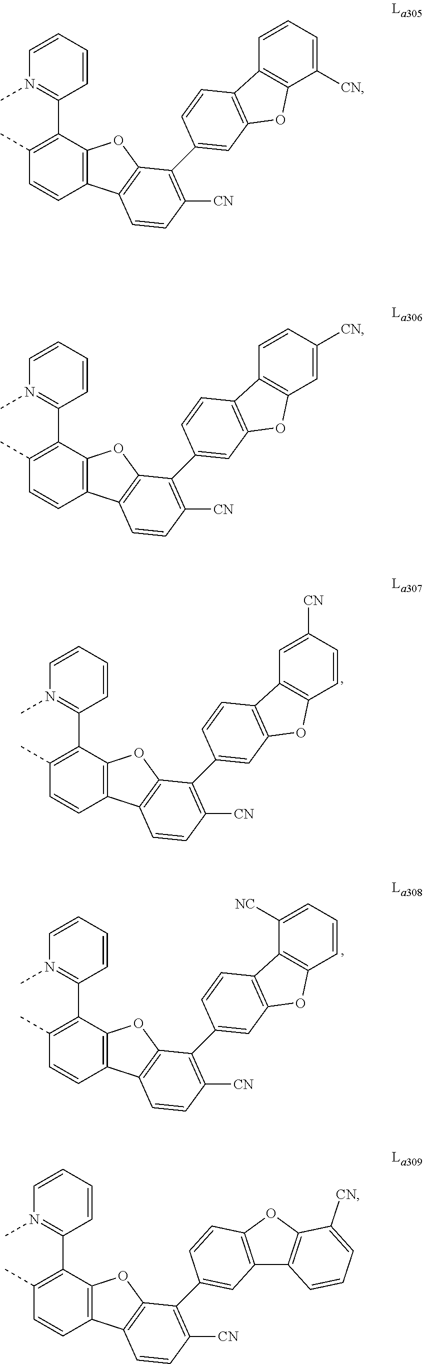 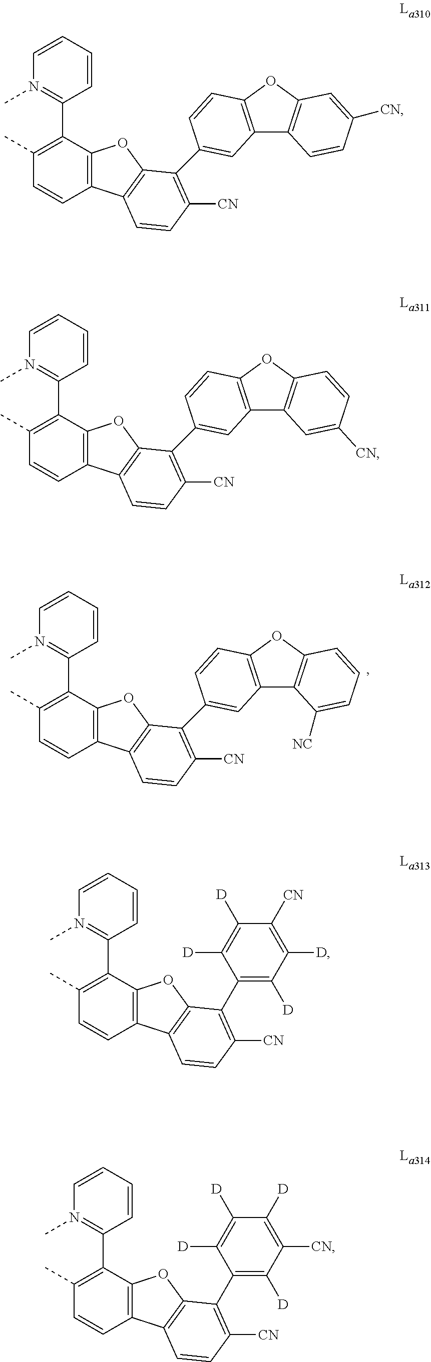 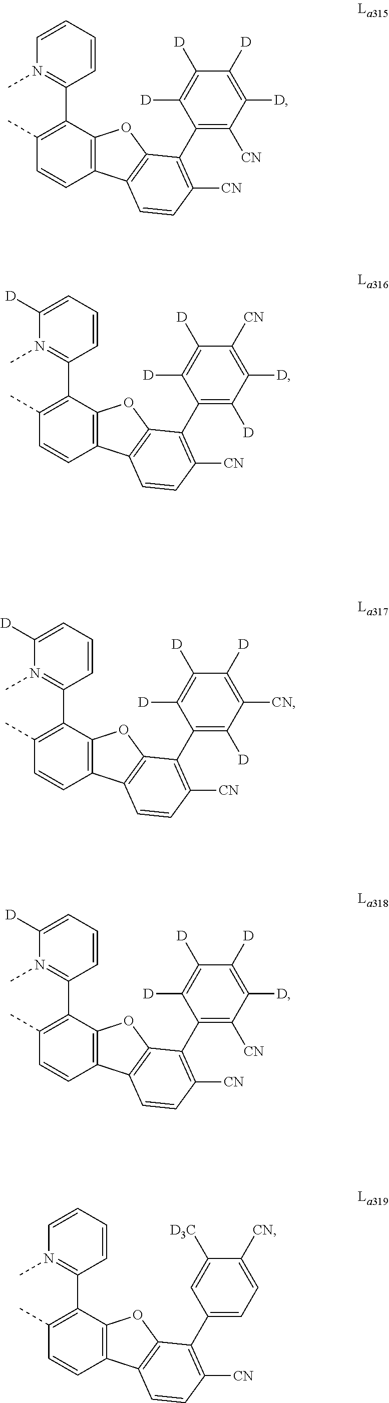 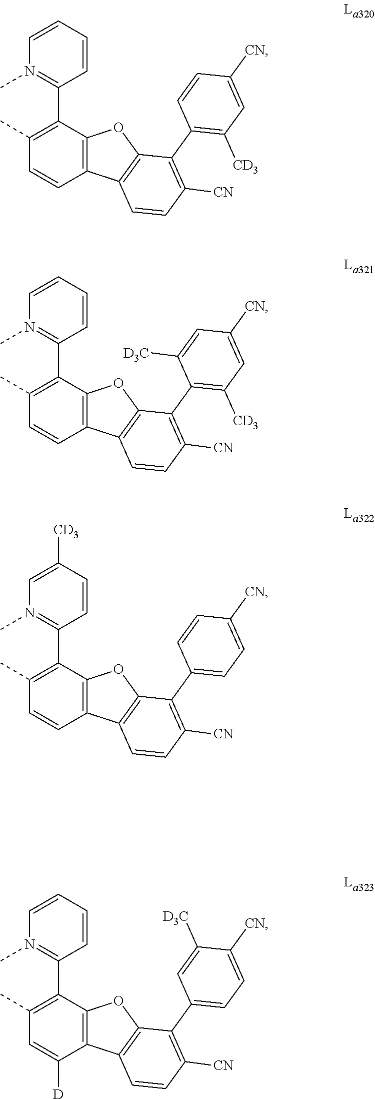 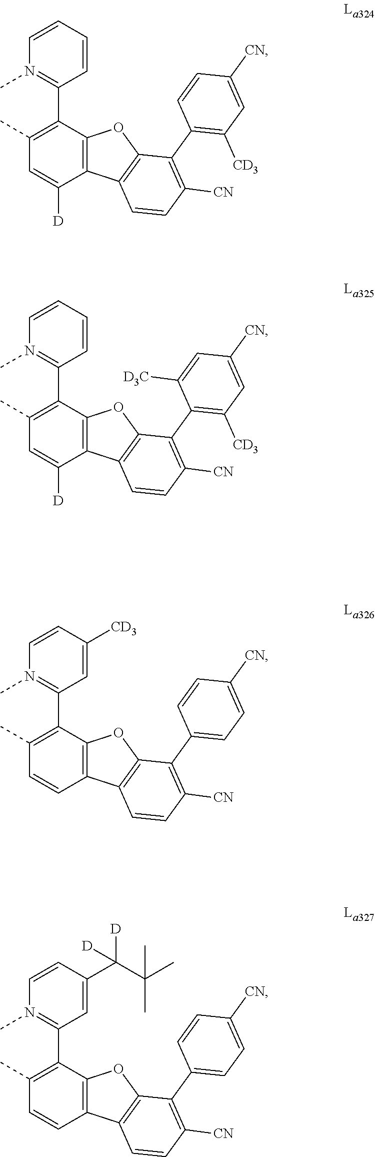 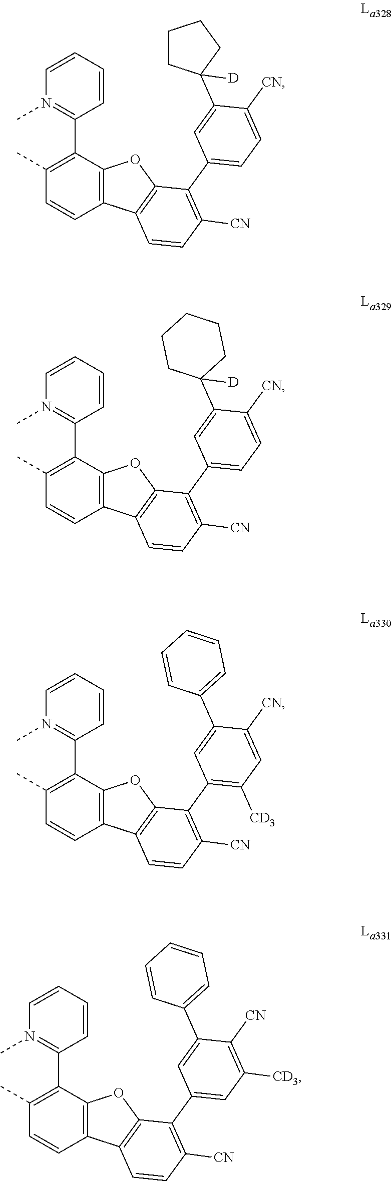 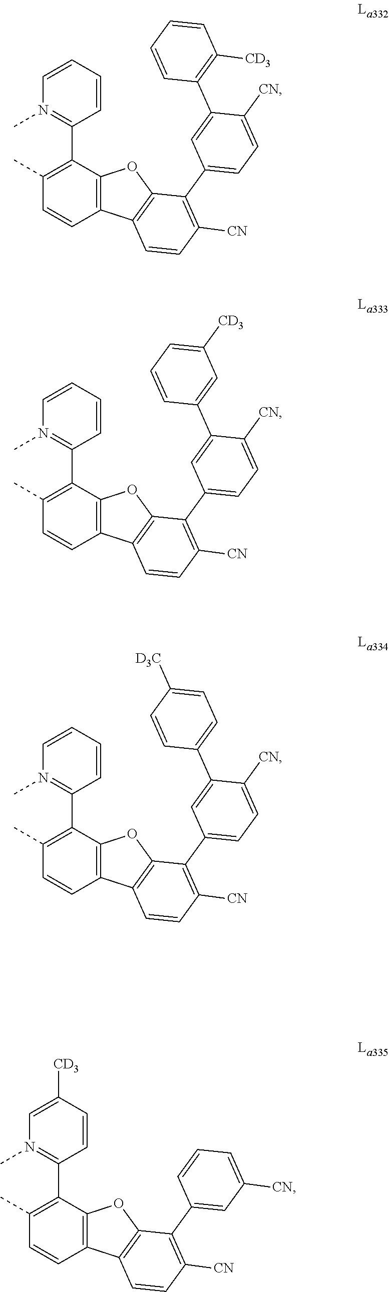 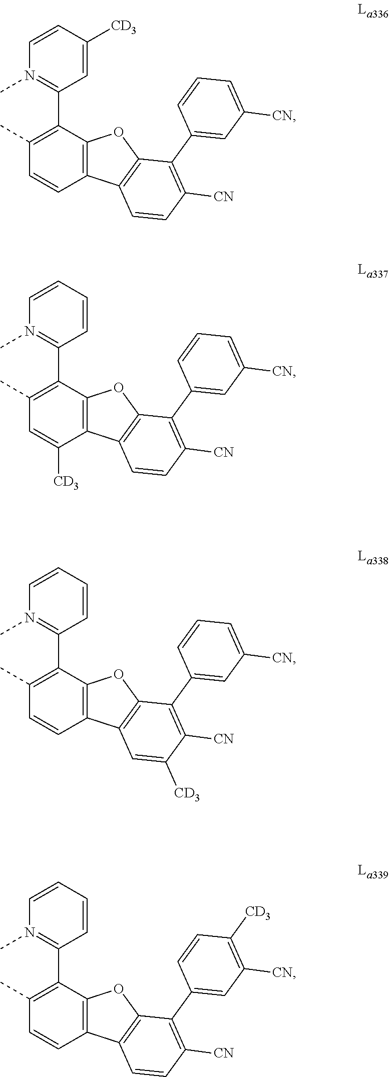 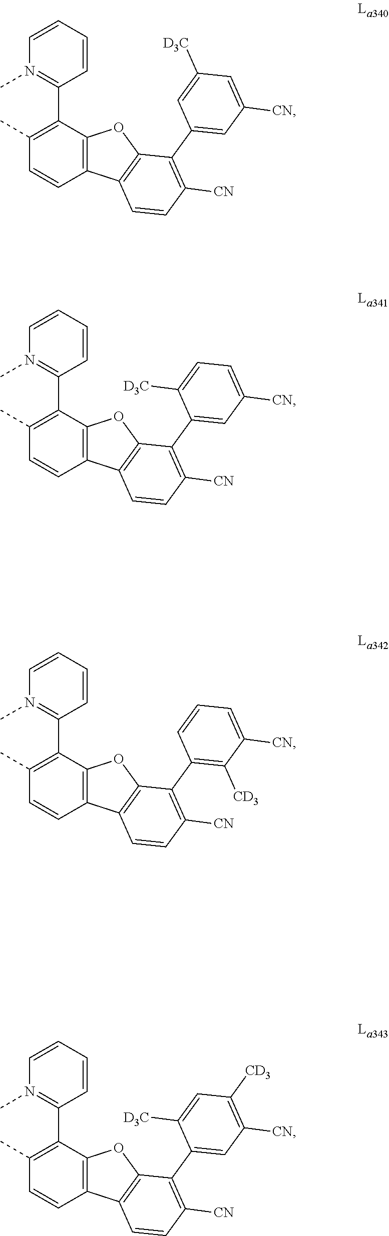 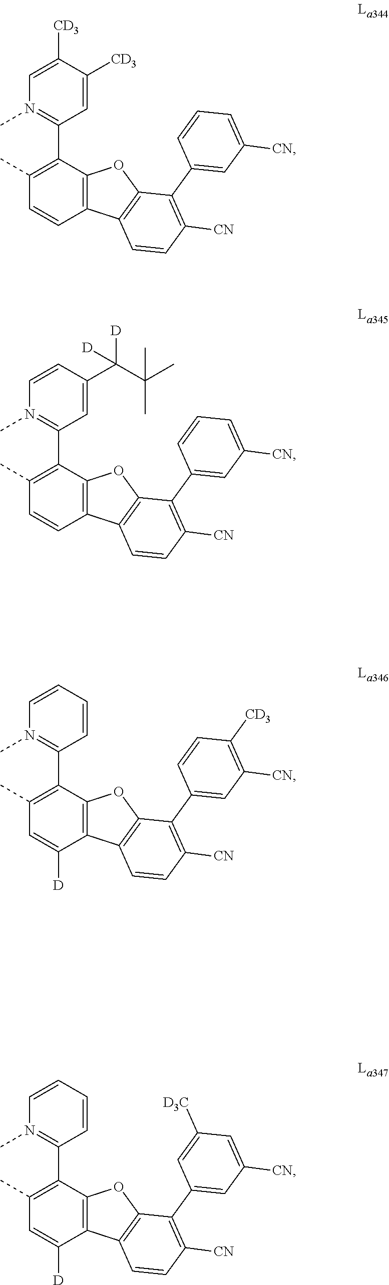 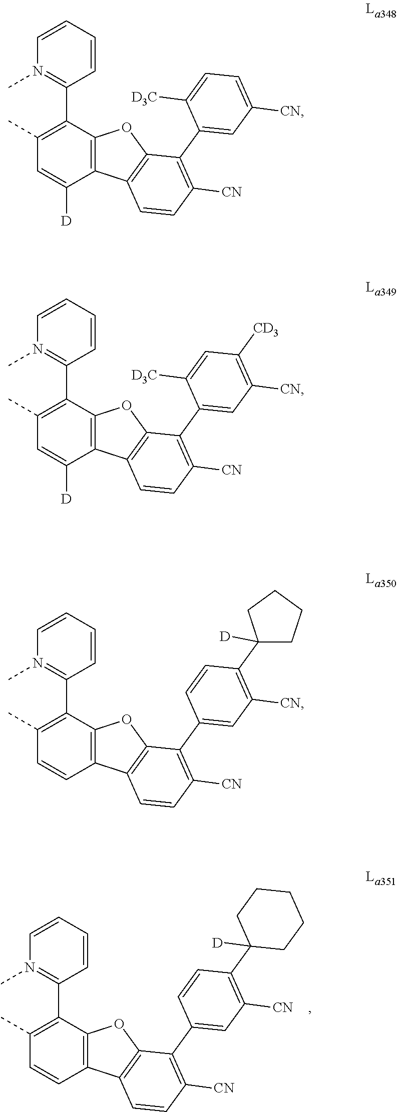 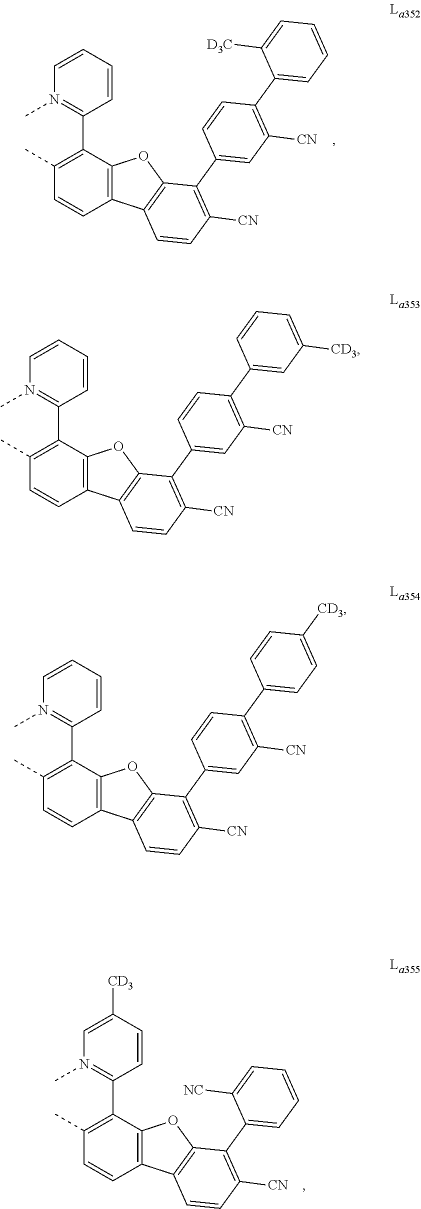 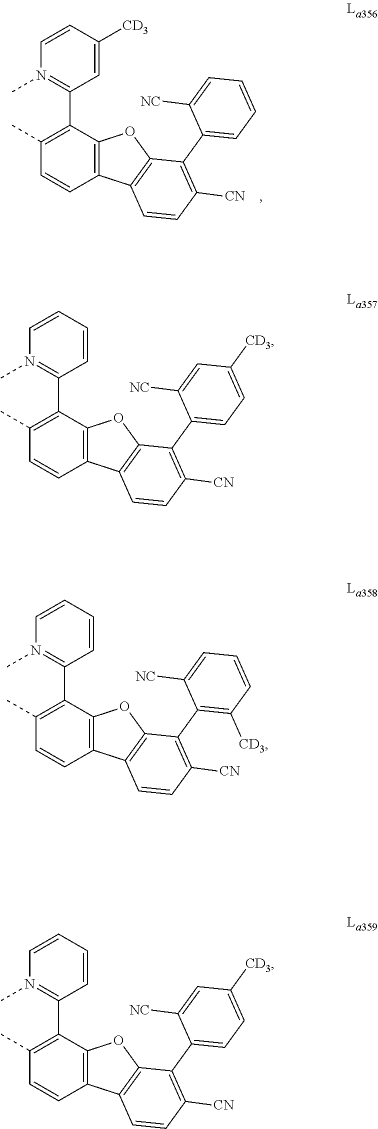 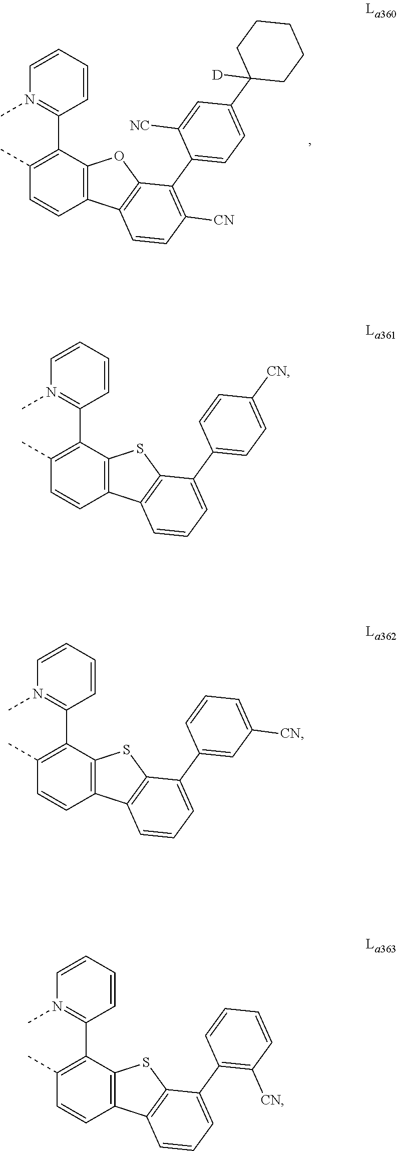 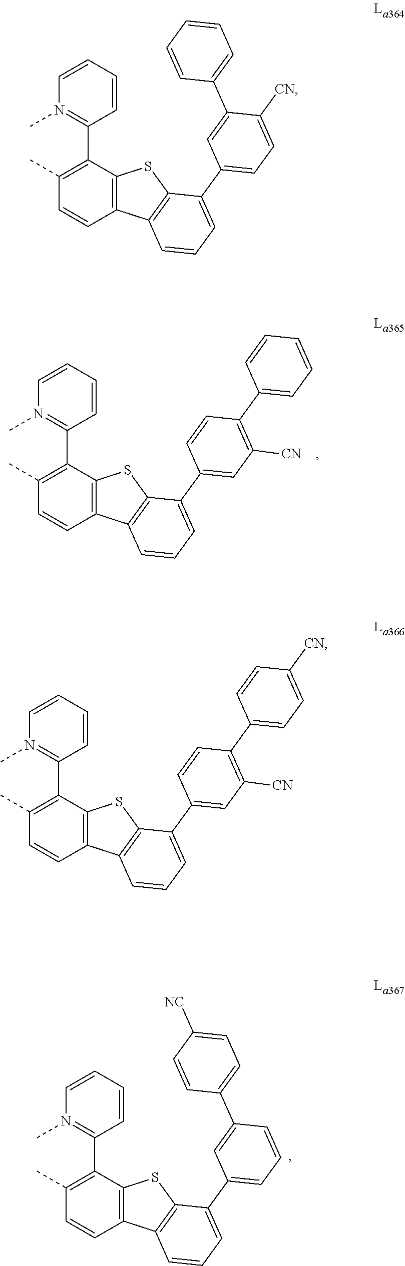 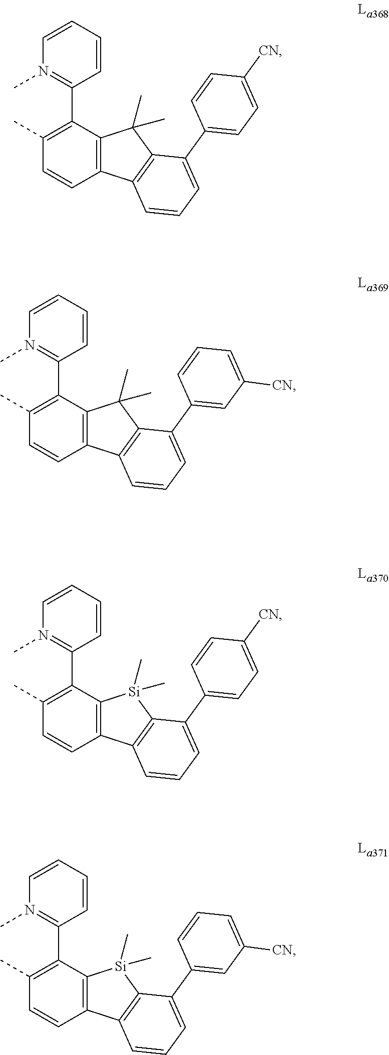 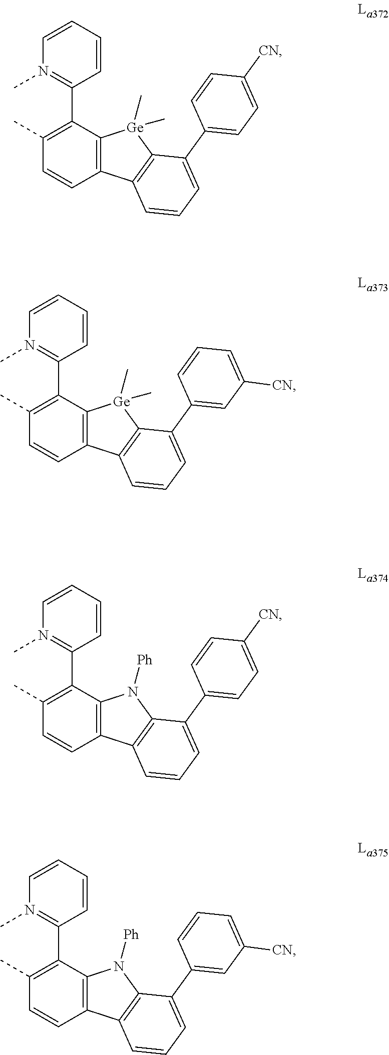 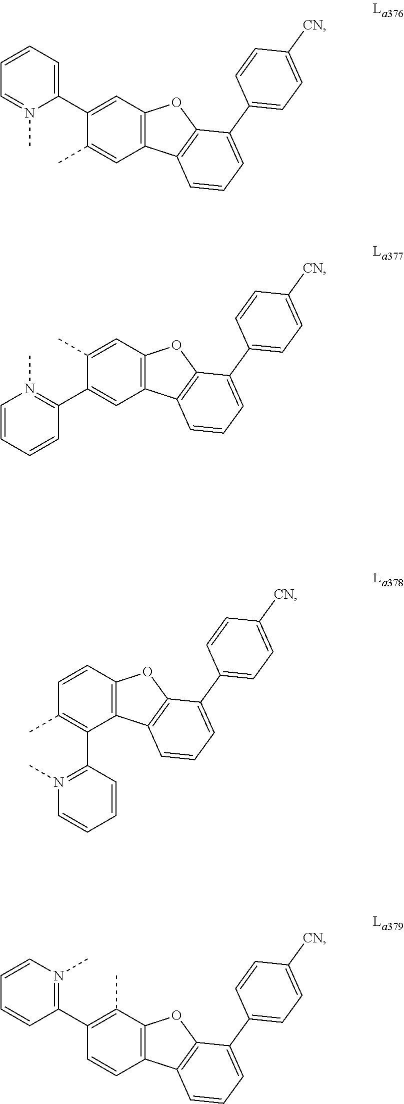 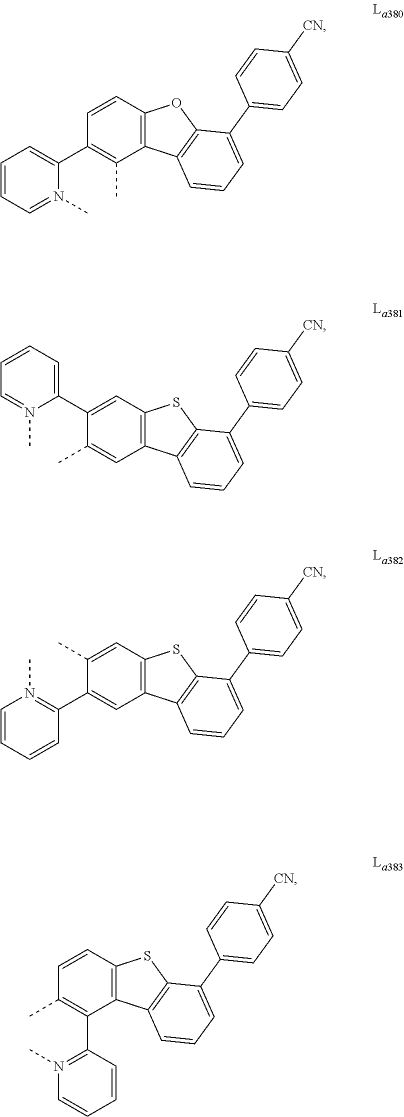 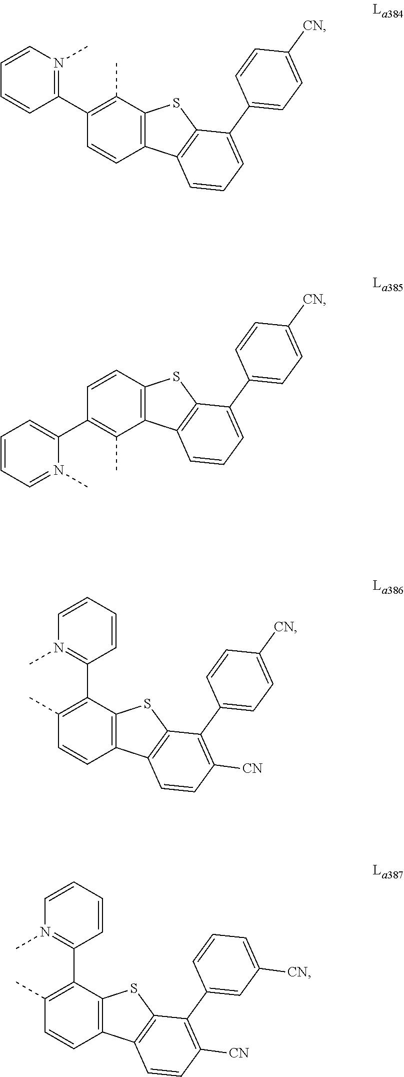 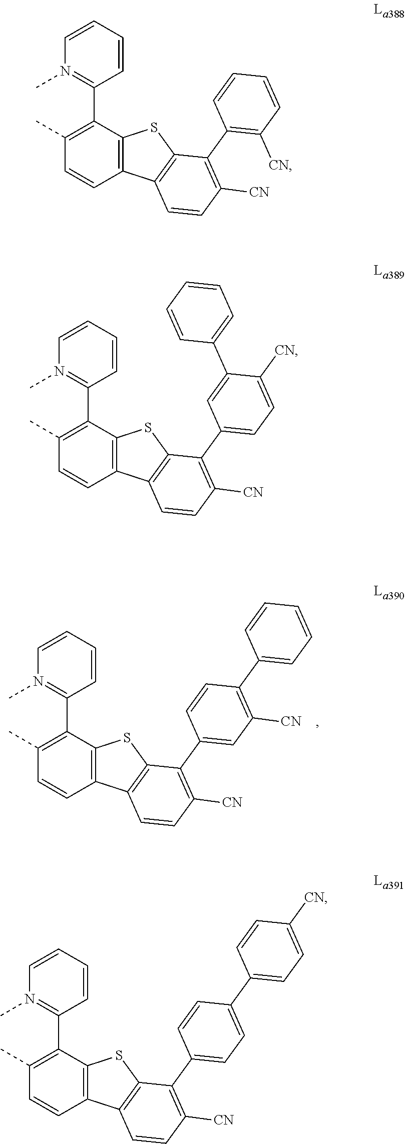 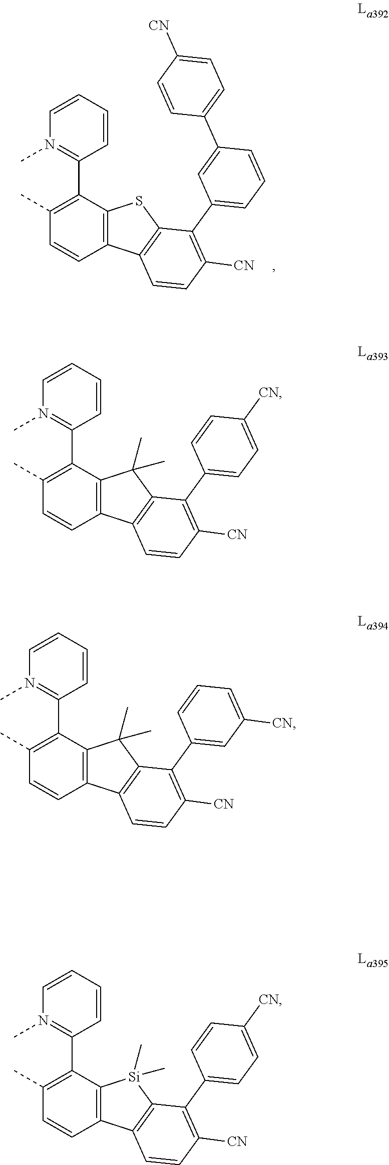 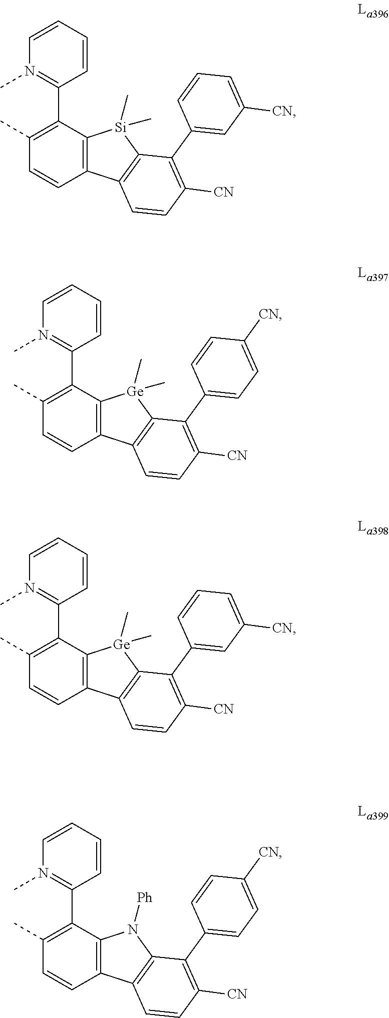 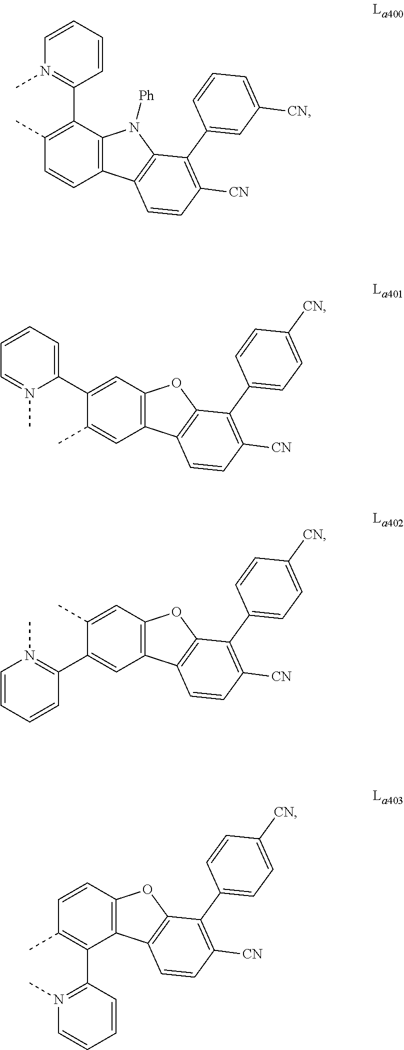 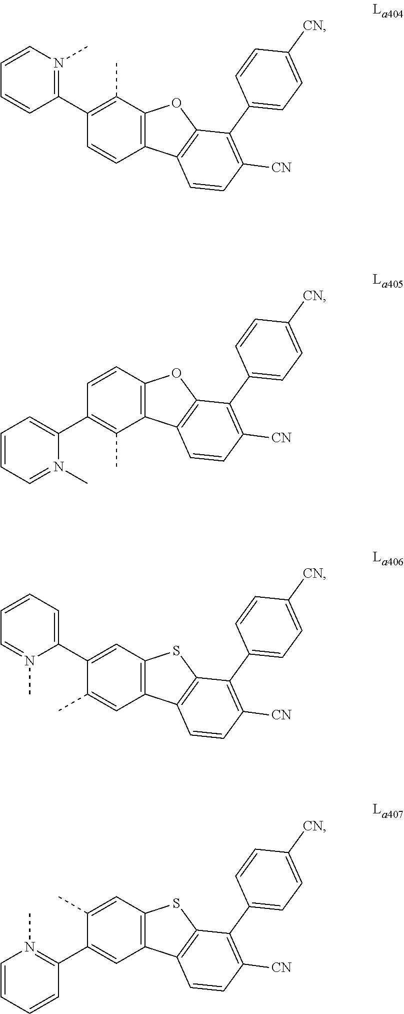 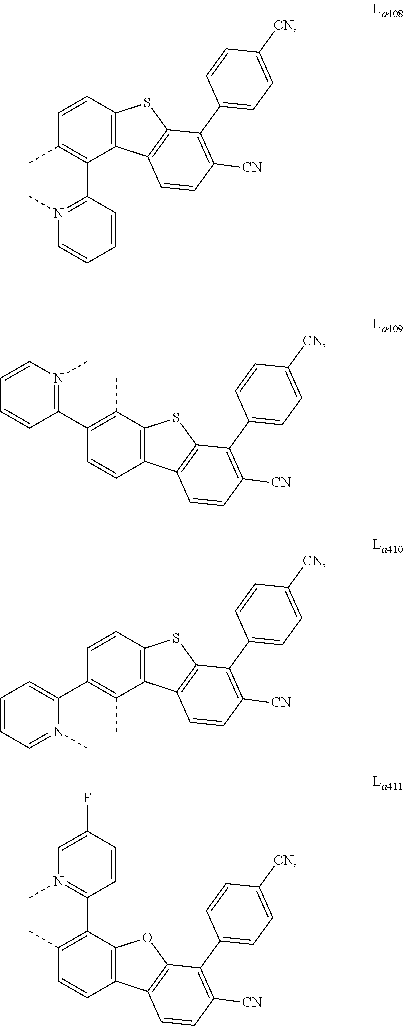 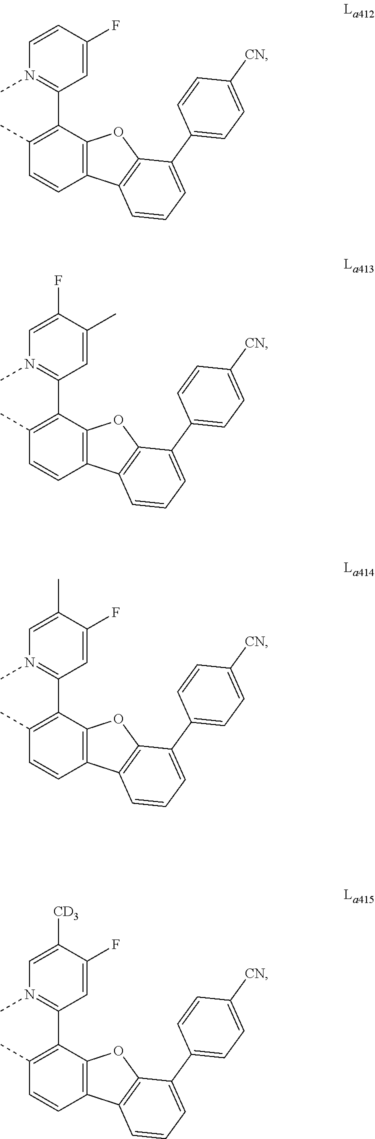 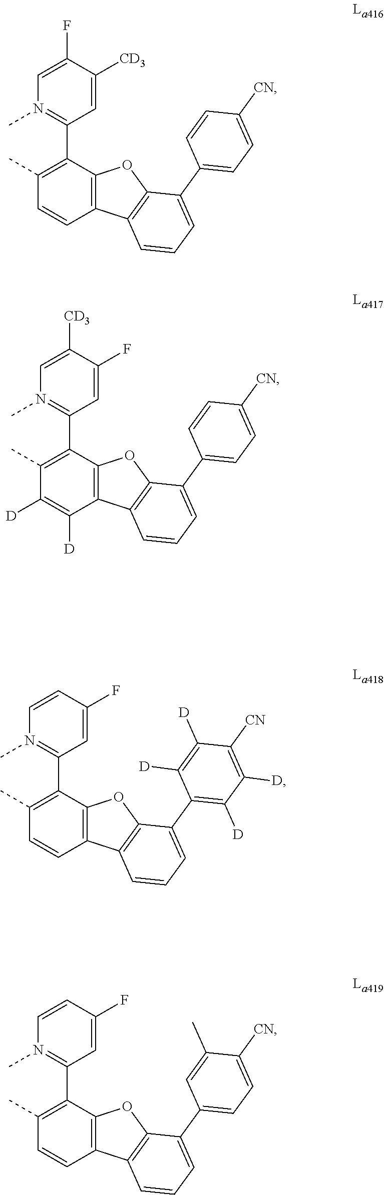 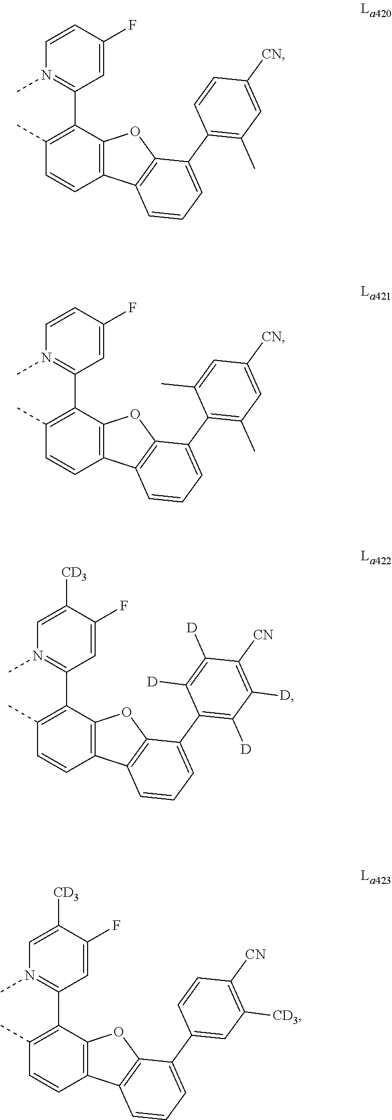 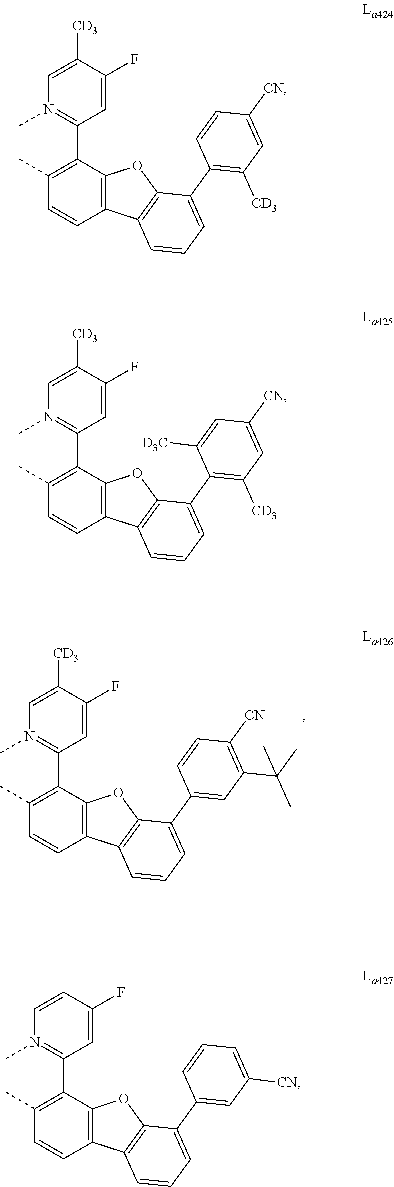 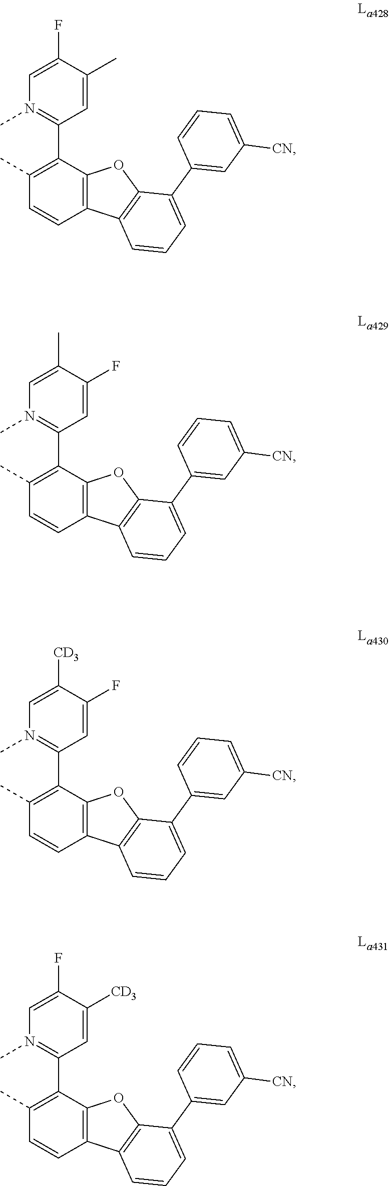 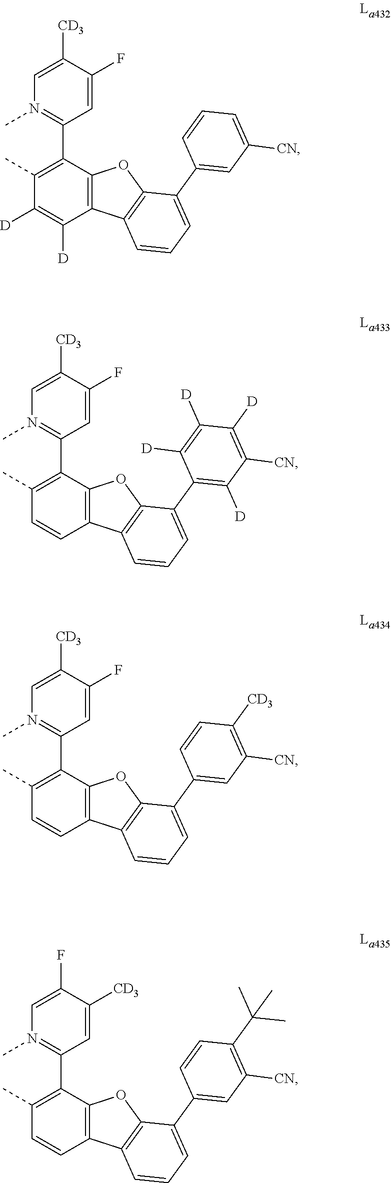 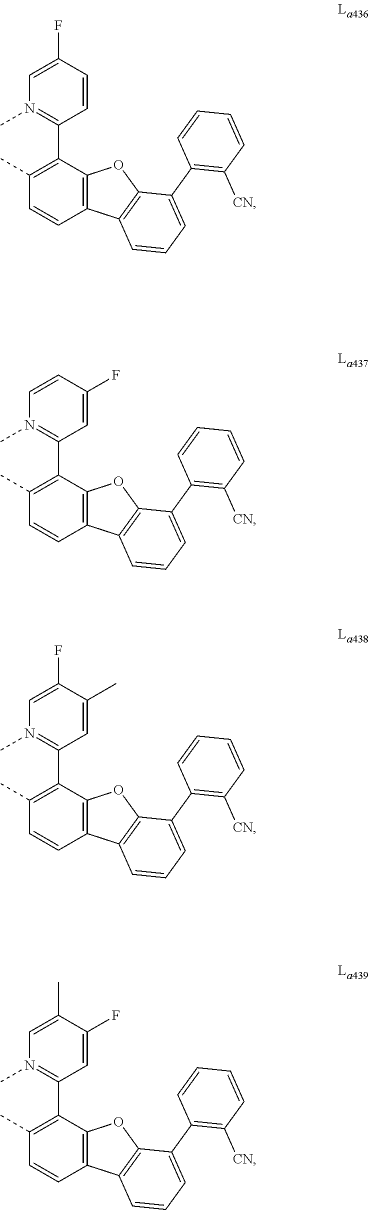 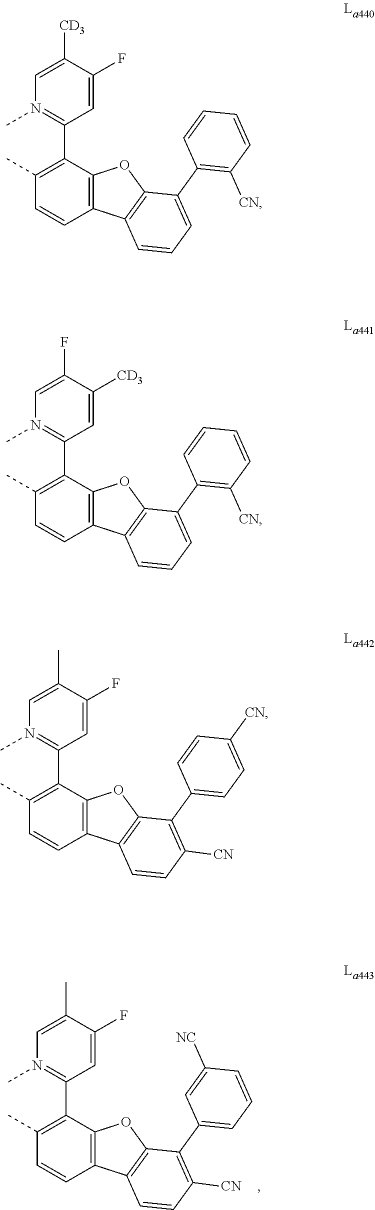 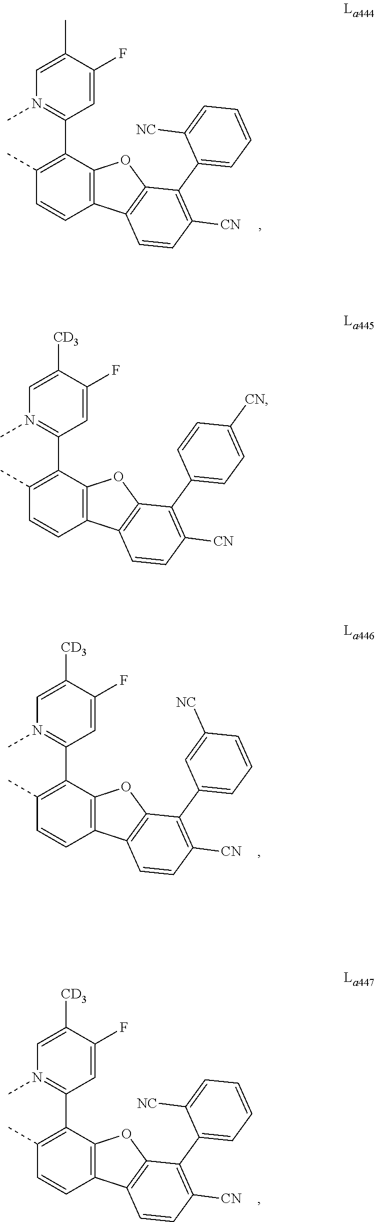 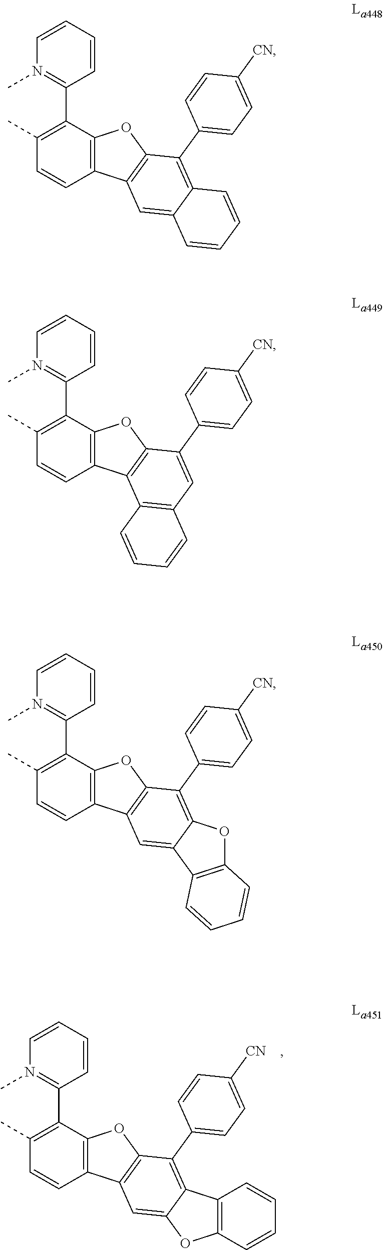 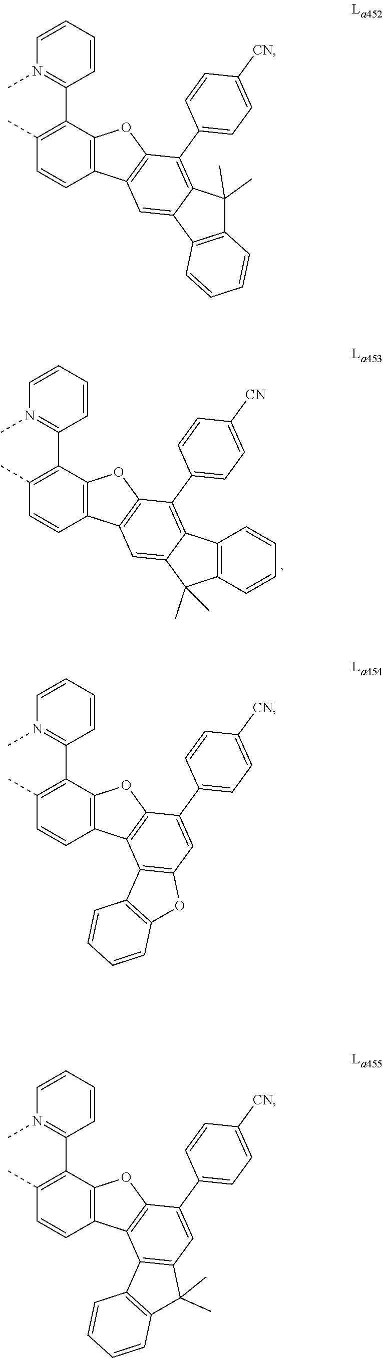 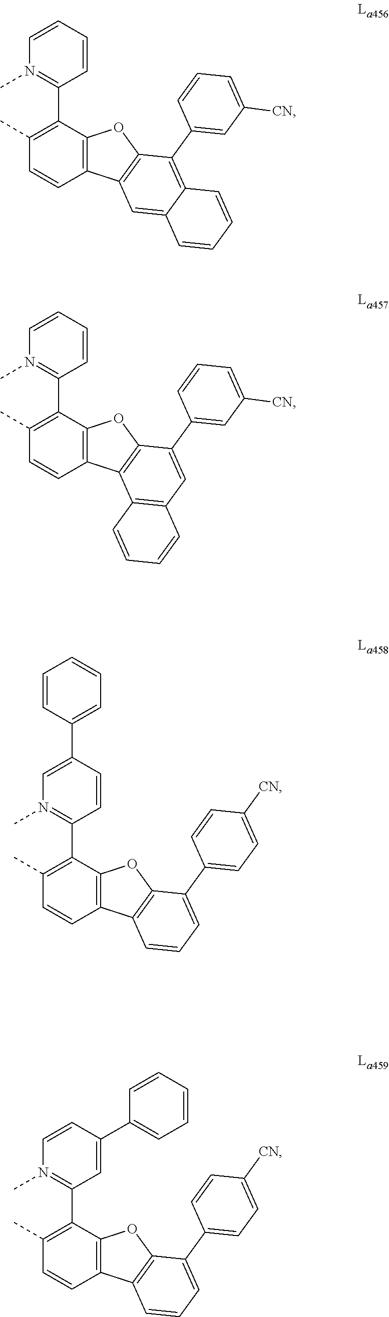 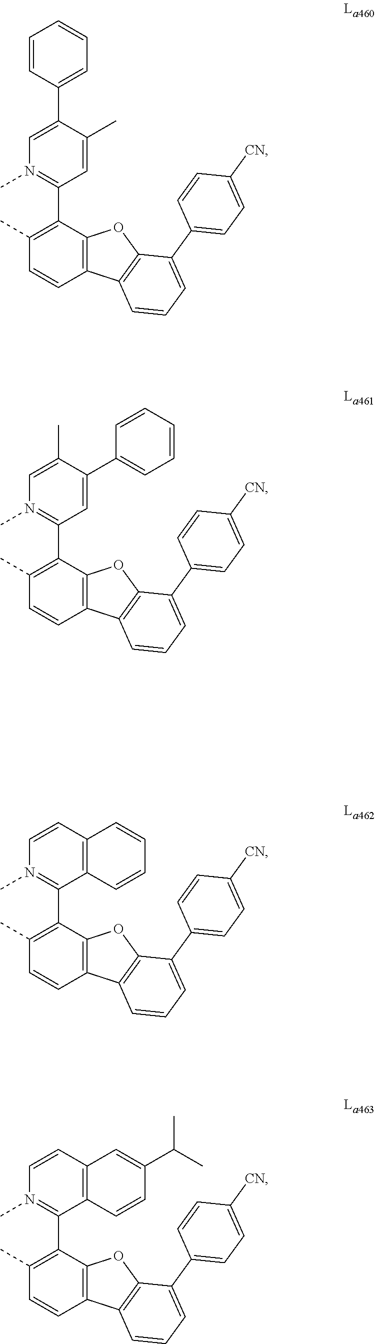 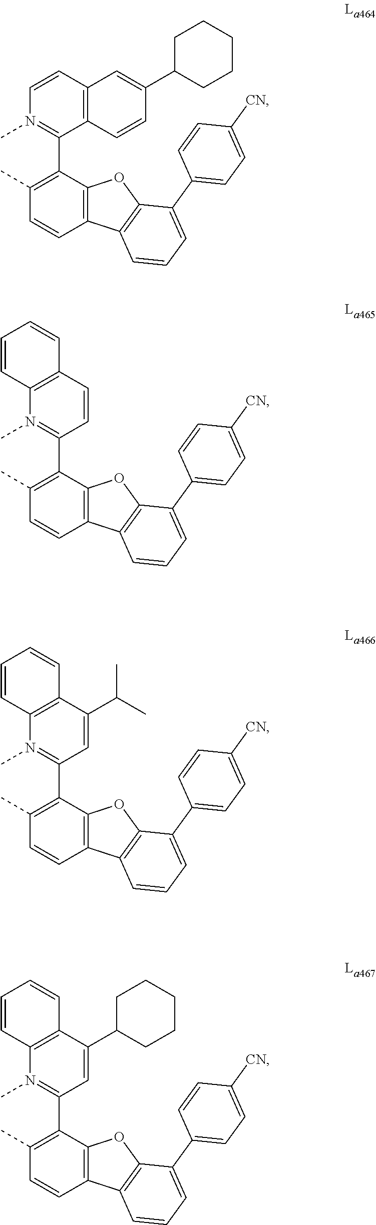 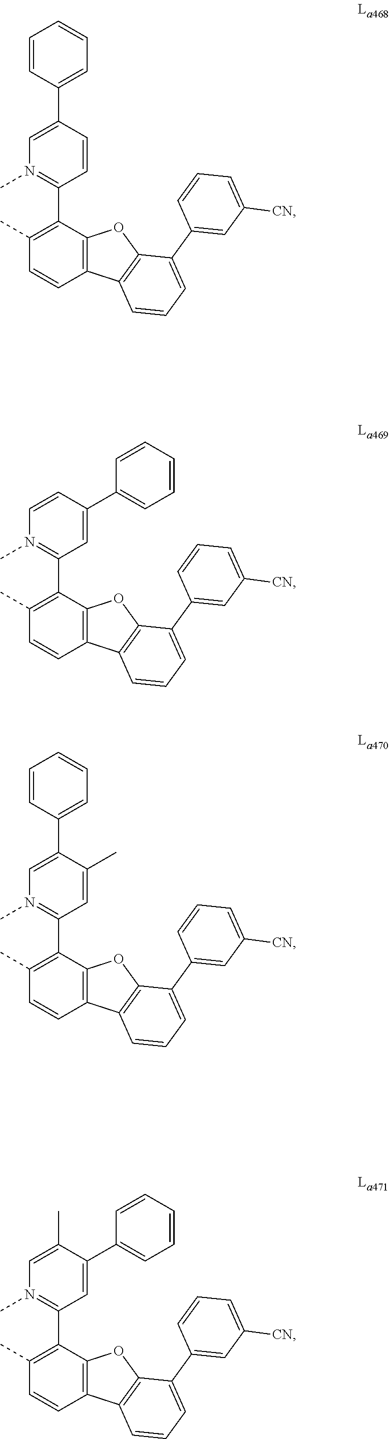 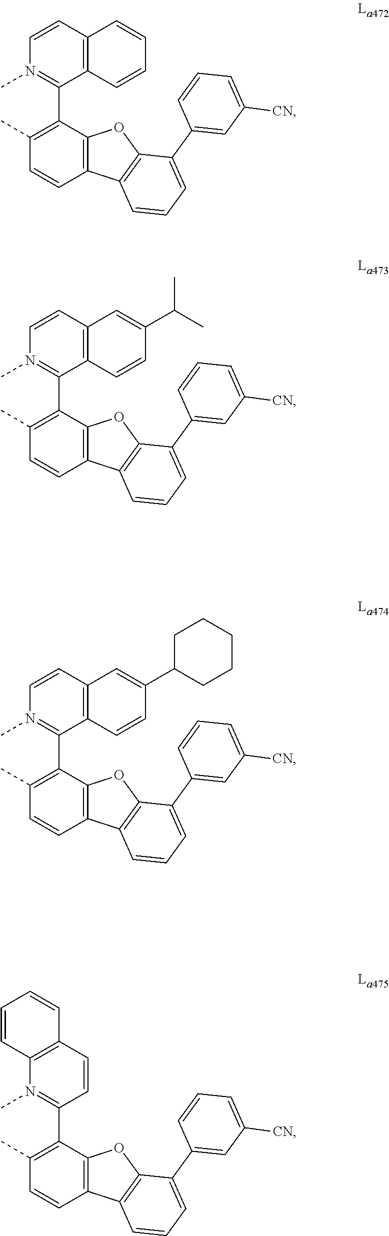 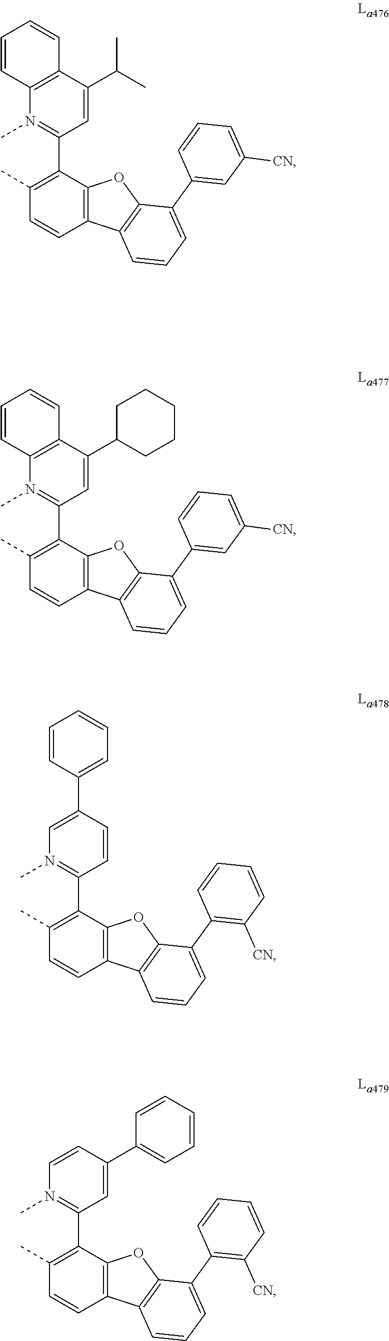 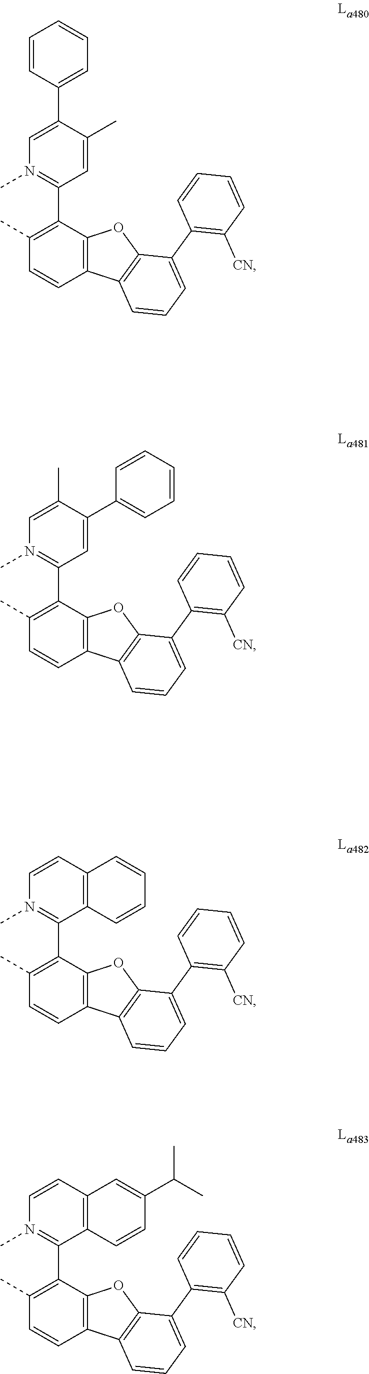 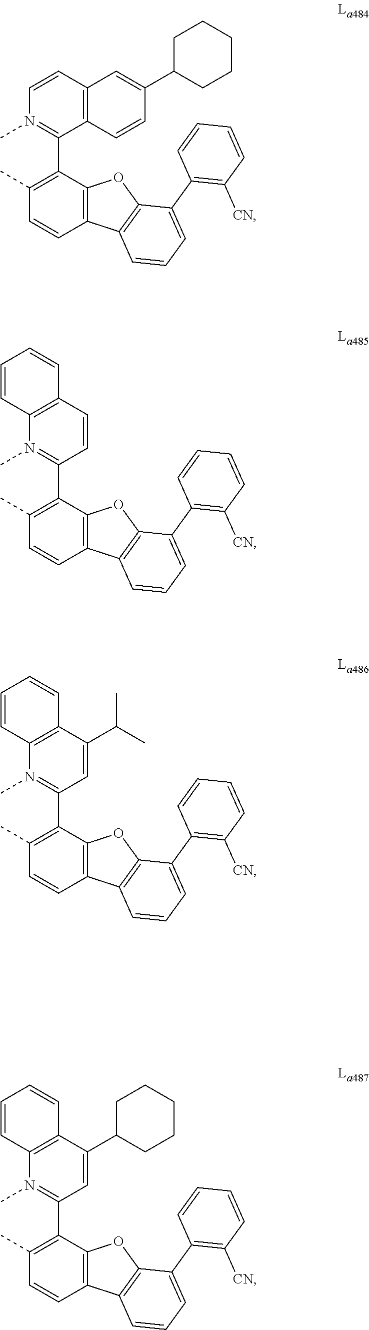 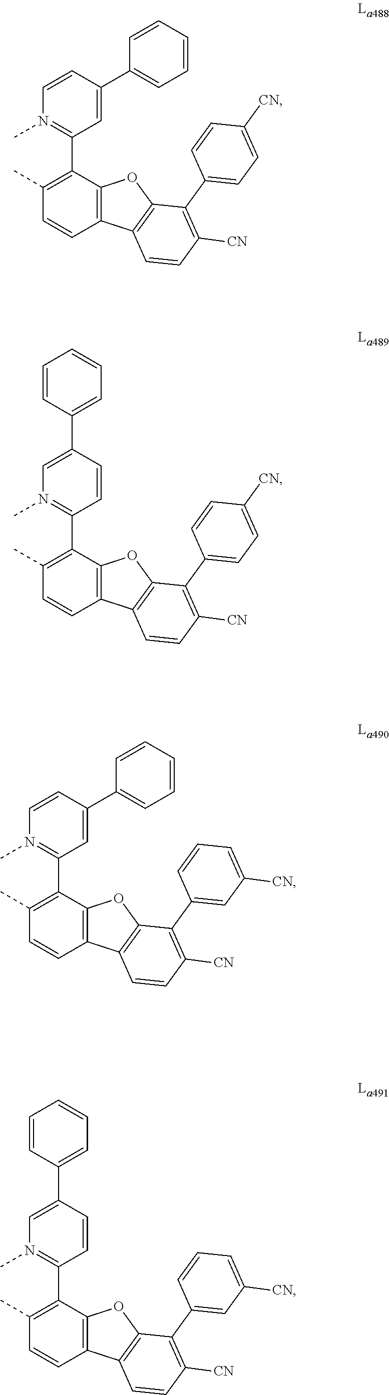 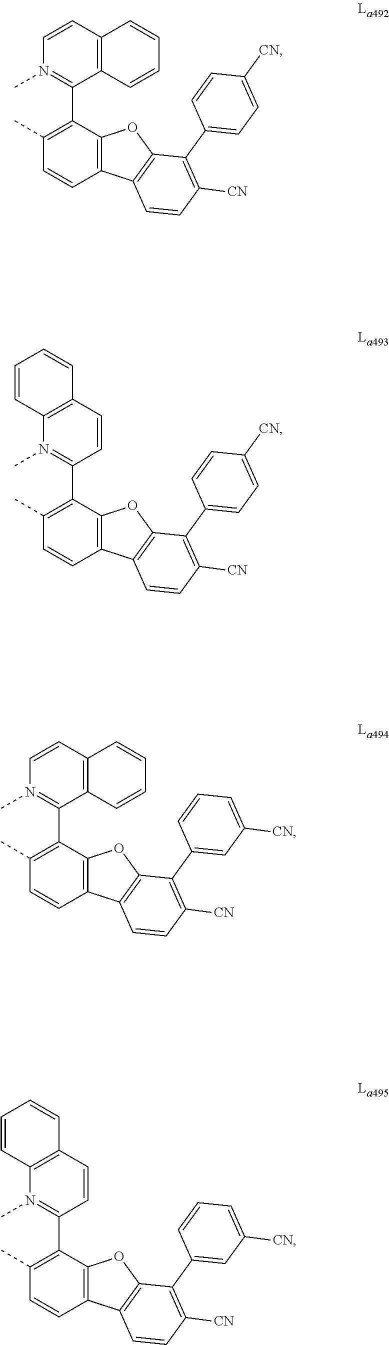 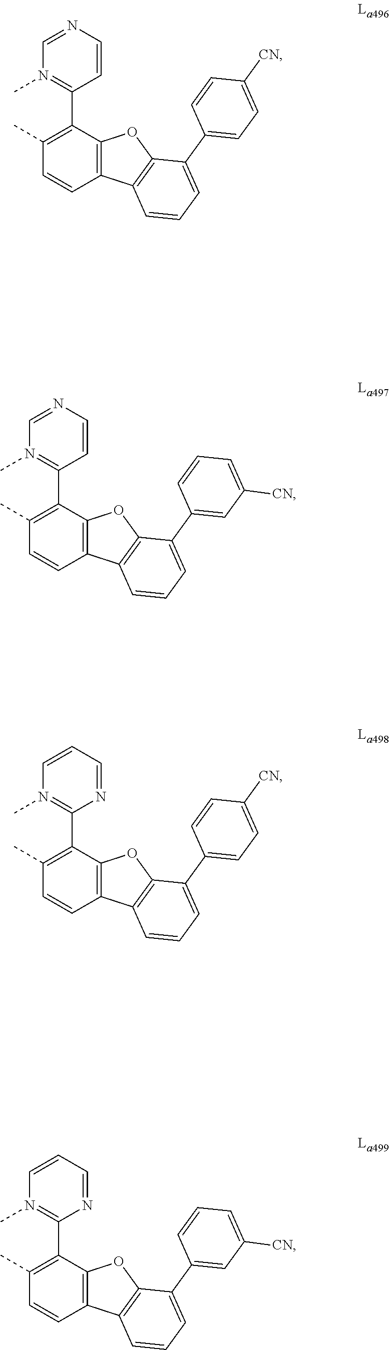 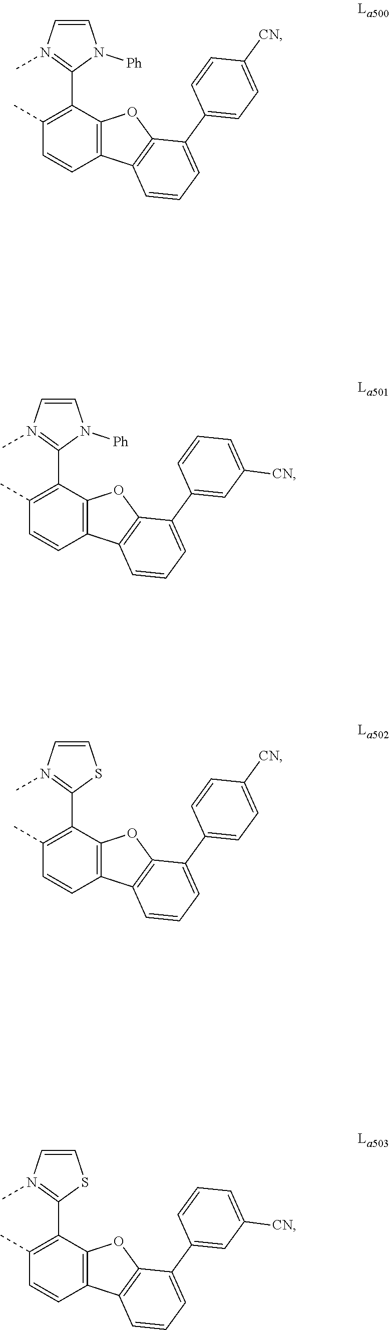 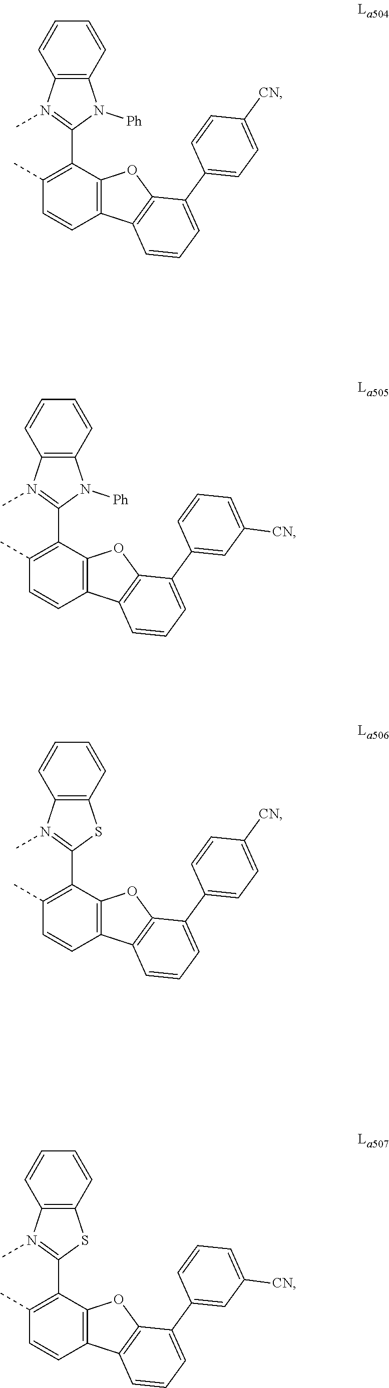 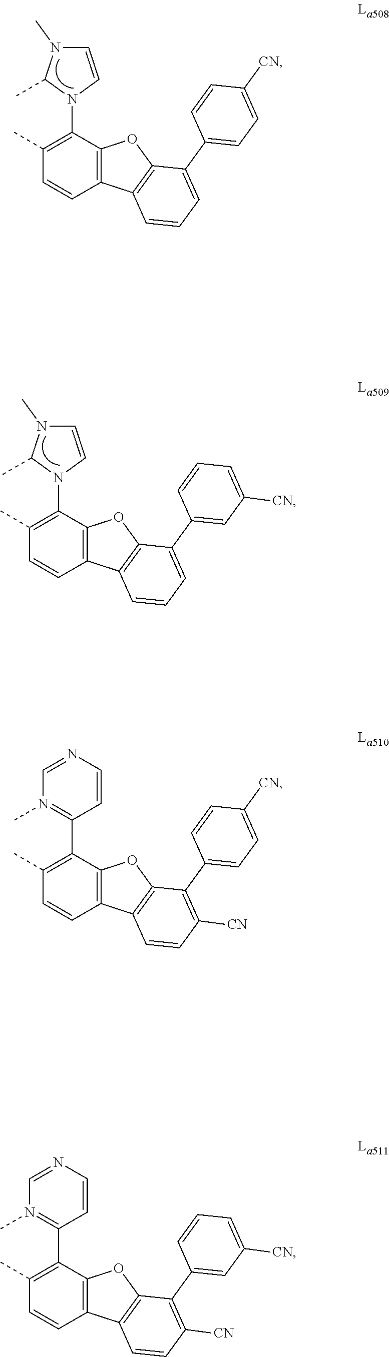 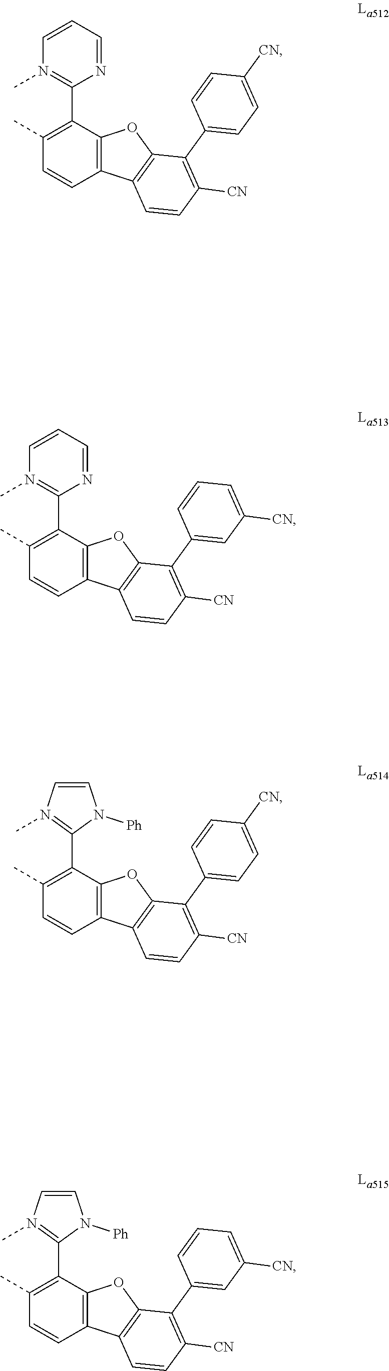 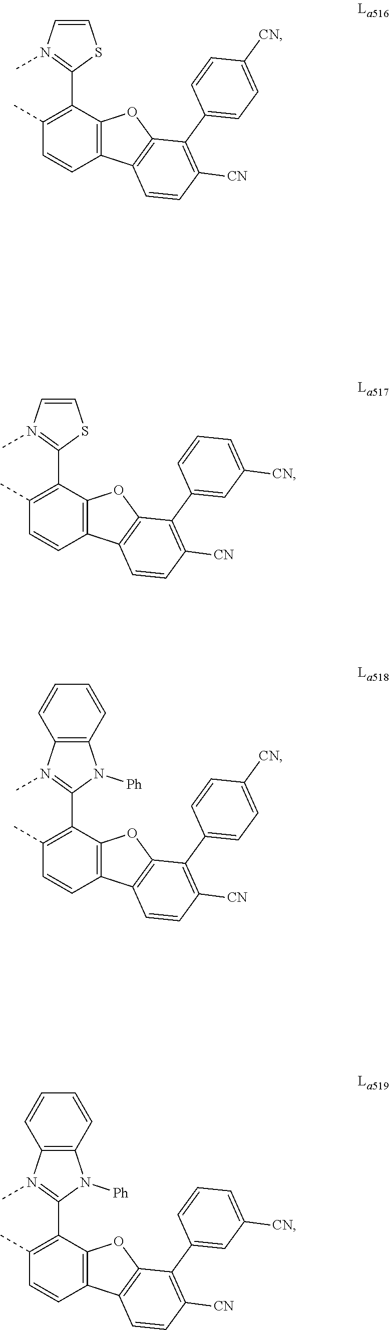 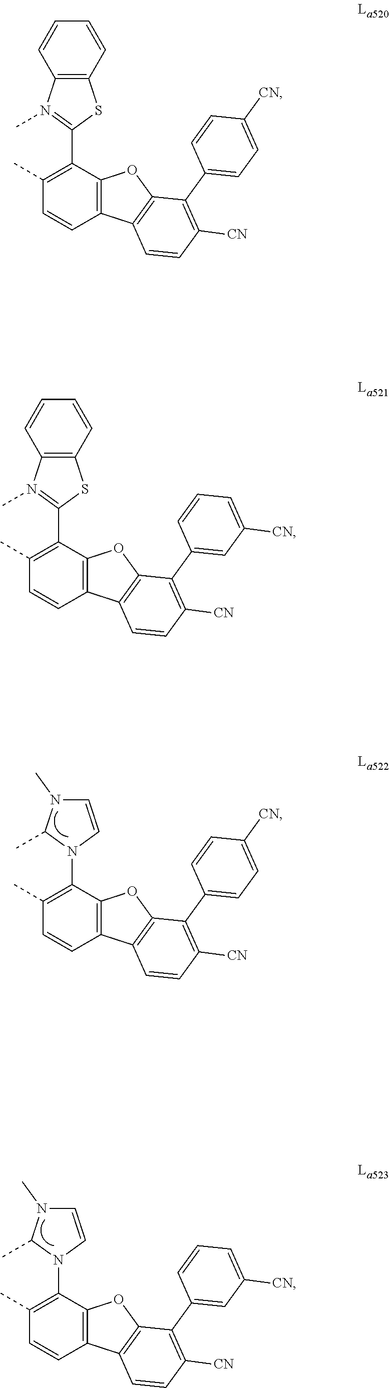 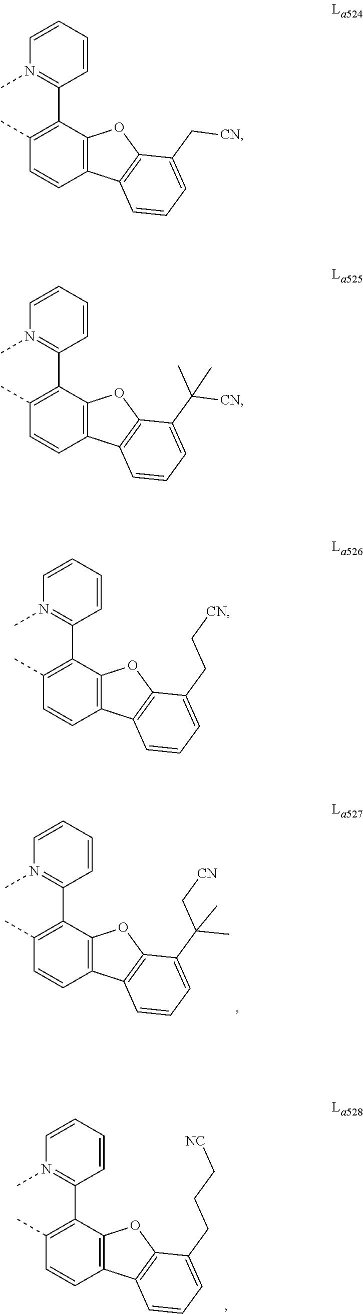 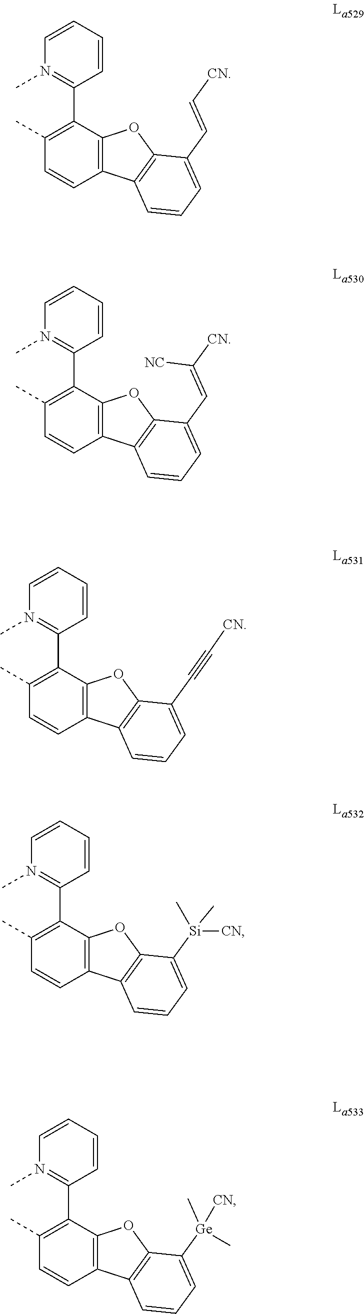 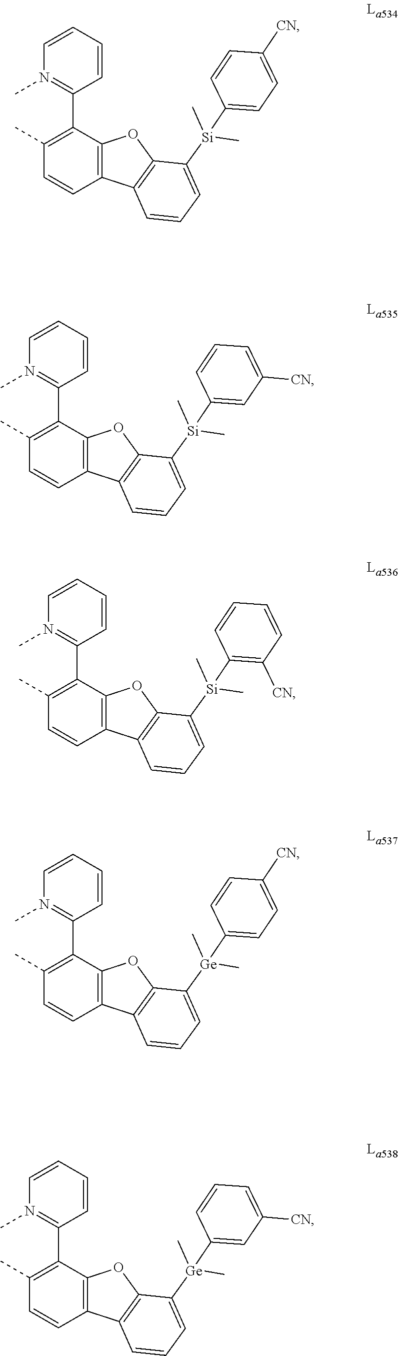 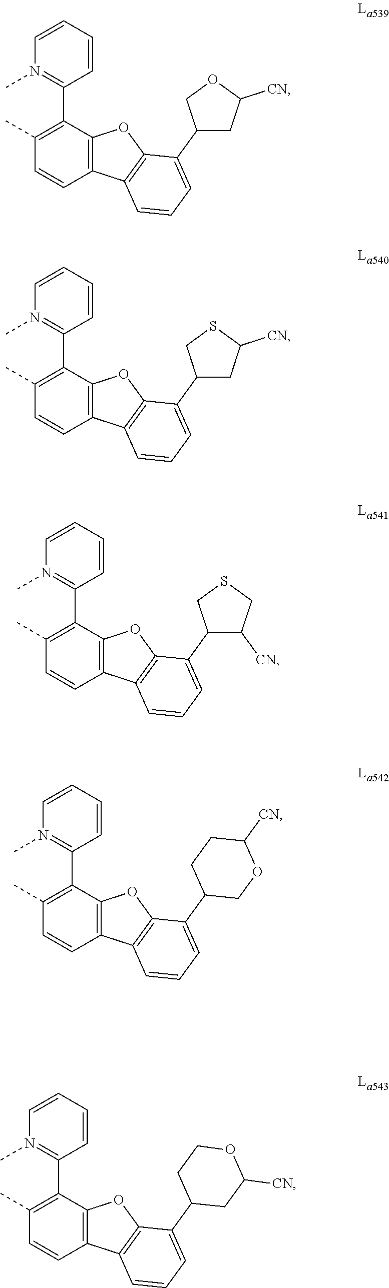 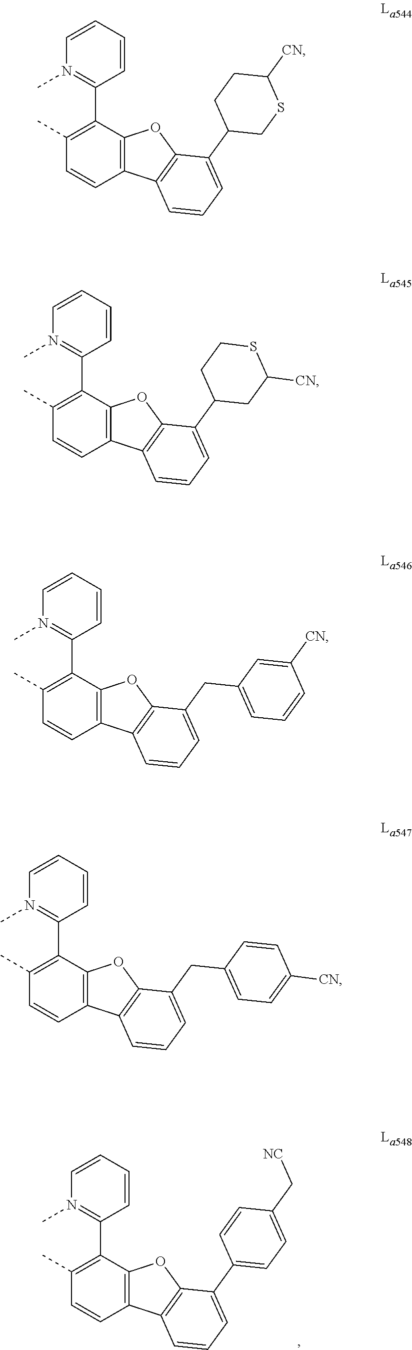 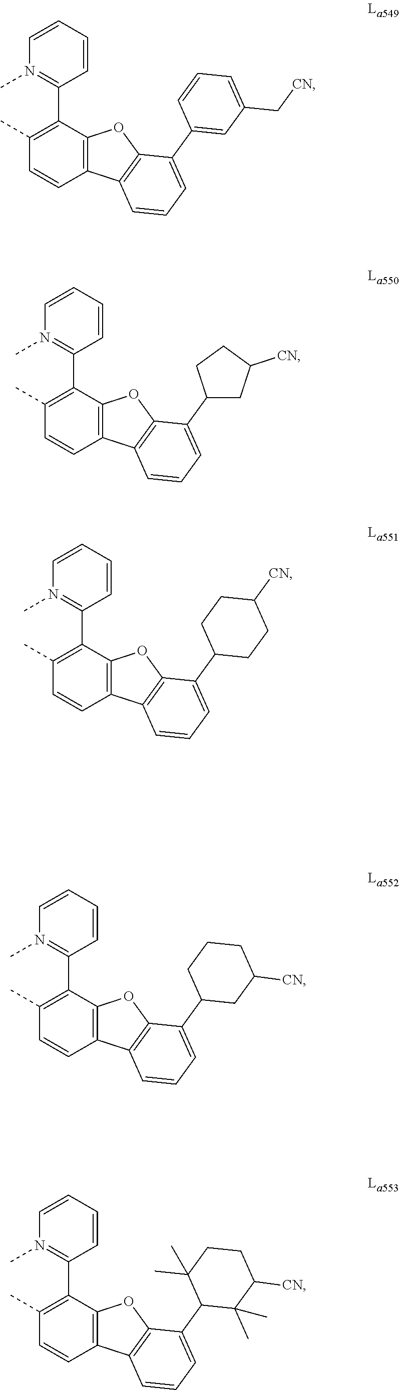 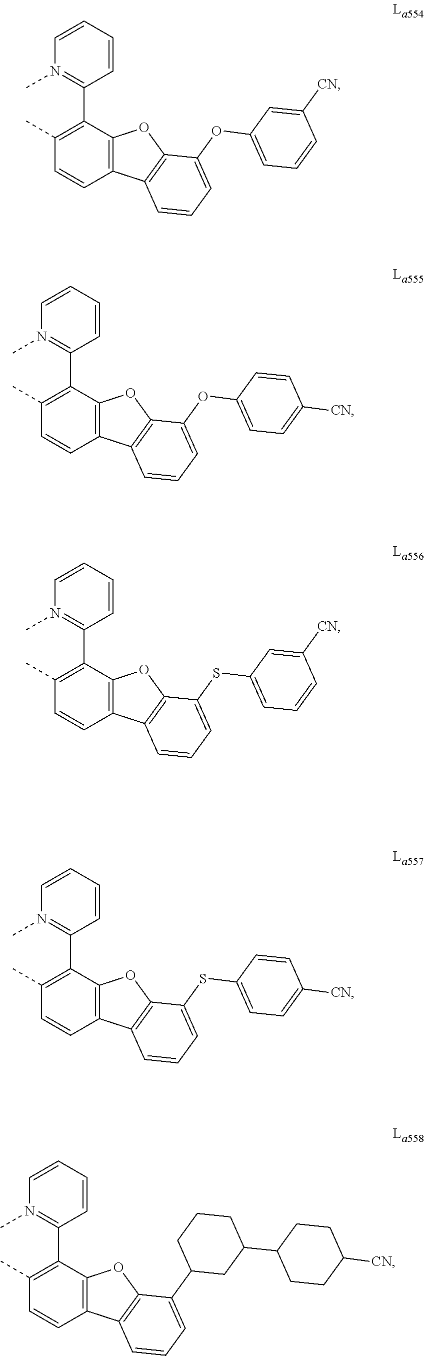 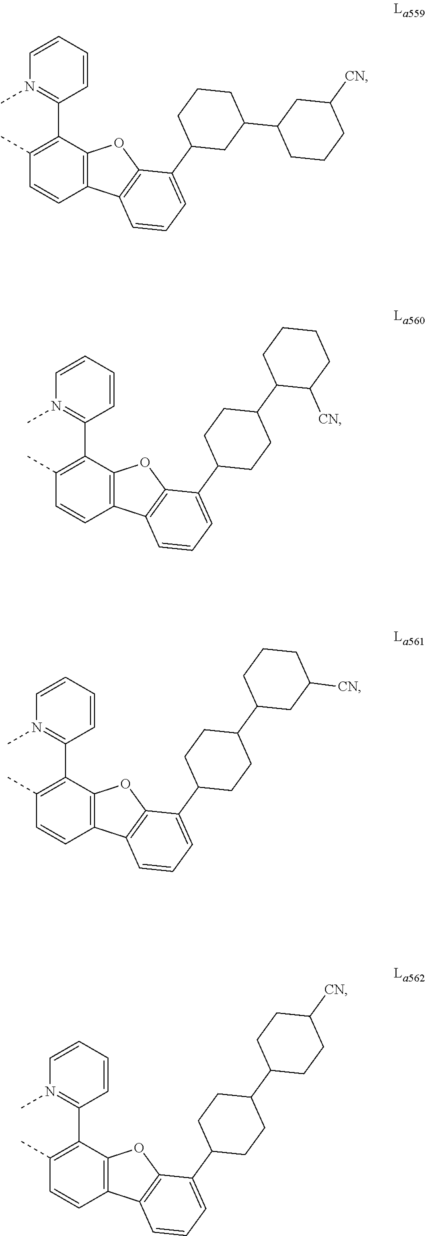 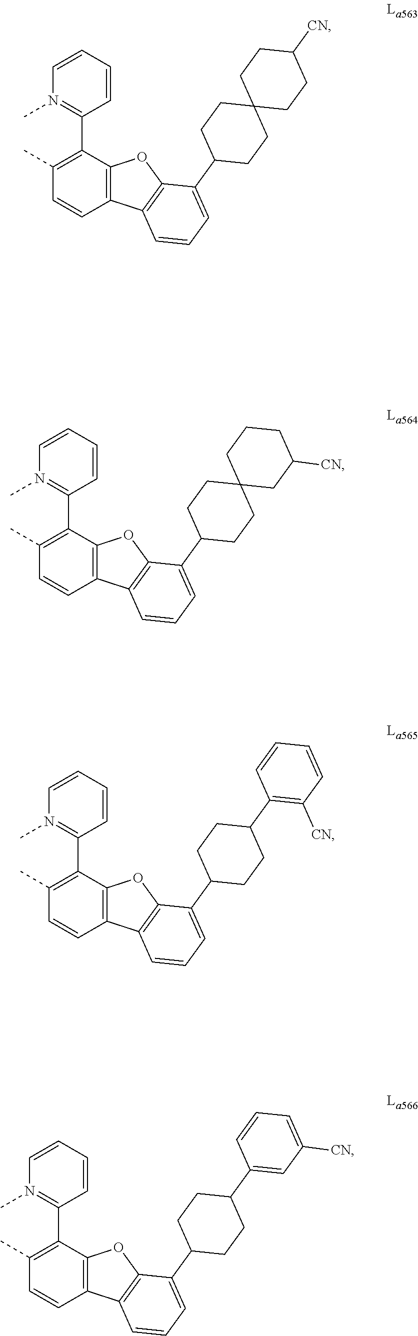 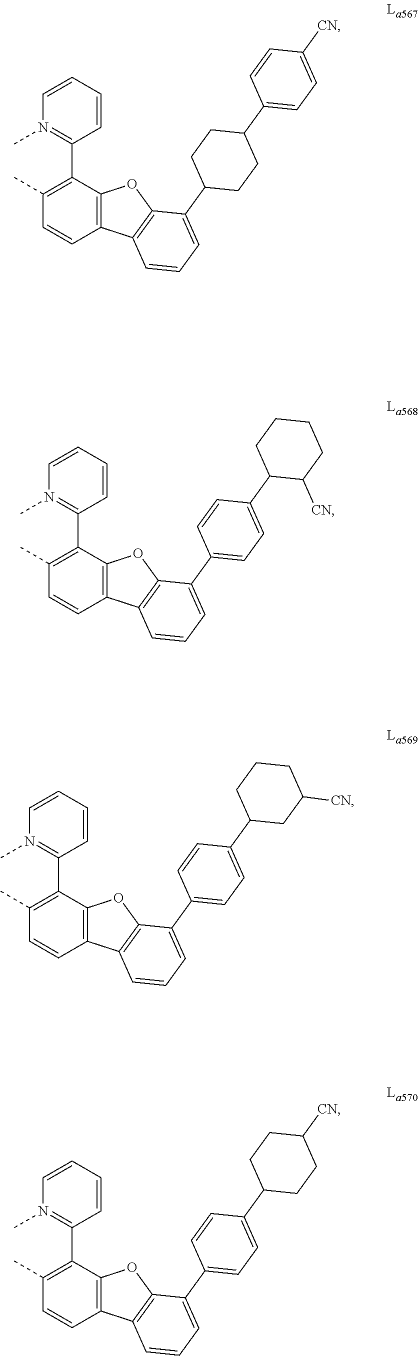 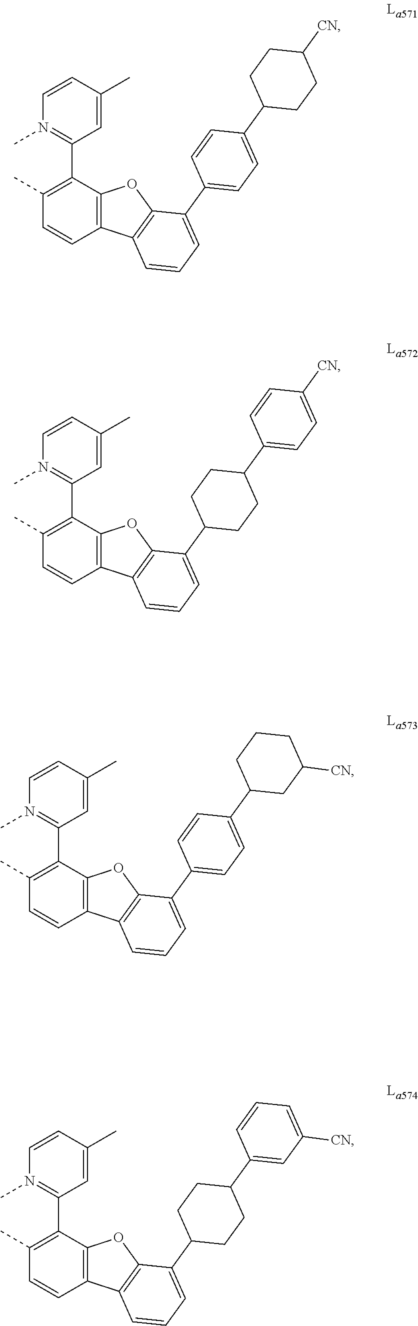 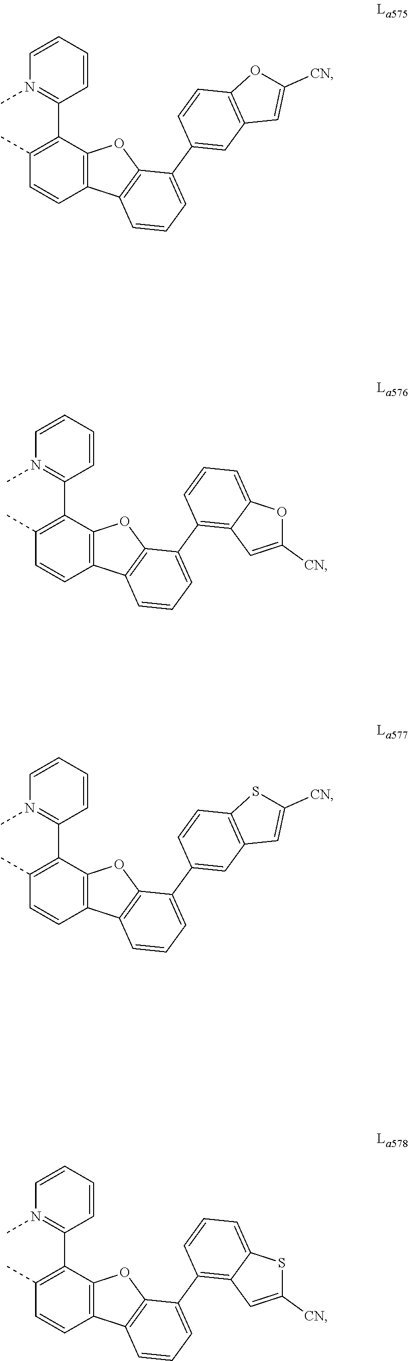 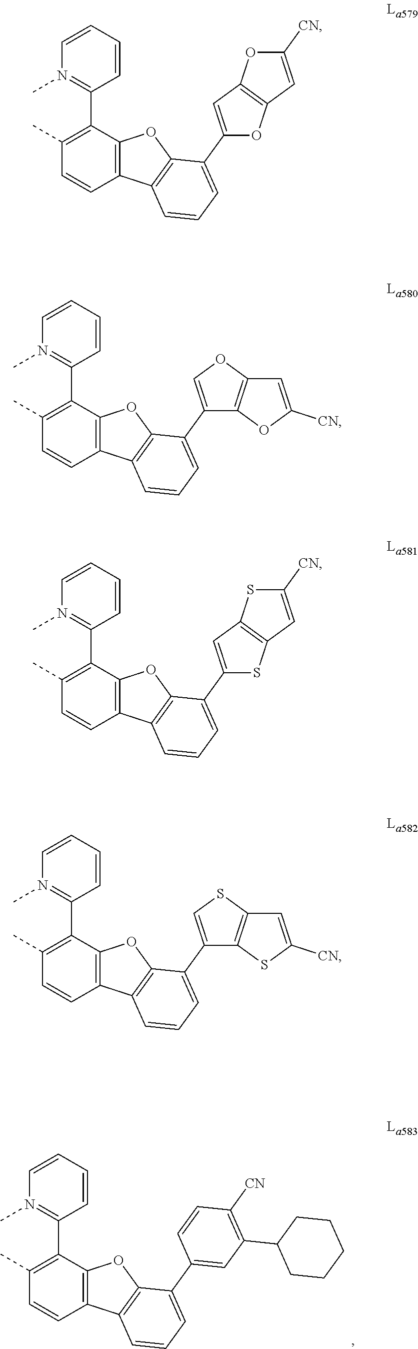 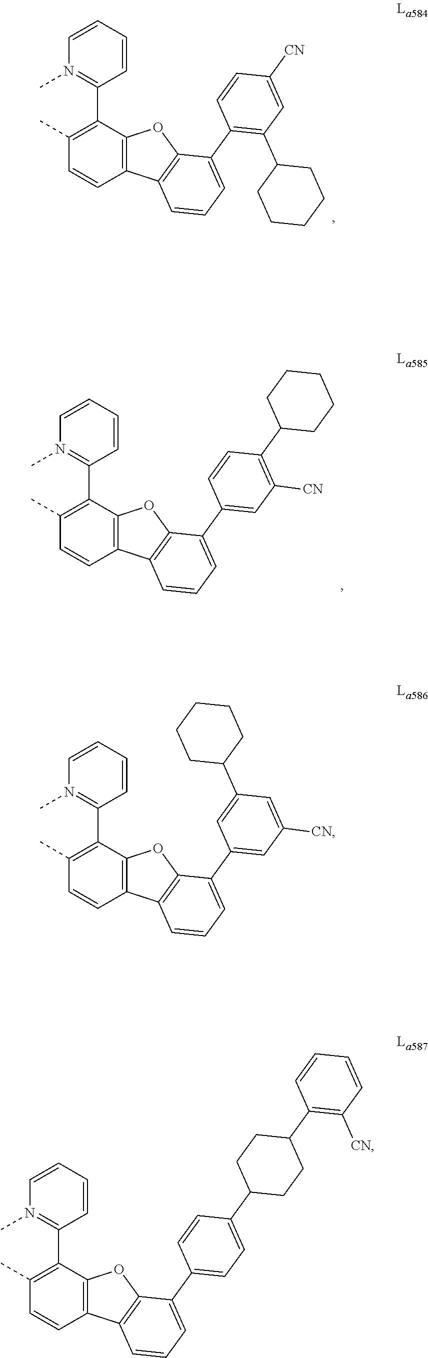 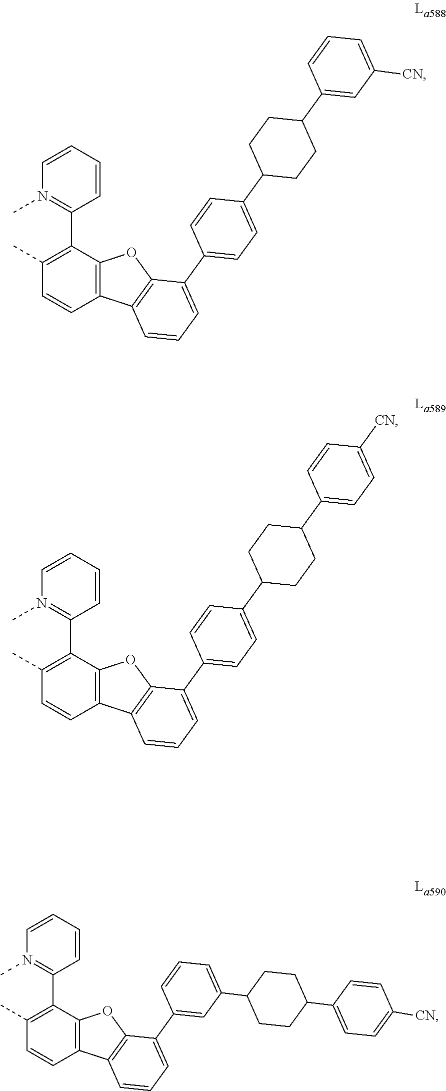 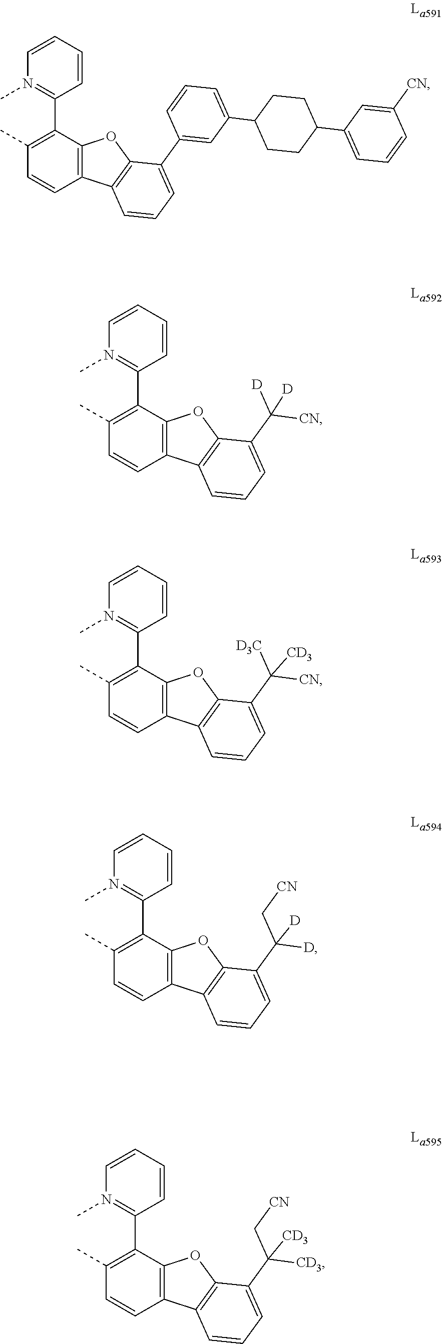 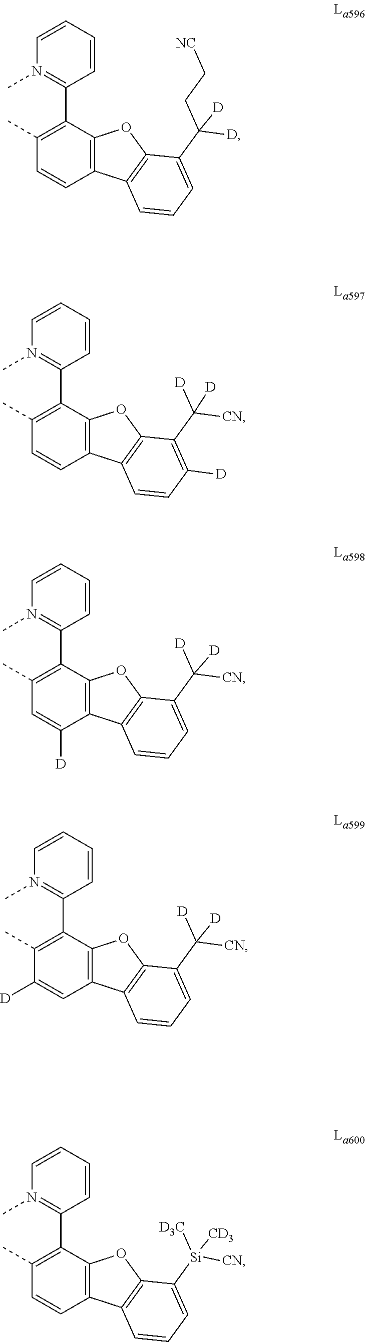 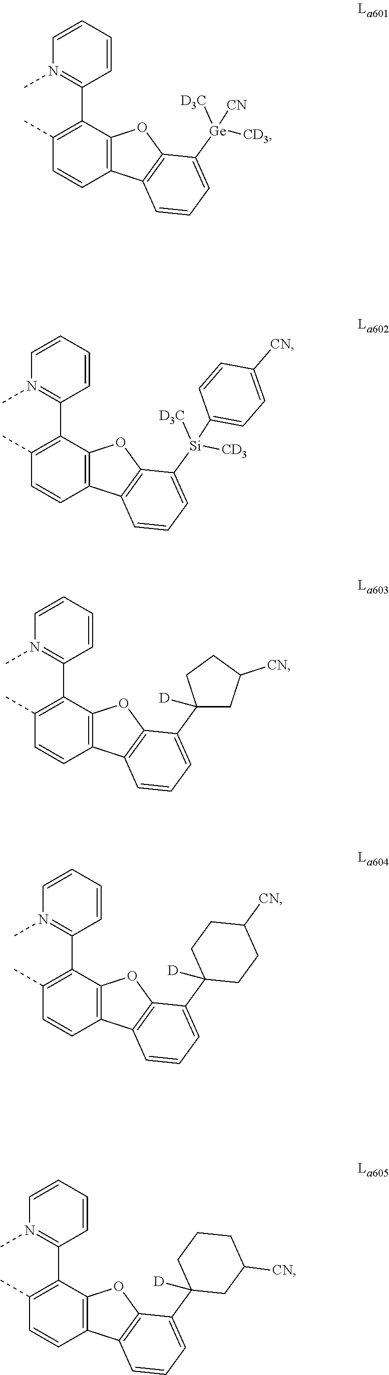 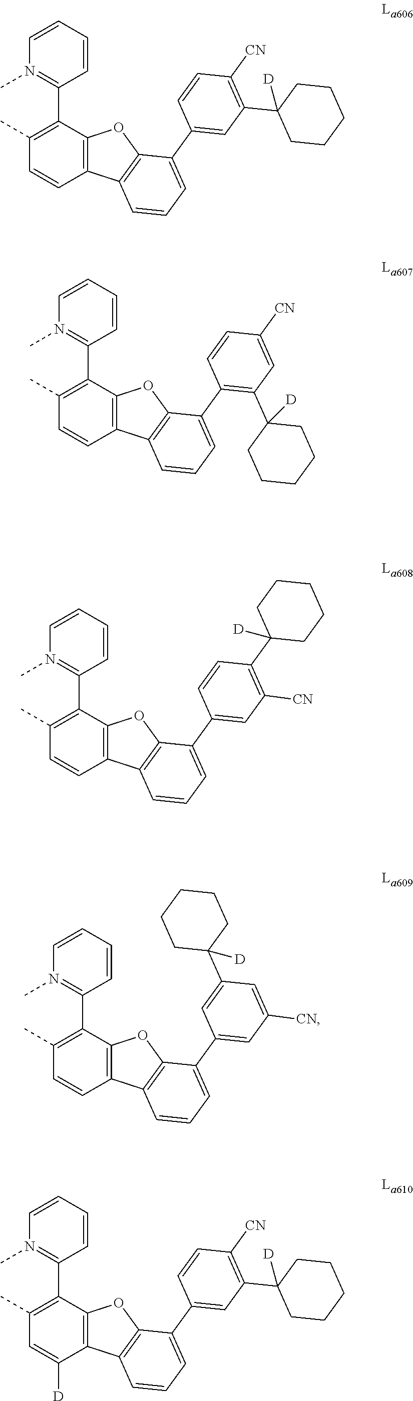 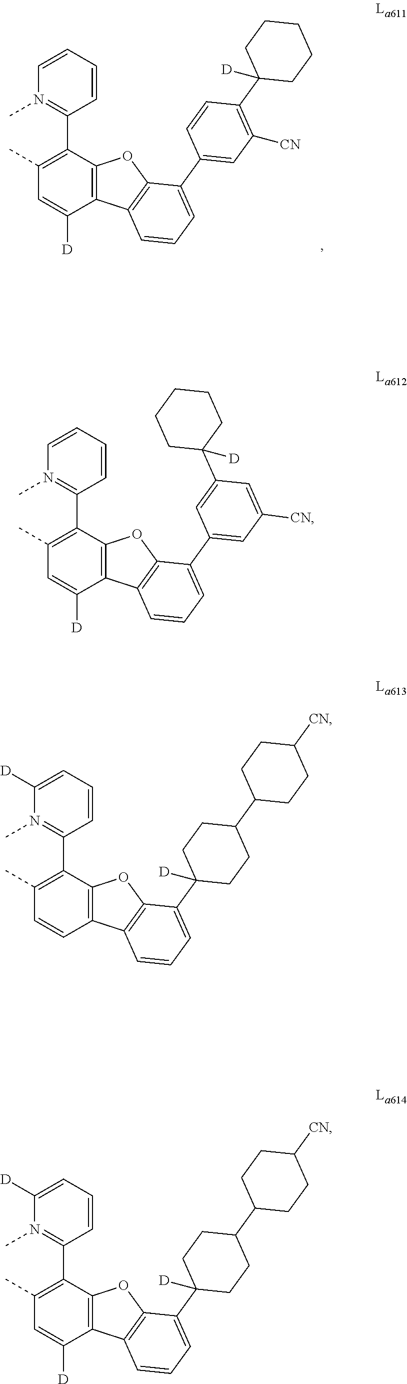 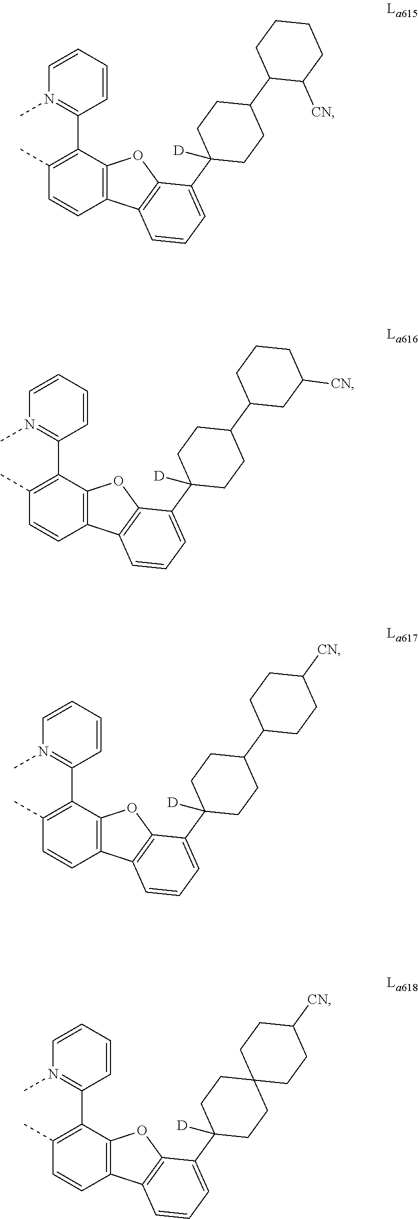 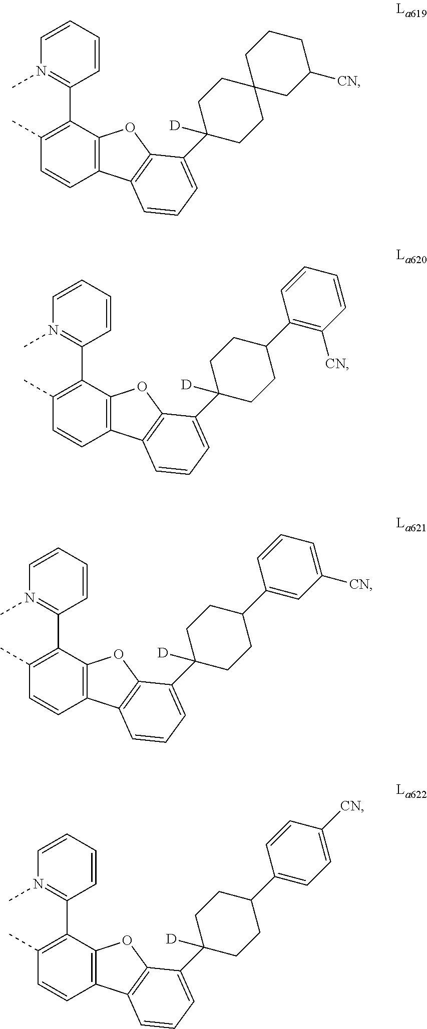 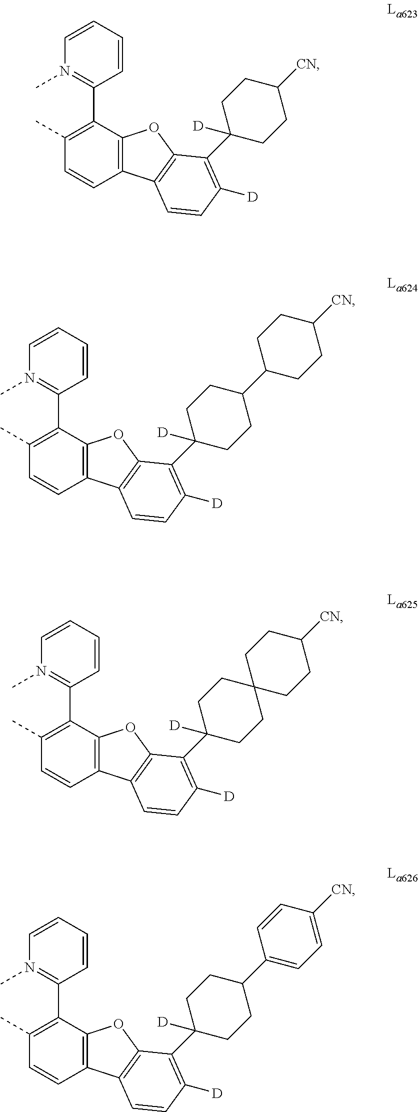 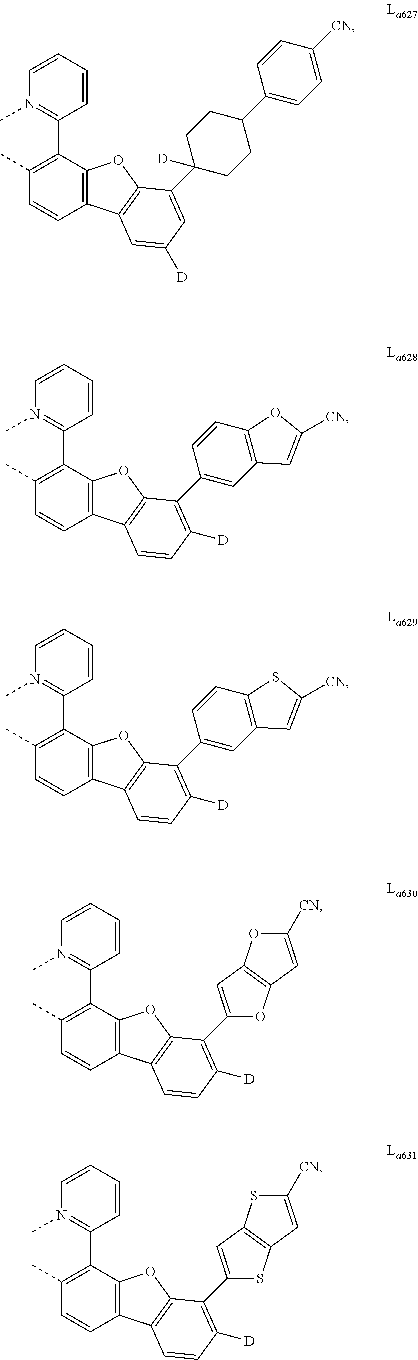 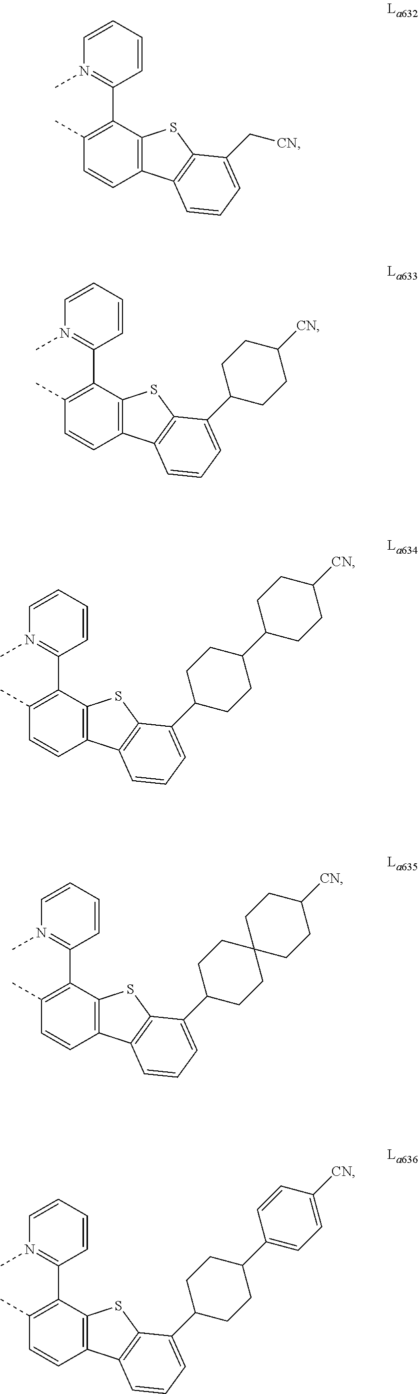 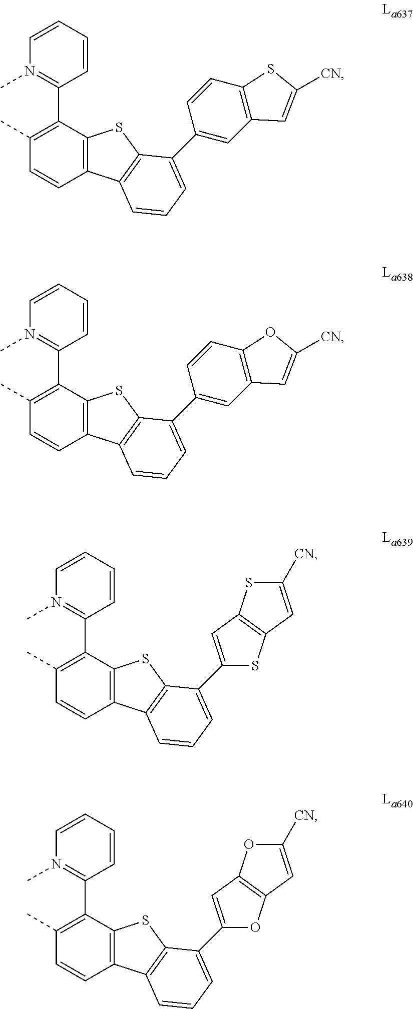 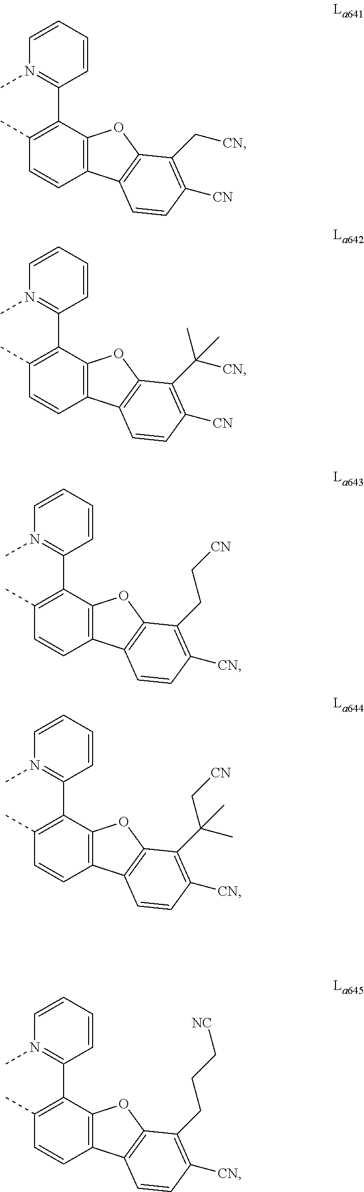 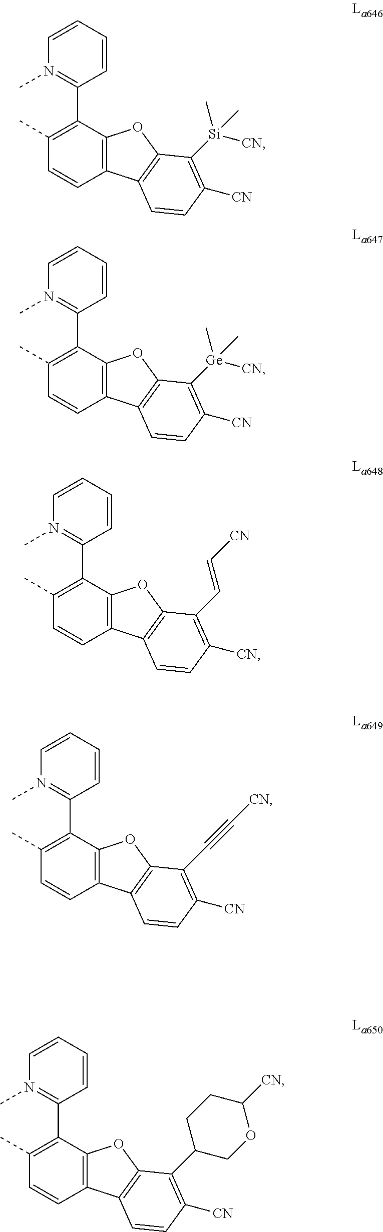 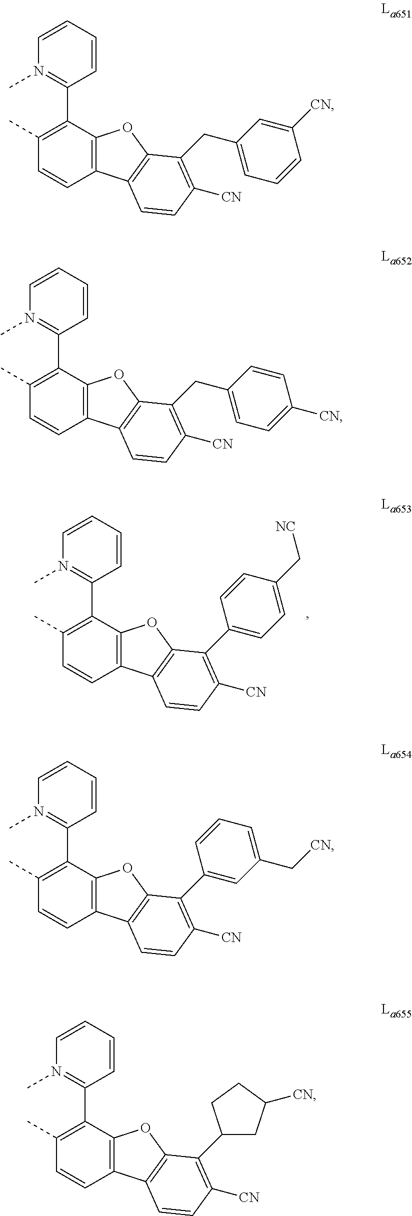 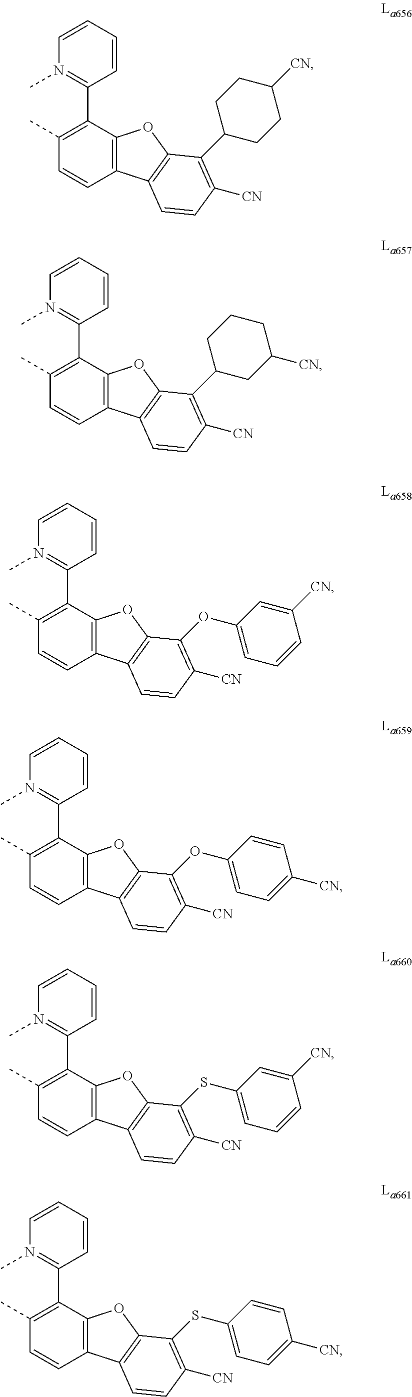 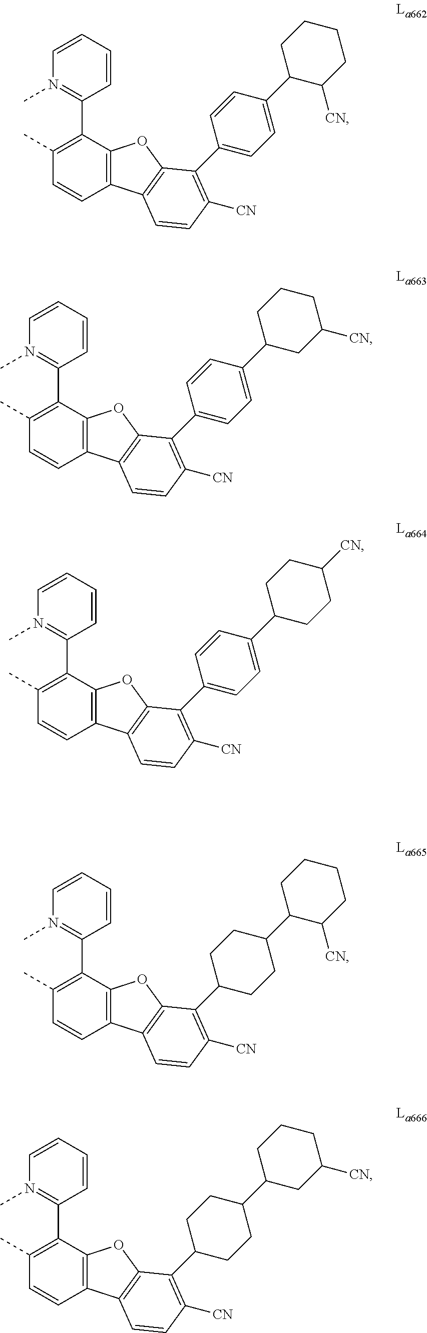 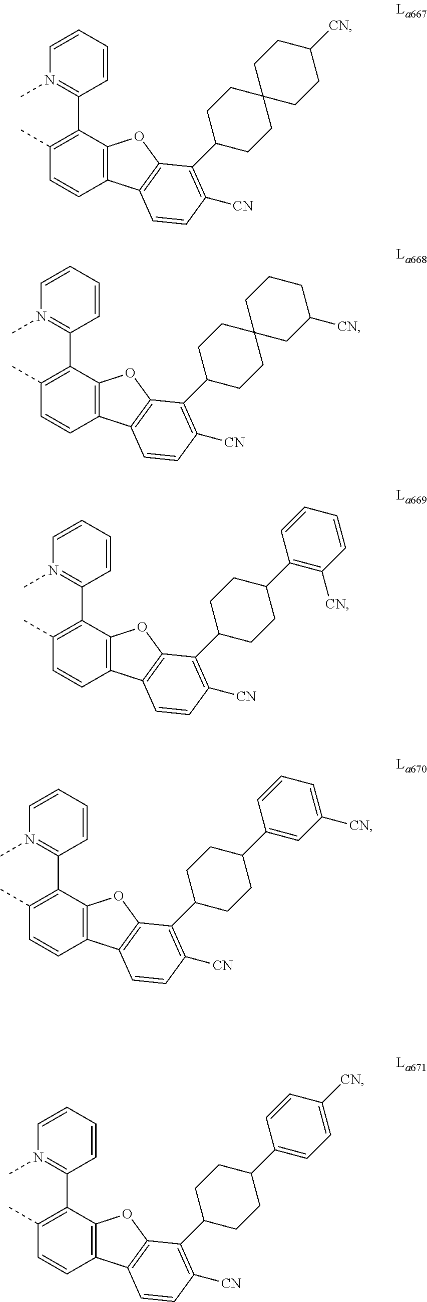 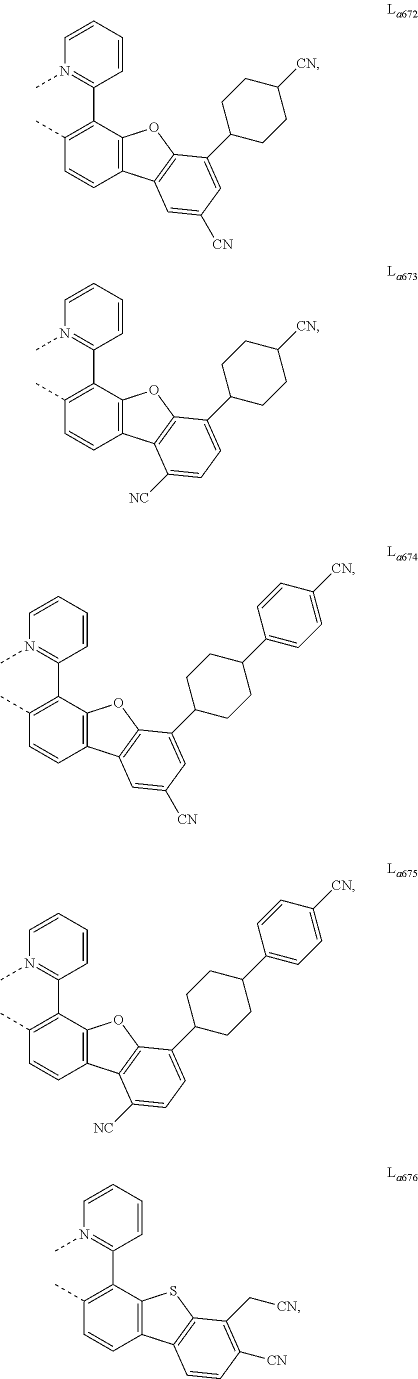 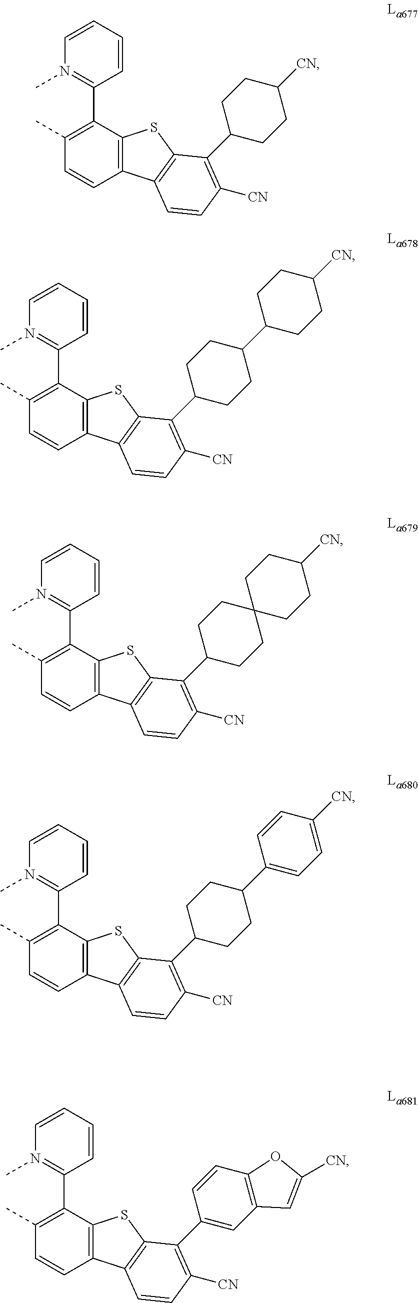 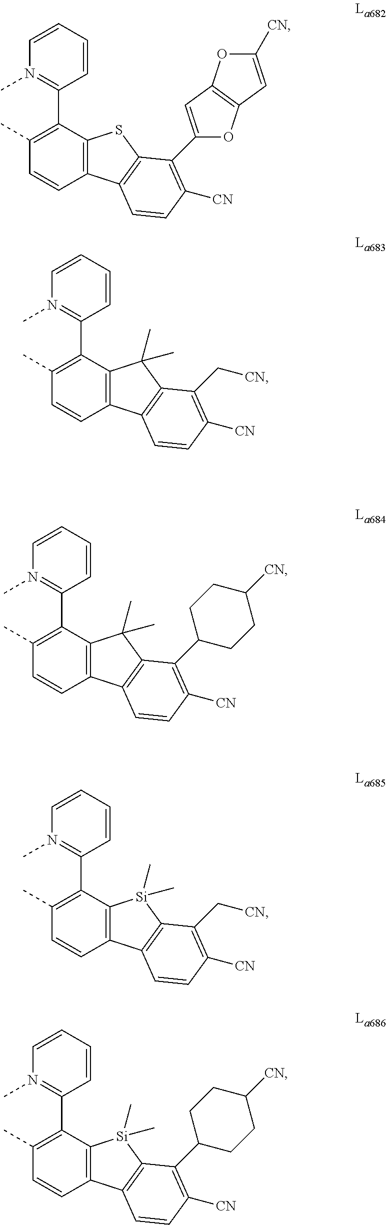 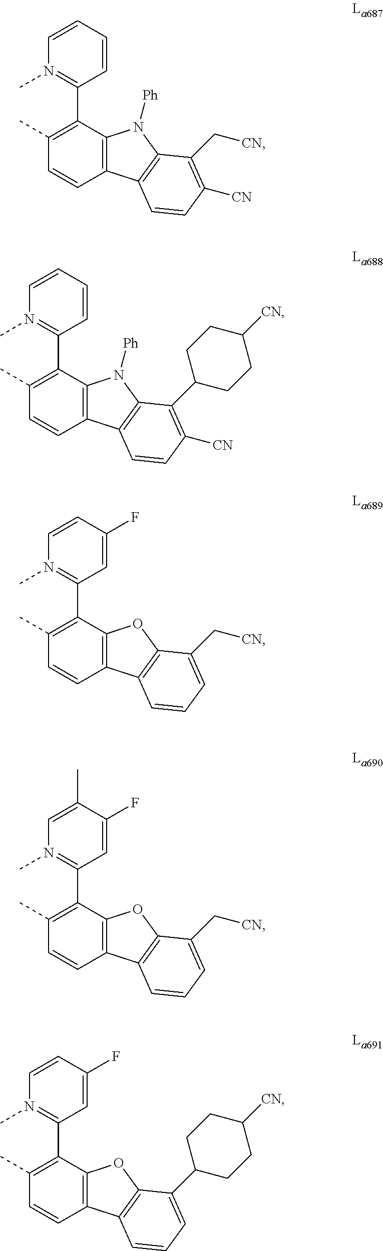 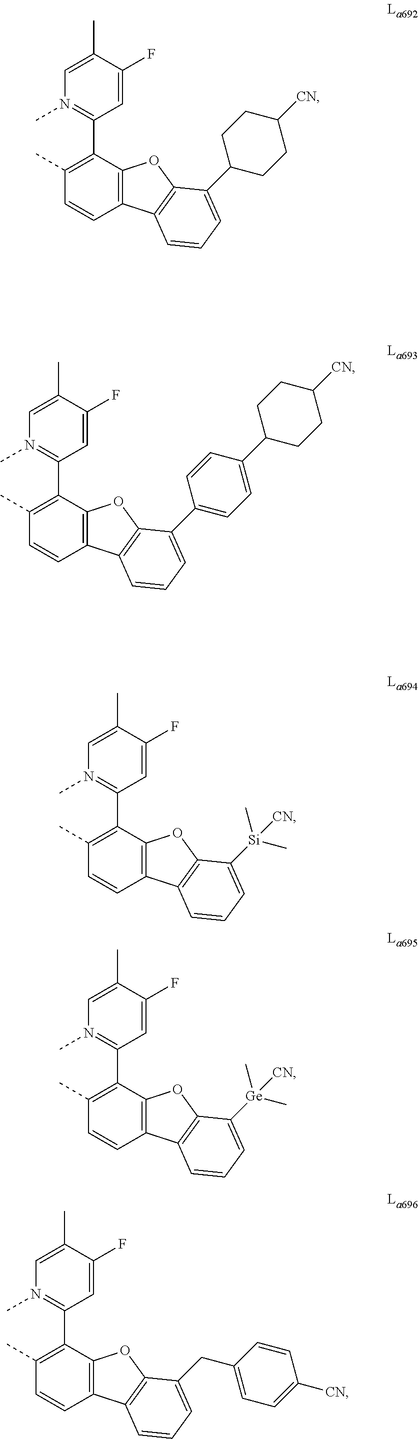 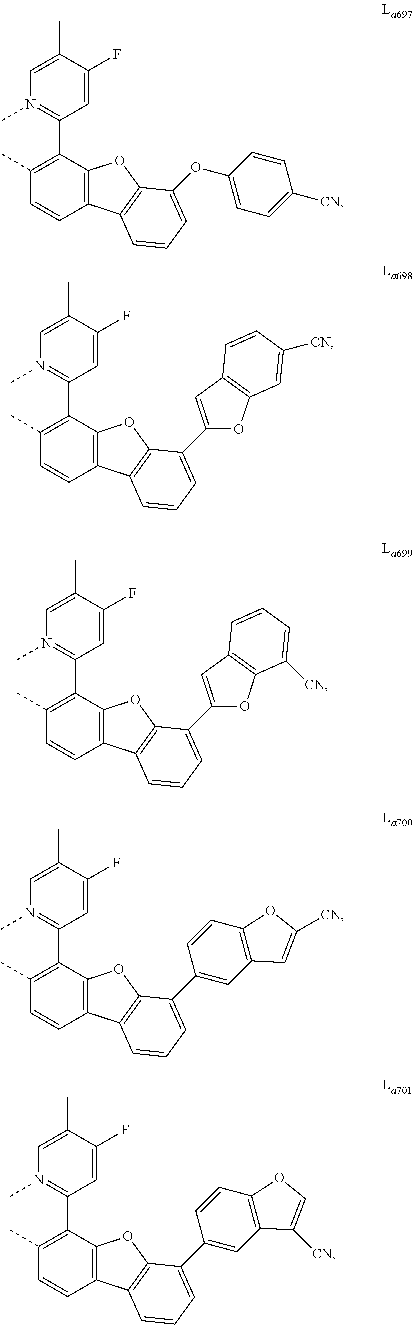 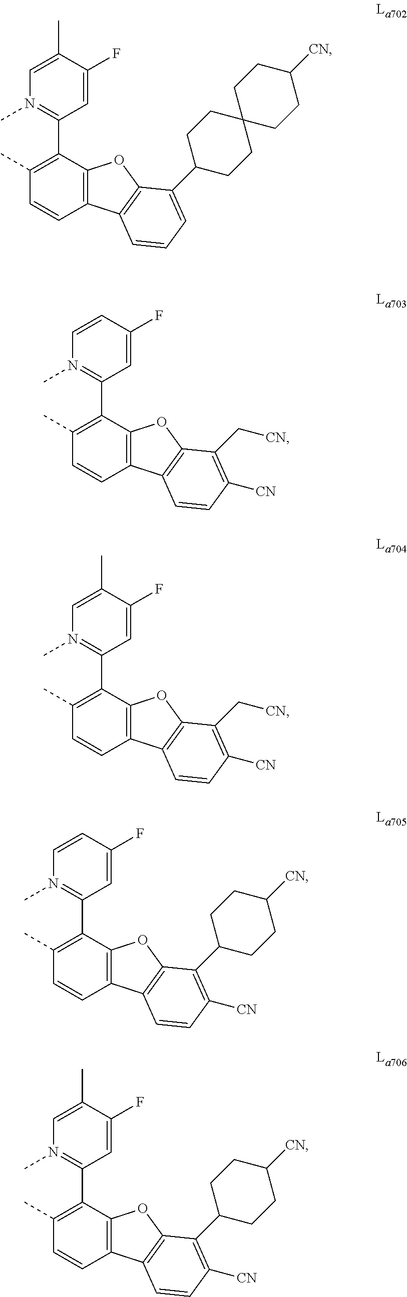 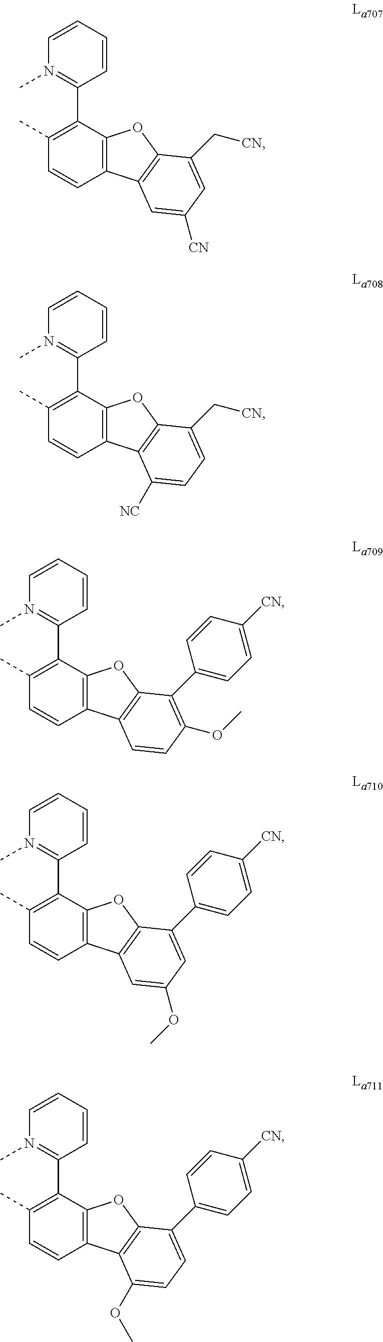 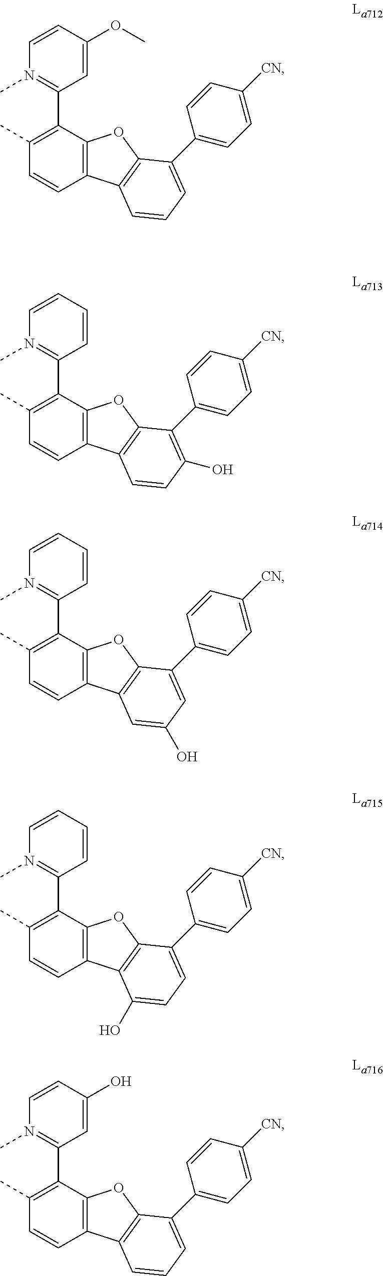 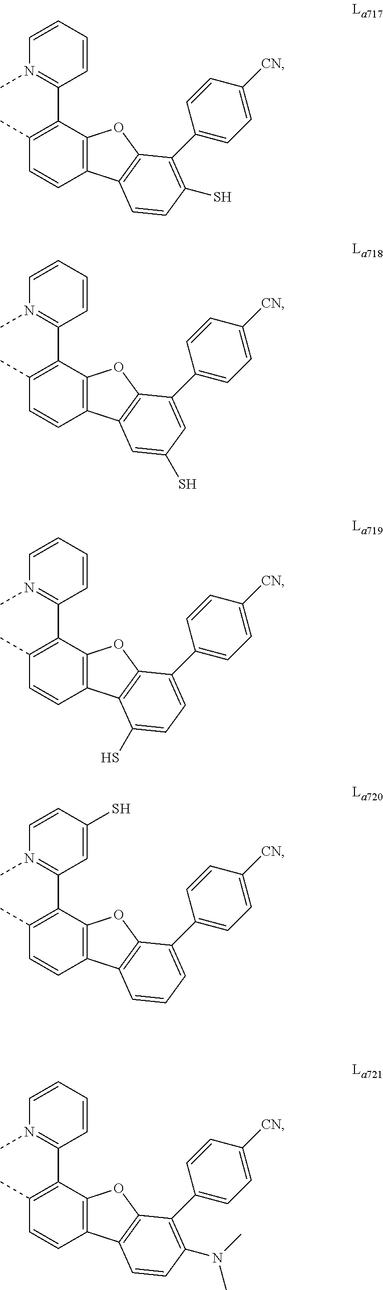 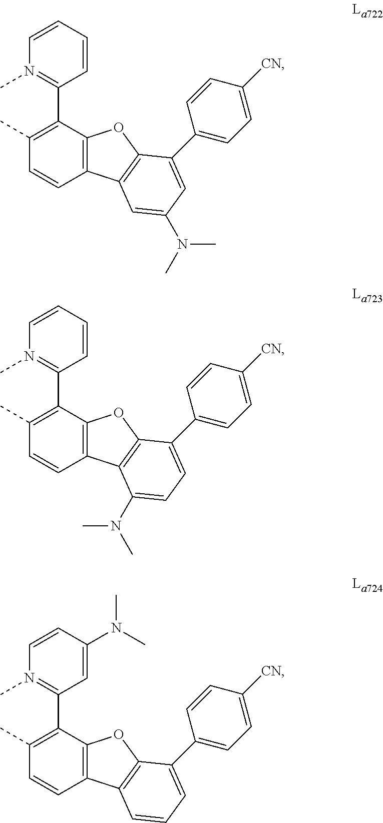 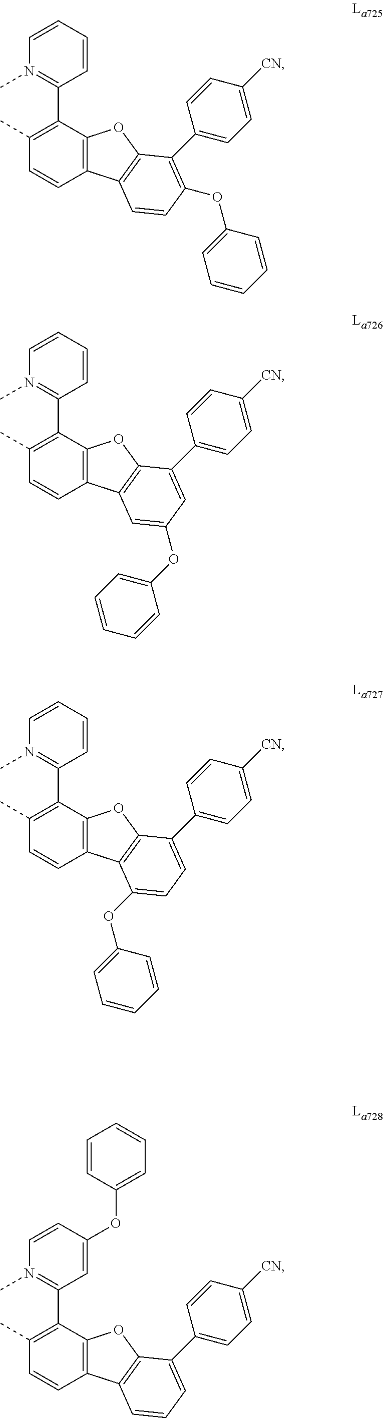 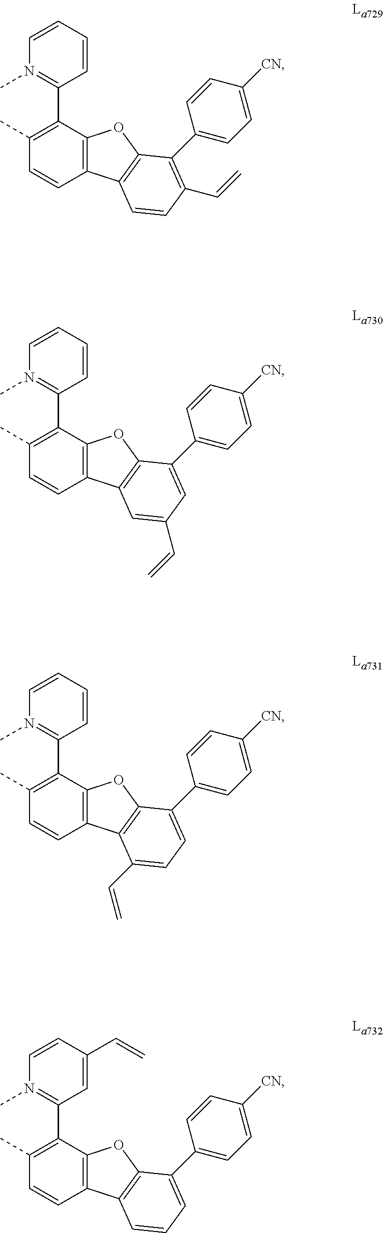 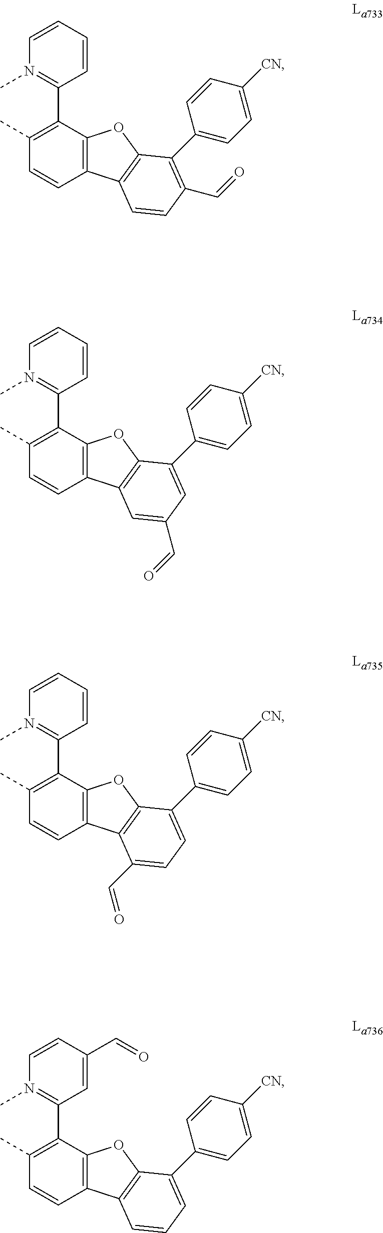 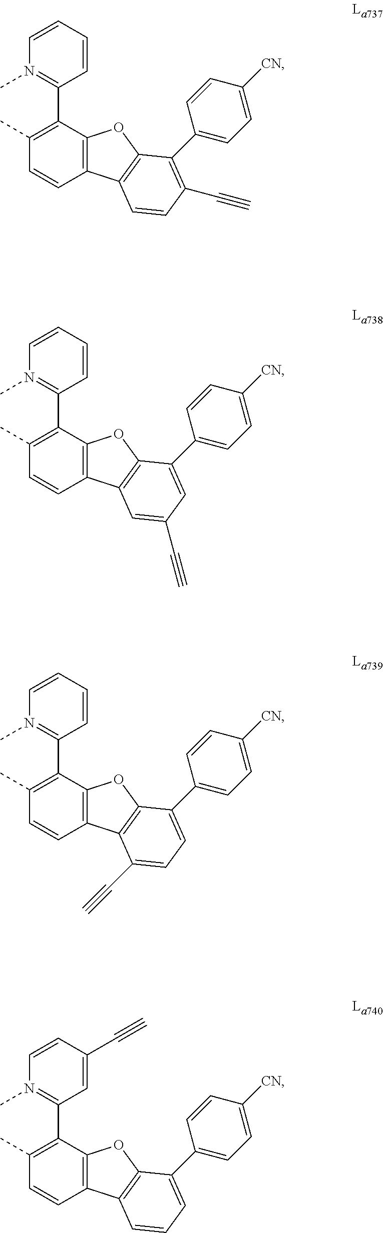 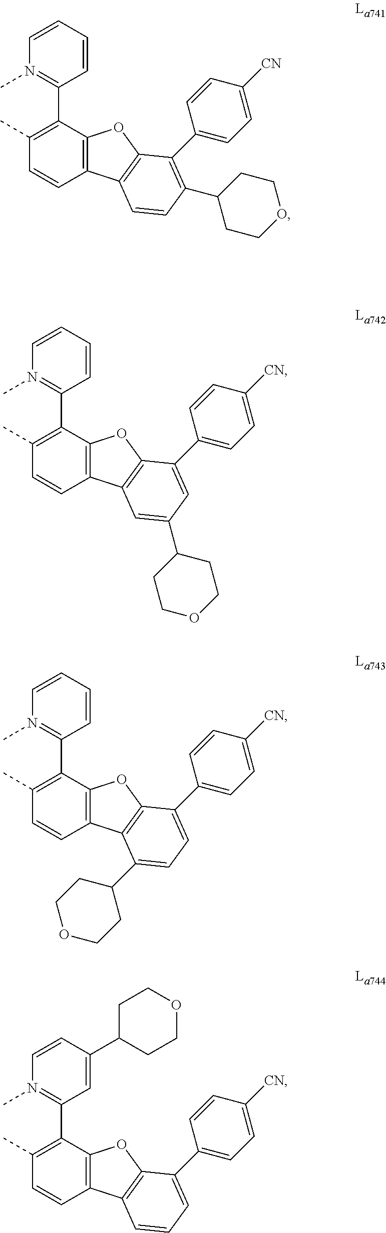 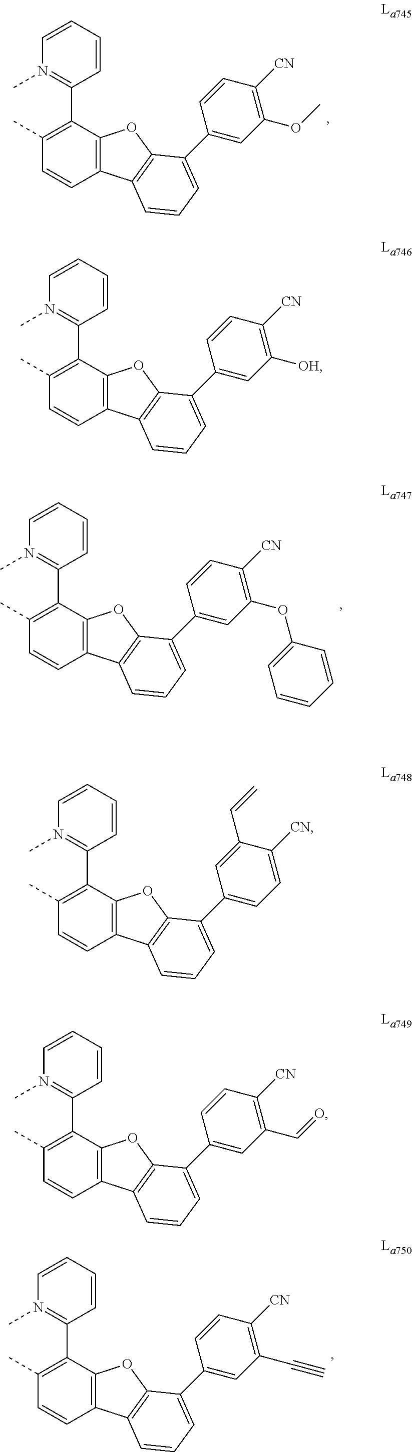 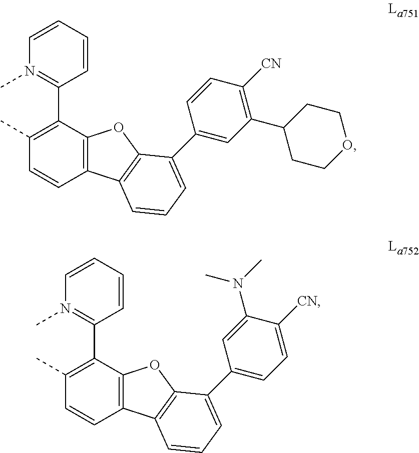 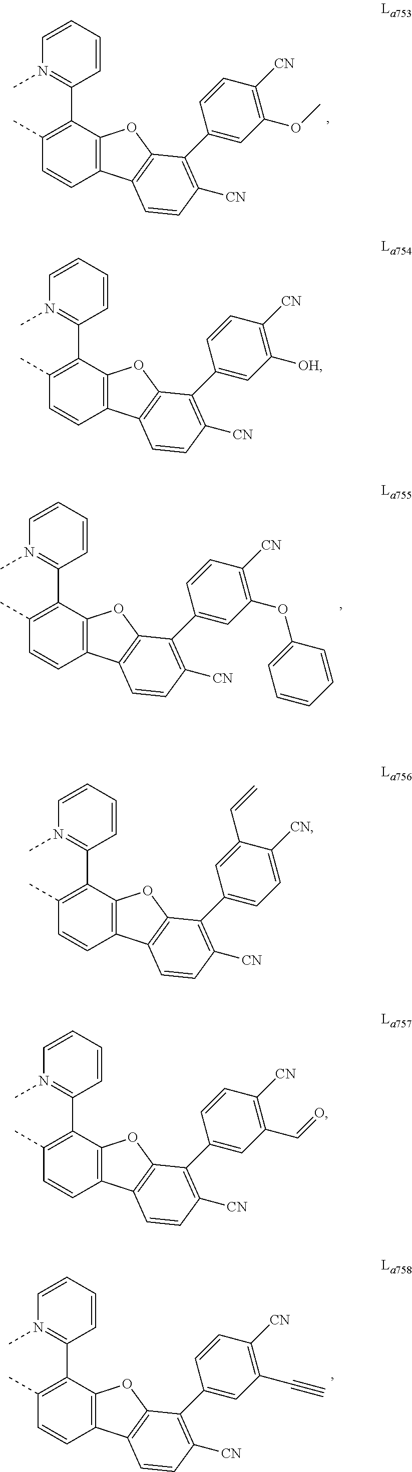 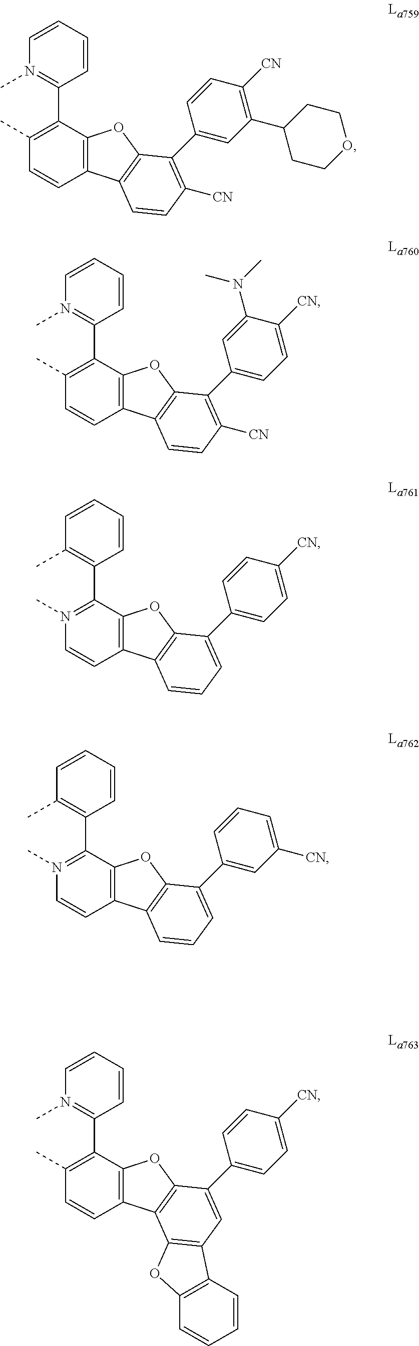 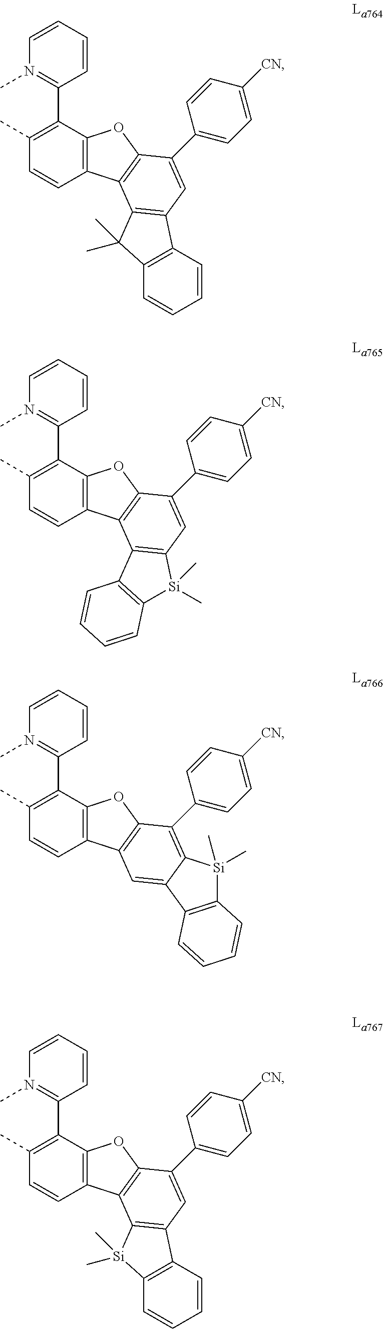 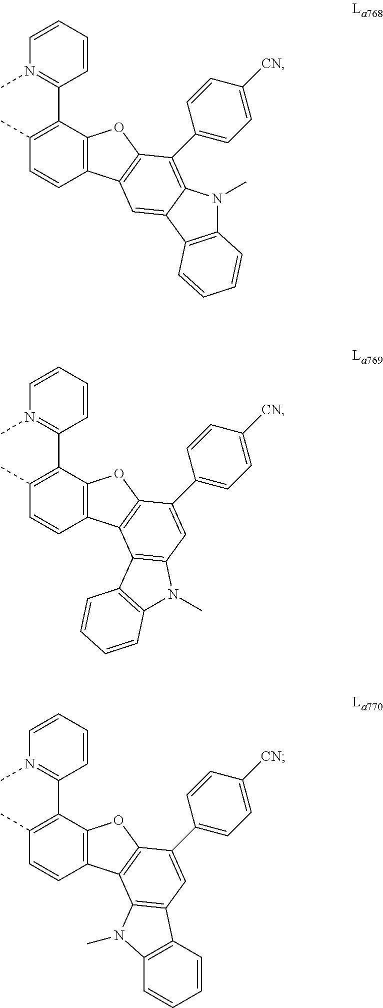
wherein, optionally, hydrogens in the structures of Lₐ₁ to Lₐ₇₇₀ can be partially or fully deuterated.

15. The metal complex of claim 3, wherein L_{b} is, at each occurrence identically or differently, selected from the group consisting of: 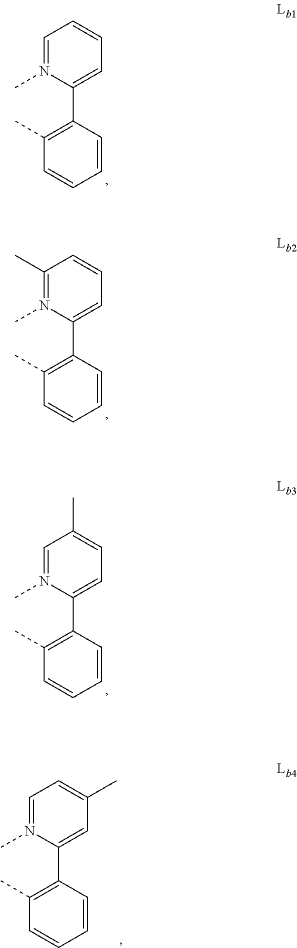 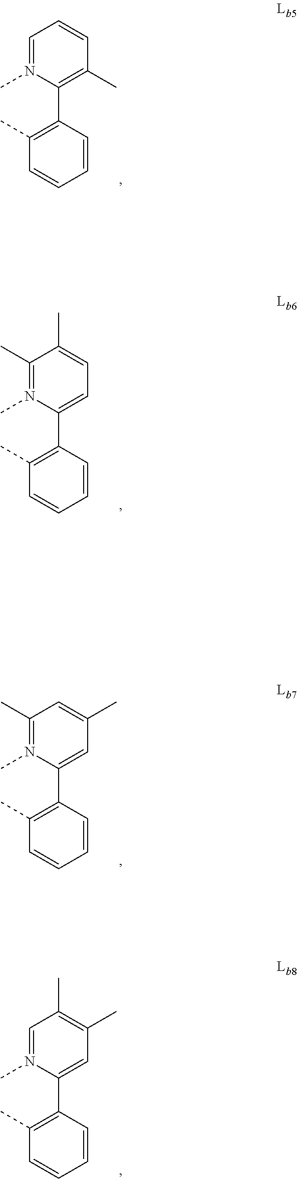 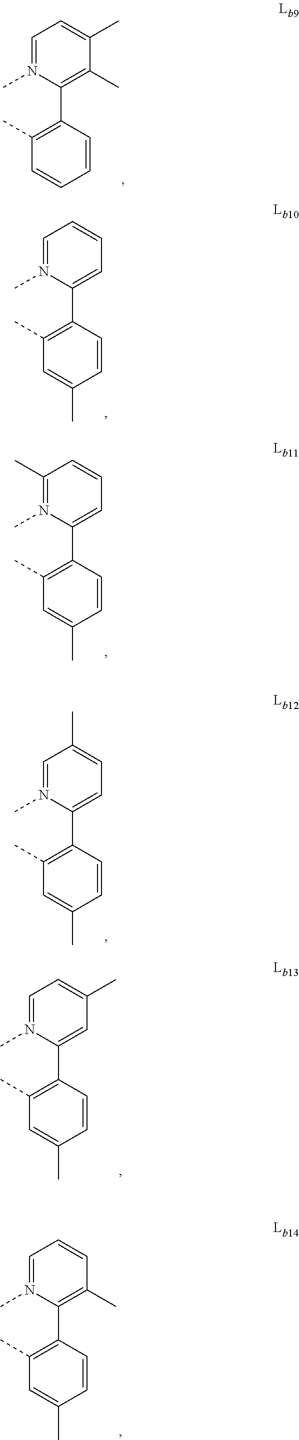 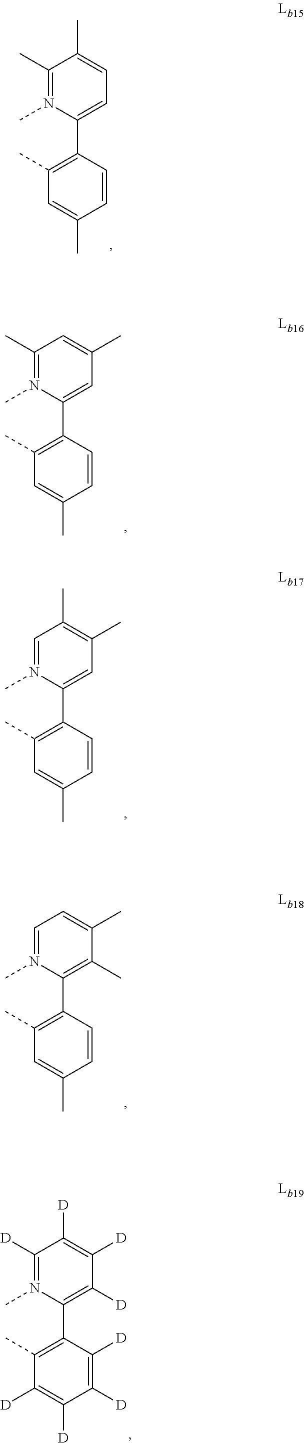 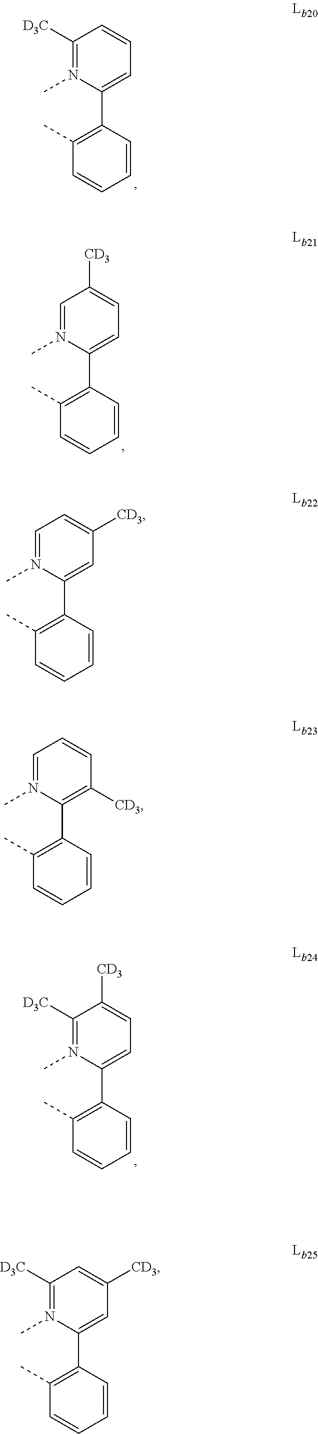 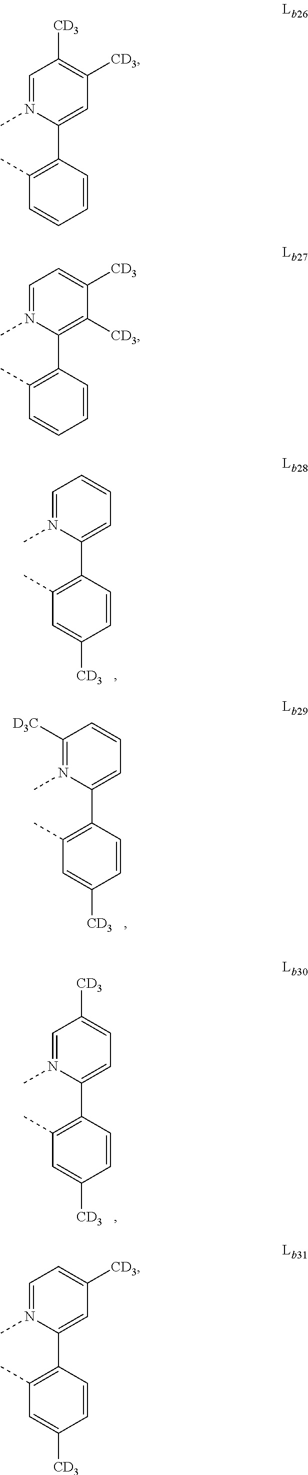 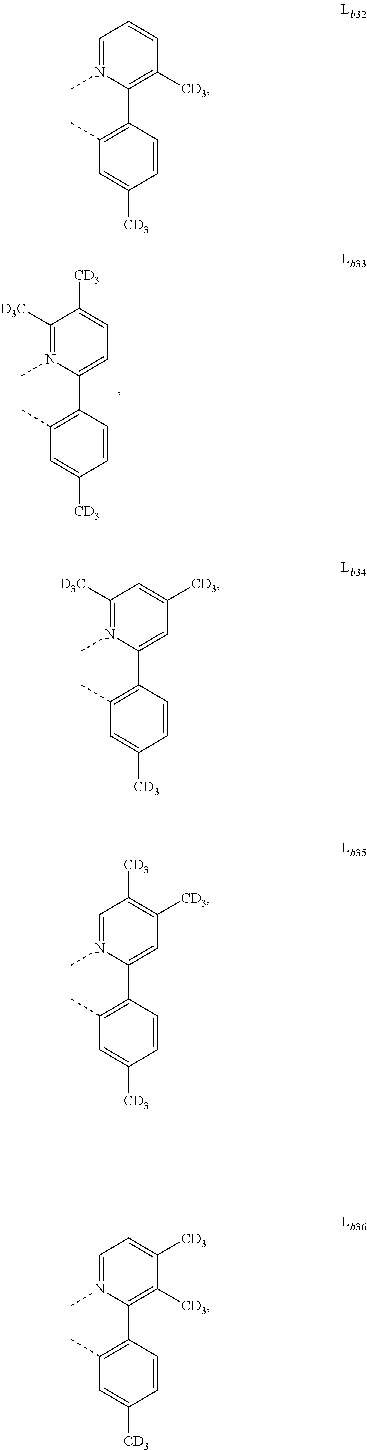 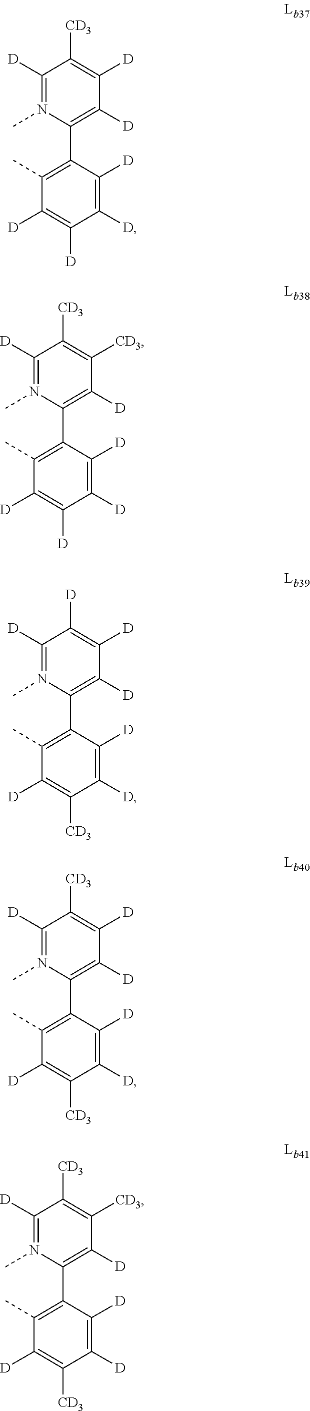 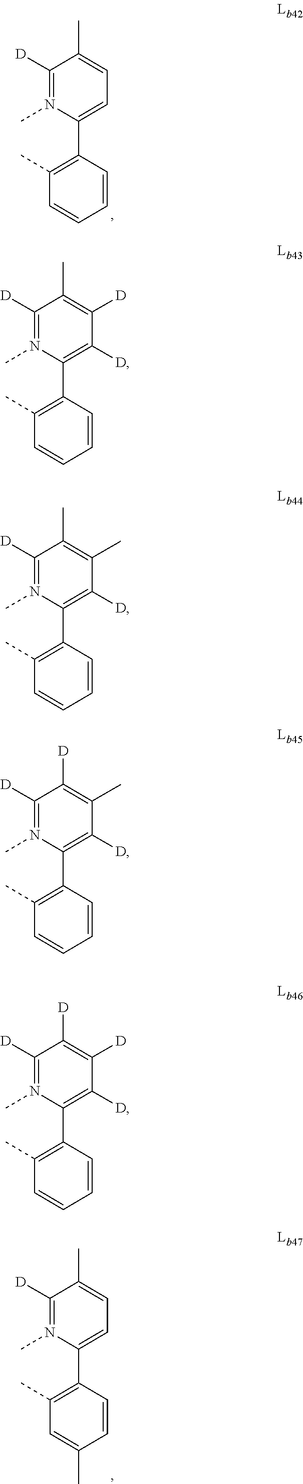 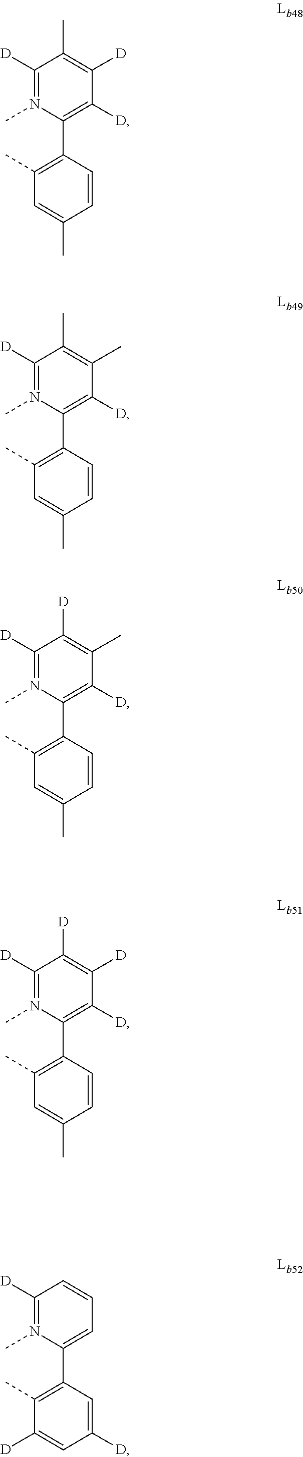 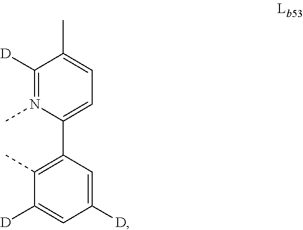 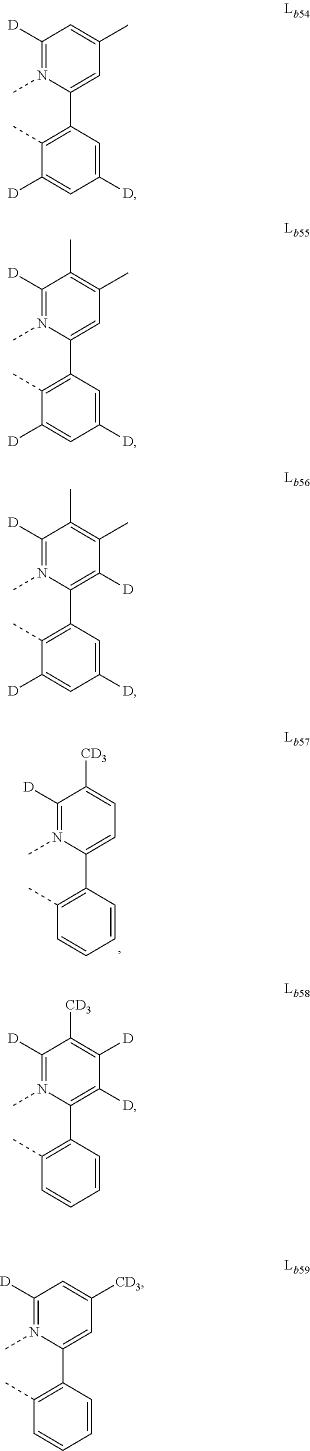 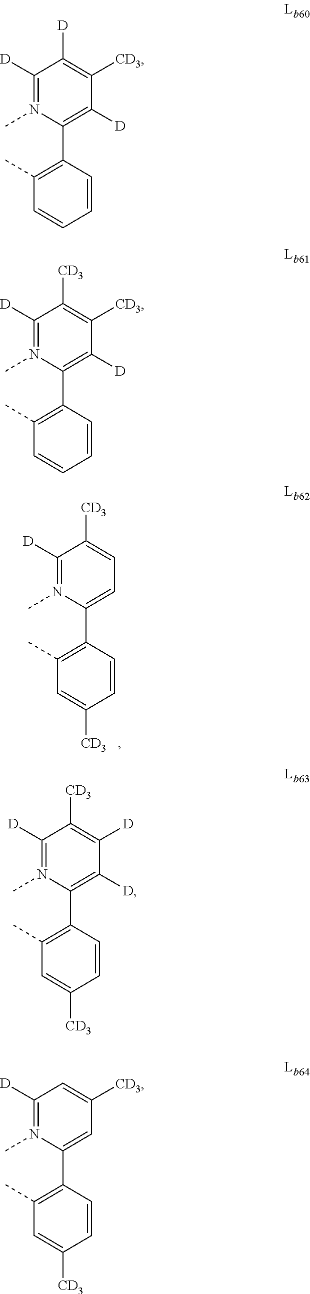 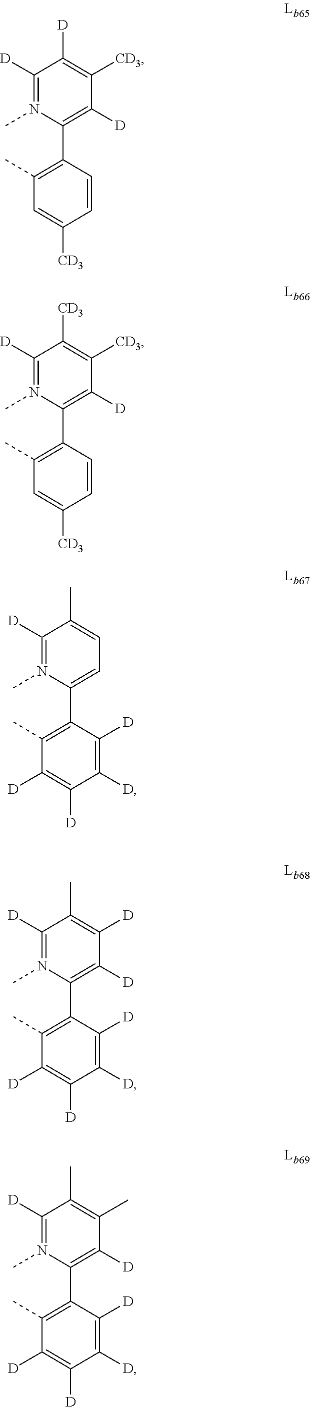 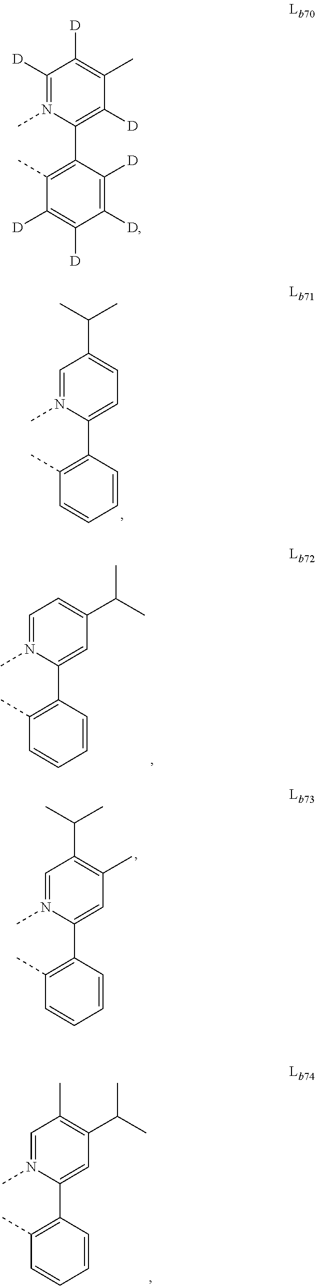 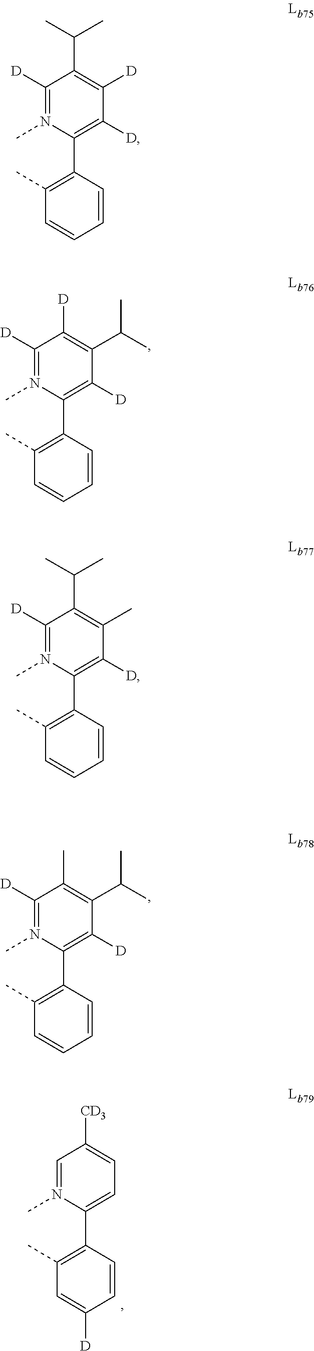 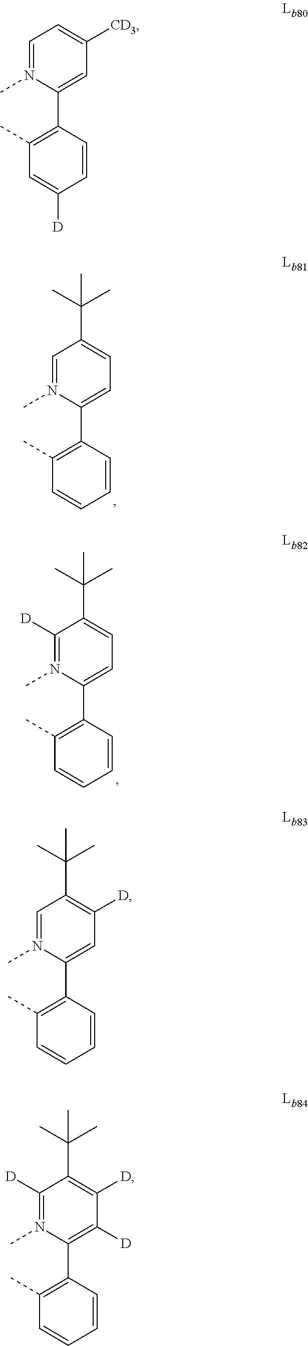 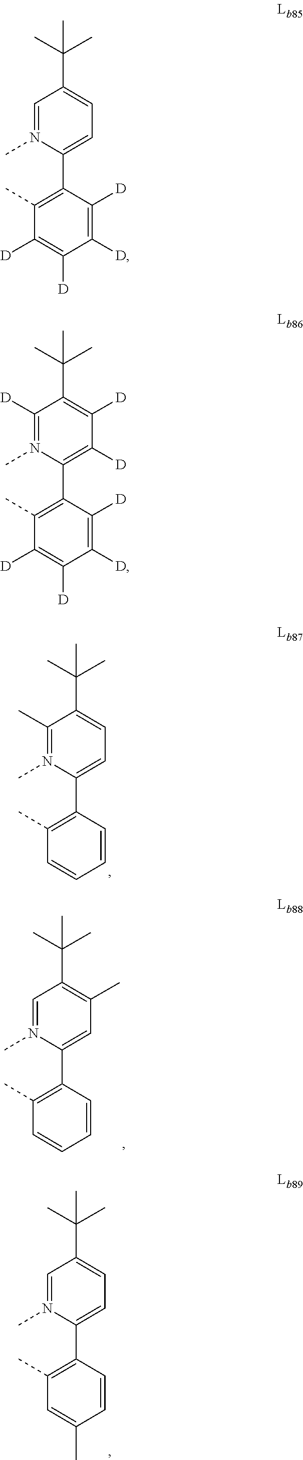 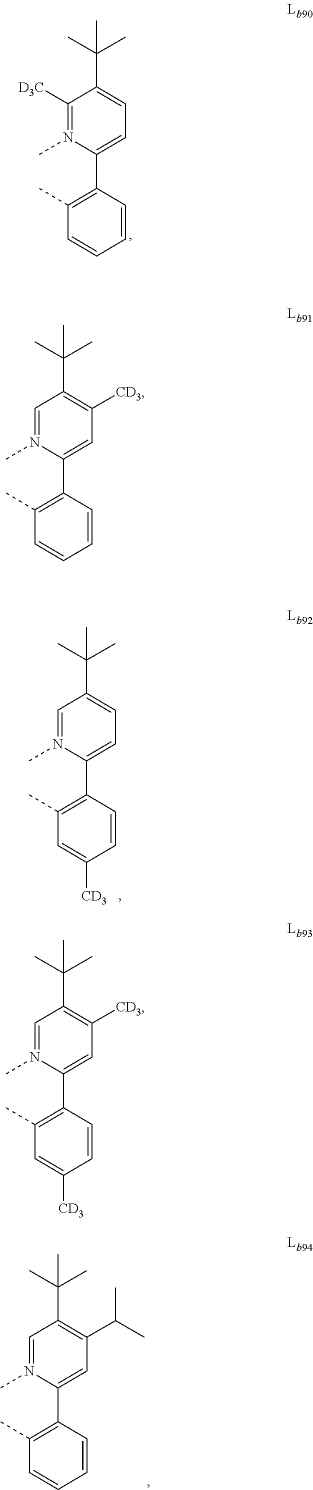 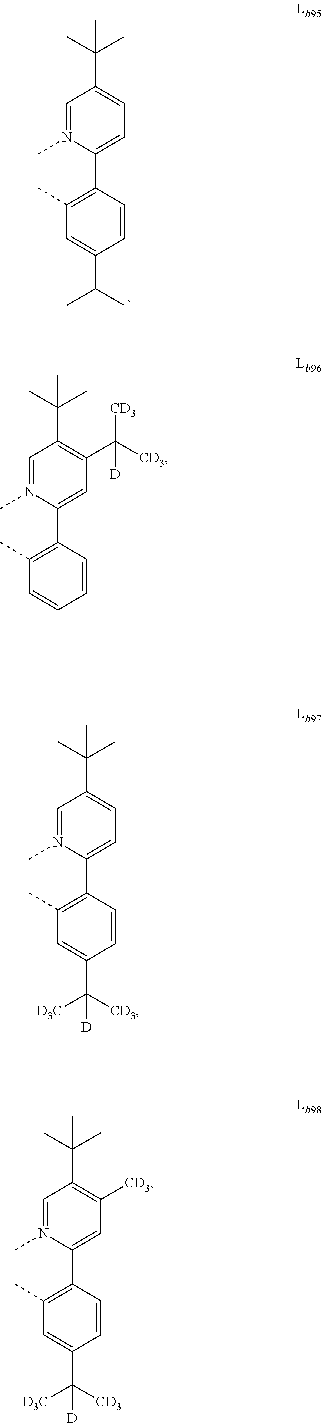 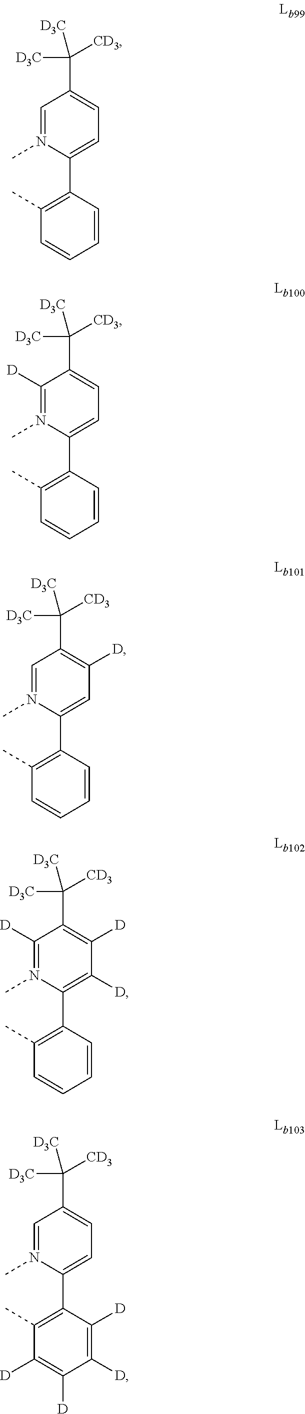 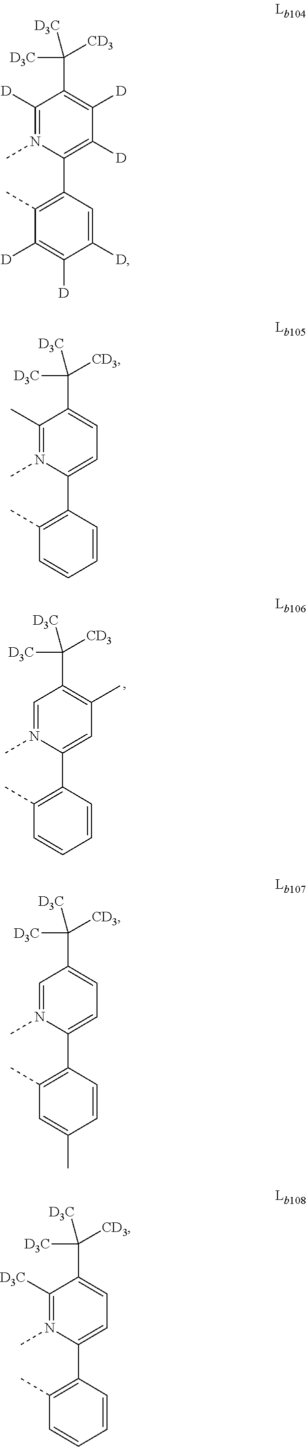 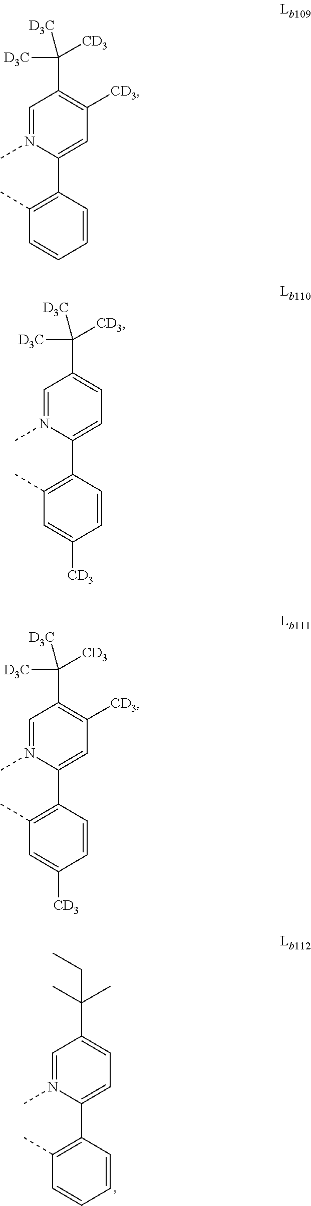 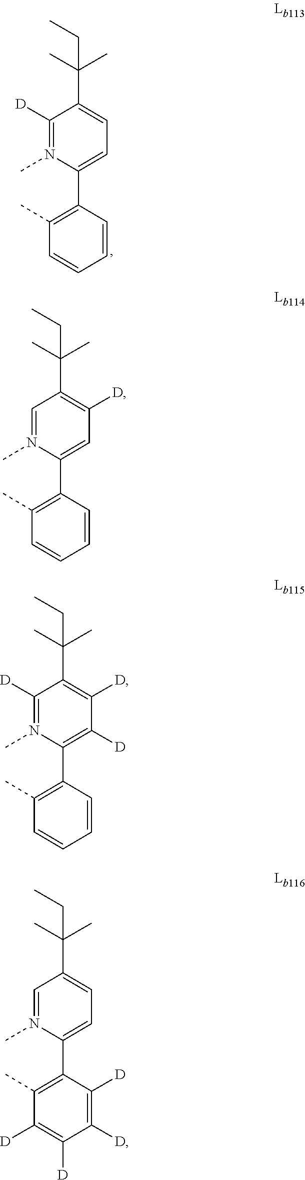 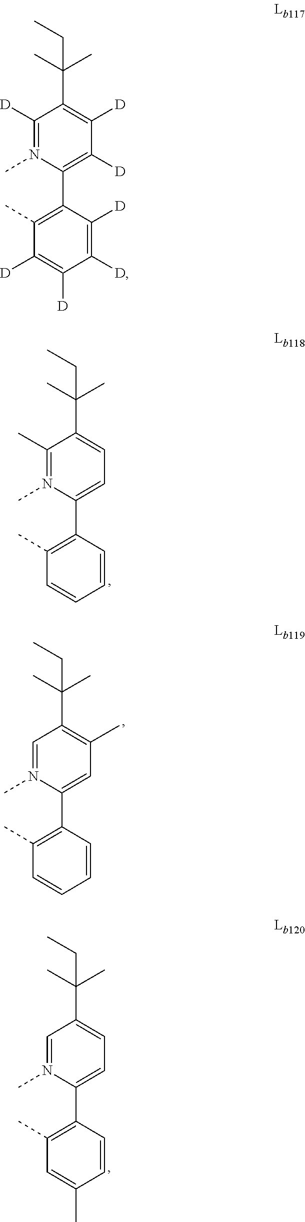 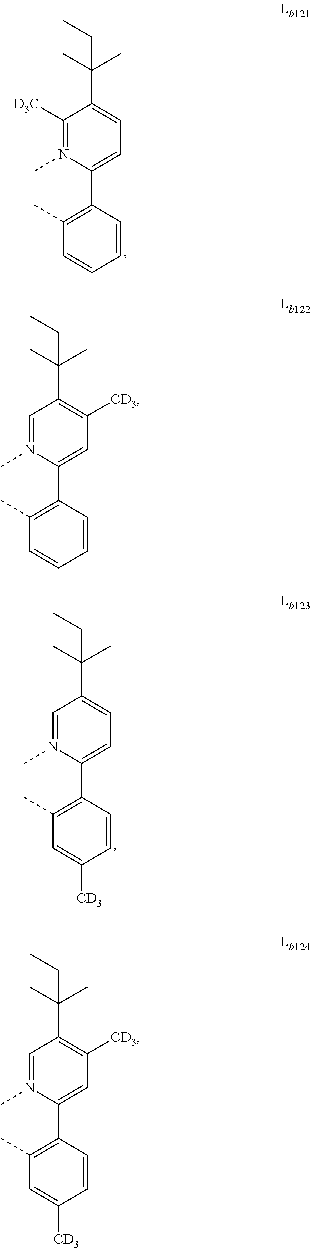 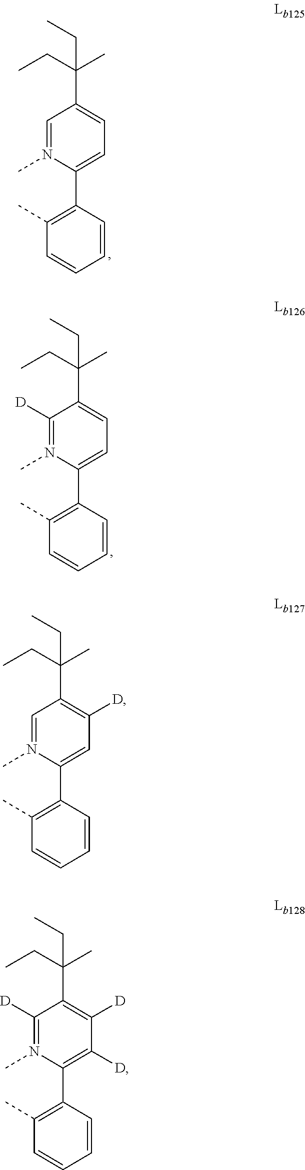 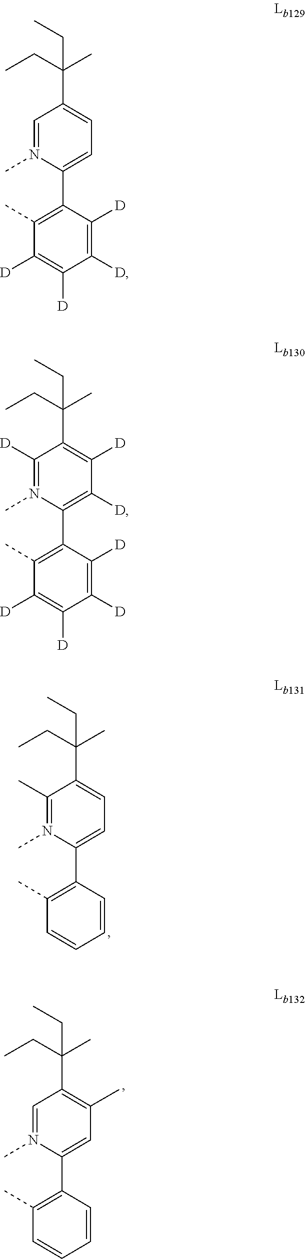 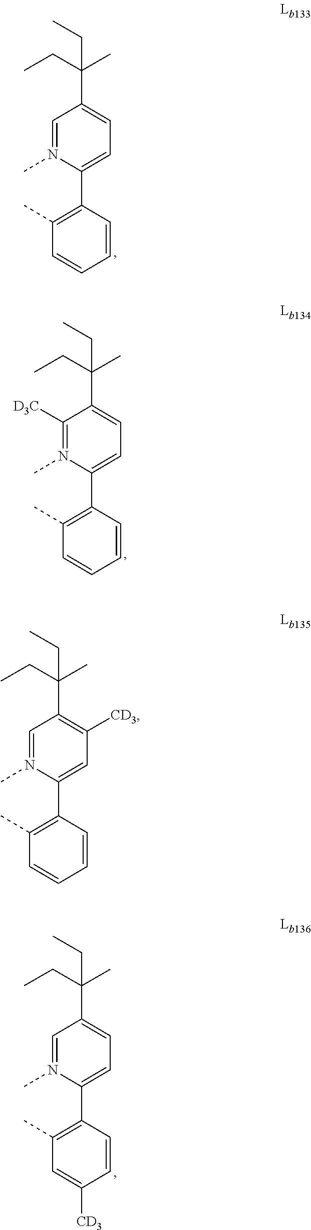 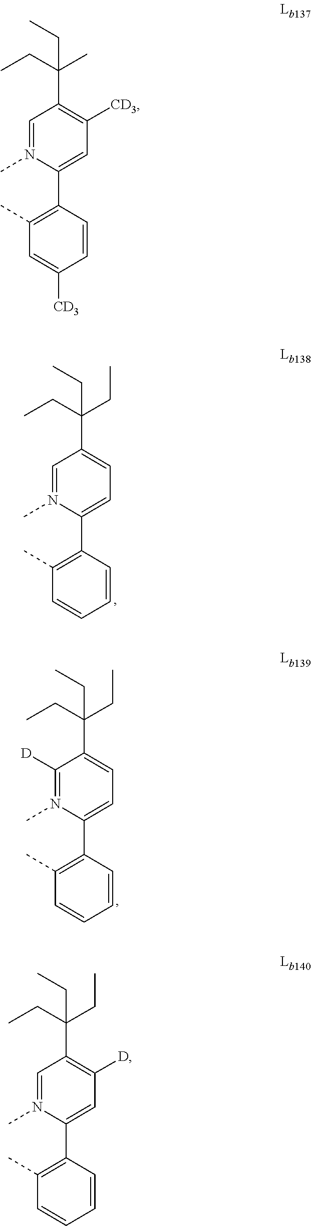 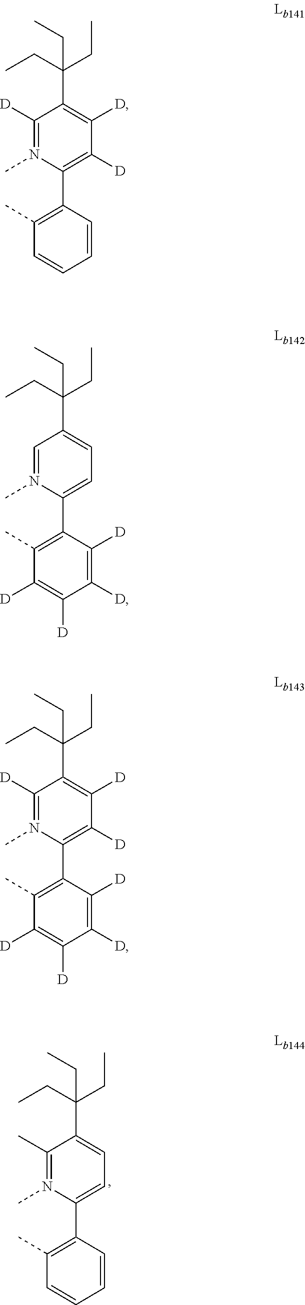 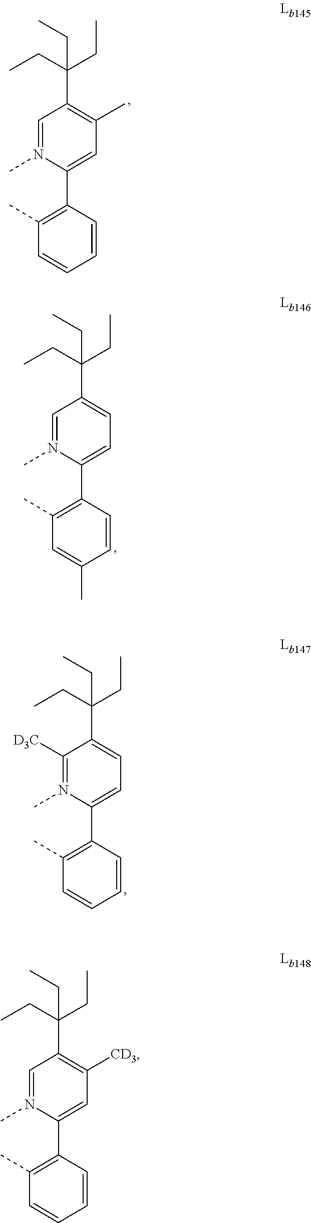 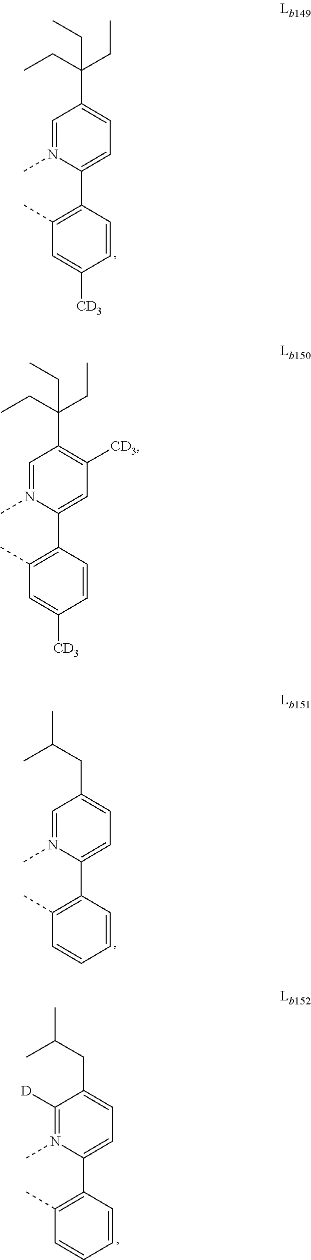 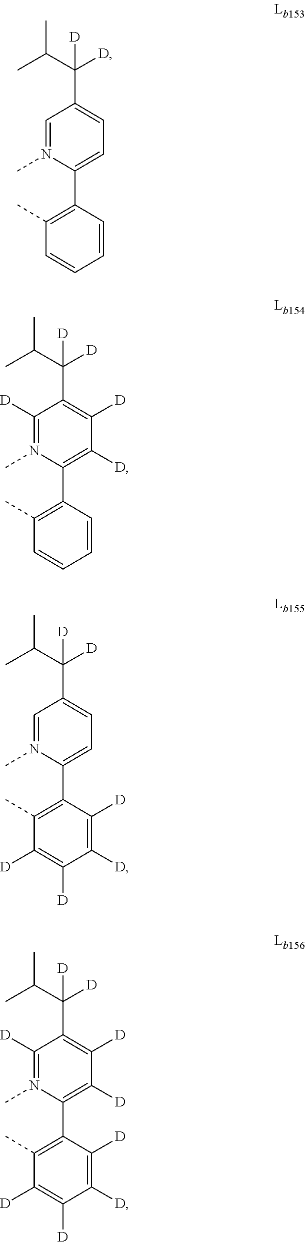 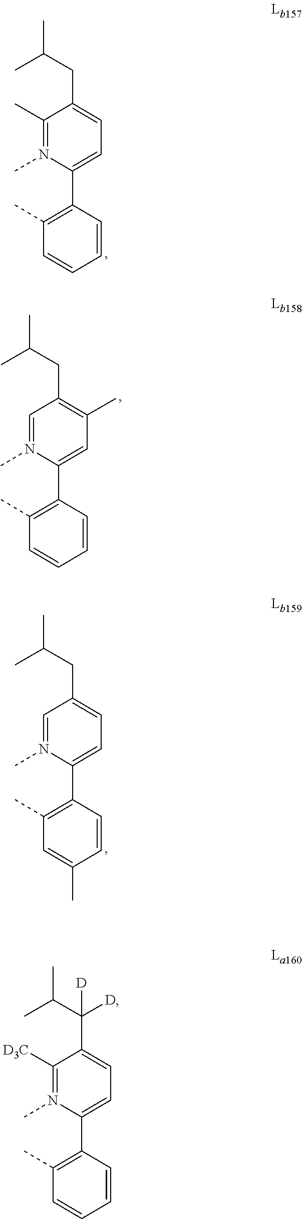 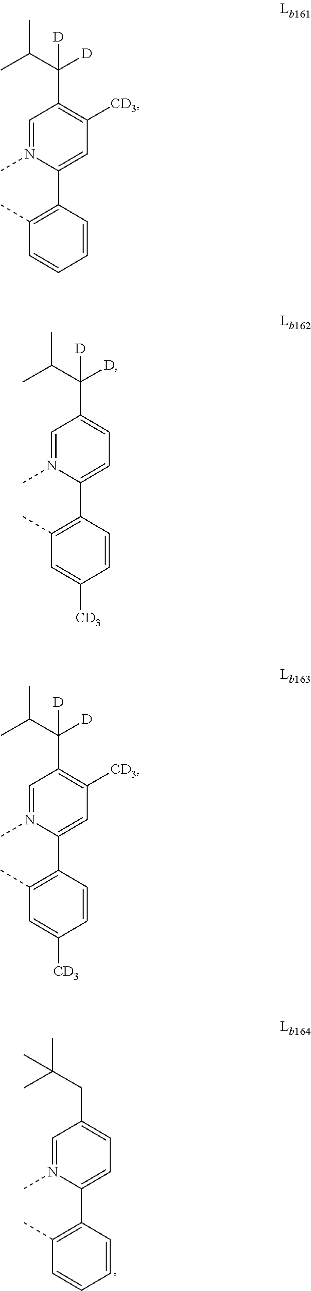 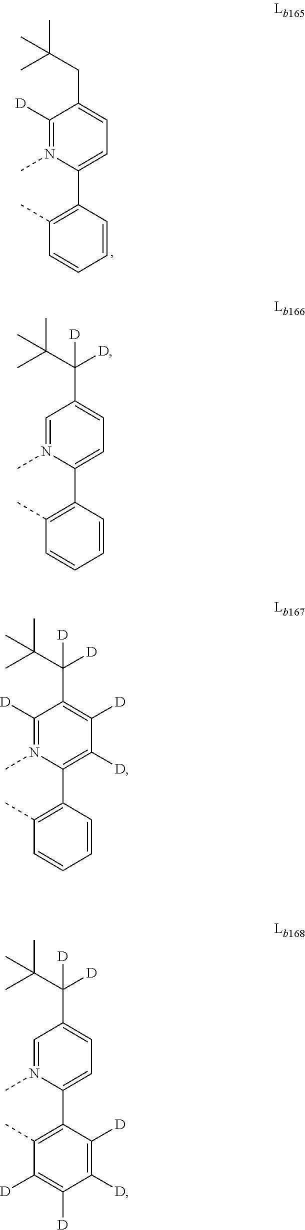 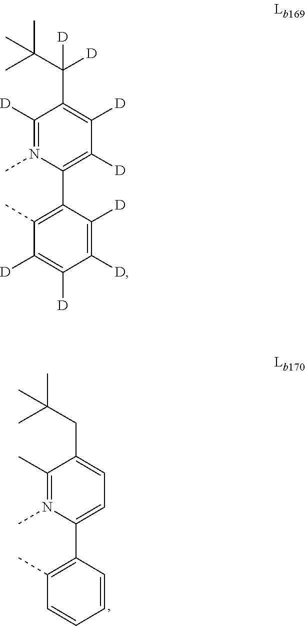 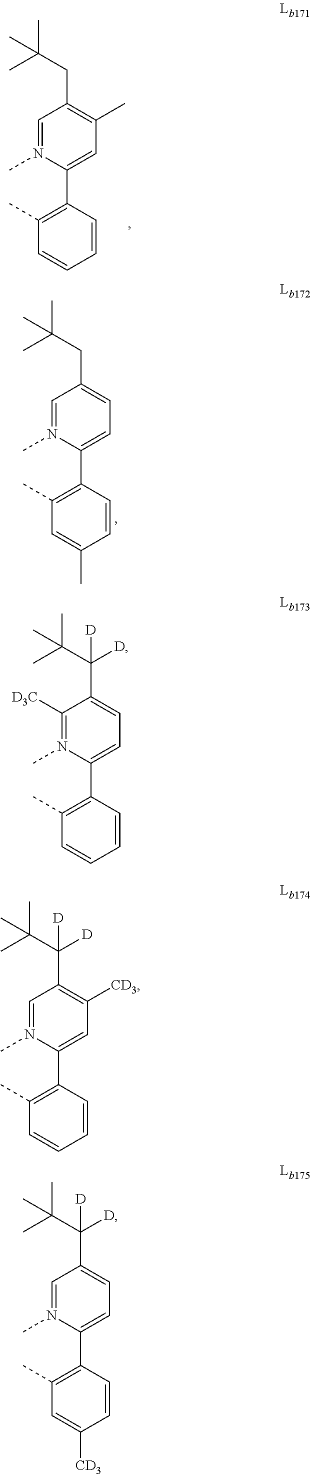 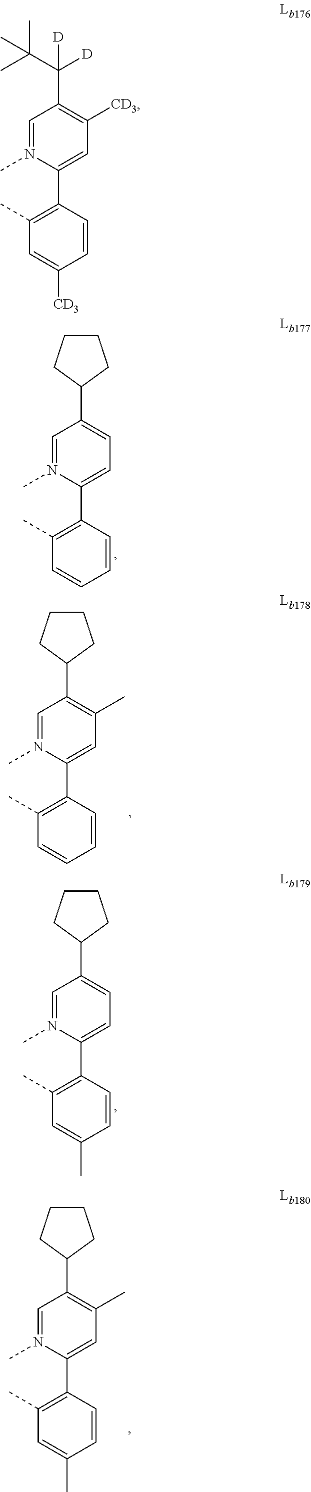 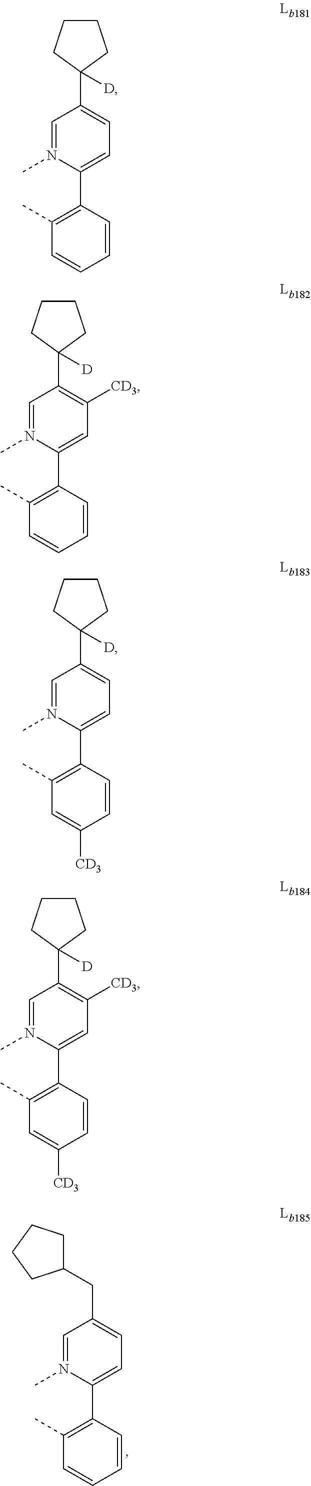 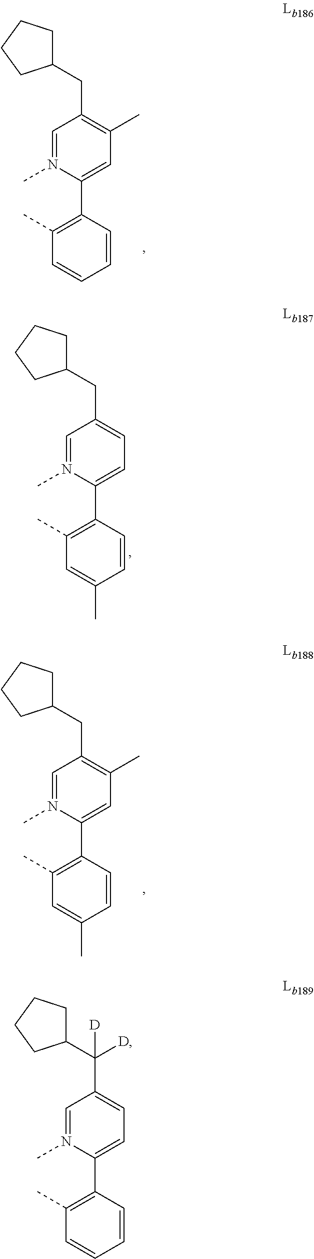 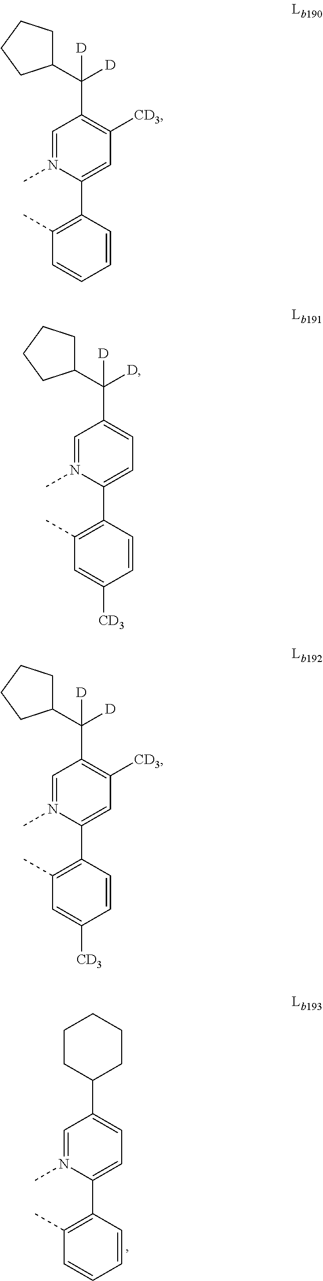 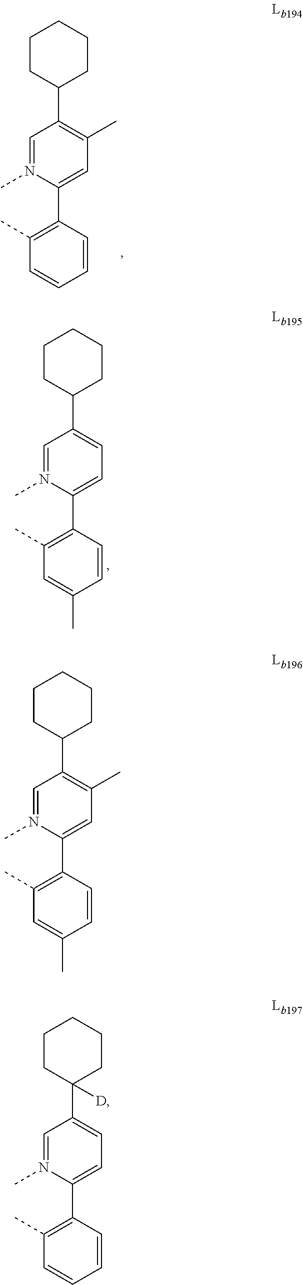 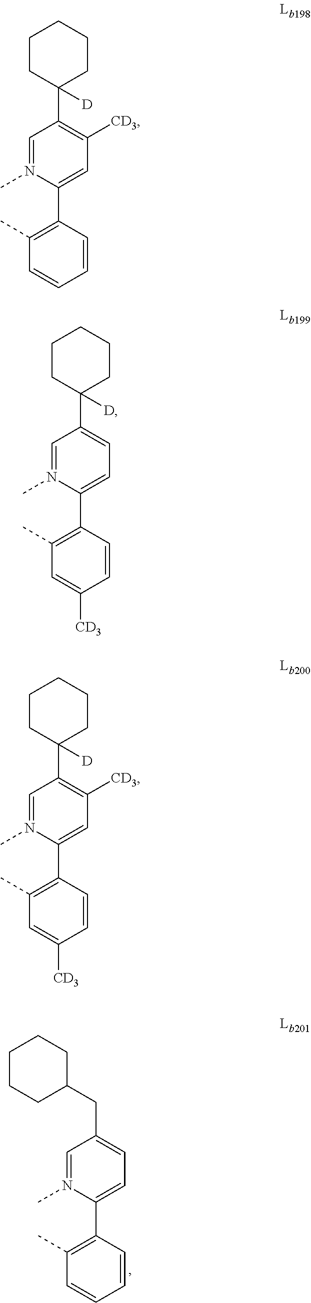 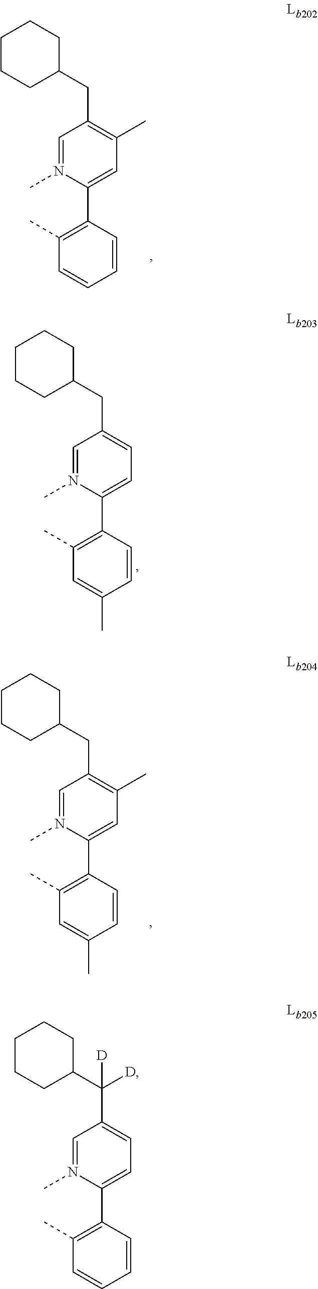 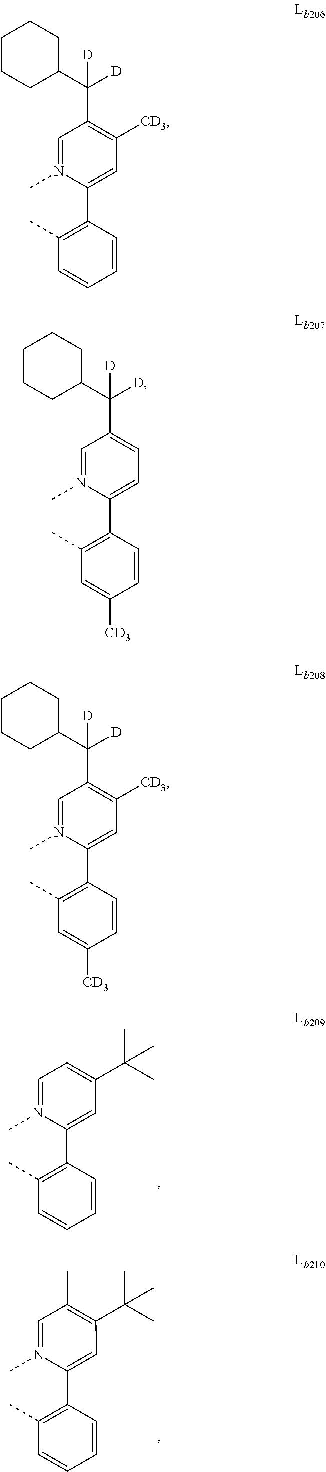 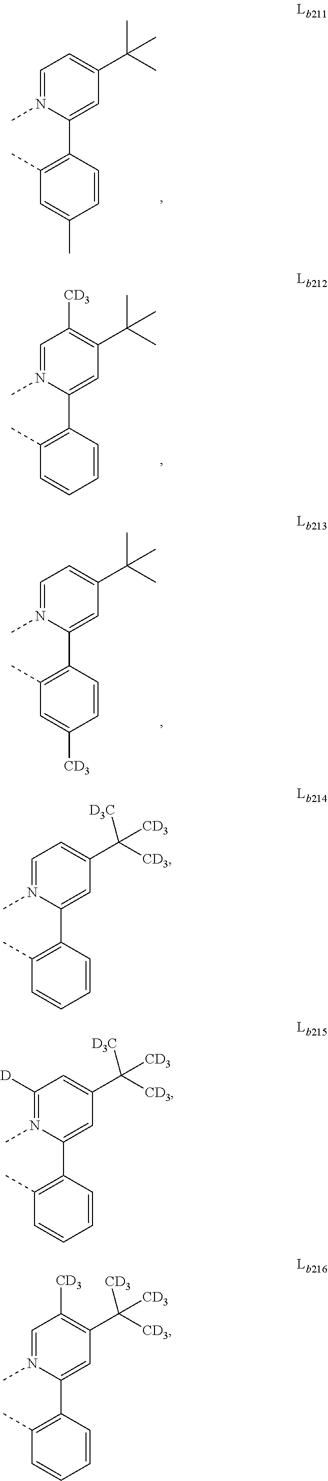 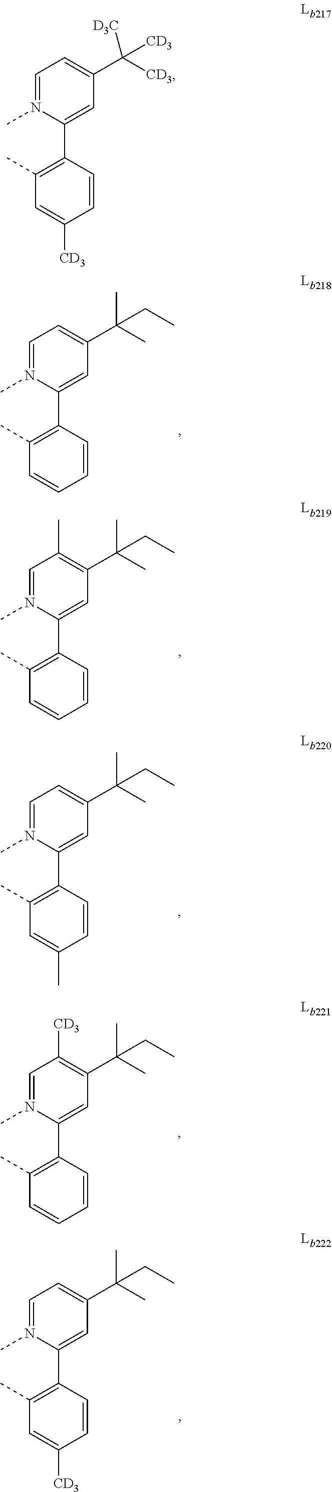 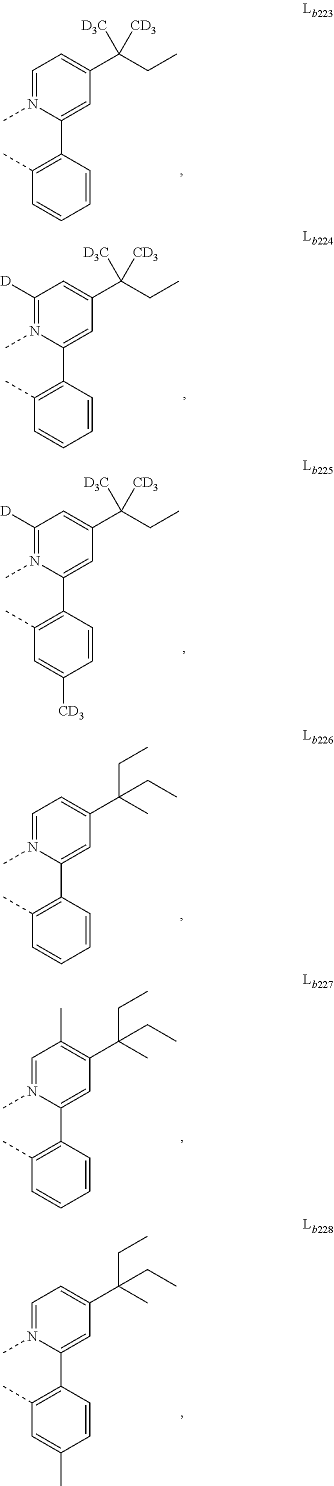 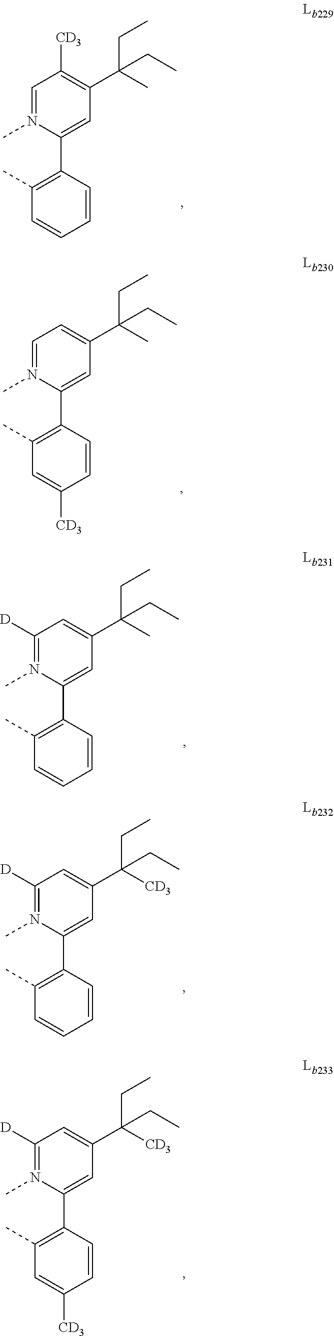 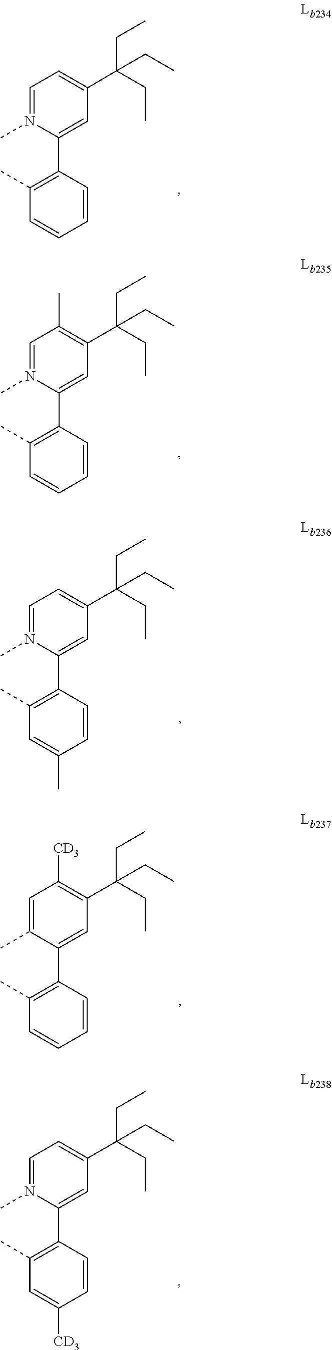 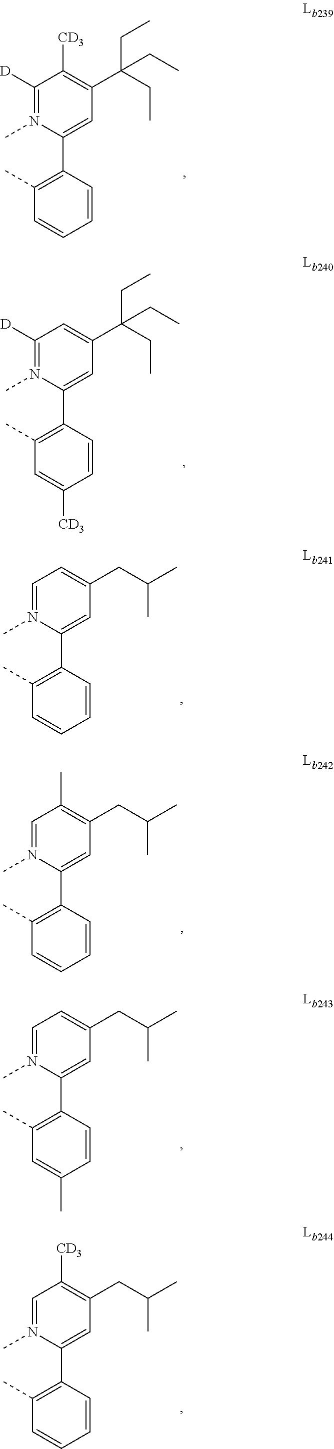 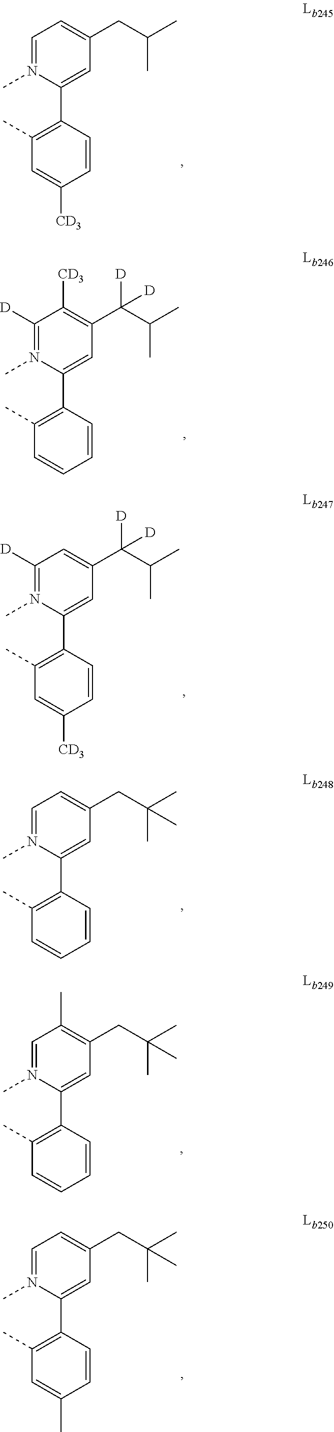 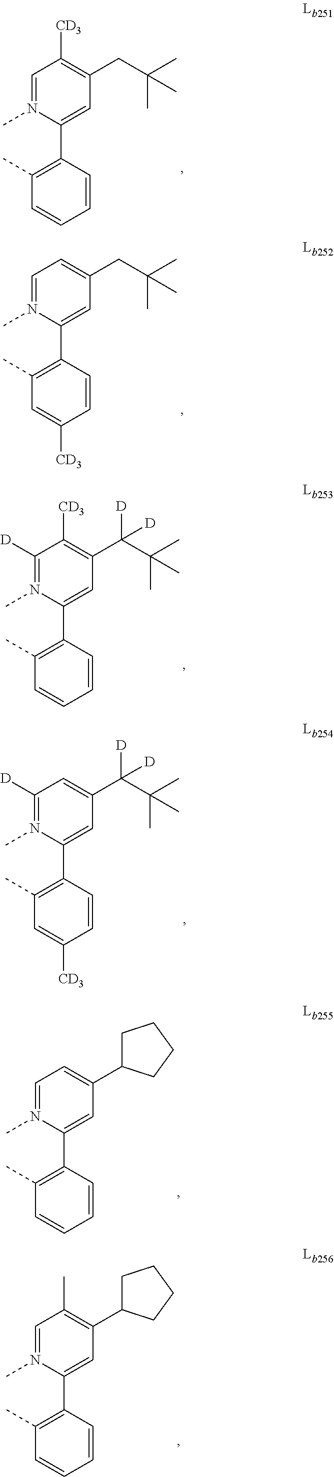 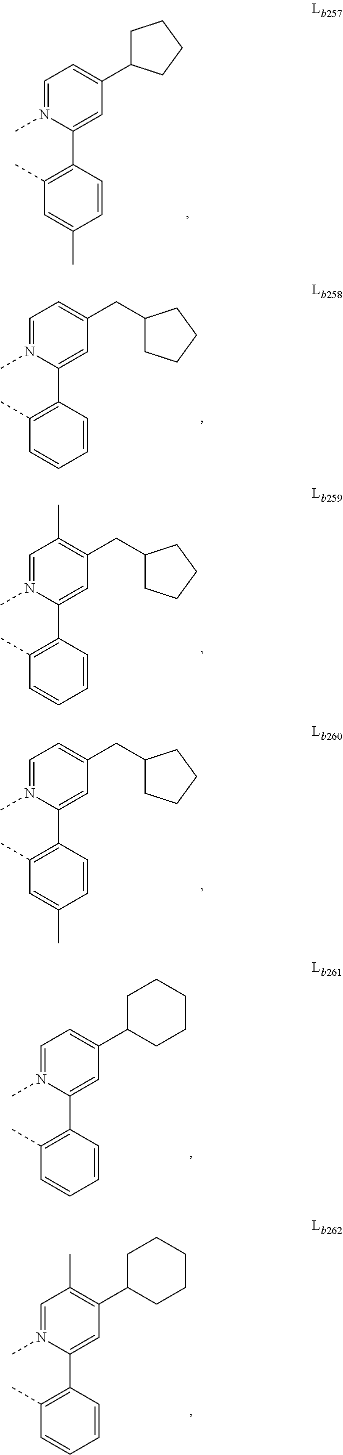 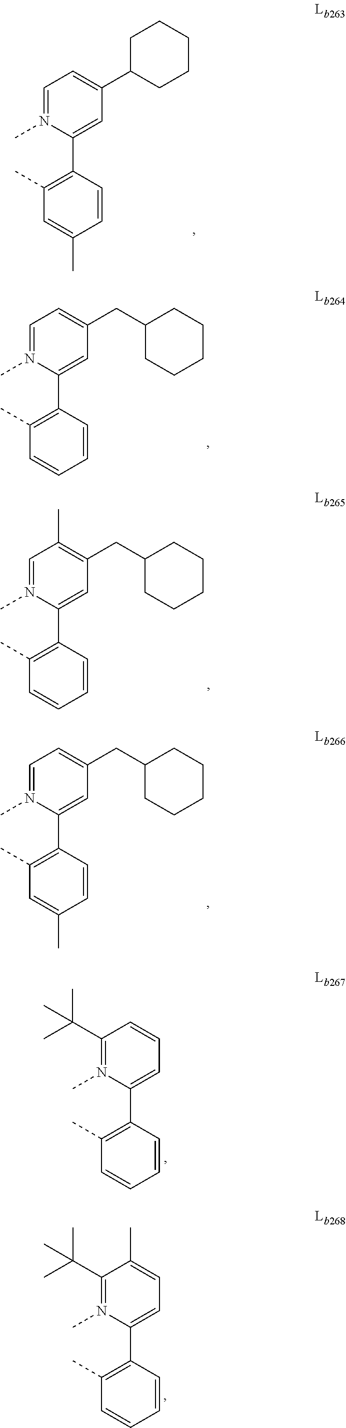 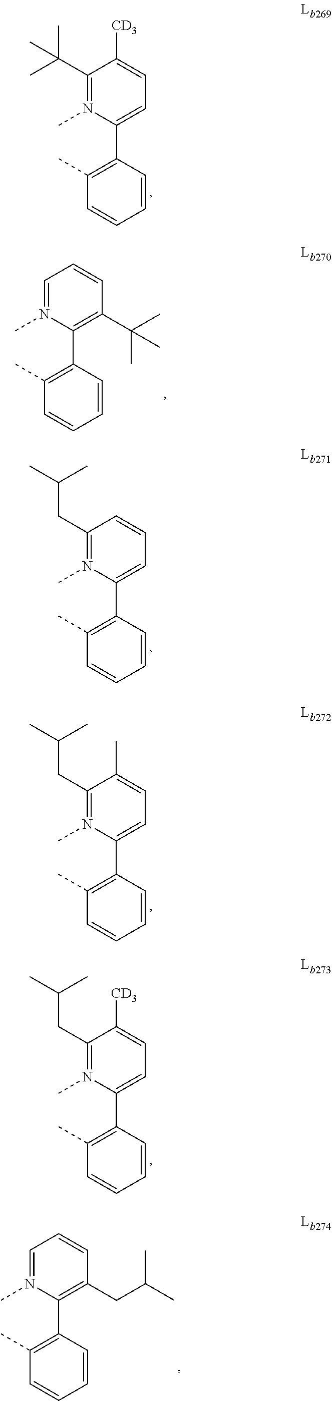 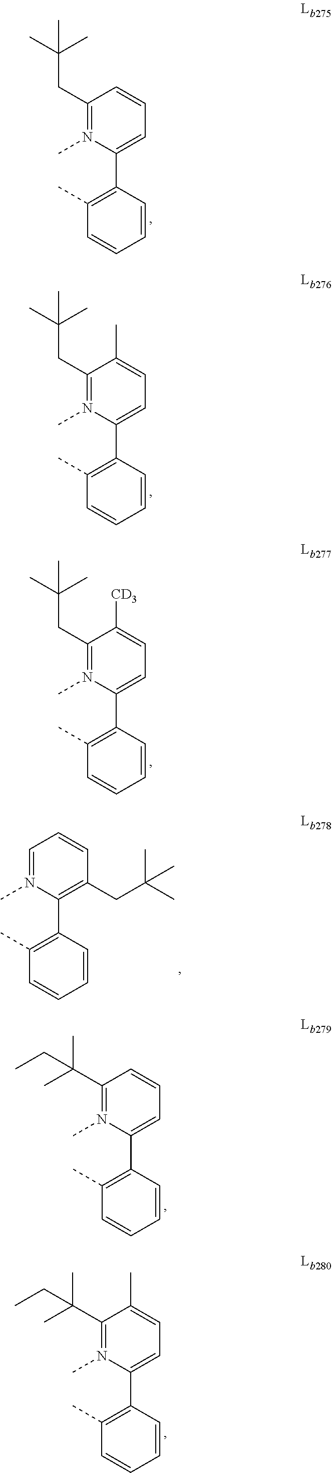 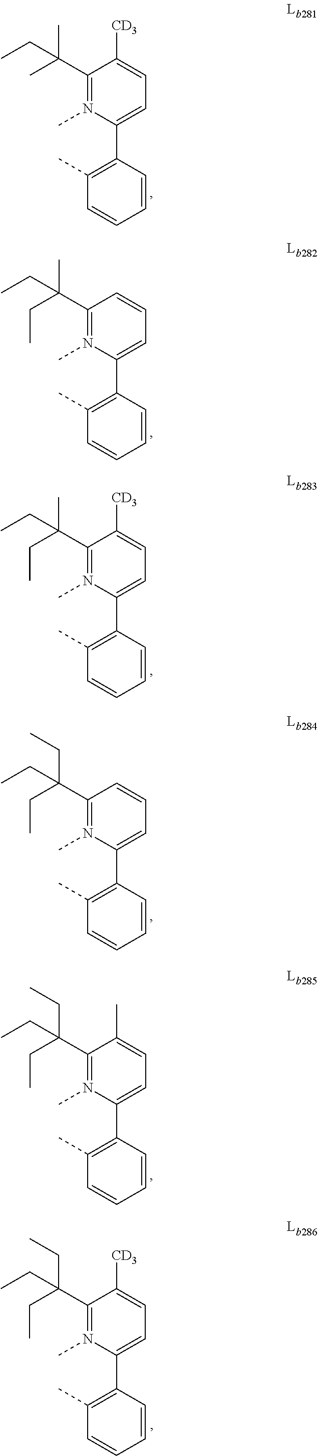 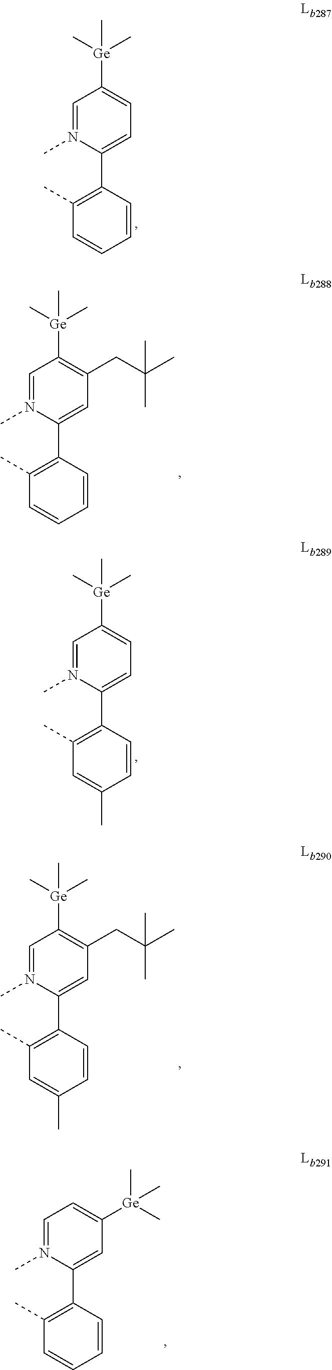 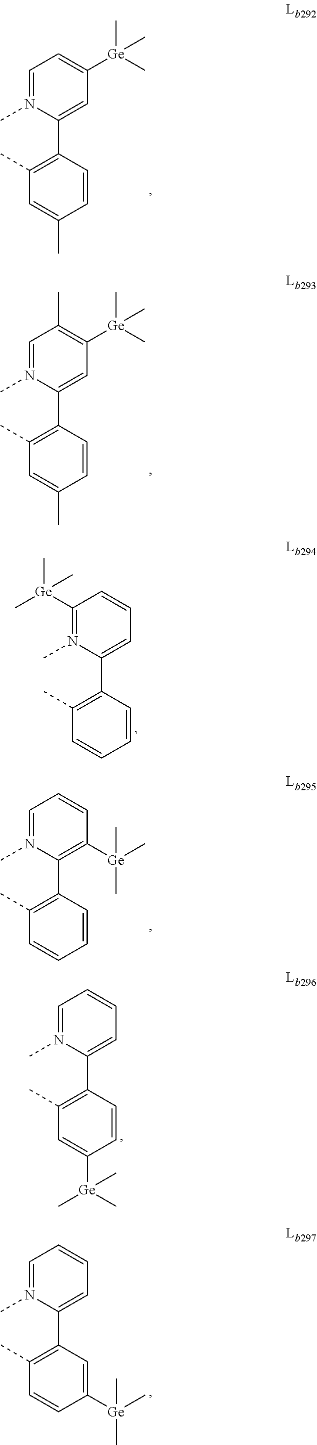 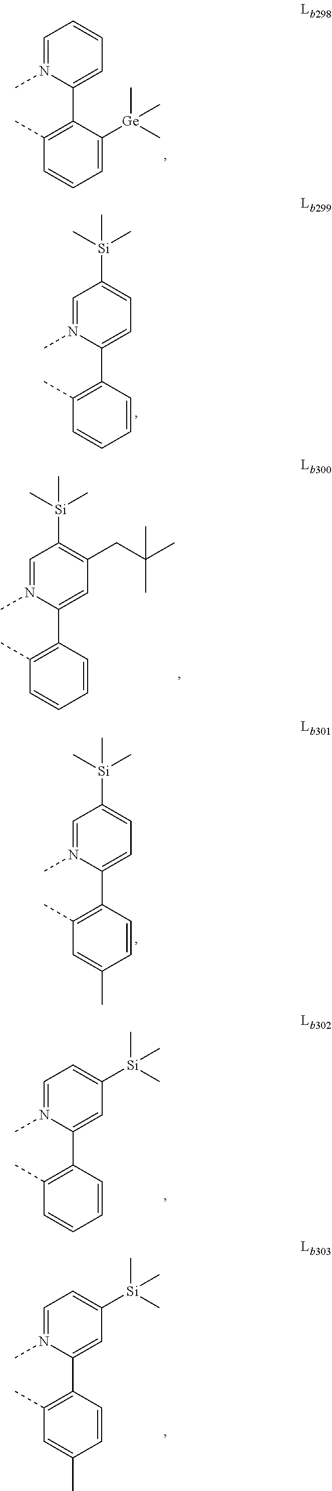 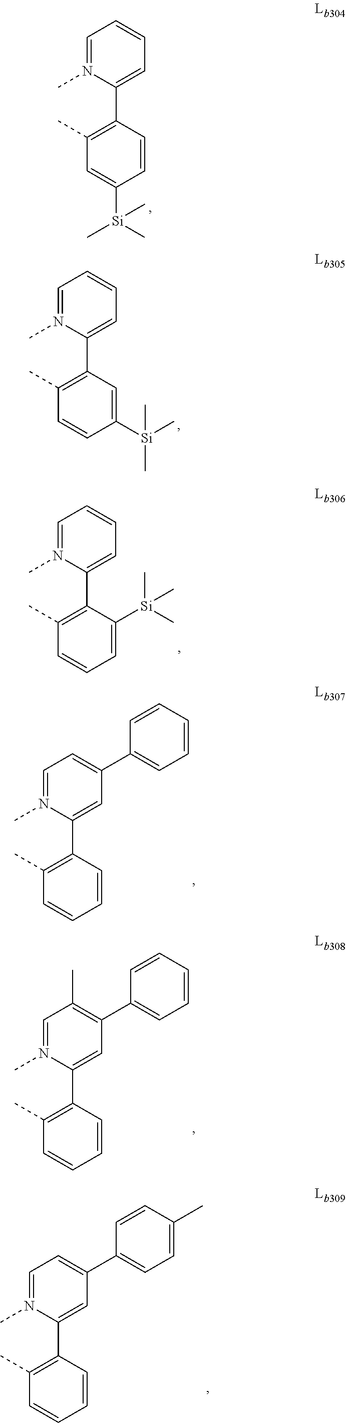 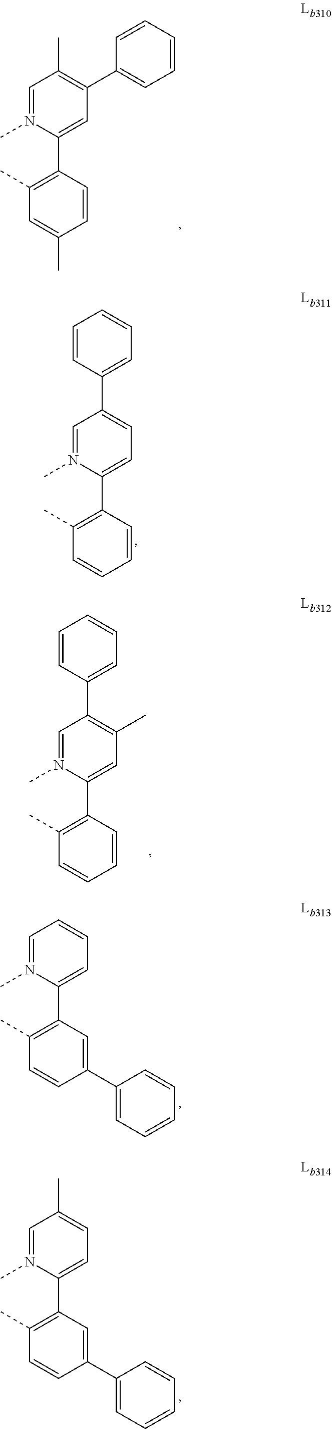 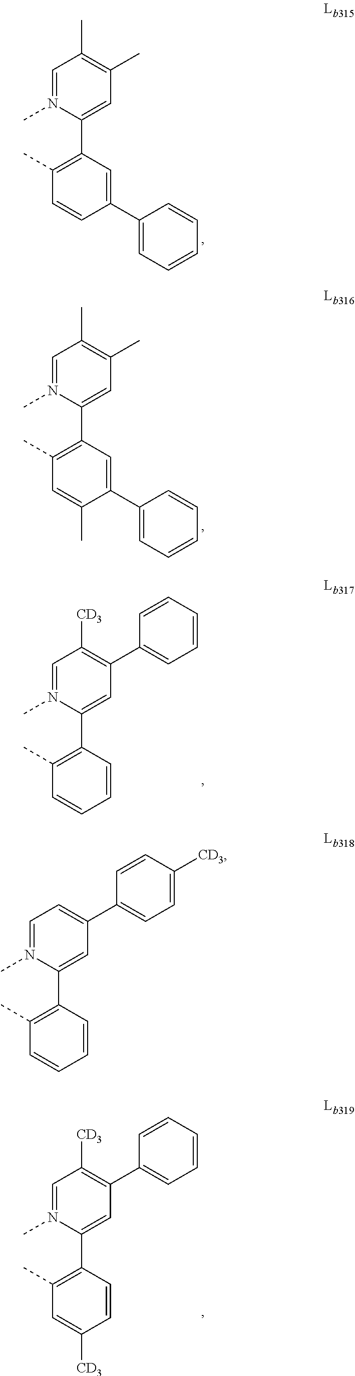 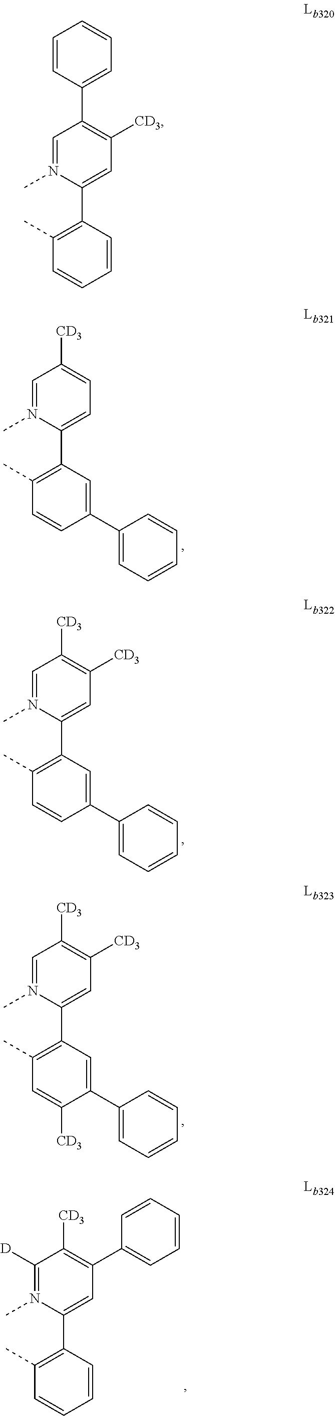 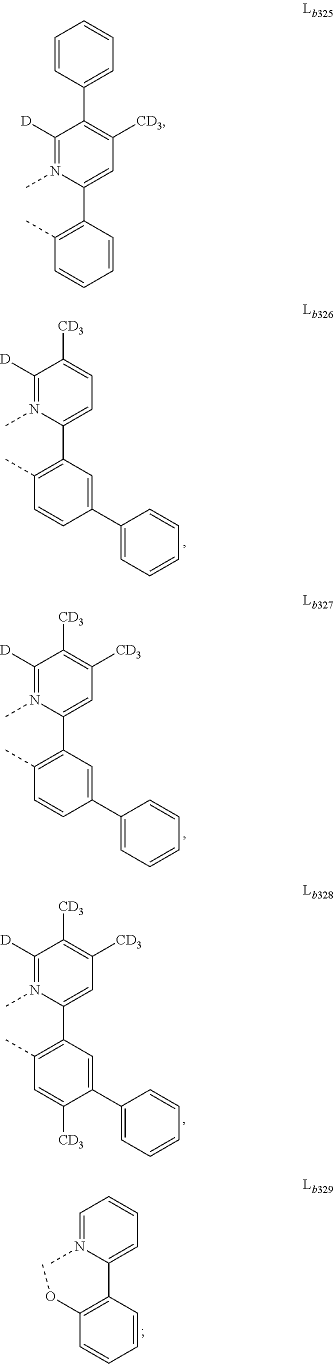
wherein, optionally, hydrogens in the structures of L_{b1} to L_{b329} can be partially or fully deuterated.

16. The metal complex of claim 3, wherein L_{c} is, at each occurrence identically or differently, selected from the group consisting of:

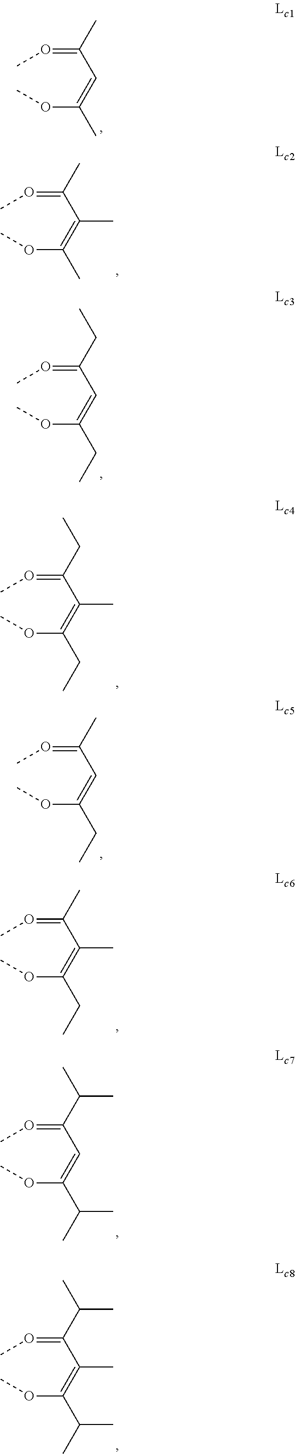

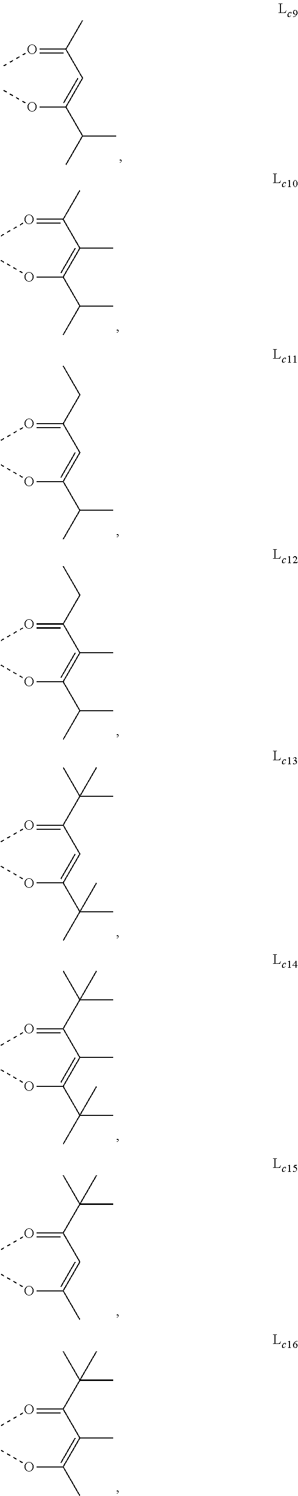

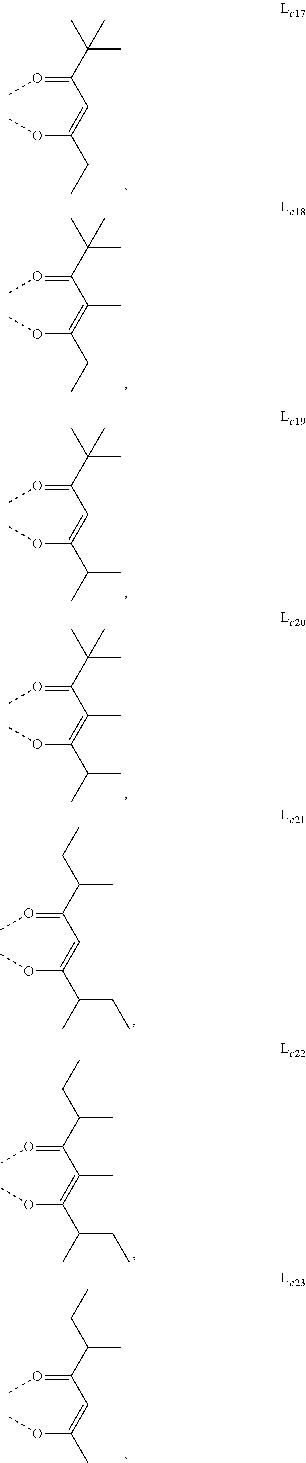

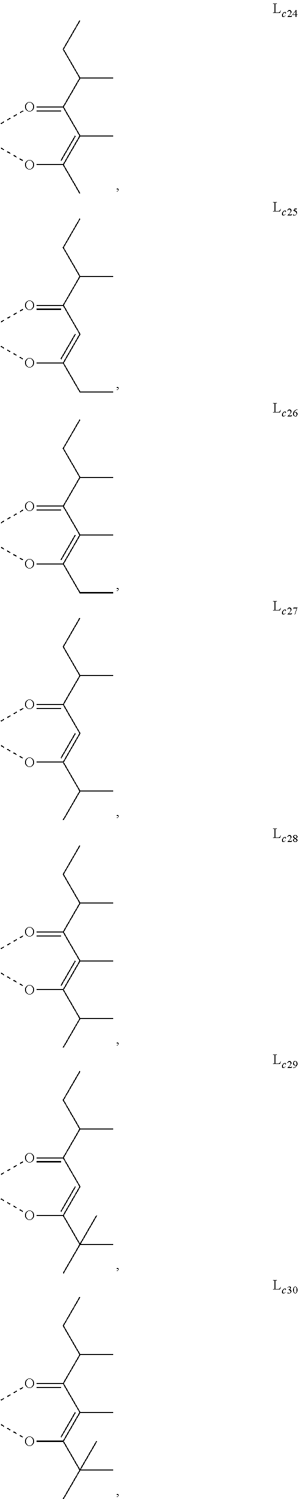

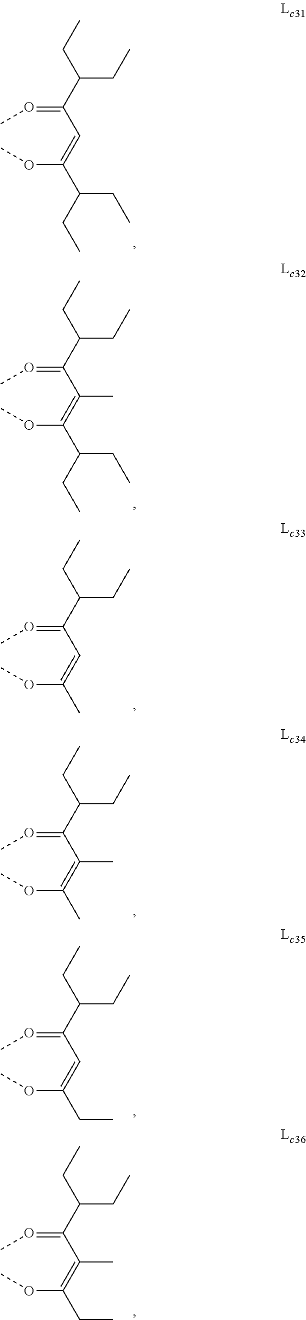

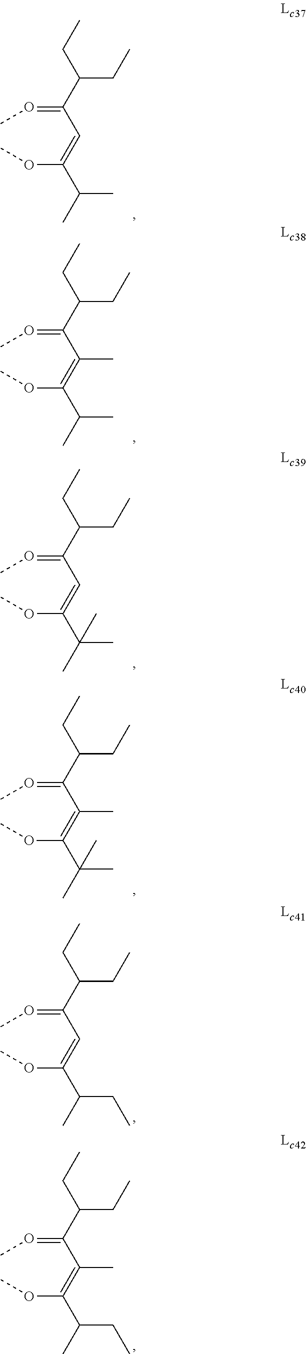

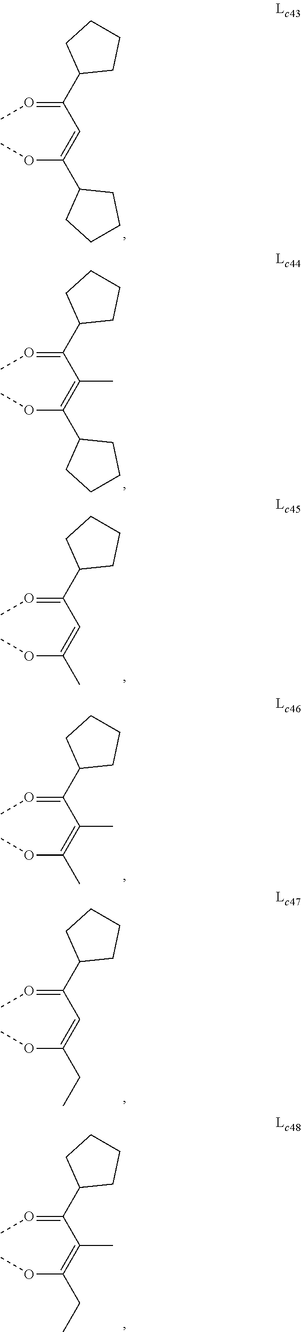

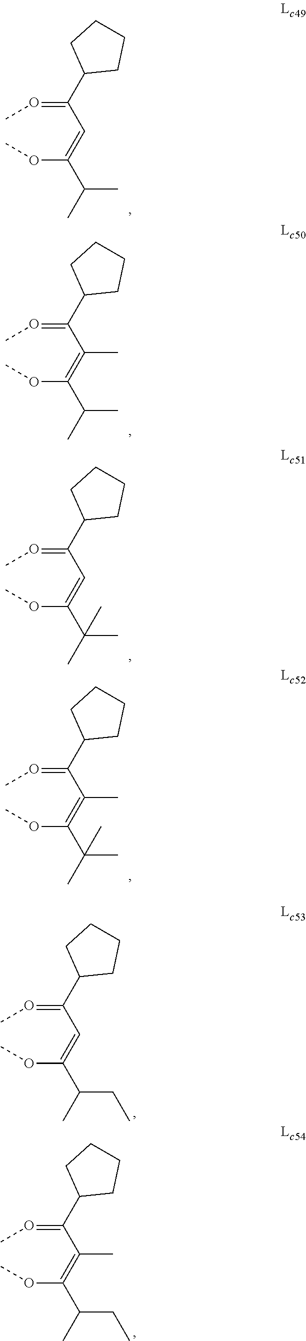

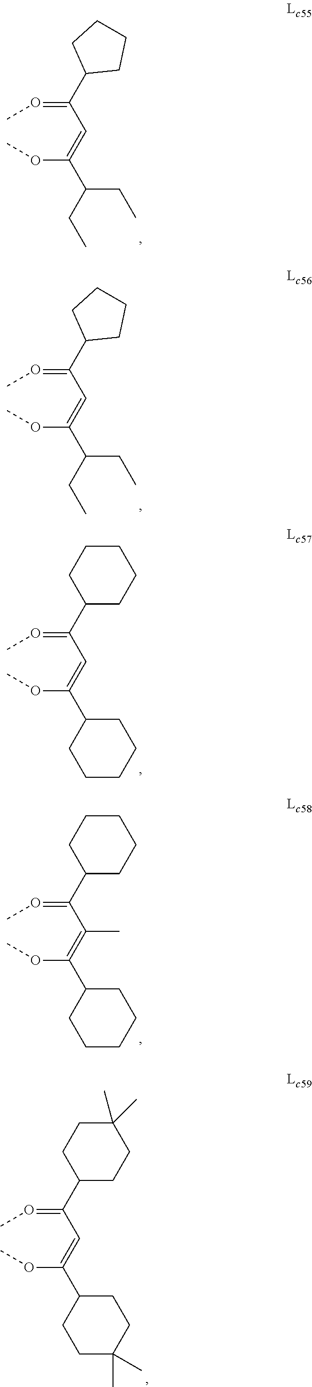

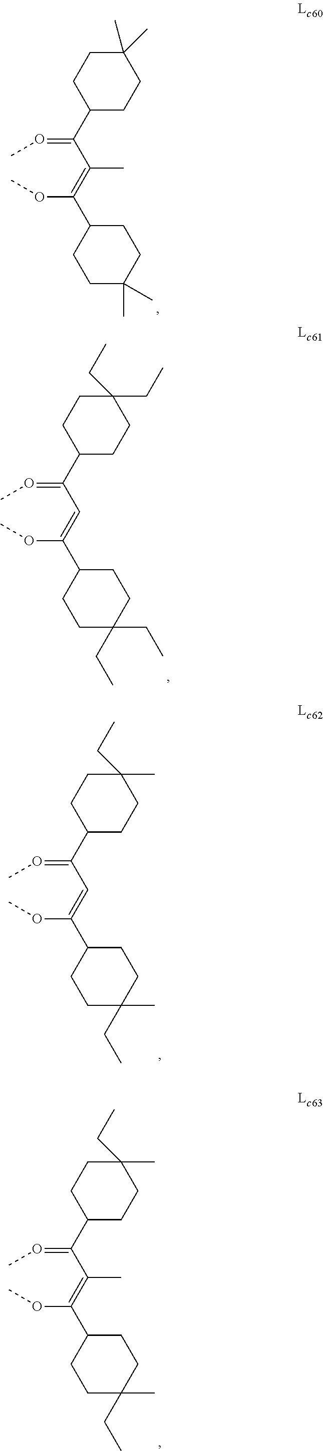

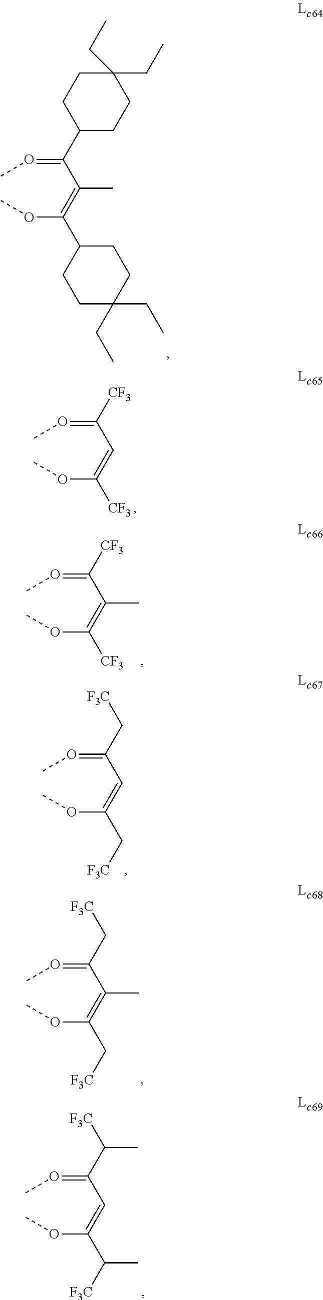

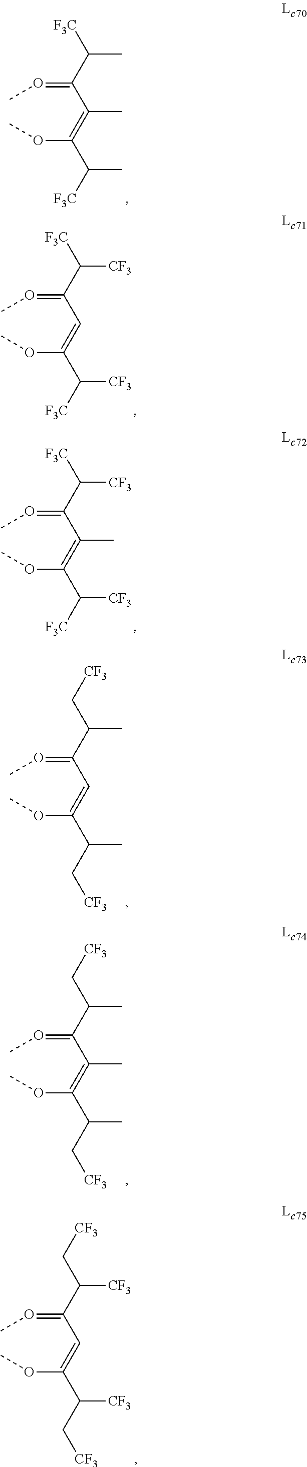

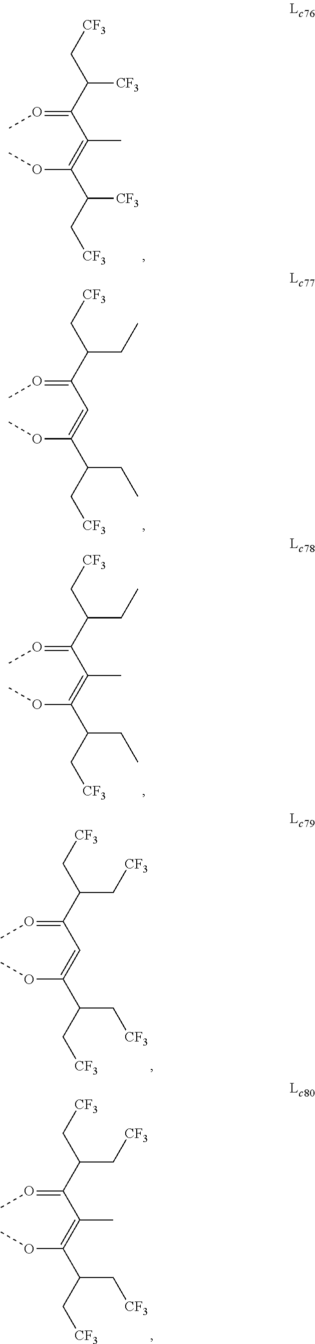

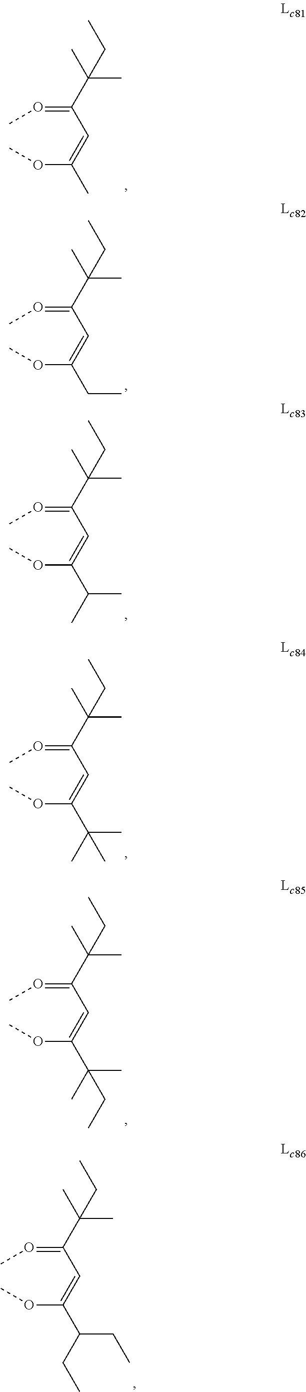

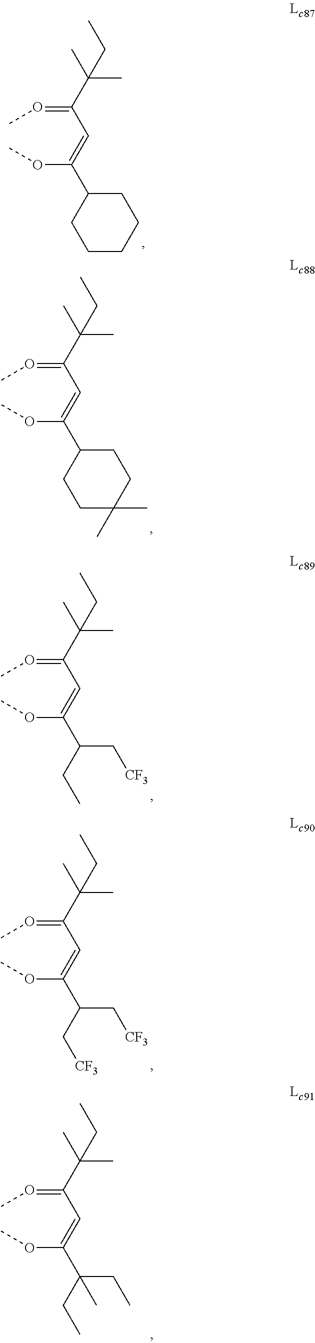

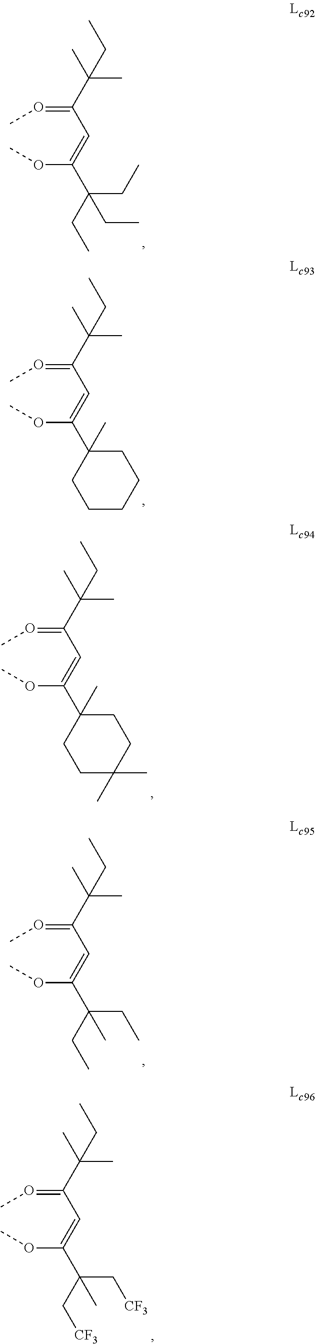

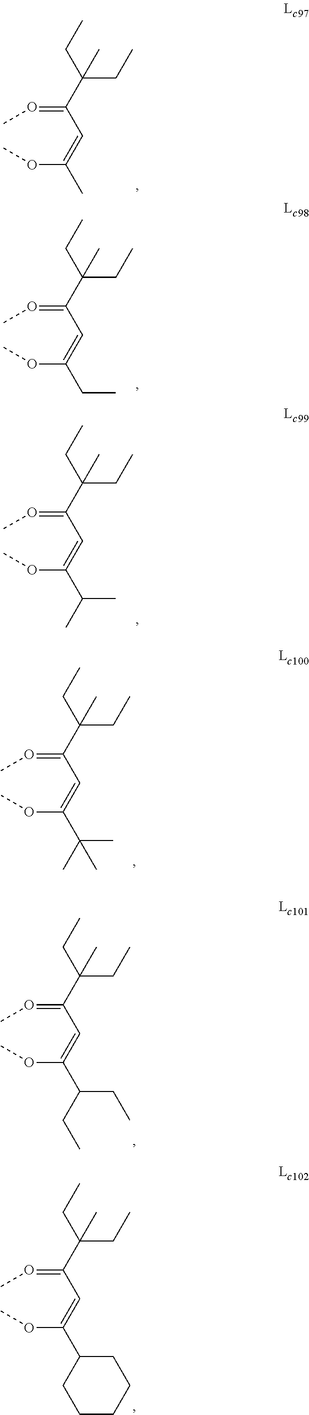

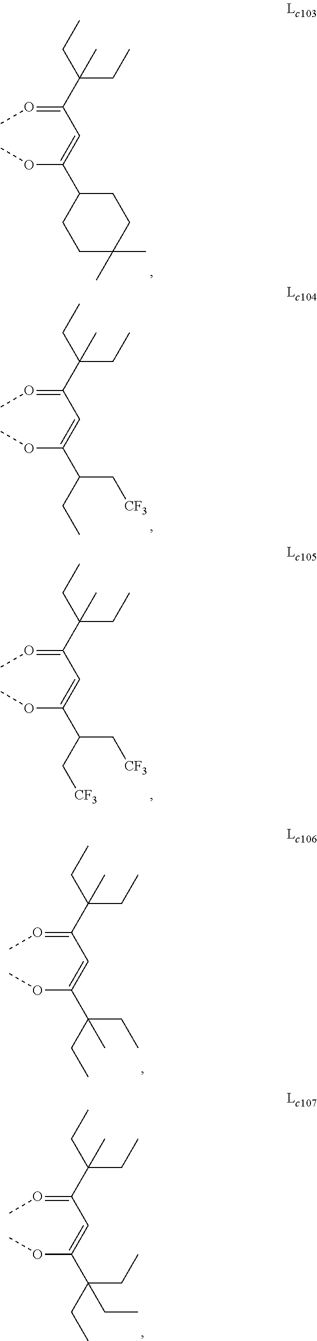

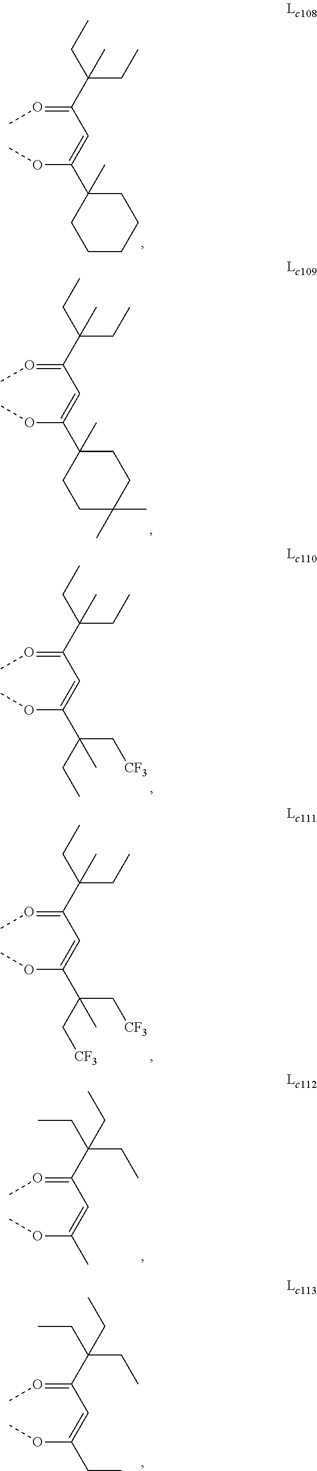

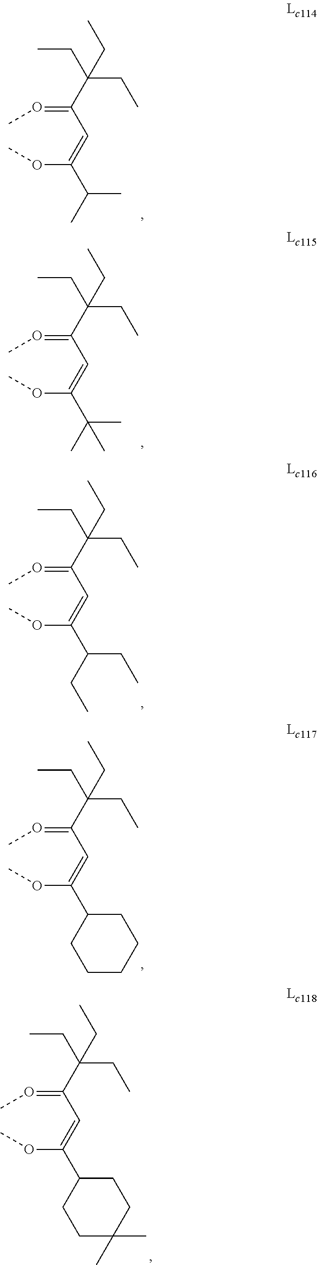

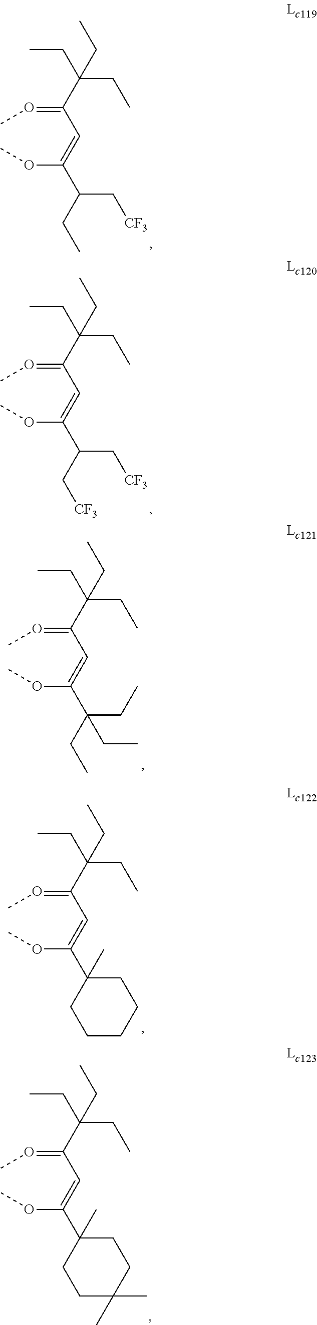

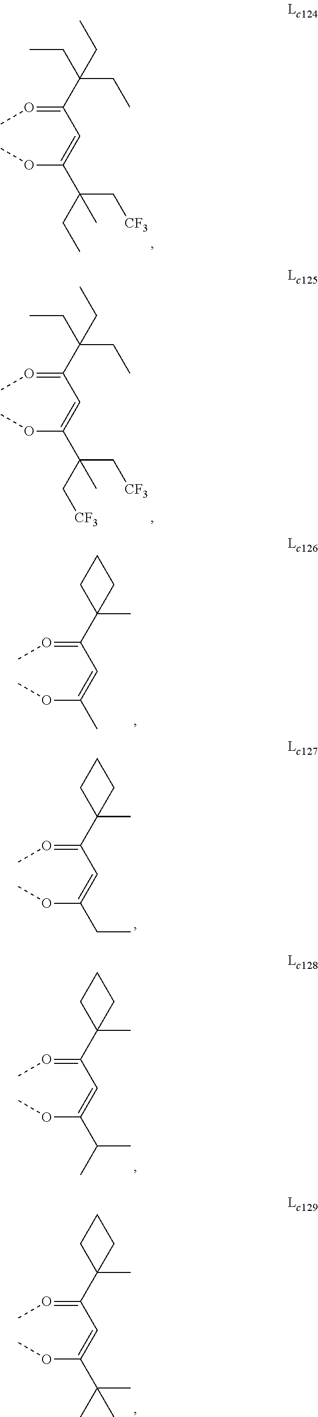

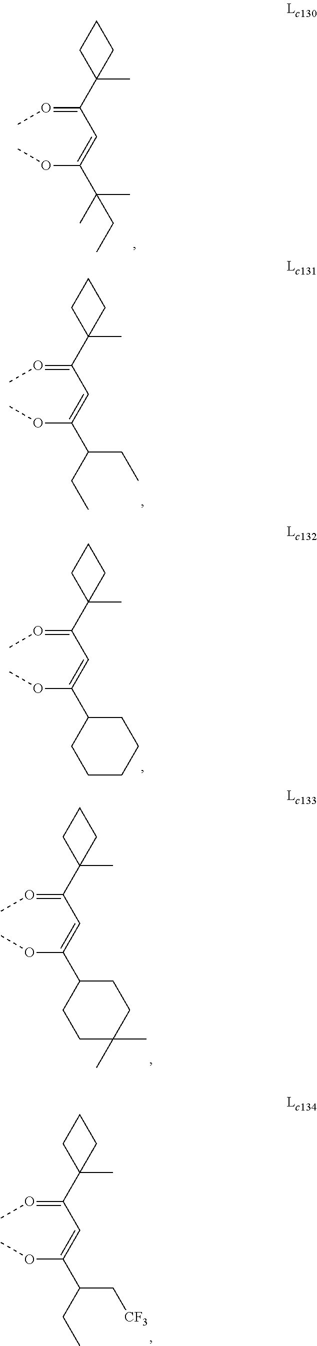

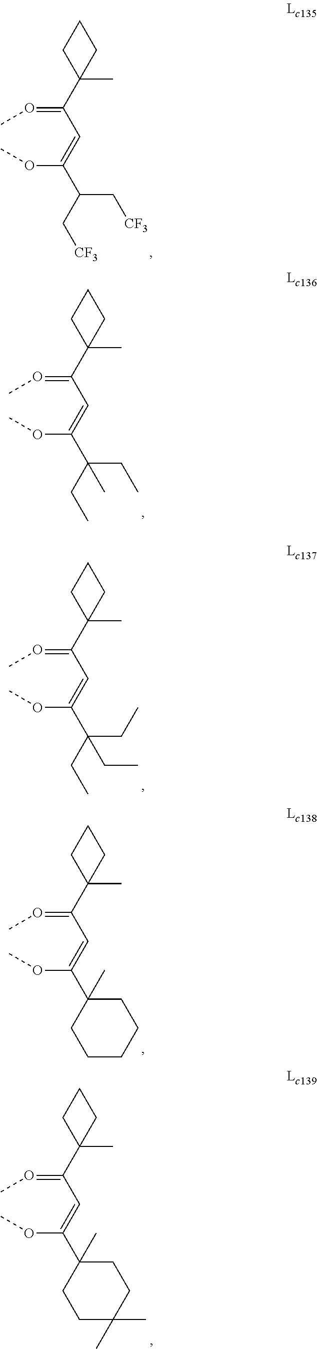

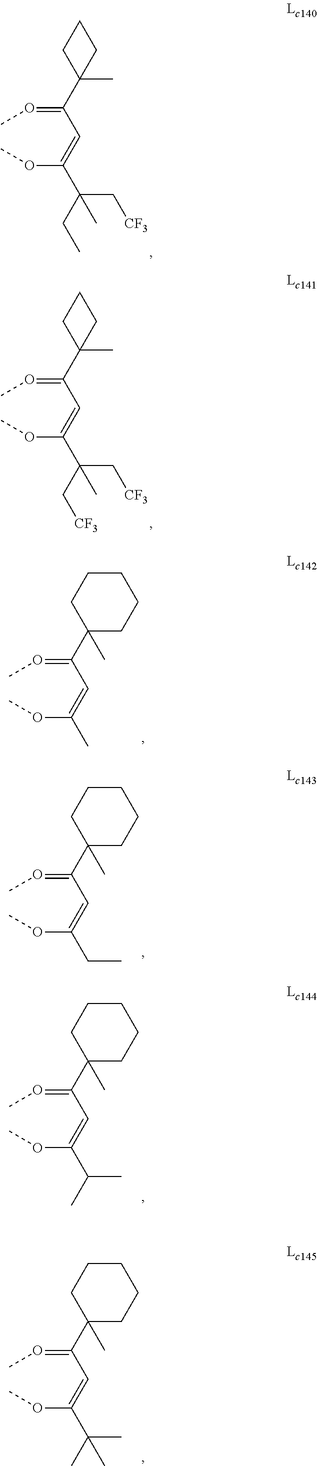

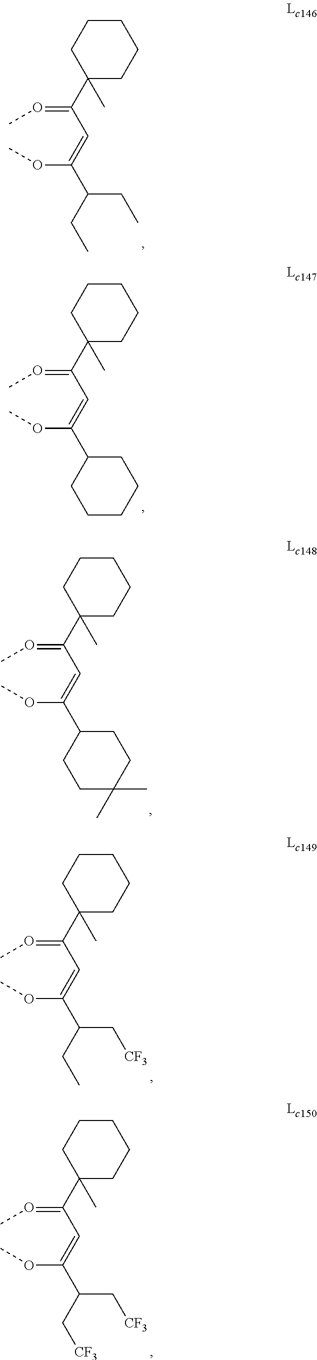

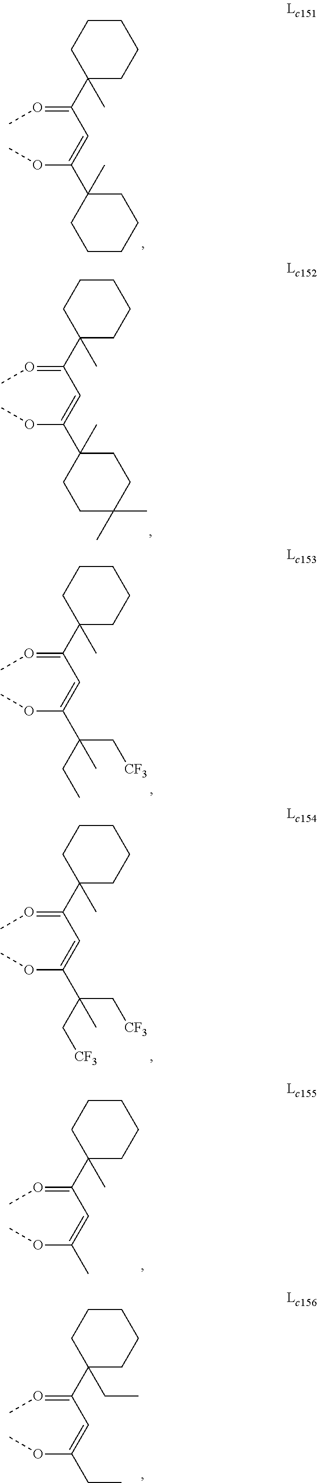

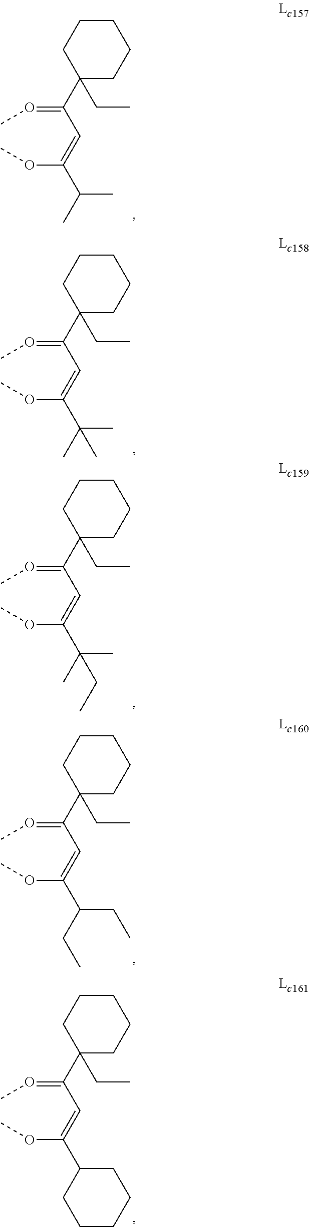

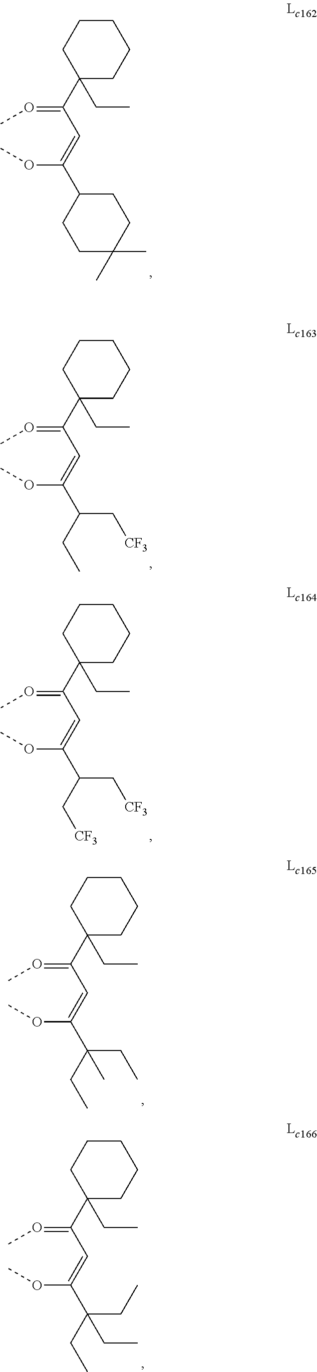

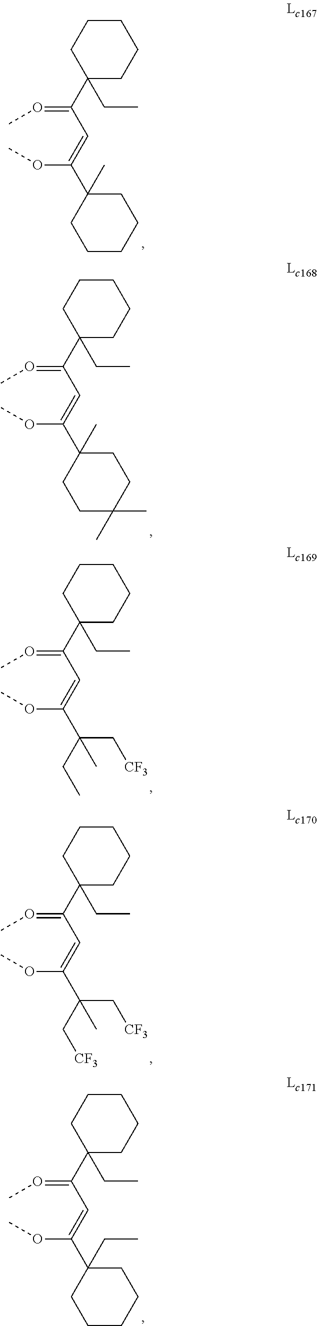

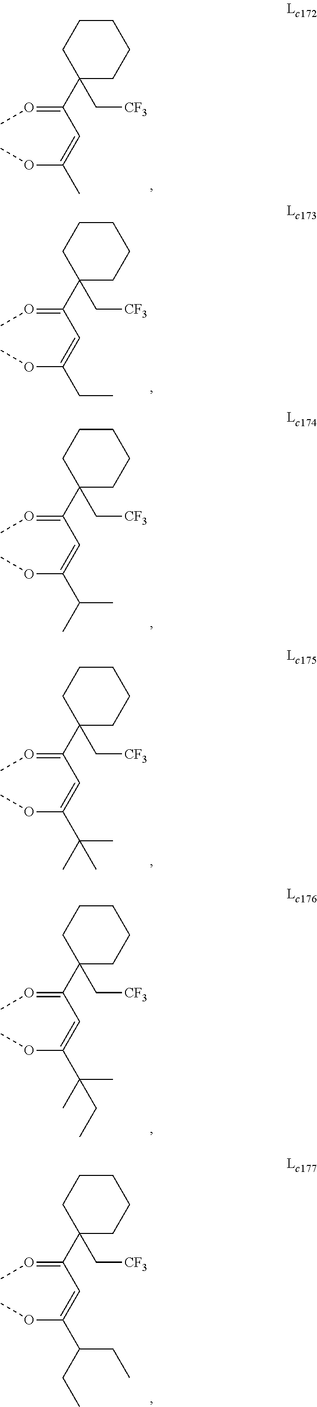

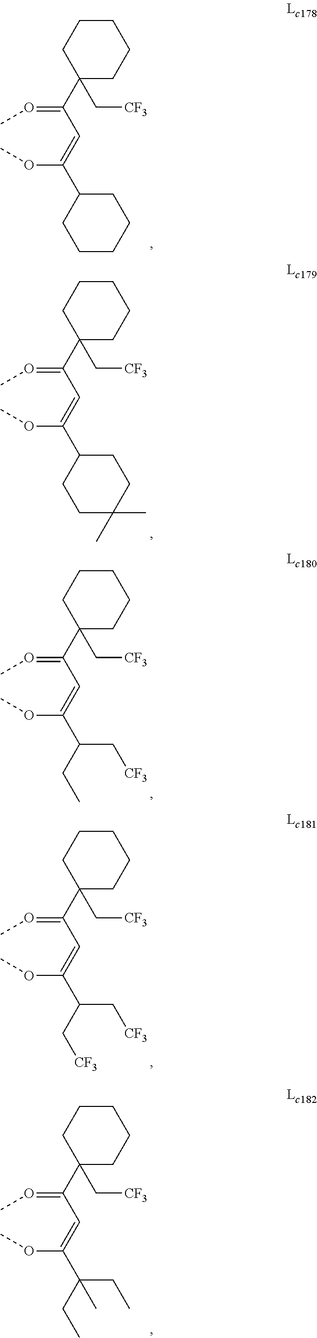

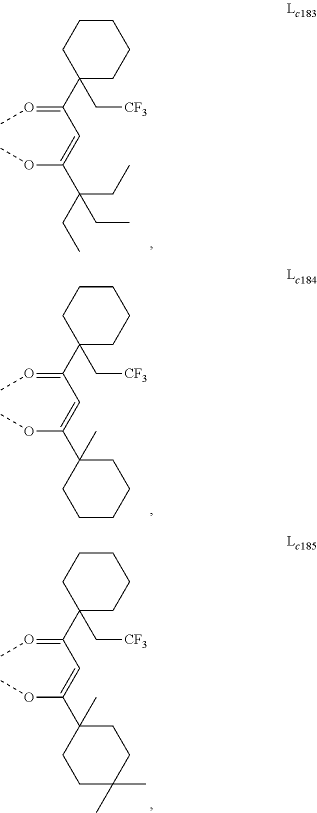

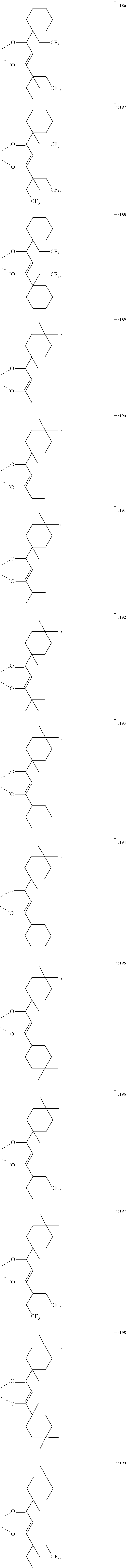

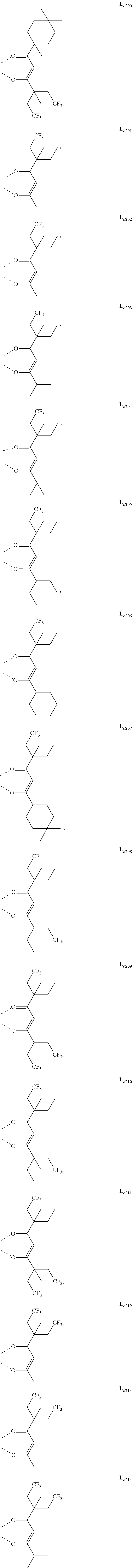

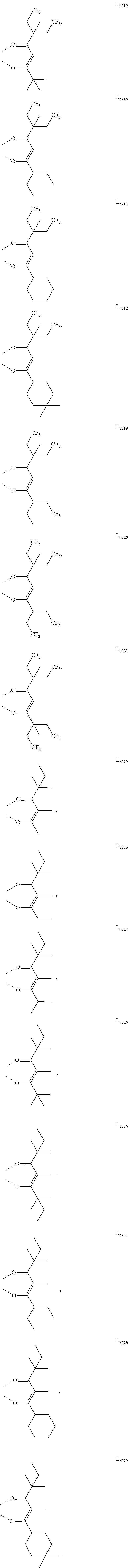

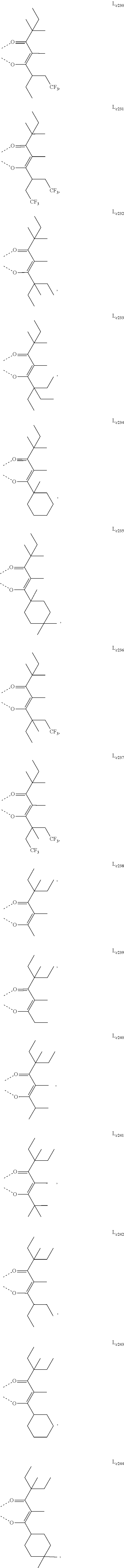

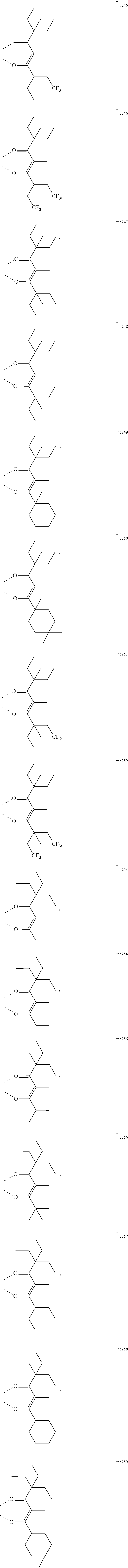

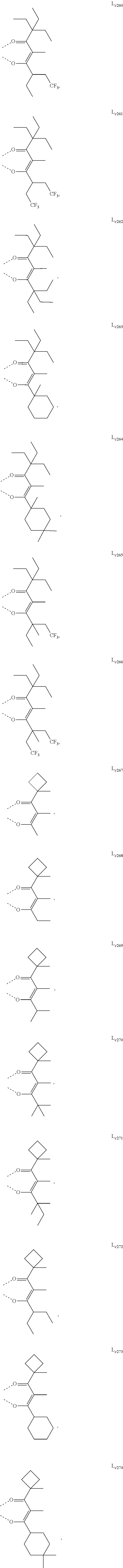

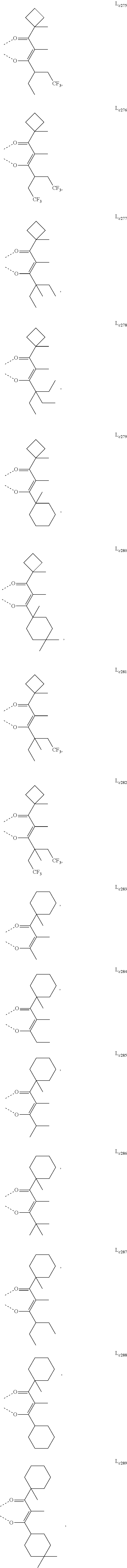

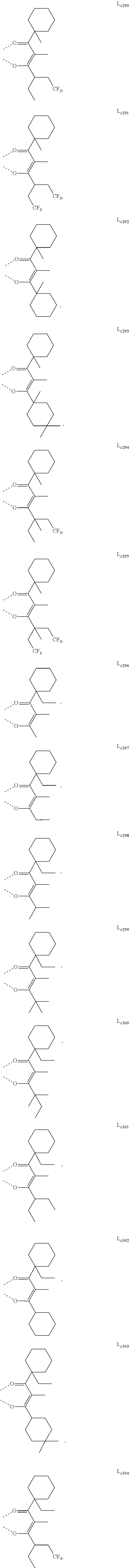

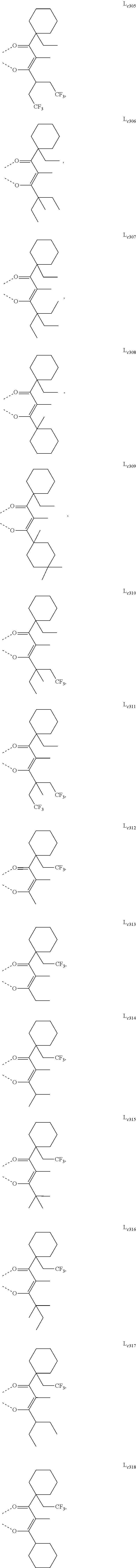

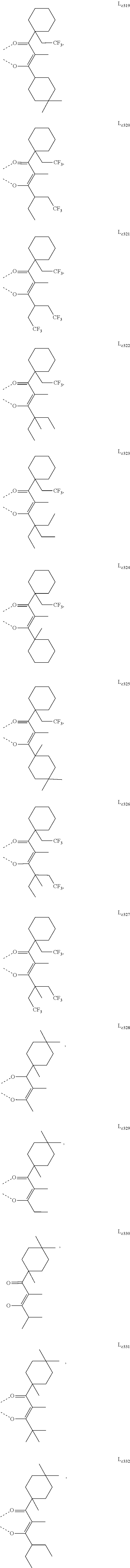

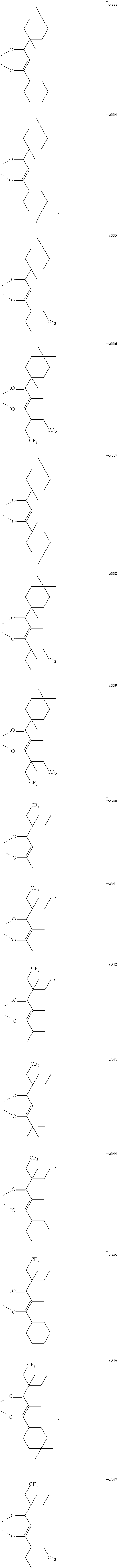

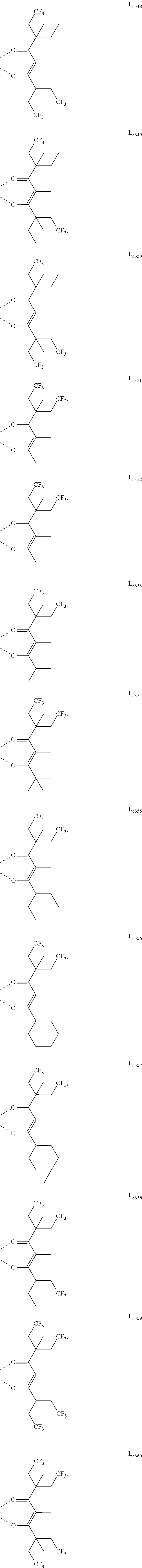

17. The metal complex of claim 1, wherein the metal complex has a structure of Ir(Lₐ)₂(L_{b}) or Ir(Lₐ)(L_{b})₂ or Ir(Lₐ)₃, wherein Lₐ is, at each occurrence identically or differently, selected from any one, any two or any three of the group consisting of Lₐ₁ to Lₐ₇₇₀, and L_{b} is selected from any one or any two of the group consisting of L_{b1} to L_{b329}; or
the metal complex has a structure of Ir(Lₐ)₂(L_{c}) or Ir(Lₐ)(L)₂, wherein Lₐ is, at each occurrence identically or differently, selected from any one or any two of the group consisting of Lₐ₁ to Lₐ₇₇₀, and L_{c} is selected from any one or any two of the group consisting of L_{c} to L_{c360}; or
the metal complex has a structure of Ir(Lₐ)(L_{b})(L_{c}), wherein Lₐ is, at each occurrence identically or differently, selected from any one of the group consisting of Lₐ₁ to Lₐ₇₇₀, L_{b} is selected from any one of the group consisting of L_{b1} to L_{b329}, and L_{c} is selected from any one of the group consisting of L_{c1} to L_{c360};
preferably, the metal complex is selected from the group consisting of Metal Complex 1 to Metal Complex 1578 which are described as follows:
Metal Complex 1 to Metal Complex 1488 each have a structure of Ir(Lₐ)(L_{b})₂, wherein the two L_{b} have the same structure or different structures, and Lₐ and the two L_{b} respectively correspond to the structures listed in the following table:

| Metal | | | | Metal | | | |
|---|---|---|---|---|---|---|---|
| Complex | Lₐ | L_{b} | L_{b} | Complex | Lₐ | L_{b} | L_{b} |
| 1 | Lₐ₁ | L_{b1} | L_{b1} | 2 | Lₐ₂ | L_{b1} | L_{b1} |
| 3 | Lₐ₃ | L_{b1} | L_{b1} | 4 | Lₐ₄ | L_{b1} | L_{b1} |
| 5 | Lₐ₅ | L_{b1} | L_{b1} | 6 | Lₐ₆ | L_{b1} | L_{b1} |
| 7 | Lₐ₇ | L_{b1} | L_{b1} | 8 | Lₐ₈ | L_{b1} | L_{b1} |
| 9 | Lₐ₉ | L_{b1} | L_{b1} | 10 | Lₐ₁₀ | L_{b1} | L_{b1} |
| 11 | Lₐ₁₁ | L_{b1} | L_{b1} | 12 | Lₐ₁₂ | L_{b1} | L_{b1} |
| 13 | Lₐ₁₃ | L_{b1} | L_{b1} | 14 | Lₐ₁₄ | L_{b1} | L_{b1} |
| 15 | Lₐ₁₅ | L_{b1} | L_{b1} | 16 | Lₐ₁₆ | L_{b1} | L_{b1} |
| 17 | Lₐ₁₇ | L_{b1} | L_{b1} | 18 | Lₐ₁₈ | L_{b1} | L_{b1} |
| 19 | Lₐ₁₉ | L_{b1} | L_{b1} | 20 | Lₐ₂₀ | L_{b1} | L_{b1} |
| 21 | Lₐ₂₁ | L_{b1} | L_{b1} | 22 | Lₐ₂₂ | L_{b1} | L_{b1} |
| 23 | Lₐ₂₃ | L_{b1} | L_{b1} | 24 | Lₐ₂₄ | L_{b1} | L_{b1} |
| 27 | Lₐ₂₇ | L_{b1} | L_{b1} | 28 | Lₐ₂₈ | L_{b1} | L_{b1} |
| 29 | Lₐ₂₉ | L_{b1} | L_{b1} | 30 | Lₐ₃₀ | L_{b1} | L_{b1} |
| 31 | Lₐ₃₁ | L_{b1} | L_{b1} | 32 | Lₐ₃₂ | L_{b1} | L_{b1} |
| 33 | Lₐ₃₃ | L_{b1} | L_{b1} | 34 | Lₐ₃₄ | L_{b1} | L_{b1} |
| 35 | Lₐ₃₅ | L_{b1} | L_{b1} | 36 | Lₐ₃₆ | L_{b1} | L_{b1} |
| 37 | Lₐ₃₇ | L_{b1} | L_{b1} | 38 | Lₐ₃₈ | L_{b1} | L_{b1} |
| 39 | Lₐ₃₉ | L_{b1} | L_{b1} | 40 | Lₐ₄₀ | L_{b1} | L_{b1} |
| 41 | Lₐ₄₁ | L_{b1} | L_{b1} | 42 | Lₐ₄₂ | L_{b1} | L_{b1} |
| 43 | Lₐ₄₃ | L_{b1} | L_{b1} | 44 | Lₐ₄₄ | L_{b1} | L_{b1} |
| 45 | Lₐ₄₅ | L_{b1} | L_{b1} | 46 | Lₐ₄₆ | L_{b1} | L_{b1} |
| 47 | Lₐ₄₇ | L_{b1} | L_{b1} | 48 | Lₐ₄₈ | L_{b1} | L_{b1} |
| 49 | Lₐ₄₉ | L_{b1} | L_{b1} | 50 | Lₐ₅₀ | L_{b1} | L_{b1} |
| 51 | Lₐ₅₁ | L_{b1} | L_{b1} | 52 | Lₐ₅₂ | L_{b1} | L_{b1} |
| 53 | Lₐ₅₃ | L_{b1} | L_{b1} | 54 | Lₐ₅₄ | L_{b1} | L_{b1} |
| 55 | Lₐ₅₅ | L_{b1} | L_{b1} | 56 | Lₐ₅₆ | L_{b1} | L_{b1} |
| 57 | Lₐ₅₇ | L_{b1} | L_{b1} | 58 | Lₐ₅₈ | L_{b1} | L_{b1} |
| 59 | Lₐ₅₉ | L_{b1} | L_{b1} | 60 | Lₐ₆₀ | L_{b1} | L_{b1} |
| 61 | Lₐ₆₁ | L_{b1} | L_{b1} | 62 | Lₐ₆₂ | L_{b1} | L_{b1} |
| 63 | Lₐ₆₃ | L_{b1} | L_{b1} | 64 | Lₐ₆₄ | L_{b1} | L_{b1} |
| 65 | Lₐ₆₅ | L_{b1} | L_{b1} | 66 | Lₐ₆₆ | L_{b1} | L_{b1} |
| 67 | Lₐ₆₇ | L_{b1} | L_{b1} | 68 | Lₐ₆₈ | L_{b1} | L_{b1} |
| 69 | Lₐ₆₉ | L_{b1} | L_{b1} | 70 | Lₐ₇₀ | L_{b1} | L_{b1} |
| 71 | Lₐ₇₁ | L_{b1} | L_{b1} | 72 | Lₐ₇₂ | L_{b1} | L_{b1} |
| 73 | Lₐ₇₃ | L_{b1} | L_{b1} | 74 | Lₐ₇₄ | L_{b1} | L_{b1} |
| 75 | Lₐ₇₅ | L_{b1} | L_{b1} | 76 | Lₐ₇₆ | L_{b1} | L_{b1} |
| 77 | Lₐ₇₇ | L_{b1} | L_{b1} | 78 | Lₐ₇₈ | L_{b1} | L_{b1} |
| 79 | Lₐ₇₉ | L_{b1} | L_{b1} | 80 | Lₐ₈₀ | L_{b1} | L_{b1} |
| 81 | Lₐ₈₁ | L_{b1} | L_{b1} | 82 | Lₐ₈₂ | L_{b1} | L_{b1} |
| 83 | Lₐ₈₃ | L_{b1} | L_{b1} | 84 | Lₐ₈₄ | L_{b1} | L_{b1} |
| 85 | Lₐ₈₅ | L_{b1} | L_{b1} | 86 | Lₐ₈₆ | L_{b1} | L_{b1} |
| 87 | Lₐ₈₇ | L_{b1} | L_{b1} | 88 | Lₐ₈₈ | L_{b1} | L_{b1} |
| 89 | Lₐ₈₉ | L_{b1} | L_{b1} | 90 | Lₐ₉₀ | L_{b1} | L_{b1} |
| 91 | Lₐ₉₁ | L_{b1} | L_{b1} | 92 | Lₐ₉₂ | L_{b1} | L_{b1} |
| 93 | Lₐ₉₃ | L_{b1} | L_{b1} | 94 | Lₐ₉₄ | L_{b1} | L_{b1} |
| 95 | Lₐ₉₅ | L_{b1} | L_{b1} | 96 | Lₐ₉₆ | L_{b1} | L_{b1} |
| 97 | Lₐ₉₇ | L_{b1} | L_{b1} | 98 | Lₐ₉₈ | L_{b1} | L_{b1} |
| 99 | Lₐ₉₉ | L_{b1} | L_{b1} | 100 | Lₐ₁₀₀ | L_{b1} | L_{b1} |
| 101 | Lₐ₁₀₁ | L_{b1} | L_{b1} | 102 | Lₐ₁₀₂ | L_{b1} | L_{b1} |
| 103 | Lₐ₁₀₃ | L_{b1} | L_{b1} | 104 | Lₐ₁₀₄ | L_{b1} | L_{b1} |
| 105 | Lₐ₁₀₅ | L_{b1} | L_{b1} | 106 | Lₐ₁₀₆ | L_{b1} | L_{b1} |
| 107 | Lₐ₁₀₇ | L_{b1} | L_{b1} | 108 | Lₐ₁₀₈ | L_{b1} | L_{b1} |
| 109 | Lₐ₁₀₉ | L_{b1} | L_{b1} | 110 | Lₐ₁₁₀ | L_{b1} | L_{b1} |
| 111 | Lₐ₁₁₁ | L_{b1} | L_{b1} | 112 | Lₐ₁₁₂ | L_{b1} | L_{b1} |
| 113 | Lₐ₁₁₃ | L_{b1} | L_{b1} | 114 | Lₐ₁₁₄ | L_{b1} | L_{b1} |
| 115 | Lₐ₁₁₅ | L_{b1} | L_{b1} | 116 | Lₐ₁₁₆ | L_{b1} | L_{b1} |
| 117 | Lₐ₁₁₇ | L_{b1} | L_{b1} | 118 | Lₐ₁₁₈ | L_{b1} | L_{b1} |
| 119 | Lₐ₁₁₉ | L_{b1} | L_{b1} | 120 | Lₐ₁₂₀ | L_{b1} | L_{b1} |
| 121 | Lₐ₁₂₁ | L_{b1} | L_{b1} | 122 | Lₐ₁₂₂ | L_{b1} | L_{b1} |
| 123 | Lₐ₁₂₃ | L_{b1} | L_{b1} | 124 | Lₐ₁₂₄ | L_{b1} | L_{b1} |
| 125 | Lₐ₁₂₅ | L_{b1} | L_{b1} | 126 | Lₐ₁₂₆ | L_{b1} | L_{b1} |
| 127 | Lₐ₁₂₇ | L_{b1} | L_{b1} | 128 | Lₐ₁₂₈ | L_{b1} | L_{b1} |
| 129 | Lₐ₁₂₉ | L_{b1} | L_{b1} | 130 | Lₐ₁₃₀ | L_{b1} | L_{b1} |
| 131 | Lₐ₁₃₁ | L_{b1} | L_{b1} | 132 | Lₐ₁₃₂ | L_{b1} | L_{b1} |
| 133 | Lₐ₁₃₃ | L_{b1} | L_{b1} | 134 | Lₐ₁₃₄ | L_{b1} | L_{b1} |
| 135 | Lₐ₁₃₅ | L_{b1} | L_{b1} | 136 | Lₐ₁₃₆ | L_{b1} | L_{b1} |
| 137 | Lₐ₁₃₇ | L_{b1} | L_{b1} | 138 | Lₐ₁₃₈ | L_{b1} | L_{b1} |
| 139 | Lₐ₁₃₉ | L_{b1} | L_{b1} | 140 | Lₐ₁₄₀ | L_{b1} | L_{b1} |
| 141 | Lₐ₁₄₁ | L_{b1} | L_{b1} | 142 | Lₐ₁₄₂ | L_{b1} | L_{b1} |
| 143 | Lₐ₁₄₃ | L_{b1} | L_{b1} | 144 | Lₐ₁₄₄ | L_{b1} | L_{b1} |
| 145 | Lₐ₁₄₅ | L_{b1} | L_{b1} | 146 | Lₐ₁₄₆ | L_{b1} | L_{b1} |
| 147 | Lₐ₁₄₇ | L_{b1} | L_{b1} | 148 | Lₐ₁₄₈ | L_{b1} | L_{b1} |
| 149 | Lₐ₁₄₉ | L_{b1} | L_{b1} | 150 | Lₐ₁₅₀ | L_{b1} | L_{b1} |
| 151 | Lₐ₁₅₁ | L_{b1} | L_{b1} | 152 | Lₐ₁₅₂ | L_{b1} | L_{b1} |
| 153 | Lₐ₁₅₃ | L_{b1} | L_{b1} | 154 | Lₐ₁₅₄ | L_{b1} | L_{b1} |
| 155 | Lₐ₁₅₅ | L_{b1} | L_{b1} | 156 | Lₐ₁₅₆ | L_{b1} | L_{b1} |
| 157 | Lₐ₁₅₇ | L_{b1} | L_{b1} | 158 | Lₐ₁₅₈ | L_{b1} | L_{b1} |
| 159 | Lₐ₁₅₉ | L_{b1} | L_{b1} | 160 | Lₐ₁₆₀ | L_{b1} | L_{b1} |
| 161 | Lₐ₁₆₁ | L_{b1} | L_{b1} | 162 | Lₐ₁₆₂ | L_{b1} | L_{b1} |
| 163 | Lₐ₁₆₃ | L_{b1} | L_{b1} | 164 | Lₐ₁₆₄ | L_{b1} | L_{b1} |
| 165 | Lₐ₁₆₅ | L_{b1} | L_{b1} | 166 | Lₐ₁₆₆ | L_{b1} | L_{b1} |
| 167 | Lₐ₁₆₇ | L_{b1} | L_{b1} | 168 | Lₐ₁₆₈ | L_{b1} | L_{b1} |
| 169 | Lₐ₁₆₉ | L_{b1} | L_{b1} | 170 | Lₐ₁₇₀ | L_{b1} | L_{b1} |
| 171 | Lₐ₁₇₁ | L_{b1} | L_{b1} | 172 | Lₐ₁₇₂ | L_{b1} | L_{b1} |
| 173 | Lₐ₁₇₃ | L_{b1} | L_{b1} | 174 | Lₐ₁₇₄ | L_{b1} | L_{b1} |
| 175 | Lₐ₁₇₅ | L_{b1} | L_{b1} | 176 | Lₐ₁₇₆ | L_{b1} | L_{b1} |
| 177 | Lₐ₁₇₇ | L_{b1} | L_{b1} | 178 | Lₐ₁₇₈ | L_{b1} | L_{b1} |
| 179 | Lₐ₁₇₉ | L_{b1} | L_{b1} | 180 | Lₐ₁₈₀ | L_{b1} | L_{b1} |
| 181 | Lₐ₁₈₁ | L_{b1} | L_{b1} | 182 | Lₐ₁₈₂ | L_{b1} | L_{b1} |
| 183 | Lₐ₁₈₃ | L_{b1} | L_{b1} | 184 | Lₐ₁₈₄ | L_{b1} | L_{b1} |
| 185 | Lₐ₁₈₅ | L_{b1} | L_{b1} | 186 | Lₐ₁₈₆ | L_{b1} | L_{b1} |
| 187 | Lₐ₁₈₇ | L_{b1} | L_{b1} | 188 | Lₐ₁₈₈ | L_{b1} | L_{b1} |
| 189 | Lₐ₁₈₉ | L_{b1} | L_{b1} | 190 | Lₐ₁₉₀ | L_{b1} | L_{b1} |
| 191 | Lₐ₁₉₁ | L_{b1} | L_{b1} | 192 | Lₐ₁₉₂ | L_{b1} | L_{b1} |
| 193 | Lₐ₁₉₃ | L_{b1} | L_{b1} | 194 | Lₐ₁₉₄ | L_{b1} | L_{b1} |
| 195 | Lₐ₁₉₅ | L_{b1} | L_{b1} | 196 | Lₐ₁₉₆ | L_{b1} | L_{b1} |
| 197 | Lₐ₁₉₇ | L_{b1} | L_{b1} | 198 | Lₐ₁₉₈ | L_{b1} | L_{b1} |
| 199 | Lₐ₁₉₉ | L_{b1} | L_{b1} | 200 | Lₐ₂₀₀ | L_{b1} | L_{b1} |
| 201 | Lₐ₂₀₁ | L_{b1} | L_{b1} | 202 | Lₐ₂₀₂ | L_{b1} | L_{b1} |
| 203 | Lₐ₂₀₃ | L_{b1} | L_{b1} | 204 | Lₐ₂₀₄ | L_{b1} | L_{b1} |
| 205 | Lₐ₂₀₅ | L_{b1} | L_{b1} | 206 | Lₐ₂₀₆ | L_{b1} | L_{b1} |
| 207 | Lₐ₂₀₇ | L_{b1} | L_{b1} | 208 | Lₐ₂₀₈ | L_{b1} | L_{b1} |
| 209 | Lₐ₂₀₉ | L_{b1} | L_{b1} | 210 | Lₐ₂₁₀ | L_{b1} | L_{b1} |
| 211 | Lₐ₂₁₁ | L_{b1} | L_{b1} | 212 | Lₐ₂₁₂ | L_{b1} | L_{b1} |
| 213 | Lₐ₂₁₃ | L_{b1} | L_{b1} | 214 | Lₐ₂₁₄ | L_{b1} | L_{b1} |
| 225 | Lₐ₂₁₅ | L_{b1} | L_{b1} | 226 | Lₐ₂₁₆ | L_{b1} | L_{b1} |
| 227 | Lₐ₂₁₇ | L_{b1} | L_{b1} | 228 | Lₐ₂₁₈ | L_{b1} | L_{b1} |
| 229 | Lₐ₂₁₉ | L_{b1} | L_{b1} | 230 | Lₐ₂₂₀ | L_{b1} | L_{b1} |
| 231 | Lₐ₂₂₁ | L_{b1} | L_{b1} | 232 | Lₐ₂₂₂ | L_{b1} | L_{b1} |
| 233 | Lₐ₂₂₃ | L_{b1} | L_{b1} | 234 | Lₐ₂₂₄ | L_{b1} | L_{b1} |
| 235 | Lₐ₂₂₅ | L_{b1} | L_{b1} | 236 | Lₐ₂₂₆ | L_{b1} | L_{b1} |
| 237 | Lₐ₂₂₇ | L_{b1} | L_{b1} | 238 | Lₐ₂₂₈ | L_{b1} | L_{b1} |
| 239 | Lₐ₂₂₉ | L_{b1} | L_{b1} | 240 | Lₐ₂₃₀ | L_{b1} | L_{b1} |
| 241 | Lₐ₂₃₁ | L_{b1} | L_{b1} | 242 | Lₐ₂₃₂ | L_{b1} | L_{b1} |
| 243 | Lₐ₂₃₃ | L_{b1} | L_{b1} | 244 | Lₐ₂₃₄ | L_{b1} | L_{b1} |
| 245 | Lₐ₂₃₅ | L_{b1} | L_{b1} | 246 | Lₐ₂₃₆ | L_{b1} | L_{b1} |
| 247 | Lₐ₂₃₇ | L_{b1} | L_{b1} | 248 | Lₐ₂₃₈ | L_{b1} | L_{b1} |
| 249 | Lₐ₂₃₉ | L_{b1} | L_{b1} | 250 | Lₐ₂₄₀ | L_{b1} | L_{b1} |
| 251 | Lₐ₂₄₁ | L_{b1} | L_{b1} | 252 | Lₐ₂₄₂ | L_{b1} | L_{b1} |
| 253 | Lₐ₂₄₃ | L_{b1} | L_{b1} | 254 | Lₐ₂₄₄ | L_{b1} | L_{b1} |
| 255 | Lₐ₂₄₅ | L_{b1} | L_{b1} | 256 | Lₐ₂₄₆ | L_{b1} | L_{b1} |
| 257 | Lₐ₂₄₇ | L_{b1} | L_{b1} | 258 | Lₐ₂₄₈ | L_{b1} | L_{b1} |
| 259 | Lₐ₂₄₉ | L_{b1} | L_{b1} | 260 | Lₐ₂₅₀ | L_{b1} | L_{b1} |
| 261 | Lₐ₂₅₁ | L_{b1} | L_{b1} | 262 | Lₐ₂₅₂ | L_{b1} | L_{b1} |
| 263 | Lₐ₂₅₃ | L_{b1} | L_{b1} | 264 | Lₐ₂₅₄ | L_{b1} | L_{b1} |
| 265 | Lₐ₂₅₅ | L_{b1} | L_{b1} | 266 | Lₐ₂₅₆ | L_{b1} | L_{b1} |
| 267 | Lₐ₂₅₇ | L_{b1} | L_{b1} | 268 | Lₐ₂₅₈ | L_{b1} | L_{b1} |
| 269 | Lₐ₂₅₉ | L_{b1} | L_{b1} | 270 | Lₐ₂₆₀ | L_{b1} | L_{b1} |
| 271 | Lₐ₂₆₁ | L_{b1} | L_{b1} | 272 | Lₐ₂₆₂ | L_{b1} | L_{b1} |
| 273 | Lₐ₂₆₃ | L_{b1} | L_{b1} | 274 | Lₐ₂₆₄ | L_{b1} | L_{b1} |
| 275 | Lₐ₂₆₅ | L_{b1} | L_{b1} | 276 | Lₐ₂₆₆ | L_{b1} | L_{b1} |
| 277 | Lₐ₂₆₇ | L_{b1} | L_{b1} | 278 | Lₐ₂₆₈ | L_{b1} | L_{b1} |
| 279 | Lₐ₂₆₉ | L_{b1} | L_{b1} | 280 | Lₐ₂₇₀ | L_{b1} | L_{b1} |
| 281 | Lₐ₂₇₁ | L_{b1} | L_{b1} | 282 | Lₐ₂₇₂ | L_{b1} | L_{b1} |
| 283 | Lₐ₂₇₃ | L_{b1} | L_{b1} | 284 | Lₐ₂₇₄ | L_{b1} | L_{b1} |
| 285 | Lₐ₂₇₅ | L_{b1} | L_{b1} | 286 | Lₐ₂₇₆ | L_{b1} | L_{b1} |
| 287 | Lₐ₂₇₇ | L_{b1} | L_{b1} | 288 | Lₐ₂₇₈ | L_{b1} | L_{b1} |
| 289 | Lₐ₂₇₉ | L_{b1} | L_{b1} | 290 | Lₐ₂₈₀ | L_{b1} | L_{b1} |
| 291 | Lₐ₂₈₁ | L_{b1} | L_{b1} | 292 | Lₐ₂₈₂ | L_{b1} | L_{b1} |
| 293 | Lₐ₂₈₃ | L_{b1} | L_{b1} | 294 | Lₐ₂₈₄ | L_{b1} | L_{b1} |
| 295 | Lₐ₂₈₅ | L_{b1} | L_{b1} | 296 | Lₐ₂₈₆ | L_{b1} | L_{b1} |
| 297 | Lₐ₂₈₇ | L_{b1} | L_{b1} | 298 | Lₐ₂₈₈ | L_{b1} | L_{b1} |
| 299 | Lₐ₂₈₉ | L_{b1} | L_{b1} | 300 | Lₐ₂₉₀ | L_{b1} | L_{b1} |
| 301 | Lₐ₂₉₁ | L_{b1} | L_{b1} | 302 | Lₐ₂₉₂ | L_{b1} | L_{b1} |
| 303 | Lₐ₂₉₃ | L_{b1} | L_{b1} | 304 | Lₐ₂₉₄ | L_{b1} | L_{b1} |
| 305 | Lₐ₂₉₅ | L_{b1} | L_{b1} | 306 | Lₐ₂₉₆ | L_{b1} | L_{b1} |
| 307 | Lₐ₂₉₇ | L_{b1} | L_{b1} | 308 | Lₐ₂₉₈ | L_{b1} | L_{b1} |
| 309 | Lₐ₂₉₉ | L_{b1} | L_{b1} | 310 | Lₐ₃₀₀ | L_{b1} | L_{b1} |
| 311 | Lₐ₃₀₁ | L_{b1} | L_{b1} | 312 | Lₐ₃₀₂ | L_{b1} | L_{b1} |
| 313 | Lₐ₃₀₃ | L_{b1} | L_{b1} | 314 | Lₐ₃₀₄ | L_{b1} | L_{b1} |
| 315 | Lₐ₃₀₅ | L_{b1} | L_{b1} | 316 | Lₐ₃₀₆ | L_{b1} | L_{b1} |
| 317 | Lₐ₃₀₇ | L_{b1} | L_{b1} | 318 | Lₐ₃₀₈ | L_{b1} | L_{b1} |
| 319 | Lₐ₃₀₉ | L_{b1} | L_{b1} | 320 | Lₐ₃₁₀ | L_{b1} | L_{b1} |
| 321 | Lₐ₃₁₁ | L_{b1} | L_{b1} | 322 | Lₐ₃₁₂ | L_{b1} | L_{b1} |
| 323 | Lₐ₃₁₃ | L_{b1} | L_{b1} | 324 | Lₐ₃₁₄ | L_{b1} | L_{b1} |
| 325 | Lₐ₃₁₅ | L_{b1} | L_{b1} | 326 | Lₐ₃₁₆ | L_{b1} | L_{b1} |
| 327 | Lₐ₃₁₇ | L_{b1} | L_{b1} | 328 | Lₐ₃₁₈ | L_{b1} | L_{b1} |
| 329 | Lₐ₃₁₉ | L_{b1} | L_{b1} | 330 | Lₐ₃₂₀ | L_{b1} | L_{b1} |
| 331 | Lₐ₃₂₁ | L_{b1} | L_{b1} | 332 | Lₐ₃₂₂ | L_{b1} | L_{b1} |
| 333 | Lₐ₃₂₃ | L_{b1} | L_{b1} | 334 | Lₐ₃₂₄ | L_{b1} | L_{b1} |
| 335 | Lₐ₃₂₅ | L_{b1} | L_{b1} | 336 | Lₐ₃₂₆ | L_{b1} | L_{b1} |
| 337 | Lₐ₃₂₇ | L_{b1} | L_{b1} | 338 | Lₐ₃₂₈ | L_{b1} | L_{b1} |
| 339 | Lₐ₃₂₉ | L_{b1} | L_{b1} | 340 | Lₐ₃₃₀ | L_{b1} | L_{b1} |
| 341 | Lₐ₃₃₁ | L_{b1} | L_{b1} | 342 | Lₐ₃₃₂ | L_{b1} | L_{b1} |
| 343 | Lₐ₃₃₃ | L_{b1} | L_{b1} | 344 | Lₐ₃₃₄ | L_{b1} | L_{b1} |
| 345 | Lₐ₃₃₅ | L_{b1} | L_{b1} | 346 | Lₐ₃₃₆ | L_{b1} | L_{b1} |
| 347 | Lₐ₃₃₇ | L_{b1} | L_{b1} | 348 | Lₐ₃₃₈ | L_{b1} | L_{b1} |
| 349 | Lₐ₃₃₉ | L_{b1} | L_{b1} | 350 | Lₐ₃₄₀ | L_{b1} | L_{b1} |
| 351 | Lₐ₃₄₁ | L_{b1} | L_{b1} | 352 | Lₐ₃₄₂ | L_{b1} | L_{b1} |
| 353 | Lₐ₃₄₃ | L_{b1} | L_{b1} | 354 | Lₐ₃₄₄ | L_{b1} | L_{b1} |
| 355 | Lₐ₃₄₅ | L_{b1} | L_{b1} | 356 | Lₐ₃₄₆ | L_{b1} | L_{b1} |
| 357 | Lₐ₃₄₇ | L_{b1} | L_{b1} | 358 | Lₐ₃₄₈ | L_{b1} | L_{b1} |
| 359 | Lₐ₃₄₉ | L_{b1} | L_{b1} | 360 | Lₐ₃₅₀ | L_{b1} | L_{b1} |
| 361 | Lₐ₃₅₁ | L_{b1} | L_{b1} | 362 | Lₐ₃₅₂ | L_{b1} | L_{b1} |
| 363 | Lₐ₃₅₃ | L_{b1} | L_{b1} | 364 | Lₐ₃₅₄ | L_{b1} | L_{b1} |
| 365 | Lₐ₃₅₅ | L_{b1} | L_{b1} | 366 | Lₐ₃₅₆ | L_{b1} | L_{b1} |
| 367 | Lₐ₃₅₇ | L_{b1} | L_{b1} | 368 | Lₐ₃₅₈ | L_{b1} | L_{b1} |
| 369 | Lₐ₃₅₉ | L_{b1} | L_{b1} | 370 | Lₐ₃₆₀ | L_{b1} | L_{b1} |
| 371 | Lₐ₃₆₁ | L_{b1} | L_{b1} | 372 | Lₐ₃₆₂ | L_{b1} | L_{b1} |
| 373 | Lₐ₃₆₃ | L_{b1} | L_{b1} | 374 | Lₐ₃₆₄ | L_{b1} | L_{b1} |
| 375 | Lₐ₃₆₅ | L_{b1} | L_{b1} | 376 | Lₐ₃₆₆ | L_{b1} | L_{b1} |
| 377 | Lₐ₃₆₇ | L_{b1} | L_{b1} | 378 | Lₐ₃₆₈ | L_{b1} | L_{b1} |
| 379 | Lₐ₃₆₉ | L_{b1} | L_{b1} | 380 | Lₐ₃₇₀ | L_{b1} | L_{b1} |
| 381 | Lₐ₃₇₁ | L_{b1} | L_{b1} | 382 | Lₐ₃₇₂ | L_{b1} | L_{b1} |
| 383 | Lₐ₃₇₃ | L_{b1} | L_{b1} | 384 | Lₐ₃₇₄ | L_{b1} | L_{b1} |
| 385 | Lₐ₃₇₅ | L_{b1} | L_{b1} | 386 | Lₐ₃₇₆ | L_{b1} | L_{b1} |
| 387 | Lₐ₃₇₇ | L_{b1} | L_{b1} | 388 | Lₐ₃₇₈ | L_{b1} | L_{b1} |
| 389 | Lₐ₃₇₉ | L_{b1} | L_{b1} | 390 | Lₐ₃₈₀ | L_{b1} | L_{b1} |
| 391 | Lₐ₃₈₁ | L_{b1} | L_{b1} | 392 | Lₐ₃₈₂ | L_{b1} | L_{b1} |
| 393 | Lₐ₃₈₃ | L_{b1} | L_{b1} | 394 | Lₐ₃₈₄ | L_{b1} | L_{b1} |
| 395 | Lₐ₃₈₅ | L_{b1} | L_{b1} | 396 | Lₐ₃₈₆ | L_{b1} | L_{b1} |
| 397 | Lₐ₃₈₇ | L_{b1} | L_{b1} | 398 | Lₐ₃₈₈ | L_{b1} | L_{b1} |
| 399 | Lₐ₃₈₉ | L_{b1} | L_{b1} | 400 | Lₐ₃₉₀ | L_{b1} | L_{b1} |
| 401 | Lₐ₃₉₁ | L_{b1} | L_{b1} | 402 | Lₐ₃₉₂ | L_{b1} | L_{b1} |
| 403 | Lₐ₃₉₃ | L_{b1} | L_{b1} | 404 | Lₐ₃₉₄ | L_{b1} | L_{b1} |
| 405 | Lₐ₃₉₅ | L_{b1} | L_{b1} | 406 | Lₐ₃₉₆ | L_{b1} | L_{b1} |
| 407 | Lₐ₃₉₇ | L_{b1} | L_{b1} | 408 | Lₐ₃₉₈ | L_{b1} | L_{b1} |
| 409 | Lₐ₃₉₉ | L_{b1} | L_{b1} | 410 | Lₐ₄₀₀ | L_{b1} | L_{b1} |
| 411 | Lₐ₄₀₁ | L_{b1} | L_{b1} | 412 | Lₐ₄₀₂ | L_{b1} | L_{b1} |
| 413 | Lₐ₄₀₃ | L_{b1} | L_{b1} | 414 | Lₐ₄₀₄ | L_{b1} | L_{b1} |
| 415 | Lₐ₄₀₅ | L_{b1} | L_{b1} | 416 | Lₐ₄₀₆ | L_{b1} | L_{b1} |
| 417 | Lₐ₄₀₇ | L_{b1} | L_{b1} | 418 | Lₐ₄₀₈ | L_{b1} | L_{b1} |
| 419 | Lₐ₄₀₉ | L_{b1} | L_{b1} | 420 | Lₐ₄₁₀ | L_{b1} | L_{b1} |
| 421 | Lₐ₄₁₁ | L_{b1} | L_{b1} | 422 | Lₐ₄₁₂ | L_{b1} | L_{b1} |
| 423 | Lₐ₄₁₃ | L_{b1} | L_{b1} | 424 | Lₐ₄₁₄ | L_{b1} | L_{b1} |
| 425 | Lₐ₄₁₅ | L_{b1} | L_{b1} | 426 | Lₐ₄₁₆ | L_{b1} | L_{b1} |
| 427 | Lₐ₄₁₇ | L_{b1} | L_{b1} | 428 | Lₐ₄₁₈ | L_{b1} | L_{b1} |
| 429 | Lₐ₄₁₉ | L_{b1} | L_{b1} | 430 | Lₐ₄₂₀ | L_{b1} | L_{b1} |
| 431 | Lₐ₄₂₁ | L_{b1} | L_{b1} | 432 | Lₐ₄₂₂ | L_{b1} | L_{b1} |
| 433 | Lₐ₄₂₃ | L_{b1} | L_{b1} | 434 | Lₐ₄₂₄ | L_{b1} | L_{b1} |
| 435 | Lₐ₄₂₅ | L_{b1} | L_{b1} | 436 | Lₐ₄₂₆ | L_{b1} | L_{b1} |
| 437 | Lₐ₄₂₇ | L_{b1} | L_{b1} | 438 | Lₐ₄₂₈ | L_{b1} | L_{b1} |
| 439 | Lₐ₄₂₉ | L_{b1} | L_{b1} | 440 | Lₐ₄₃₀ | L_{b1} | L_{b1} |
| 441 | Lₐ₄₃₁ | L_{b1} | L_{b1} | 442 | Lₐ₄₃₂ | L_{b1} | L_{b1} |
| 443 | Lₐ₄₃₃ | L_{b1} | L_{b1} | 444 | Lₐ₄₃₄ | L_{b1} | L_{b1} |
| 445 | Lₐ₄₃₅ | L_{b1} | L_{b1} | 446 | Lₐ₄₃₆ | L_{b1} | L_{b1} |
| 447 | Lₐ₄₃₇ | L_{b1} | L_{b1} | 448 | Lₐ₄₃₈ | L_{b1} | L_{b1} |
| 449 | Lₐ₄₃₉ | L_{b1} | L_{b1} | 450 | Lₐ₄₄₀ | L_{b1} | L_{b1} |
| 451 | Lₐ₄₄₁ | L_{b1} | L_{b1} | 452 | Lₐ₄₄₂ | L_{b1} | L_{b1} |
| 453 | Lₐ₄₄₃ | L_{b1} | L_{b1} | 454 | Lₐ₄₄₄ | L_{b1} | L_{b1} |
| 455 | Lₐ₄₄₅ | L_{b1} | L_{b1} | 456 | Lₐ₄₄₆ | L_{b1} | L_{b1} |
| 457 | Lₐ₄₄₇ | L_{b1} | L_{b1} | 458 | Lₐ₄₄₈ | L_{b1} | L_{b1} |
| 459 | Lₐ₄₄₉ | L_{b1} | L_{b1} | 460 | Lₐ₄₅₀ | L_{b1} | L_{b1} |
| 461 | Lₐ₄₅₁ | L_{b1} | L_{b1} | 462 | Lₐ₄₅₂ | L_{b1} | L_{b1} |
| 463 | Lₐ₄₅₃ | L_{b1} | L_{b1} | 464 | Lₐ₄₅₄ | L_{b1} | L_{b1} |
| 465 | Lₐ₄₅₅ | L_{b1} | L_{b1} | 466 | Lₐ₄₅₆ | L_{b1} | L_{b1} |
| 467 | Lₐ₄₅₇ | L_{b1} | L_{b1} | 468 | Lₐ₄₅₈ | L_{b1} | L_{b1} |
| 469 | Lₐ₄₅₉ | L_{b1} | L_{b1} | 470 | Lₐ₄₆₀ | L_{b1} | L_{b1} |
| 471 | Lₐ₄₉₆ | L_{b1} | L_{b1} | 472 | Lₐ₅₀₀ | L_{b1} | L_{b1} |
| 473 | Lₐ₅₀₂ | L_{b1} | L_{b1} | 474 | Lₐ₅₀₄ | L_{b1} | L_{b1} |
| 475 | Lₐ₅₀₈ | L_{b1} | L_{b1} | 476 | Lₐ₅₀₉ | L_{b1} | L_{b1} |
| 477 | Lₐ₅₁₀ | L_{b1} | L_{b1} | 478 | Lₐ₅₁₅ | L_{b1} | L_{b1} |
| 479 | Lₐ₅₂₂ | L_{b1} | L_{b1} | 480 | Lₐ₅₂₃ | L_{b1} | L_{b1} |
| 481 | Lₐ₅₂₄ | L_{b1} | L_{b1} | 482 | Lₐ₅₂₅ | L_{b1} | L_{b1} |
| 483 | Lₐ₅₃₄ | L_{b1} | L_{b1} | 484 | Lₐ₅₃₅ | L_{b1} | L_{b1} |
| 485 | Lₐ₅₆₇ | L_{b1} | L_{b1} | 486 | Lₐ₅₇₀ | L_{b1} | L_{b1} |
| 487 | Lₐ₅₈₃ | L_{b1} | L_{b1} | 488 | Lₐ₅₈₅ | L_{b1} | L_{b1} |
| 489 | Lₐ₅₈₆ | L_{b1} | L_{b1} | 490 | Lₐ₆₈₉ | L_{b1} | L_{b1} |
| 491 | Lₐ₆₉₈ | L_{b1} | L_{b1} | 492 | Lₐ₇₀₀ | L_{b1} | L_{b1} |
| 493 | Lₐ₁ | L_{b3} | L_{b3} | 494 | Lₐ₂ | L_{b3} | L_{b3} |
| 495 | Lₐ₃ | L_{b3} | L_{b3} | 496 | Lₐ₄ | L_{b3} | L_{b3} |
| 497 | Lₐ₅ | L_{b3} | L_{b3} | 498 | Lₐ₆ | L_{b3} | L_{b3} |
| 499 | Lₐ₇ | L_{b3} | L_{b3} | 500 | Lₐ₈ | L_{b3} | L_{b3} |
| 501 | Lₐ₉ | L_{b3} | L_{b3} | 502 | Lₐ₁₀ | L_{b3} | L_{b3} |
| 503 | Lₐ₁₁ | L_{b3} | L_{b3} | 504 | Lₐ₁₂ | L_{b3} | L_{b3} |
| 505 | Lₐ₁₃ | L_{b3} | L_{b3} | 506 | Lₐ₁₄ | L_{b3} | L_{b3} |
| 507 | Lₐ₁₅ | L_{b3} | L_{b3} | 508 | Lₐ₁₆ | L_{b3} | L_{b3} |
| 509 | Lₐ₁₇ | L_{b3} | L_{b3} | 510 | Lₐ₁₈ | L_{b3} | L_{b3} |
| 511 | Lₐ₁₉ | L_{b3} | L_{b3} | 512 | Lₐ₂₀ | L_{b3} | L_{b3} |
| 513 | Lₐ₂₁ | L_{b3} | L_{b3} | 514 | Lₐ₂₂ | L_{b3} | L_{b3} |
| 515 | Lₐ₂₃ | L_{b3} | L_{b3} | 516 | Lₐ₂₄ | L_{b3} | L_{b3} |
| 517 | Lₐ₂₅ | L_{b3} | L_{b3} | 518 | Lₐ₂₆ | L_{b3} | L_{b3} |
| 519 | Lₐ₂₇ | L_{b3} | L_{b3} | 520 | Lₐ₂₈ | L_{b3} | L_{b3} |
| 521 | Lₐ₂₉ | L_{b3} | L_{b3} | 522 | Lₐ₃₀ | L_{b3} | L_{b3} |
| 523 | Lₐ₃₁ | L_{b3} | L_{b3} | 524 | Lₐ₃₂ | L_{b3} | L_{b3} |
| 525 | Lₐ₃₃ | L_{b3} | L_{b3} | 526 | Lₐ₃₄ | L_{b3} | L_{b3} |
| 527 | Lₐ₃₅ | L_{b3} | L_{b3} | 528 | Lₐ₃₆ | L_{b3} | L_{b3} |
| 529 | Lₐ₃₇ | L_{b3} | L_{b3} | 530 | Lₐ₃₈ | L_{b3} | L_{b3} |
| 531 | Lₐ₃₉ | L_{b3} | L_{b3} | 532 | Lₐ₄₀ | L_{b3} | L_{b3} |
| 533 | Lₐ₄₁ | L_{b3} | L_{b3} | 534 | Lₐ₄₂ | L_{b3} | L_{b3} |
| 535 | Lₐ₄₃ | L_{b3} | L_{b3} | 536 | Lₐ₄₄ | L_{b3} | L_{b3} |
| 537 | Lₐ₄₅ | L_{b3} | L_{b3} | 538 | Lₐ₄₆ | L_{b3} | L_{b3} |
| 539 | Lₐ₄₇ | L_{b3} | L_{b3} | 540 | Lₐ₄₈ | L_{b3} | L_{b3} |
| 541 | Lₐ₄₉ | L_{b3} | L_{b3} | 542 | Lₐ₅₀ | L_{b3} | L_{b3} |
| 543 | Lₐ₅₁ | L_{b3} | L_{b3} | 544 | Lₐ₅₂ | L_{b3} | L_{b3} |
| 545 | Lₐ₅₃ | L_{b3} | L_{b3} | 546 | Lₐ₅₄ | L_{b3} | L_{b3} |
| 547 | Lₐ₅₅ | L_{b3} | L_{b3} | 548 | Lₐ₅₆ | L_{b3} | L_{b3} |
| 549 | Lₐ₅₇ | L_{b3} | L_{b3} | 550 | Lₐ₅₈ | L_{b3} | L_{b3} |
| 551 | Lₐ₅₉ | L_{b3} | L_{b3} | 552 | Lₐ₆₀ | L_{b3} | L_{b3} |
| 553 | Lₐ₆₁ | L_{b3} | L_{b3} | 554 | Lₐ₆₂ | L_{b3} | L_{b3} |
| 555 | Lₐ₆₃ | L_{b3} | L_{b3} | 556 | Lₐ₆₄ | L_{b3} | L_{b3} |
| 557 | Lₐ₆₅ | L_{b3} | L_{b3} | 558 | Lₐ₆₆ | L_{b3} | L_{b3} |
| 559 | Lₐ₆₇ | L_{b3} | L_{b3} | 560 | Lₐ₆₈ | L_{b3} | L_{b3} |
| 561 | Lₐ₆₉ | L_{b3} | L_{b3} | 562 | Lₐ₇₀ | L_{b3} | L_{b3} |
| 563 | Lₐ₇₁ | L_{b3} | L_{b3} | 564 | Lₐ₇₂ | L_{b3} | L_{b3} |
| 565 | Lₐ₇₃ | L_{b3} | L_{b3} | 566 | Lₐ₇₄ | L_{b3} | L_{b3} |
| 567 | Lₐ₇₅ | L_{b3} | L_{b3} | 568 | Lₐ₇₆ | L_{b3} | L_{b3} |
| 569 | Lₐ₇₇ | L_{b3} | L_{b3} | 570 | Lₐ₇₈ | L_{b3} | L_{b3} |
| 571 | Lₐ₇₉ | L_{b3} | L_{b3} | 572 | Lₐ₈₀ | L_{b3} | L_{b3} |
| 573 | Lₐ₈₁ | L_{b3} | L_{b3} | 574 | Lₐ₈₂ | L_{b3} | L_{b3} |
| 575 | Lₐ₈₃ | L_{b3} | L_{b3} | 576 | Lₐ₈₄ | L_{b3} | L_{b3} |
| 577 | Lₐ₈₅ | L_{b3} | L_{b3} | 578 | Lₐ₈₆ | L_{b3} | L_{b3} |
| 579 | Lₐ₈₇ | L_{b3} | L_{b3} | 580 | Lₐ₈₈ | L_{b3} | L_{b3} |
| 581 | Lₐ₈₉ | L_{b3} | L_{b3} | 582 | Lₐ₉₀ | L_{b3} | L_{b3} |
| 583 | Lₐ₉₁ | L_{b3} | L_{b3} | 584 | Lₐ₉₂ | L_{b3} | L_{b3} |
| 585 | Lₐ₉₃ | L_{b3} | L_{b3} | 586 | Lₐ₉₄ | L_{b3} | L_{b3} |
| 587 | Lₐ₉₅ | L_{b3} | L_{b3} | 588 | Lₐ₉₆ | L_{b3} | L_{b3} |
| 589 | Lₐ₉₇ | L_{b3} | L_{b3} | 590 | Lₐ₉₈ | L_{b3} | L_{b3} |
| 591 | Lₐ₉₉ | L_{b3} | L_{b3} | 592 | Lₐ₁₀₀ | L_{b3} | L_{b3} |
| 593 | Lₐ₁₀₁ | L_{b3} | L_{b3} | 594 | Lₐ₁₀₂ | L_{b3} | L_{b3} |
| 595 | Lₐ₁₀₃ | L_{b3} | L_{b3} | 596 | Lₐ₁₀₄ | L_{b3} | L_{b3} |
| 597 | Lₐ₁₀₅ | L_{b3} | L_{b3} | 598 | Lₐ₁₀₆ | L_{b3} | L_{b3} |
| 599 | Lₐ₁₀₇ | L_{b3} | L_{b3} | 600 | Lₐ₁₀₈ | L_{b3} | L_{b3} |
| 601 | Lₐ₁₀₉ | L_{b3} | L_{b3} | 602 | Lₐ₁₁₀ | L_{b3} | L_{b3} |
| 603 | Lₐ₁₁₁ | L_{b3} | L_{b3} | 604 | Lₐ₁₁₂ | L_{b3} | L_{b3} |
| 605 | Lₐ₁₁₃ | L_{b3} | L_{b3} | 606 | Lₐ₁₁₄ | L_{b3} | L_{b3} |
| 607 | Lₐ₁₁₅ | L_{b3} | L_{b3} | 608 | Lₐ₁₁₆ | L_{b3} | L_{b3} |
| 609 | Lₐ₁₁₇ | L_{b3} | L_{b3} | 610 | Lₐ₁₁₈ | L_{b3} | L_{b3} |
| 611 | Lₐ₁₁₉ | L_{b3} | L_{b3} | 612 | Lₐ₁₂₀ | L_{b3} | L_{b3} |
| 613 | Lₐ₁₂₁ | L_{b3} | L_{b3} | 614 | Lₐ₁₂₂ | L_{b3} | L_{b3} |
| 615 | Lₐ₁₂₃ | L_{b3} | L_{b3} | 616 | Lₐ₁₂₄ | L_{b3} | L_{b3} |
| 617 | Lₐ₁₂₅ | L_{b3} | L_{b3} | 618 | Lₐ₁₂₆ | L_{b3} | L_{b3} |
| 619 | Lₐ₁₂₇ | L_{b3} | L_{b3} | 620 | Lₐ₁₂₈ | L_{b3} | L_{b3} |
| 621 | Lₐ₁₂₉ | L_{b3} | L_{b3} | 622 | Lₐ₁₃₀ | L_{b3} | L_{b3} |
| 623 | Lₐ₁₃₁ | L_{b3} | L_{b3} | 624 | Lₐ₁₃₂ | L_{b3} | L_{b3} |
| 625 | Lₐ₁₃₃ | L_{b3} | L_{b3} | 626 | Lₐ₁₃₄ | L_{b3} | L_{b3} |
| 627 | Lₐ₁₃₅ | L_{b3} | L_{b3} | 628 | Lₐ₁₃₆ | L_{b3} | L_{b3} |
| 629 | Lₐ₁₃₇ | L_{b3} | L_{b3} | 630 | Lₐ₁₃₈ | L_{b3} | L_{b3} |
| 631 | Lₐ₁₃₉ | L_{b3} | L_{b3} | 632 | Lₐ₁₄₀ | L_{b3} | L_{b3} |
| 633 | Lₐ₁₄₁ | L_{b3} | L_{b3} | 634 | Lₐ₁₄₂ | L_{b3} | L_{b3} |
| 635 | Lₐ₁₄₃ | L_{b3} | L_{b3} | 636 | Lₐ₁₄₄ | L_{b3} | L_{b3} |
| 637 | Lₐ₁₄₅ | L_{b3} | L_{b3} | 638 | Lₐ₁₄₆ | L_{b3} | L_{b3} |
| 639 | Lₐ₁₄₇ | L_{b3} | L_{b3} | 640 | Lₐ₁₄₈ | L_{b3} | L_{b3} |
| 641 | Lₐ₁₄₉ | L_{b3} | L_{b3} | 642 | Lₐ₁₅₀ | L_{b3} | L_{b3} |
| 643 | Lₐ₁₅₁ | L_{b3} | L_{b3} | 644 | Lₐ₁₅₂ | L_{b3} | L_{b3} |
| 645 | Lₐ₁₅₃ | L_{b3} | L_{b3} | 646 | Lₐ₁₅₄ | L_{b3} | L_{b3} |
| 647 | Lₐ₁₅₅ | L_{b3} | L_{b3} | 648 | Lₐ₁₅₆ | L_{b3} | L_{b3} |
| 649 | Lₐ₁₅₇ | L_{b3} | L_{b3} | 650 | Lₐ₁₅₈ | L_{b3} | L_{b3} |
| 651 | Lₐ₁₅₉ | L_{b3} | L_{b3} | 652 | Lₐ₁₆₀ | L_{b3} | L_{b3} |
| 653 | Lₐ₁₆₁ | L_{b3} | L_{b3} | 654 | Lₐ₁₆₂ | L_{b3} | L_{b3} |
| 655 | Lₐ₁₆₃ | L_{b3} | L_{b3} | 656 | Lₐ₁₆₄ | L_{b3} | L_{b3} |
| 657 | Lₐ₁₆₅ | L_{b3} | L_{b3} | 658 | Lₐ₁₆₆ | L_{b3} | L_{b3} |
| 659 | Lₐ₁₆₇ | L_{b3} | L_{b3} | 660 | Lₐ₁₆₈ | L_{b3} | L_{b3} |
| 661 | Lₐ₁₆₉ | L_{b3} | L_{b3} | 662 | Lₐ₁₇₀ | L_{b3} | L_{b3} |
| 663 | Lₐ₁₇₁ | L_{b3} | L_{b3} | 664 | Lₐ₁₇₂ | L_{b3} | L_{b3} |
| 665 | Lₐ₁₇₃ | L_{b3} | L_{b3} | 666 | Lₐ₁₇₄ | L_{b3} | L_{b3} |
| 667 | Lₐ₁₇₅ | L_{b3} | L_{b3} | 668 | Lₐ₁₇₆ | L_{b3} | L_{b3} |
| 669 | Lₐ₁₇₇ | L_{b3} | L_{b3} | 670 | Lₐ₁₇₈ | L_{b3} | L_{b3} |
| 671 | Lₐ₁₇₉ | L_{b3} | L_{b3} | 672 | Lₐ₁₈₀ | L_{b3} | L_{b3} |
| 673 | Lₐ₁₈₁ | L_{b3} | L_{b3} | 674 | Lₐ₁₈₂ | L_{b3} | L_{b3} |
| 675 | Lₐ₁₈₃ | L_{b3} | L_{b3} | 676 | Lₐ₁₈₄ | L_{b3} | L_{b3} |
| 677 | Lₐ₁₈₅ | L_{b3} | L_{b3} | 678 | Lₐ₁₈₆ | L_{b3} | L_{b3} |
| 679 | Lₐ₁₈₇ | L_{b3} | L_{b3} | 680 | Lₐ₁₈₈ | L_{b3} | L_{b3} |
| 681 | Lₐ₁₈₉ | L_{b3} | L_{b3} | 682 | Lₐ₁₉₀ | L_{b3} | L_{b3} |
| 683 | Lₐ₁₉₁ | L_{b3} | L_{b3} | 684 | Lₐ₁₉₂ | L_{b3} | L_{b3} |
| 685 | Lₐ₁₉₃ | L_{b3} | L_{b3} | 686 | Lₐ₁₉₄ | L_{b3} | L_{b3} |
| 687 | Lₐ₁₉₅ | L_{b3} | L_{b3} | 688 | Lₐ₁₉₆ | L_{b3} | L_{b3} |
| 689 | Lₐ₁₉₇ | L_{b3} | L_{b3} | 690 | Lₐ₁₉₈ | L_{b3} | L_{b3} |
| 691 | Lₐ₁₉₉ | L_{b3} | L_{b3} | 692 | Lₐ₂₀₀ | L_{b3} | L_{b3} |
| 693 | Lₐ₂₀₁ | L_{b3} | L_{b3} | 694 | Lₐ₂₀₂ | L_{b3} | L_{b3} |
| 695 | Lₐ₂₀₃ | L_{b3} | L_{b3} | 696 | Lₐ₂₀₄ | L_{b3} | L_{b3} |
| 697 | Lₐ₂₀₅ | L_{b3} | L_{b3} | 698 | Lₐ₂₀₆ | L_{b3} | L_{b3} |
| 699 | Lₐ₂₀₇ | L_{b3} | L_{b3} | 700 | Lₐ₂₀₈ | L_{b3} | L_{b3} |
| 701 | Lₐ₂₀₉ | L_{b3} | L_{b3} | 702 | Lₐ₂₁₀ | L_{b3} | L_{b3} |
| 703 | Lₐ₂₁₁ | L_{b3} | L_{b3} | 704 | Lₐ₂₁₂ | L_{b3} | L_{b3} |
| 705 | Lₐ₂₁₃ | L_{b3} | L_{b3} | 706 | Lₐ₂₁₄ | L_{b3} | L_{b3} |
| 707 | Lₐ₂₁₅ | L_{b3} | L_{b3} | 708 | Lₐ₂₁₆ | L_{b3} | L_{b3} |
| 709 | Lₐ₂₁₇ | L_{b3} | L_{b3} | 710 | Lₐ₂₁₈ | L_{b3} | L_{b3} |
| 711 | Lₐ₂₁₉ | L_{b3} | L_{b3} | 712 | Lₐ₂₂₀ | L_{b3} | L_{b3} |
| 713 | Lₐ₂₂₁ | L_{b3} | L_{b3} | 714 | Lₐ₂₂₂ | L_{b3} | L_{b3} |
| 715 | Lₐ₂₂₃ | L_{b3} | L_{b3} | 716 | Lₐ₂₂₄ | L_{b3} | L_{b3} |
| 717 | Lₐ₂₂₅ | L_{b3} | L_{b3} | 718 | Lₐ₂₂₆ | L_{b3} | L_{b3} |
| 719 | Lₐ₂₂₇ | L_{b3} | L_{b3} | 720 | Lₐ₂₂₈ | L_{b3} | L_{b3} |
| 721 | Lₐ₂₂₉ | L_{b3} | L_{b3} | 722 | Lₐ₂₃₀ | L_{b3} | L_{b3} |
| 723 | Lₐ₂₃₁ | L_{b3} | L_{b3} | 724 | Lₐ₂₃₂ | L_{b3} | L_{b3} |
| 725 | Lₐ₂₃₃ | L_{b3} | L_{b3} | 726 | Lₐ₂₃₄ | L_{b3} | L_{b3} |
| 727 | Lₐ₂₃₅ | L_{b3} | L_{b3} | 728 | Lₐ₂₃₆ | L_{b3} | L_{b3} |
| 729 | Lₐ₂₃₇ | L_{b3} | L_{b3} | 730 | Lₐ₂₃₈ | L_{b3} | L_{b3} |
| 731 | Lₐ₂₃₉ | L_{b3} | L_{b3} | 732 | Lₐ₂₄₀ | L_{b3} | L_{b3} |
| 733 | Lₐ₂₄₁ | L_{b3} | L_{b3} | 734 | Lₐ₂₄₂ | L_{b3} | L_{b3} |
| 735 | Lₐ₂₄₃ | L_{b3} | L_{b3} | 736 | Lₐ₂₄₄ | L_{b3} | L_{b3} |
| 737 | Lₐ₂₄₅ | L_{b3} | L_{b3} | 738 | Lₐ₂₄₆ | L_{b3} | L_{b3} |
| 739 | Lₐ₂₄₇ | L_{b3} | L_{b3} | 740 | Lₐ₂₄₈ | L_{b3} | L_{b3} |
| 741 | Lₐ₂₄₉ | L_{b3} | L_{b3} | 742 | Lₐ₂₅₀ | L_{b3} | L_{b3} |
| 743 | Lₐ₂₅₁ | L_{b3} | L_{b3} | 744 | Lₐ₂₅₂ | L_{b3} | L_{b3} |
| 745 | Lₐ₂₅₃ | L_{b3} | L_{b3} | 746 | Lₐ₂₅₄ | L_{b3} | L_{b3} |
| 747 | Lₐ₂₅₅ | L_{b3} | L_{b3} | 748 | Lₐ₂₅₆ | L_{b3} | L_{b3} |
| 749 | Lₐ₂₅₇ | L_{b3} | L_{b3} | 750 | Lₐ₂₅₈ | L_{b3} | L_{b3} |
| 751 | Lₐ₂₅₉ | L_{b3} | L_{b3} | 752 | Lₐ₂₆₀ | L_{b3} | L_{b3} |
| 753 | Lₐ₂₆₁ | L_{b3} | L_{b3} | 754 | Lₐ₂₆₂ | L_{b3} | L_{b3} |
| 755 | Lₐ₂₆₃ | L_{b3} | L_{b3} | 756 | Lₐ₂₆₄ | L_{b3} | L_{b3} |
| 757 | Lₐ₂₆₅ | L_{b3} | L_{b3} | 758 | Lₐ₂₆₆ | L_{b3} | L_{b3} |
| 759 | Lₐ₂₆₇ | L_{b3} | L_{b3} | 760 | Lₐ₂₆₈ | L_{b3} | L_{b3} |
| 761 | Lₐ₂₆₉ | L_{b3} | L_{b3} | 762 | Lₐ₂₇₀ | L_{b3} | L_{b3} |
| 763 | Lₐ₂₇₁ | L_{b3} | L_{b3} | 764 | Lₐ₂₇₂ | L_{b3} | L_{b3} |
| 765 | Lₐ₂₇₃ | L_{b3} | L_{b3} | 766 | Lₐ₂₇₄ | L_{b3} | L_{b3} |
| 767 | Lₐ₂₇₅ | L_{b3} | L_{b3} | 768 | Lₐ₂₇₆ | L_{b3} | L_{b3} |
| 769 | Lₐ₂₇₇ | L_{b3} | L_{b3} | 770 | Lₐ₂₇₈ | L_{b3} | L_{b3} |
| 771 | Lₐ₂₇₉ | L_{b3} | L_{b3} | 772 | Lₐ₂₈₀ | L_{b3} | L_{b3} |
| 773 | Lₐ₂₈₁ | L_{b3} | L_{b3} | 774 | Lₐ₂₈₂ | L_{b3} | L_{b3} |
| 775 | Lₐ₂₈₃ | L_{b3} | L_{b3} | 776 | Lₐ₂₈₄ | L_{b3} | L_{b3} |
| 777 | Lₐ₂₈₅ | L_{b3} | L_{b3} | 778 | Lₐ₂₈₆ | L_{b3} | L_{b3} |
| 779 | Lₐ₂₈₇ | L_{b3} | L_{b3} | 780 | Lₐ₂₈₈ | L_{b3} | L_{b3} |
| 781 | Lₐ₂₈₉ | L_{b3} | L_{b3} | 782 | Lₐ₂₉₀ | L_{b3} | L_{b3} |
| 783 | Lₐ₂₉₁ | L_{b3} | L_{b3} | 784 | Lₐ₂₉₂ | L_{b3} | L_{b3} |
| 785 | Lₐ₂₉₃ | L_{b3} | L_{b3} | 786 | Lₐ₂₉₄ | L_{b3} | L_{b3} |
| 787 | Lₐ₂₉₅ | L_{b3} | L_{b3} | 788 | Lₐ₂₉₆ | L_{b3} | L_{b3} |
| 789 | Lₐ₂₉₇ | L_{b3} | L_{b3} | 790 | Lₐ₂₉₈ | L_{b3} | L_{b3} |
| 791 | Lₐ₂₉₉ | L_{b3} | L_{b3} | 792 | Lₐ₃₀₀ | L_{b3} | L_{b3} |
| 793 | Lₐ₃₀₁ | L_{b3} | L_{b3} | 794 | Lₐ₃₀₂ | L_{b3} | L_{b3} |
| 795 | Lₐ₃₀₃ | L_{b3} | L_{b3} | 796 | Lₐ₃₀₄ | L_{b3} | L_{b3} |
| 797 | Lₐ₃₀₅ | L_{b3} | L_{b3} | 798 | Lₐ₃₀₆ | L_{b3} | L_{b3} |
| 799 | Lₐ₃₀₇ | L_{b3} | L_{b3} | 800 | Lₐ₃₀₈ | L_{b3} | L_{b3} |
| 801 | Lₐ₃₀₉ | L_{b3} | L_{b3} | 802 | Lₐ₃₁₀ | L_{b3} | L_{b3} |
| 803 | Lₐ₃₁₁ | L_{b3} | L_{b3} | 804 | Lₐ₃₁₂ | L_{b3} | L_{b3} |
| 805 | Lₐ₃₁₃ | L_{b3} | L_{b3} | 806 | Lₐ₃₁₄ | L_{b3} | L_{b3} |
| 807 | Lₐ₃₁₅ | L_{b3} | L_{b3} | 808 | Lₐ₃₁₆ | L_{b3} | L_{b3} |
| 809 | Lₐ₃₁₇ | L_{b3} | L_{b3} | 810 | Lₐ₃₁₈ | L_{b3} | L_{b3} |
| 811 | Lₐ₃₁₉ | L_{b3} | L_{b3} | 812 | Lₐ₃₂₀ | L_{b3} | L_{b3} |
| 813 | Lₐ₃₂₁ | L_{b3} | L_{b3} | 814 | Lₐ₃₂₂ | L_{b3} | L_{b3} |
| 815 | Lₐ₃₂₃ | L_{b3} | L_{b3} | 816 | Lₐ₃₂₄ | L_{b3} | L_{b3} |
| 817 | Lₐ₃₂₅ | L_{b3} | L_{b3} | 818 | Lₐ₃₂₆ | L_{b3} | L_{b3} |
| 819 | Lₐ₃₂₇ | L_{b3} | L_{b3} | 820 | Lₐ₃₂₈ | L_{b3} | L_{b3} |
| 821 | Lₐ₃₂₉ | L_{b3} | L_{b3} | 822 | Lₐ₃₃₀ | L_{b3} | L_{b3} |
| 823 | Lₐ₃₃₁ | L_{b3} | L_{b3} | 824 | Lₐ₃₃₂ | L_{b3} | L_{b3} |
| 825 | Lₐ₃₃₃ | L_{b3} | L_{b3} | 826 | Lₐ₃₃₄ | L_{b3} | L_{b3} |
| 827 | Lₐ₃₃₅ | L_{b3} | L_{b3} | 828 | Lₐ₃₃₆ | L_{b3} | L_{b3} |
| 829 | Lₐ₃₃₇ | L_{b3} | L_{b3} | 830 | Lₐ₃₃₈ | L_{b3} | L_{b3} |
| 831 | Lₐ₃₃₉ | L_{b3} | L_{b3} | 832 | Lₐ₃₄₀ | L_{b3} | L_{b3} |
| 833 | Lₐ₃₄₁ | L_{b3} | L_{b3} | 834 | Lₐ₃₄₂ | L_{b3} | L_{b3} |
| 835 | Lₐ₃₄₃ | L_{b3} | L_{b3} | 836 | Lₐ₃₄₄ | L_{b3} | L_{b3} |
| 837 | Lₐ₃₄₅ | L_{b3} | L_{b3} | 838 | Lₐ₃₄₆ | L_{b3} | L_{b3} |
| 839 | Lₐ₃₄₇ | L_{b3} | L_{b3} | 840 | Lₐ₃₄₈ | L_{b3} | L_{b3} |
| 841 | Lₐ₃₄₉ | L_{b3} | L_{b3} | 842 | Lₐ₃₅₀ | L_{b3} | L_{b3} |
| 843 | Lₐ₃₅₁ | L_{b3} | L_{b3} | 844 | Lₐ₃₅₂ | L_{b3} | L_{b3} |
| 845 | Lₐ₃₅₃ | L_{b3} | L_{b3} | 846 | Lₐ₃₅₄ | L_{b3} | L_{b3} |
| 847 | Lₐ₃₅₅ | L_{b3} | L_{b3} | 848 | Lₐ₃₅₆ | L_{b3} | L_{b3} |
| 849 | Lₐ₃₅₇ | L_{b3} | L_{b3} | 850 | Lₐ₃₅₈ | L_{b3} | L_{b3} |
| 851 | Lₐ₃₅₉ | L_{b3} | L_{b3} | 852 | Lₐ₃₆₀ | L_{b3} | L_{b3} |
| 853 | Lₐ₃₆₁ | L_{b3} | L_{b3} | 854 | Lₐ₃₆₂ | L_{b3} | L_{b3} |
| 855 | Lₐ₃₆₃ | L_{b3} | L_{b3} | 856 | Lₐ₃₆₄ | L_{b3} | L_{b3} |
| 857 | Lₐ₃₆₅ | L_{b3} | L_{b3} | 858 | Lₐ₃₆₆ | L_{b3} | L_{b3} |
| 859 | Lₐ₃₆₇ | L_{b3} | L_{b3} | 860 | Lₐ₃₆₈ | L_{b3} | L_{b3} |
| 861 | Lₐ₃₆₉ | L_{b3} | L_{b3} | 862 | Lₐ₃₇₀ | L_{b3} | L_{b3} |
| 863 | Lₐ₃₇₁ | L_{b3} | L_{b3} | 864 | Lₐ₃₇₂ | L_{b3} | L_{b3} |
| 865 | Lₐ₃₇₃ | L_{b3} | L_{b3} | 866 | Lₐ₃₇₄ | L_{b3} | L_{b3} |
| 867 | Lₐ₃₇₅ | L_{b3} | L_{b3} | 868 | Lₐ₃₇₆ | L_{b3} | L_{b3} |
| 869 | Lₐ₃₇₇ | L_{b3} | L_{b3} | 870 | Lₐ₃₇₈ | L_{b3} | L_{b3} |
| 871 | Lₐ₃₇₉ | L_{b3} | L_{b3} | 872 | Lₐ₃₈₀ | L_{b3} | L_{b3} |
| 873 | Lₐ₃₈₁ | L_{b3} | L_{b3} | 874 | Lₐ₃₈₂ | L_{b3} | L_{b3} |
| 875 | Lₐ₃₈₃ | L_{b3} | L_{b3} | 876 | Lₐ₃₈₄ | L_{b3} | L_{b3} |
| 877 | Lₐ₃₈₅ | L_{b3} | L_{b3} | 878 | Lₐ₃₈₆ | L_{b3} | L_{b3} |
| 879 | Lₐ₃₈₇ | L_{b3} | L_{b3} | 880 | Lₐ₃₈₈ | L_{b3} | L_{b3} |
| 881 | Lₐ₃₈₉ | L_{b3} | L_{b3} | 882 | Lₐ₃₉₀ | L_{b3} | L_{b3} |
| 883 | Lₐ₃₉₁ | L_{b3} | L_{b3} | 884 | Lₐ₃₉₂ | L_{b3} | L_{b3} |
| 885 | Lₐ₃₉₃ | L_{b3} | L_{b3} | 886 | Lₐ₃₉₄ | L_{b3} | L_{b3} |
| 887 | Lₐ₃₉₅ | L_{b3} | L_{b3} | 888 | Lₐ₃₉₆ | L_{b3} | L_{b3} |
| 889 | Lₐ₃₉₇ | L_{b3} | L_{b3} | 890 | Lₐ₃₉₈ | L_{b3} | L_{b3} |
| 891 | Lₐ₃₉₉ | L_{b3} | L_{b3} | 892 | Lₐ₄₀₀ | L_{b3} | L_{b3} |
| 893 | Lₐ₄₀₁ | L_{b3} | L_{b3} | 894 | Lₐ₄₀₂ | L_{b3} | L_{b3} |
| 895 | Lₐ₄₀₃ | L_{b3} | L_{b3} | 896 | Lₐ₄₀₄ | L_{b3} | L_{b3} |
| 897 | Lₐ₄₀₅ | L_{b3} | L_{b3} | 898 | Lₐ₄₀₆ | L_{b3} | L_{b3} |
| 899 | Lₐ₄₀₇ | L_{b3} | L_{b3} | 900 | Lₐ₄₀₈ | L_{b3} | L_{b3} |
| 901 | Lₐ₄₀₉ | L_{b3} | L_{b3} | 902 | Lₐ₄₁₀ | L_{b3} | L_{b3} |
| 903 | Lₐ₄₁₁ | L_{b3} | L_{b3} | 904 | Lₐ₄₁₂ | L_{b3} | L_{b3} |
| 905 | Lₐ₄₁₃ | L_{b3} | L_{b3} | 906 | Lₐ₄₁₄ | L_{b3} | L_{b3} |
| 907 | Lₐ₄₁₅ | L_{b3} | L_{b3} | 908 | Lₐ₄₁₆ | L_{b3} | L_{b3} |
| 909 | Lₐ₄₁₇ | L_{b3} | L_{b3} | 910 | Lₐ₄₁₈ | L_{b3} | L_{b3} |
| 911 | Lₐ₄₁₉ | L_{b3} | L_{b3} | 912 | Lₐ₄₂₀ | L_{b3} | L_{b3} |
| 913 | Lₐ₄₂₁ | L_{b3} | L_{b3} | 914 | Lₐ₄₂₂ | L_{b3} | L_{b3} |
| 915 | Lₐ₄₂₃ | L_{b3} | L_{b3} | 916 | Lₐ₄₂₄ | L_{b3} | L_{b3} |
| 917 | Lₐ₄₂₅ | L_{b3} | L_{b3} | 918 | Lₐ₄₂₆ | L_{b3} | L_{b3} |
| 919 | Lₐ₄₂₇ | L_{b3} | L_{b3} | 920 | Lₐ₄₂₈ | L_{b3} | L_{b3} |
| 921 | Lₐ₄₂₉ | L_{b3} | L_{b3} | 922 | Lₐ₄₃₀ | L_{b3} | L_{b3} |
| 923 | Lₐ₄₃₁ | L_{b3} | L_{b3} | 924 | Lₐ₄₃₂ | L_{b3} | L_{b3} |
| 925 | Lₐ₄₃₃ | L_{b3} | L_{b3} | 926 | Lₐ₄₃₄ | L_{b3} | L_{b3} |
| 927 | Lₐ₄₃₅ | L_{b3} | L_{b3} | 928 | Lₐ₄₃₆ | L_{b3} | L_{b3} |
| 929 | Lₐ₄₃₇ | L_{b3} | L_{b3} | 930 | Lₐ₄₃₈ | L_{b3} | L_{b3} |
| 931 | Lₐ₄₃₉ | L_{b3} | L_{b3} | 932 | Lₐ₄₄₀ | L_{b3} | L_{b3} |
| 933 | Lₐ₄₄₁ | L_{b3} | L_{b3} | 934 | Lₐ₄₄₂ | L_{b3} | L_{b3} |
| 935 | Lₐ₄₄₃ | L_{b3} | L_{b3} | 936 | Lₐ₄₄₄ | L_{b3} | L_{b3} |
| 937 | Lₐ₄₄₅ | L_{b3} | L_{b3} | 938 | Lₐ₄₄₆ | L_{b3} | L_{b3} |
| 939 | Lₐ₄₄₇ | L_{b3} | L_{b3} | 940 | Lₐ₄₄₈ | L_{b3} | L_{b3} |
| 941 | Lₐ₄₄₉ | L_{b3} | L_{b3} | 942 | Lₐ₄₅₀ | L_{b3} | L_{b3} |
| 943 | Lₐ₄₅₁ | L_{b3} | L_{b3} | 944 | Lₐ₄₅₂ | L_{b3} | L_{b3} |
| 945 | Lₐ₄₅₃ | L_{b3} | L_{b3} | 946 | Lₐ₄₅₄ | L_{b3} | L_{b3} |
| 947 | Lₐ₄₅₅ | L_{b3} | L_{b3} | 948 | Lₐ₄₅₆ | L_{b3} | L_{b3} |
| 949 | Lₐ₄₅₇ | L_{b3} | L_{b3} | 950 | Lₐ₄₅₈ | L_{b3} | L_{b3} |
| 951 | Lₐ₄₅₉ | L_{b3} | L_{b3} | 952 | Lₐ₄₆₀ | L_{b3} | L_{b3} |
| 953 | Lₐ₄₉₆ | L_{b3} | L_{b3} | 954 | Lₐ₅₀₀ | L_{b3} | L_{b3} |
| 955 | Lₐ₅₀₂ | L_{b3} | L_{b3} | 956 | Lₐ₅₀₄ | L_{b3} | L_{b3} |
| 957 | Lₐ₅₀₈ | L_{b3} | L_{b3} | 958 | Lₐ₅₀₉ | L_{b3} | L_{b3} |
| 959 | Lₐ₅₁₀ | L_{b3} | L_{b3} | 960 | Lₐ₅₁₅ | L_{b3} | L_{b3} |
| 961 | Lₐ₅₂₂ | L_{b3} | L_{b3} | 962 | Lₐ₅₂₃ | L_{b3} | L_{b3} |
| 963 | Lₐ₅₂₄ | L_{b3} | L_{b3} | 964 | Lₐ₅₂₅ | L_{b3} | L_{b3} |
| 965 | Lₐ₅₃₄ | L_{b3} | L_{b3} | 966 | Lₐ₅₃₅ | L_{b3} | L_{b3} |
| 967 | Lₐ₅₆₇ | L_{b3} | L_{b3} | 968 | Lₐ₅₇₀ | L_{b3} | L_{b3} |
| 969 | Lₐ₅₈₃ | L_{b3} | L_{b3} | 970 | Lₐ₅₈₅ | L_{b3} | L_{b3} |
| 971 | Lₐ₅₈₆ | L_{b3} | L_{b3} | 972 | Lₐ₆₈₉ | L_{b3} | L_{b3} |
| 973 | Lₐ₆₉₈ | L_{b3} | L_{b3} | 974 | Lₐ₇₀₀ | L_{b3} | L_{b3} |
| 975 | Lₐ₁ | L_{b81} | L_{b81} | 976 | Lₐ₂ | L_{b81} | L_{b81} |
| 977 | Lₐ₃ | L_{b81} | L_{b81} | 978 | Lₐ₄ | L_{b81} | L_{b81} |
| 979 | Lₐ₅ | L_{b81} | L_{b81} | 980 | Lₐ₆ | L_{b81} | L_{b81} |
| 981 | Lₐ₇ | L_{b81} | L_{b81} | 982 | Lₐ₈ | L_{b81} | L_{b81} |
| 983 | Lₐ₉ | L_{b81} | L_{b81} | 984 | Lₐ₁₀ | L_{b81} | L_{b81} |
| 985 | Lₐ₁₁ | L_{b81} | L_{b81} | 986 | Lₐ₁₂ | L_{b81} | L_{b81} |
| 987 | Lₐ₁₃ | L_{b81} | L_{b81} | 988 | Lₐ₁₄ | L_{b81} | L_{b81} |
| 989 | Lₐ₁₅ | L_{b81} | L_{b81} | 990 | Lₐ₁₆ | L_{b81} | L_{b81} |
| 991 | Lₐ₁₇ | L_{b81} | L_{b81} | 992 | Lₐ₁₈ | L_{b81} | L_{b81} |
| 993 | Lₐ₁₉ | L_{b81} | L_{b81} | 994 | Lₐ₂₀ | L_{b81} | L_{b81} |
| 995 | Lₐ₂₁ | L_{b81} | L_{b81} | 996 | Lₐ₂₂ | L_{b81} | L_{b81} |
| 997 | Lₐ₂₃ | L_{b81} | L_{b81} | 998 | Lₐ₂₄ | L_{b81} | L_{b81} |
| 999 | Lₐ₂₅ | L_{b81} | L_{b81} | 1000 | Lₐ₂₆ | L_{b81} | L_{b81} |
| 1001 | Lₐ₂₇ | L_{b81} | L_{b81} | 1002 | Lₐ₂₈ | L_{b81} | L_{b81} |
| 1003 | Lₐ₂₉ | L_{b81} | L_{b81} | 1004 | Lₐ₃₀ | L_{b81} | L_{b81} |
| 1005 | Lₐ₃₁ | L_{b81} | L_{b81} | 1006 | Lₐ₃₂ | L_{b81} | L_{b81} |
| 1007 | Lₐ₃₃ | L_{b81} | L_{b81} | 1008 | Lₐ₃₄ | L_{b81} | L_{b81} |
| 1009 | Lₐ₃₅ | L_{b81} | L_{b81} | 1010 | Lₐ₃₆ | L_{b81} | L_{b81} |
| 1011 | Lₐ₃₇ | L_{b81} | L_{b81} | 1012 | Lₐ₃₈ | L_{b81} | L_{b81} |
| 1013 | Lₐ₃₉ | L_{b81} | L_{b81} | 1014 | Lₐ₄₀ | L_{b81} | L_{b81} |
| 1015 | Lₐ₄₁ | L_{b81} | L_{b81} | 1016 | Lₐ₄₂ | L_{b81} | L_{b81} |
| 1017 | Lₐ₄₃ | L_{b81} | L_{b81} | 1018 | Lₐ₄₄ | L_{b81} | L_{b81} |
| 1019 | Lₐ₄₅ | L_{b81} | L_{b81} | 1020 | Lₐ₄₆ | L_{b81} | L_{b81} |
| 1021 | Lₐ₄₇ | L_{b81} | L_{b81} | 1022 | Lₐ₄₈ | L_{b81} | L_{b81} |
| 1023 | Lₐ₄₉ | L_{b81} | L_{b81} | 1024 | Lₐ₅₀ | L_{b81} | L_{b81} |
| 1025 | Lₐ₅₁ | L_{b81} | L_{b81} | 1026 | Lₐ₅₂ | L_{b81} | L_{b81} |
| 1027 | Lₐ₅₃ | L_{b81} | L_{b81} | 1028 | Lₐ₅₄ | L_{b81} | L_{b81} |
| 1029 | Lₐ₅₅ | L_{b81} | L_{b81} | 1030 | Lₐ₅₆ | L_{b81} | L_{b81} |
| 1031 | Lₐ₅₇ | L_{b81} | L_{b81} | 1032 | Lₐ₅₈ | L_{b81} | L_{b81} |
| 1033 | Lₐ₅₉ | L_{b81} | L_{b81} | 1034 | Lₐ₆₀ | L_{b81} | L_{b81} |
| 1035 | Lₐ₆₁ | L_{b81} | L_{b81} | 1036 | Lₐ₆₂ | L_{b81} | L_{b81} |
| 1037 | Lₐ₆₃ | L_{b81} | L_{b81} | 1038 | Lₐ₆₄ | L_{b81} | L_{b81} |
| 1039 | Lₐ₆₅ | L_{b81} | L_{b81} | 1040 | Lₐ₆₆ | L_{b81} | L_{b81} |
| 1041 | Lₐ₆₇ | L_{b81} | L_{b81} | 1042 | Lₐ₆₈ | L_{b81} | L_{b81} |
| 1043 | Lₐ₆₉ | L_{b81} | L_{b81} | 1044 | Lₐ₇₀ | L_{b81} | L_{b81} |
| 1045 | Lₐ₇₁ | L_{b81} | L_{b81} | 1046 | Lₐ₇₂ | L_{b81} | L_{b81} |
| 1047 | Lₐ₇₃ | L_{b81} | L_{b81} | 1048 | Lₐ₇₄ | L_{b81} | L_{b81} |
| 1049 | Lₐ₇₅ | L_{b81} | L_{b81} | 1050 | Lₐ₇₆ | L_{b81} | L_{b81} |
| 1051 | Lₐ₇₇ | L_{b81} | L_{b81} | 1052 | Lₐ₇₈ | L_{b81} | L_{b81} |
| 1053 | Lₐ₇₉ | L_{b81} | L_{b81} | 1054 | Lₐ₈₀ | L_{b81} | L_{b81} |
| 1055 | Lₐ₈₁ | L_{b81} | L_{b81} | 1056 | Lₐ₈₂ | L_{b81} | L_{b81} |
| 1057 | Lₐ₈₃ | L_{b81} | L_{b81} | 1058 | Lₐ₈₄ | L_{b81} | L_{b81} |
| 1059 | Lₐ₈₅ | L_{b81} | L_{b81} | 1060 | Lₐ₈₆ | L_{b81} | L_{b81} |
| 1061 | Lₐ₈₇ | L_{b81} | L_{b81} | 1062 | Lₐ₈₈ | L_{b81} | L_{b81} |
| 1063 | Lₐ₈₉ | L_{b81} | L_{b81} | 1064 | Lₐ₉₀ | L_{b81} | L_{b81} |
| 1065 | Lₐ₉₁ | L_{b81} | L_{b81} | 1066 | Lₐ₉₂ | L_{b81} | L_{b81} |
| 1067 | Lₐ₉₃ | L_{b81} | L_{b81} | 1068 | Lₐ₉₄ | L_{b81} | L_{b81} |
| 1069 | Lₐ₉₅ | L_{b81} | L_{b81} | 1070 | Lₐ₉₆ | L_{b81} | L_{b81} |
| 1071 | Lₐ₉₇ | L_{b81} | L_{b81} | 1072 | Lₐ₉₈ | L_{b81} | L_{b81} |
| 1073 | Lₐ₉₉ | L_{b81} | L_{b81} | 1074 | Lₐ₁₀₀ | L_{b81} | L_{b81} |
| 1075 | Lₐ₁₀₁ | L_{b81} | L_{b81} | 1076 | Lₐ₁₀₂ | L_{b81} | L_{b81} |
| 1077 | Lₐ₁₀₃ | L_{b81} | L_{b81} | 1078 | Lₐ₁₀₄ | L_{b81} | L_{b81} |
| 1079 | Lₐ₁₀₅ | L_{b81} | L_{b81} | 1080 | Lₐ₁₀₆ | L_{b81} | L_{b81} |
| 1081 | Lₐ₁₀₇ | L_{b81} | L_{b81} | 1082 | Lₐ₁₀₈ | L_{b81} | L_{b81} |
| 1083 | Lₐ₁₀₉ | L_{b81} | L_{b81} | 1084 | Lₐ₁₁₀ | L_{b81} | L_{b81} |
| 1085 | Lₐ₁₁₁ | L_{b81} | L_{b81} | 1086 | Lₐ₁₁₂ | L_{b81} | L_{b81} |
| 1087 | Lₐ₁₁₃ | L_{b81} | L_{b81} | 1088 | Lₐ₁₁₄ | L_{b81} | L_{b81} |
| 1089 | Lₐ₁₁₅ | L_{b81} | L_{b81} | 1090 | Lₐ₁₁₆ | L_{b81} | L_{b81} |
| 1091 | Lₐ₁₁₇ | L_{b81} | L_{b81} | 1092 | Lₐ₁₁₈ | L_{b81} | L_{b81} |
| 1093 | Lₐ₁₁₉ | L_{b81} | L_{b81} | 1094 | Lₐ₁₂₀ | L_{b81} | L_{b81} |
| 1095 | Lₐ₁₂₁ | L_{b81} | L_{b81} | 1096 | Lₐ₁₂₂ | L_{b81} | L_{b81} |
| 1097 | Lₐ₁₂₃ | L_{b81} | L_{b81} | 1098 | Lₐ₁₂₄ | L_{b81} | L_{b81} |
| 1099 | Lₐ₁₂₅ | L_{b81} | L_{b81} | 1100 | Lₐ₁₂₆ | L_{b81} | L_{b81} |
| 1101 | Lₐ₁₂₇ | L_{b81} | L_{b81} | 1102 | Lₐ₁₂₈ | L_{b81} | L_{b81} |
| 1103 | Lₐ₁₂₉ | L_{b81} | L_{b81} | 1104 | Lₐ₁₃₀ | L_{b81} | L_{b81} |
| 1105 | Lₐ₁₃₁ | L_{b81} | L_{b81} | 1106 | Lₐ₁₃₂ | L_{b81} | L_{b81} |
| 1107 | Lₐ₁₃₃ | L_{b81} | L_{b81} | 1108 | Lₐ₁₃₄ | L_{b81} | L_{b81} |
| 1109 | Lₐ₁₃₅ | L_{b81} | L_{b81} | 1110 | Lₐ₁₃₆ | L_{b81} | L_{b81} |
| 1111 | Lₐ₁₃₇ | L_{b81} | L_{b81} | 1112 | Lₐ₁₃₈ | L_{b81} | L_{b81} |
| 1113 | Lₐ₁₃₉ | L_{b81} | L_{b81} | 1114 | Lₐ₁₄₀ | L_{b81} | L_{b81} |
| 1115 | Lₐ₁₄₁ | L_{b81} | L_{b81} | 1116 | Lₐ₁₄₂ | L_{b81} | L_{b81} |
| 1117 | Lₐ₁₄₃ | L_{b81} | L_{b81} | 1118 | Lₐ₁₄₄ | L_{b81} | L_{b81} |
| 1119 | Lₐ₁₄₅ | L_{b81} | L_{b81} | 1120 | Lₐ₁₄₆ | L_{b81} | L_{b81} |
| 1121 | Lₐ₁₄₇ | L_{b81} | L_{b81} | 1122 | Lₐ₁₄₈ | L_{b81} | L_{b81} |
| 1123 | Lₐ₁₄₉ | L_{b81} | L_{b81} | 1124 | Lₐ₁₅₀ | L_{b81} | L_{b81} |
| 1125 | Lₐ₁₅₁ | L_{b81} | L_{b81} | 1126 | Lₐ₁₅₂ | L_{b81} | L_{b81} |
| 1127 | Lₐ₁₅₃ | L_{b81} | L_{b81} | 1128 | Lₐ₁₅₄ | L_{b81} | L_{b81} |
| 1129 | Lₐ₁₅₅ | L_{b81} | L_{b81} | 1130 | Lₐ₁₅₆ | L_{b81} | L_{b81} |
| 1131 | Lₐ₁₅₇ | L_{b81} | L_{b81} | 1132 | Lₐ₁₅₈ | L_{b81} | L_{b81} |
| 1133 | Lₐ₁₅₉ | L_{b81} | L_{b81} | 1134 | Lₐ₁₆₀ | L_{b81} | L_{b81} |
| 1135 | Lₐ₁₆₁ | L_{b81} | L_{b81} | 1136 | Lₐ₁₆₂ | L_{b81} | L_{b81} |
| 1137 | Lₐ₁₆₃ | L_{b81} | L_{b81} | 1138 | Lₐ₁₆₄ | L_{b81} | L_{b81} |
| 1139 | Lₐ₁₆₅ | L_{b81} | L_{b81} | 1140 | Lₐ₁₆₆ | L_{b81} | L_{b81} |
| 1141 | Lₐ₁₆₇ | L_{b81} | L_{b81} | 1142 | Lₐ₁₆₈ | L_{b81} | L_{b81} |
| 1143 | Lₐ₁₆₉ | L_{b81} | L_{b81} | 1144 | Lₐ₁₇₀ | L_{b81} | L_{b81} |
| 1145 | Lₐ₁₇₁ | L_{b81} | L_{b81} | 1146 | Lₐ₁₇₂ | L_{b81} | L_{b81} |
| 1147 | Lₐ₁₇₃ | L_{b81} | L_{b81} | 1148 | Lₐ₁₇₄ | L_{b81} | L_{b81} |
| 1149 | Lₐ₁₇₅ | L_{b81} | L_{b81} | 1150 | Lₐ₁₇₆ | L_{b81} | L_{b81} |
| 1151 | Lₐ₁₇₇ | L_{b81} | L_{b81} | 1152 | Lₐ₁₇₈ | L_{b81} | L_{b81} |
| 1153 | Lₐ₁₇₉ | L_{b81} | L_{b81} | 1154 | Lₐ₁₈₀ | L_{b81} | L_{b81} |
| 1155 | Lₐ₁₈₁ | L_{b81} | L_{b81} | 1156 | Lₐ₁₈₂ | L_{b81} | L_{b81} |
| 1157 | Lₐ₁₈₃ | L_{b81} | L_{b81} | 1158 | Lₐ₁₈₄ | L_{b81} | L_{b81} |
| 1159 | Lₐ₁₈₅ | L_{b81} | L_{b81} | 1160 | Lₐ₁₈₆ | L_{b81} | L_{b81} |
| 1161 | Lₐ₁₈₇ | L_{b81} | L_{b81} | 1162 | Lₐ₁₈₈ | L_{b81} | L_{b81} |
| 1163 | Lₐ₁₈₉ | L_{b81} | L_{b81} | 1164 | Lₐ₁₉₀ | L_{b81} | L_{b81} |
| 1165 | Lₐ₁₉₁ | L_{b81} | L_{b81} | 1166 | Lₐ₁₉₂ | L_{b81} | L_{b81} |
| 1167 | Lₐ₁₉₃ | L_{b81} | L_{b81} | 1168 | Lₐ₁₉₄ | L_{b81} | L_{b81} |
| 1169 | Lₐ₁₉₅ | L_{b81} | L_{b81} | 1170 | Lₐ₁₉₆ | L_{b81} | L_{b81} |
| 1171 | Lₐ₁₉₇ | L_{b81} | L_{b81} | 1172 | Lₐ₁₉₈ | L_{b81} | L_{b81} |
| 1173 | Lₐ₁₉₉ | L_{b81} | L_{b81} | 1174 | Lₐ₂₀₀ | L_{b81} | L_{b81} |
| 1175 | Lₐ₂₀₁ | L_{b81} | L_{b81} | 1176 | Lₐ₂₀₂ | L_{b81} | L_{b81} |
| 1177 | Lₐ₂₀₃ | L_{b81} | L_{b81} | 1178 | Lₐ₂₀₄ | L_{b81} | L_{b81} |
| 1179 | Lₐ₂₀₅ | L_{b81} | L_{b81} | 1180 | Lₐ₂₀₆ | L_{b81} | L_{b81} |
| 1181 | Lₐ₂₀₇ | L_{b81} | L_{b81} | 1182 | Lₐ₂₀₈ | L_{b81} | L_{b81} |
| 1183 | Lₐ₂₀₉ | L_{b81} | L_{b81} | 1184 | Lₐ₂₁₀ | L_{b81} | L_{b81} |
| 1185 | Lₐ₂₁₁ | L_{b81} | L_{b81} | 1186 | Lₐ₂₁₂ | L_{b81} | L_{b81} |
| 1187 | Lₐ₂₁₃ | L_{b81} | L_{b81} | 1188 | Lₐ₂₁₄ | L_{b81} | L_{b81} |
| 1189 | Lₐ₂₁₅ | L_{b81} | L_{b81} | 1190 | Lₐ₂₁₆ | L_{b81} | L_{b81} |
| 1191 | Lₐ₂₁₇ | L_{b81} | L_{b81} | 1192 | Lₐ₂₁₈ | L_{b81} | L_{b81} |
| 1193 | Lₐ₂₁₉ | L_{b81} | L_{b81} | 1194 | Lₐ₂₂₀ | L_{b81} | L_{b81} |
| 1195 | Lₐ₂₂₁ | L_{b81} | L_{b81} | 1196 | Lₐ₂₂₂ | L_{b81} | L_{b81} |
| 1197 | Lₐ₂₂₃ | L_{b81} | L_{b81} | 1198 | Lₐ₂₂₄ | L_{b81} | L_{b81} |
| 1199 | Lₐ₂₂₅ | L_{b81} | L_{b81} | 1200 | Lₐ₂₂₆ | L_{b81} | L_{b81} |
| 1201 | Lₐ₂₂₇ | L_{b81} | L_{b81} | 1202 | Lₐ₂₂₈ | L_{b81} | L_{b81} |
| 1203 | Lₐ₂₂₉ | L_{b81} | L_{b81} | 1204 | Lₐ₂₃₀ | L_{b81} | L_{b81} |
| 1205 | Lₐ₂₃₁ | L_{b81} | L_{b81} | 1206 | Lₐ₂₃₂ | L_{b81} | L_{b81} |
| 1207 | Lₐ₂₃₃ | L_{b81} | L_{b81} | 1208 | Lₐ₂₃₄ | L_{b81} | L_{b81} |
| 1209 | Lₐ₂₃₅ | L_{b81} | L_{b81} | 1210 | Lₐ₂₃₆ | L_{b81} | L_{b81} |
| 1211 | Lₐ₂₃₇ | L_{b81} | L_{b81} | 1212 | Lₐ₂₃₈ | L_{b81} | L_{b81} |
| 1213 | Lₐ₂₃₉ | L_{b81} | L_{b81} | 1214 | Lₐ₂₄₀ | L_{b81} | L_{b81} |
| 1215 | Lₐ₂₄₁ | L_{b81} | L_{b81} | 1216 | Lₐ₂₄₂ | L_{b81} | L_{b81} |
| 1217 | Lₐ₂₄₃ | L_{b81} | L_{b81} | 1218 | Lₐ₂₄₄ | L_{b81} | L_{b81} |
| 1219 | Lₐ₂₄₅ | L_{b81} | L_{b81} | 1220 | Lₐ₂₄₆ | L_{b81} | L_{b81} |
| 1221 | Lₐ₂₄₇ | L_{b81} | L_{b81} | 1222 | Lₐ₂₄₈ | L_{b81} | L_{b81} |
| 1223 | Lₐ₂₄₉ | L_{b81} | L_{b81} | 1224 | Lₐ₂₅₀ | L_{b81} | L_{b81} |
| 1225 | Lₐ₂₅₁ | L_{b81} | L_{b81} | 1226 | Lₐ₂₅₂ | L_{b81} | L_{b81} |
| 1227 | Lₐ₂₅₃ | L_{b81} | L_{b81} | 1228 | Lₐ₂₅₄ | L_{b81} | L_{b81} |
| 1229 | Lₐ₂₅₅ | L_{b81} | L_{b81} | 1230 | Lₐ₂₅₆ | L_{b81} | L_{b81} |
| 1231 | Lₐ₂₅₇ | L_{b81} | L_{b81} | 1232 | Lₐ₂₅₈ | L_{b81} | L_{b81} |
| 1233 | Lₐ₂₅₉ | L_{b81} | L_{b81} | 1234 | Lₐ₂₆₀ | L_{b81} | L_{b81} |
| 1235 | Lₐ₂₆₁ | L_{b81} | L_{b81} | 1236 | Lₐ₂₆₂ | L_{b81} | L_{b81} |
| 1237 | Lₐ₂₆₃ | L_{b81} | L_{b81} | 1238 | Lₐ₂₆₄ | L_{b81} | L_{b81} |
| 1239 | Lₐ₂₆₅ | L_{b81} | L_{b81} | 1240 | Lₐ₂₆₆ | L_{b81} | L_{b81} |
| 1241 | Lₐ₂₆₇ | L_{b81} | L_{b81} | 1242 | Lₐ₂₆₈ | L_{b81} | L_{b81} |
| 1243 | Lₐ₂₆₉ | L_{b81} | L_{b81} | 1244 | Lₐ₂₇₀ | L_{b81} | L_{b81} |
| 1245 | Lₐ₂₇₁ | L_{b81} | L_{b81} | 1246 | Lₐ₂₇₂ | L_{b81} | L_{b81} |
| 1247 | Lₐ₂₇₃ | L_{b81} | L_{b81} | 1248 | Lₐ₂₇₄ | L_{b81} | L_{b81} |
| 1249 | Lₐ₂₇₅ | L_{b81} | L_{b81} | 1250 | Lₐ₂₇₆ | L_{b81} | L_{b81} |
| 1251 | Lₐ₂₇₇ | L_{b81} | L_{b81} | 1252 | Lₐ₂₇₈ | L_{b81} | L_{b81} |
| 1253 | Lₐ₂₇₉ | L_{b81} | L_{b81} | 1254 | Lₐ₂₈₀ | L_{b81} | L_{b81} |
| 1255 | Lₐ₂₈₁ | L_{b81} | L_{b81} | 1256 | Lₐ₂₈₂ | L_{b81} | L_{b81} |
| 1257 | Lₐ₂₈₃ | L_{b81} | L_{b81} | 1258 | Lₐ₂₈₄ | L_{b81} | L_{b81} |
| 1259 | Lₐ₂₈₅ | L_{b81} | L_{b81} | 1260 | Lₐ₂₈₆ | L_{b81} | L_{b81} |
| 1261 | Lₐ₂₈₇ | L_{b81} | L_{b81} | 1262 | Lₐ₂₈₈ | L_{b81} | L_{b81} |
| 1263 | Lₐ₂₈₉ | L_{b81} | L_{b81} | 1264 | Lₐ₂₉₀ | L_{b81} | L_{b81} |
| 1265 | Lₐ₂₉₁ | L_{b81} | L_{b81} | 1266 | Lₐ₂₉₂ | L_{b81} | L_{b81} |
| 1267 | Lₐ₂₉₃ | L_{b81} | L_{b81} | 1268 | Lₐ₂₉₄ | L_{b81} | L_{b81} |
| 1269 | Lₐ₂₉₅ | L_{b81} | L_{b81} | 1270 | Lₐ₂₉₆ | L_{b81} | L_{b81} |
| 1271 | Lₐ₂₉₇ | L_{b81} | L_{b81} | 1272 | Lₐ₂₉₈ | L_{b81} | L_{b81} |
| 1273 | Lₐ₂₉₉ | L_{b81} | L_{b81} | 1274 | Lₐ₃₀₀ | L_{b81} | L_{b81} |
| 1275 | Lₐ₃₀₁ | L_{b81} | L_{b81} | 1276 | Lₐ₃₀₂ | L_{b81} | L_{b81} |
| 1277 | Lₐ₃₀₃ | L_{b81} | L_{b81} | 1278 | Lₐ₃₀₄ | L_{b81} | L_{b81} |
| 1279 | Lₐ₃₀₅ | L_{b81} | L_{b81} | 1280 | Lₐ₃₀₆ | L_{b81} | L_{b81} |
| 1281 | Lₐ₃₀₇ | L_{b81} | L_{b81} | 1282 | Lₐ₃₀₈ | L_{b81} | L_{b81} |
| 1283 | Lₐ₃₀₉ | L_{b81} | L_{b81} | 1284 | Lₐ₃₁₀ | L_{b81} | L_{b81} |
| 1285 | Lₐ₃₁₁ | L_{b81} | L_{b81} | 1286 | Lₐ₃₁₂ | L_{b81} | L_{b81} |
| 1287 | Lₐ₃₁₃ | L_{b81} | L_{b81} | 1288 | Lₐ₃₁₄ | L_{b81} | L_{b81} |
| 1289 | Lₐ₃₁₅ | L_{b81} | L_{b81} | 1290 | Lₐ₃₁₆ | L_{b81} | L_{b81} |
| 1291 | Lₐ₃₁₇ | L_{b81} | L_{b81} | 1292 | Lₐ₃₁₈ | L_{b81} | L_{b81} |
| 1293 | Lₐ₃₁₉ | L_{b81} | L_{b81} | 1294 | Lₐ₃₂₀ | L_{b81} | L_{b81} |
| 1295 | Lₐ₃₂₁ | L_{b81} | L_{b81} | 1296 | Lₐ₃₂₂ | L_{b81} | L_{b81} |
| 1297 | Lₐ₃₂₃ | L_{b81} | L_{b81} | 1298 | Lₐ₃₂₄ | L_{b81} | L_{b81} |
| 1299 | Lₐ₃₂₅ | L_{b81} | L_{b81} | 1300 | Lₐ₃₂₆ | L_{b81} | L_{b81} |
| 1301 | Lₐ₃₂₇ | L_{b81} | L_{b81} | 1302 | Lₐ₃₂₈ | L_{b81} | L_{b81} |
| 1303 | Lₐ₃₂₉ | L_{b81} | L_{b81} | 1304 | Lₐ₃₃₀ | L_{b81} | L_{b81} |
| 1305 | Lₐ₃₃₁ | L_{b81} | L_{b81} | 1306 | Lₐ₃₃₂ | L_{b81} | L_{b81} |
| 1307 | Lₐ₃₃₃ | L_{b81} | L_{b81} | 1308 | Lₐ₃₃₄ | L_{b81} | L_{b81} |
| 1309 | Lₐ₃₃₅ | L_{b81} | L_{b81} | 1310 | Lₐ₃₃₆ | L_{b81} | L_{b81} |
| 1311 | Lₐ₃₃₇ | L_{b81} | L_{b81} | 1312 | Lₐ₃₃₈ | L_{b81} | L_{b81} |
| 1313 | Lₐ₃₃₉ | L_{b81} | L_{b81} | 1314 | Lₐ₃₄₀ | L_{b81} | L_{b81} |
| 1315 | Lₐ₃₄₁ | L_{b81} | L_{b81} | 1316 | Lₐ₃₄₂ | L_{b81} | L_{b81} |
| 1317 | Lₐ₃₄₃ | L_{b81} | L_{b81} | 1318 | Lₐ₃₄₄ | L_{b81} | L_{b81} |
| 1319 | Lₐ₃₄₅ | L_{b81} | L_{b81} | 1320 | Lₐ₃₄₆ | L_{b81} | L_{b81} |
| 1321 | Lₐ₃₄₇ | L_{b81} | L_{b81} | 1322 | Lₐ₃₄₈ | L_{b81} | L_{b81} |
| 1323 | Lₐ₃₄₉ | L_{b81} | L_{b81} | 1324 | Lₐ₃₅₀ | L_{b81} | L_{b81} |
| 1325 | Lₐ₃₅₁ | L_{b81} | L_{b81} | 1326 | Lₐ₃₅₂ | L_{b81} | L_{b81} |
| 1327 | Lₐ₃₅₃ | L_{b81} | L_{b81} | 1328 | Lₐ₃₅₄ | L_{b81} | L_{b81} |
| 1329 | Lₐ₃₅₅ | L_{b81} | L_{b81} | 1330 | Lₐ₃₅₆ | L_{b81} | L_{b81} |
| 1331 | Lₐ₃₅₇ | L_{b81} | L_{b81} | 1332 | Lₐ₃₅₈ | L_{b81} | L_{b81} |
| 1333 | Lₐ₃₅₉ | L_{b81} | L_{b81} | 1334 | Lₐ₃₆₀ | L_{b81} | L_{b81} |
| 1335 | Lₐ₃₆₁ | L_{b81} | L_{b81} | 1336 | Lₐ₃₆₂ | L_{b81} | L_{b81} |
| 1337 | Lₐ₃₆₃ | L_{b81} | L_{b81} | 1338 | Lₐ₃₆₄ | L_{b81} | L_{b81} |
| 1339 | Lₐ₃₆₅ | L_{b81} | L_{b81} | 1340 | Lₐ₃₆₆ | L_{b81} | L_{b81} |
| 1341 | Lₐ₃₆₇ | L_{b81} | L_{b81} | 1342 | Lₐ₃₆₈ | L_{b81} | L_{b81} |
| 1343 | Lₐ₃₆₉ | L_{b81} | L_{b81} | 1344 | Lₐ₃₇₀ | L_{b81} | L_{b81} |
| 1345 | Lₐ₃₇₁ | L_{b81} | L_{b81} | 1346 | Lₐ₃₇₂ | L_{b81} | L_{b81} |
| 1347 | Lₐ₃₇₃ | L_{b81} | L_{b81} | 1348 | Lₐ₃₇₄ | L_{b81} | L_{b81} |
| 1349 | Lₐ₃₇₅ | L_{b81} | L_{b81} | 1350 | Lₐ₃₇₆ | L_{b81} | L_{b81} |
| 1351 | Lₐ₃₇₇ | L_{b81} | L_{b81} | 1352 | Lₐ₃₇₈ | L_{b81} | L_{b81} |
| 1353 | Lₐ₃₇₉ | L_{b81} | L_{b81} | 1354 | Lₐ₃₈₀ | L_{b81} | L_{b81} |
| 1355 | Lₐ₃₈₁ | L_{b81} | L_{b81} | 1356 | Lₐ₃₈₂ | L_{b81} | L_{b81} |
| 1357 | Lₐ₃₈₃ | L_{b81} | L_{b81} | 1358 | Lₐ₃₈₄ | L_{b81} | L_{b81} |
| 1359 | Lₐ₃₈₅ | L_{b81} | L_{b81} | 1360 | Lₐ₃₈₆ | L_{b81} | L_{b81} |
| 1361 | Lₐ₃₈₇ | L_{b81} | L_{b81} | 1362 | Lₐ₃₈₈ | L_{b81} | L_{b81} |
| 1363 | Lₐ₃₈₉ | L_{b81} | L_{b81} | 1364 | Lₐ₃₉₀ | L_{b81} | L_{b81} |
| 1365 | Lₐ₃₉₁ | L_{b81} | L_{b81} | 1366 | Lₐ₃₉₂ | L_{b81} | L_{b81} |
| 1367 | Lₐ₃₉₃ | L_{b81} | L_{b81} | 1368 | Lₐ₃₉₄ | L_{b81} | L_{b81} |
| 1369 | Lₐ₃₉₅ | L_{b81} | L_{b81} | 1370 | Lₐ₃₉₆ | L_{b81} | L_{b81} |
| 1371 | Lₐ₃₉₇ | L_{b81} | L_{b81} | 1372 | Lₐ₃₉₈ | L_{b81} | L_{b81} |
| 1373 | Lₐ₃₉₉ | L_{b81} | L_{b81} | 1374 | Lₐ₄₀₀ | L_{b81} | L_{b81} |
| 1375 | Lₐ₄₀₁ | L_{b81} | L_{b81} | 1376 | Lₐ₄₀₂ | L_{b81} | L_{b81} |
| 1377 | Lₐ₄₀₃ | L_{b81} | L_{b81} | 1378 | Lₐ₄₀₄ | L_{b81} | L_{b81} |
| 1379 | Lₐ₄₀₅ | L_{b81} | L_{b81} | 1380 | Lₐ₄₀₆ | L_{b81} | L_{b81} |
| 1381 | Lₐ₄₀₇ | L_{b81} | L_{b81} | 1382 | Lₐ₄₀₈ | L_{b81} | L_{b81} |
| 1383 | Lₐ₄₀₉ | L_{b81} | L_{b81} | 1384 | Lₐ₄₁₀ | L_{b81} | L_{b81} |
| 1385 | Lₐ₄₁₁ | L_{b81} | L_{b81} | 1386 | Lₐ₄₁₂ | L_{b81} | L_{b81} |
| 1387 | Lₐ₄₁₃ | L_{b81} | L_{b81} | 1388 | Lₐ₄₁₄ | L_{b81} | L_{b81} |
| 1389 | Lₐ₄₁₅ | L_{b81} | L_{b81} | 1390 | Lₐ₄₁₆ | L_{b81} | L_{b81} |
| 1391 | Lₐ₄₁₇ | L_{b81} | L_{b81} | 1392 | Lₐ₄₁₈ | L_{b81} | L_{b81} |
| 1393 | Lₐ₄₁₉ | L_{b81} | L_{b81} | 1394 | Lₐ₄₂₀ | L_{b81} | L_{b81} |
| 1395 | Lₐ₄₂₁ | L_{b81} | L_{b81} | 1396 | Lₐ₄₂₂ | L_{b81} | L_{b81} |
| 1397 | Lₐ₄₂₃ | L_{b81} | L_{b81} | 1398 | Lₐ₄₂₄ | L_{b81} | L_{b81} |
| 1399 | Lₐ₄₂₅ | L_{b81} | L_{b81} | 1400 | Lₐ₄₂₆ | L_{b81} | L_{b81} |
| 1401 | Lₐ₄₂₇ | L_{b81} | L_{b81} | 1402 | Lₐ₄₂₈ | L_{b81} | L_{b81} |
| 1403 | Lₐ₄₂₉ | L_{b81} | L_{b81} | 1404 | Lₐ₄₃₀ | L_{b81} | L_{b81} |
| 1405 | Lₐ₄₃₁ | L_{b81} | L_{b81} | 1406 | Lₐ₄₃₂ | L_{b81} | L_{b81} |
| 1407 | Lₐ₄₃₃ | L_{b81} | L_{b81} | 1408 | Lₐ₄₃₄ | L_{b81} | L_{b81} |
| 1409 | Lₐ₄₃₅ | L_{b81} | L_{b81} | 1410 | Lₐ₄₃₆ | L_{b81} | L_{b81} |
| 1411 | Lₐ₄₃₇ | L_{b81} | L_{b81} | 1412 | Lₐ₄₃₈ | L_{b81} | L_{b81} |
| 1413 | Lₐ₄₃₉ | L_{b81} | L_{b81} | 1414 | Lₐ₄₄₀ | L_{b81} | L_{b81} |
| 1415 | Lₐ₄₄₁ | L_{b81} | L_{b81} | 1416 | Lₐ₄₄₂ | L_{b81} | L_{b81} |
| 1417 | Lₐ₄₄₃ | L_{b81} | L_{b81} | 1418 | Lₐ₄₄₄ | L_{b81} | L_{b81} |
| 1419 | Lₐ₄₄₅ | L_{b81} | L_{b81} | 1420 | Lₐ₄₄₆ | L_{b81} | L_{b81} |
| 1421 | Lₐ₄₄₇ | L_{b81} | L_{b81} | 1422 | Lₐ₄₄₈ | L_{b81} | L_{b81} |
| 1423 | Lₐ₄₄₉ | L_{b81} | L_{b81} | 1424 | Lₐ₄₅₀ | L_{b81} | L_{b81} |
| 1425 | Lₐ₄₅₁ | L_{b81} | L_{b81} | 1426 | Lₐ₄₅₂ | L_{b81} | L_{b81} |
| 1427 | Lₐ₄₅₃ | L_{b81} | L_{b81} | 1428 | Lₐ₄₅₄ | L_{b81} | L_{b81} |
| 1429 | Lₐ₄₅₅ | L_{b81} | L_{b81} | 1430 | Lₐ₄₅₆ | L_{b81} | L_{b81} |
| 1431 | Lₐ₄₅₇ | L_{b81} | L_{b81} | 1432 | Lₐ₄₅₈ | L_{b81} | L_{b81} |
| 1433 | Lₐ₄₅₉ | L_{b81} | L_{b81} | 1434 | Lₐ₄₆₀ | L_{b81} | L_{b81} |
| 1435 | Lₐ₄₉₆ | L_{b81} | L_{b81} | 1436 | Lₐ₅₀₀ | L_{b81} | L_{b81} |
| 1437 | Lₐ₅₀₂ | L_{b81} | L_{b81} | 1438 | Lₐ₅₀₄ | L_{b81} | L_{b81} |
| 1439 | Lₐ₅₀₈ | L_{b81} | L_{b81} | 1440 | Lₐ₅₀₉ | L_{b81} | L_{b81} |
| 1441 | Lₐ₅₁₀ | L_{b81} | L_{b81} | 1442 | Lₐ₅₁₅ | L_{b81} | L_{b81} |
| 1443 | Lₐ₅₂₂ | L_{b81} | L_{b81} | 1444 | Lₐ₅₂₃ | L_{b81} | L_{b81} |
| 1445 | Lₐ₅₂₄ | L_{b81} | L_{b81} | 1446 | Lₐ₅₂₅ | L_{b81} | L_{b81} |
| 1447 | Lₐ₅₃₄ | L_{b81} | L_{b81} | 1448 | Lₐ₅₃₅ | L_{b81} | L_{b81} |
| 1449 | Lₐ₅₆₇ | L_{b81} | L_{b81} | 1450 | Lₐ₅₇₀ | L_{b81} | L_{b81} |
| 1451 | Lₐ₅₈₃ | L_{b81} | L_{b81} | 1452 | Lₐ₅₈₅ | L_{b81} | L_{b81} |
| 1453 | Lₐ₅₈₆ | L_{b81} | L_{b81} | 1454 | Lₐ₆₈₉ | L_{b81} | L_{b81} |
| 1455 | Lₐ₆₉₈ | L_{b81} | L_{b81} | 1456 | Lₐ₇₀₀ | L_{b81} | L_{b81} |
| 1457 | Lₐ₁ | L_{b1} | L_{b3} | 1458 | Lₐ₁ | L_{b1} | L_{b8} |
| 1459 | Lₐ₁ | L_{b1} | L_{b12} | 1460 | Lₐ₁ | L_{b1} | L_{b17} |
| 1461 | Lₐ₁ | L_{b1} | L_{b81} | 1462 | Lₐ₁ | L_{b1} | L_{b89} |
| 1463 | Lₐ₁ | L_{b3} | L_{b12} | 1464 | Lₐ₁ | L_{b3} | L_{b89} |
| 1465 | Lₐ₅₄ | L_{b1} | L_{b3} | 1466 | Lₐ₅₄ | L_{b1} | L_{b8} |
| 1467 | Lₐ₅₄ | L_{b1} | L_{b12} | 1468 | Lₐ₅₄ | L_{b1} | L_{b17} |
| 1469 | Lₐ₅₄ | L_{b1} | L_{b81} | 1470 | Lₐ₅₄ | L_{b1} | L_{b89} |
| 1471 | Lₐ₅₄ | L_{b3} | L_{b12} | 1472 | Lₐ₅₄ | L_{b3} | L_{b89} |
| 1473 | Lₐ₂₁₈ | L_{b1} | L_{b3} | 1474 | Lₐ₂₁₈ | L_{b1} | L_{b8} |
| 1475 | Lₐ₂₁₈ | L_{b1} | L_{b12} | 1476 | Lₐ₂₁₈ | L_{b1} | L_{b17} |
| 1477 | Lₐ₂₁₈ | L_{b1} | L_{b81} | 1478 | Lₐ₂₁₈ | L_{b1} | L_{b89} |
| 1479 | Lₐ₂₁₈ | L_{b3} | L_{b12} | 1480 | Lₐ₂₁₈ | L_{b3} | L_{b89} |
| 1481 | Lₐ₂₄₃ | L_{b1} | L_{b3} | 1482 | Lₐ₂₄₃ | L_{b1} | L_{b8} |
| 1483 | Lₐ₂₄₃ | L_{b1} | L_{b12} | 1484 | Lₐ₂₄₃ | L_{b1} | L_{b17} |
| 1485 | Lₐ₂₄₃ | L_{b1} | L_{b81} | 1486 | Lₐ₂₄₃ | L_{b1} | L_{b89} |
| 1487 | Lₐ₂₄₃ | L_{b3} | L_{b12} | 1488 | Lₐ₂₄₃ | L_{b3} | L_{b89}; |

Metal Complex 1489 to Metal Complex 1530 each have a structure of Ir(Lₐ)₂L_{c}, wherein the two Lₐ are the same or different, and the two Lₐ and L_{c} respectively correspond to the structures listed in the following table:

| Metal | | | | Metal | | | |
|---|---|---|---|---|---|---|---|
| Complex | Lₐ | Lₐ | L_{c} | Complex | Lₐ | Lₐ | L_{c} |
| 1489 | Lₐ₄₆₂ | Lₐ₄₆₂ | L_{c1} | 1490 | Lₐ₄₆₃ | Lₐ₄₆₃ | L_{c1} |
| 1491 | Lₐ₄₆₄ | Lₐ₄₆₄ | L_{c1} | 1492 | Lₐ₄₆₅ | Lₐ₄₆₅ | L_{c1} |
| 1493 | Lₐ₄₆₆ | Lₐ₄₆₆ | L_{c1} | 1494 | Lₐ₄₆₇ | Lₐ₄₆₇ | L_{c1} |
| 1495 | Lₐ₄₆₈ | Lₐ₄₆₈ | L_{c1} | 1496 | Lₐ₄₆₉ | Lₐ₄₆₉ | L_{c1} |
| 1497 | Lₐ₄₇₀ | Lₐ₄₇₀ | L_{c1} | 1498 | Lₐ₄₇₁ | Lₐ₄₇₁ | L_{c1} |
| 1499 | Lₐ₄₇₂ | Lₐ₄₇₂ | L_{c31} | 1500 | Lₐ₄₇₃ | Lₐ₄₇₃ | L_{c31} |
| 1501 | Lₐ₄₇₄ | Lₐ₄₇₄ | L_{c31} | 1502 | Lₐ₄₇₅ | Lₐ₄₇₅ | L_{c31} |
| 1503 | Lₐ₄₇₆ | Lₐ₄₇₆ | L_{c31} | 1504 | Lₐ₄₇₇ | Lₐ₄₇₇ | L_{c31} |
| 1505 | Lₐ₄₇₈ | Lₐ₄₇₈ | L_{c31} | 1506 | Lₐ₄₇₉ | Lₐ₄₇₉ | L_{c31} |
| 1507 | Lₐ₄₈₀ | Lₐ₄₈₀ | L_{c31} | 1508 | Lₐ₄₈₁ | Lₐ₄₈₁ | L_{c31} |
| 1509 | Lₐ₄₈₂ | Lₐ₄₈₂ | L_{c31} | 1510 | Lₐ₄₈₃ | Lₐ₄₈₃ | L_{c31} |
| 1511 | Lₐ₄₈₄ | Lₐ₄₈₄ | L_{c31} | 1512 | Lₐ₄₈₅ | Lₐ₄₈₅ | L_{c31} |
| 1513 | Lₐ₄₈₆ | Lₐ₄₈₆ | L_{c31} | 1514 | Lₐ₄₈₇ | Lₐ₄₈₇ | L_{c31} |
| 1515 | Lₐ₄₈₈ | Lₐ₄₈₈ | L_{c31} | 1516 | Lₐ₄₈₉ | Lₐ₄₈₉ | L_{c31} |
| 1517 | Lₐ₄₉₀ | Lₐ₄₉₀ | L_{c31} | 1518 | Lₐ₄₉₁ | Lₐ₄₉₁ | L_{c31} |
| 1519 | Lₐ₄₉₂ | Lₐ₄₉₂ | L_{c31} | 1520 | Lₐ₄₉₃ | Lₐ₄₉₃ | L_{c31} |
| 1521 | Lₐ₄₉₄ | Lₐ₄₉₄ | L_{c31} | 1522 | Lₐ₄₉₅ | Lₐ₄₉₅ | L_{c31} |
| 1523 | Lₐ₄₆₂ | Lₐ₄₆₃ | L_{c31} | 1524 | Lₐ₄₆₂ | Lₐ₄₆₄ | L_{c31} |
| 1525 | Lₐ₄₆₂ | Lₐ₄₆₅ | L_{c31} | 1526 | Lₐ₄₆₂ | Lₐ₄₆₆ | L_{c31} |
| 1527 | Lₐ₄₆₂ | Lₐ₄₆₇ | L_{c31} | 1528 | Lₐ₄₆₂ | Lₐ₄₆₈ | L_{c31} |
| 1529 | Lₐ₄₆₂ | Lₐ₄₆₉ | L_{c31} | 1530 | Lₐ₄₆₂ | Lₐ₄₇₀ | L_{c31}; |

Metal Complex 1531 to Metal Complex 1554 each have a structure of Ir(Lₐ)(L_{b})(L_{c}), wherein Lₐ, L_{b} and L_{c} respectively correspond to the structures listed in the following table:

| Metal | | | | Metal | | | |
|---|---|---|---|---|---|---|---|
| Complex | Lₐ | L_{b} | L_{c} | Complex | Lₐ | L_{b} | L_{c} |
| 1531 | Lₐ₁ | L_{b1} | L_{c31} | 1532 | Lₐ₁ | L_{b3} | L_{c31} |
| 1533 | Lₐ₁ | L_{b12} | L_{c31} | 1534 | Lₐ₁ | L_{b15} | L_{c31} |
| 1535 | Lₐ₁ | L_{b17} | L_{c31} | 1536 | Lₐ₁ | L_{b81} | L_{c31} |
| 1537 | Lₐ₁ | L_{b85} | L_{c31} | 1538 | Lₐ₁ | L_{b90} | L_{c31} |
| 1539 | Lₐ₂₁₈ | L_{b1} | L_{c31} | 1540 | Lₐ₂₁₈ | L_{b3} | L_{c31} |
| 1541 | Lₐ₂₁₈ | L_{b12} | L_{c31} | 1542 | Lₐ₂₁₈ | L_{b15} | L_{c31} |
| 1543 | Lₐ₂₁₈ | L_{b17} | L_{c31} | 1544 | Lₐ₂₁₈ | L_{b81} | L_{c31} |
| 1545 | Lₐ₂₁₈ | L_{b85} | L_{c31} | 1546 | Lₐ₂₁₈ | L_{b90} | L_{c31} |
| 1547 | Lₐ₄₆₃ | L_{b1} | L_{c31} | 1548 | Lₐ₄₆₃ | L_{b3} | L_{c31} |
| 1549 | Lₐ₄₆₃ | L_{b12} | L_{c31} | 1550 | Lₐ₄₆₃ | L_{b15} | L_{c31} |
| 1551 | Lₐ₄₆₃ | L_{b7} | L_{c31} | 1552 | Lₐ₄₆₃ | L_{b81} | L_{c31} |
| 1553 | Lₐ₄₆₃ | L_{b85} | L_{c31} | 1554 | Lₐ₄₆₃ | L_{b90} | L_{c31}; |

Metal Complex 1555 to Metal Complex 1578 each have a structure of Ir(Lₐ)₃, wherein the three Lₐ are the same or different, and the three Lₐ respectively correspond to the structures listed in the following table:

| Metal | | | | Metal | | | |
|---|---|---|---|---|---|---|---|
| Complex | Lₐ | Lₐ | Lₐ | Complex | Lₐ | Lₐ | Lₐ |
| 1555 | Lₐ₁ | Lₐ₁ | Lₐ₁ | 1556 | Lₐ₅₄ | Lₐ₅₄ | Lₐ₅₄ |
| 1557 | Lₐ₂₁₈ | Lₐ₂₁₈ | Lₐ₂₁₈ | 1558 | Lₐ₂₃₀ | Lₐ₂₃₀ | Lₐ₂₃₀ |
| 1559 | Lₐ₂₄₃ | Lₐ₂₄₃ | Lₐ₂₄₃ | 1560 | Lₐ₁₅₅ | Lₐ₁₅₅ | Lₐ₁₅₅ |
| 1561 | Lₐ₃₁₃ | Lₐ₃₁₃ | Lₐ₃₁₃ | 1562 | Lₐ₂₅₄ | Lₐ₂₅₄ | Lₐ₂₅₄ |
| 1563 | Lₐ₁₇₁ | Lₐ₁₇₁ | Lₐ₁₇₁ | 1564 | Lₐ₄₆₅ | Lₐ₄₆₅ | Lₐ₄₆₅ |
| 1565 | Lₐ₁ | Lₐ₃ | Lₐ₄ | 1566 | Lₐ₁ | Lₐ₃ | Lₐ₆ |
| 1567 | Lₐ₁ | Lₐ₃ | Lₐ₁₀ | 1568 | Lₐ₁ | Lₐ₃ | Lₐ₁₃ |
| 1569 | Lₐ₁ | Lₐ₃ | Lₐ₂₅ | 1570 | Lₐ₁ | Lₐ₃ | Lₐ₂₈ |
| 1571 | Lₐ₁ | Lₐ₃ | Lₐ₃₅ | 1572 | Lₐ₁ | Lₐ₃ | Lₐ₃₇ |
| 1573 | Lₐ₁ | Lₐ₃ | Lₐ₄₀ | 1574 | Lₐ₁ | Lₐ₃ | Lₐ₄₂ |
| 1575 | Lₐ₁ | Lₐ₃ | Lₐ₄₅ | 1576 | Lₐ₁ | Lₐ₃ | Lₐ₆₅ |
| 1577 | Lₐ₁ | Lₐ₃ | Lₐ₈₀ | 1578 | Lₐ₁ | Lₐ₃ | Lₐ₈₈. |

18. An electroluminescent device, comprising:
an anode,
a cathode, and
an organic layer disposed between the anode and the cathode, wherein the organic layer comprises the metal complex of claim 1.

19. The electroluminescent device of claim 18, wherein the organic layer comprising the metal complex is a light-emitting layer.

20. The electroluminescent device of claim 19, wherein the electroluminescent device emits green light or white light.

21. The electroluminescent device of claim 19, wherein the light-emitting layer comprises a first host compound;
preferably, the light-emitting layer further comprises a second host compound;
more preferably, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

22. The electroluminescent device of claim 21, wherein the first host compound has a structure represented by Formula 4: 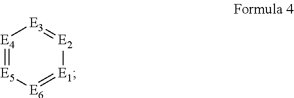
wherein
E₁ to E₆ are, at each occurrence identically or differently, selected from C, CRₑ or N, at least two of E₁ to E₆ are N, and at least one of E₁ to E₆ is C and joined to Formula A; 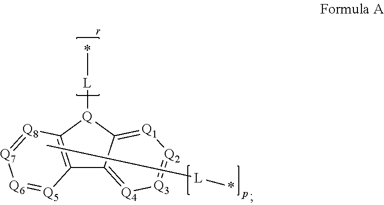
wherein
Q is, at each occurrence identically or differently, selected from the group consisting of O, S, Se, N, NR′″, CR′″R′″, SiR′″R′″, GeR′″R′″ and R′″C═CR′″; when two R′″ are present at the same time, the two R′″ may be the same or different;
p is 0 or 1; r is 0 or 1;
when Q is selected from N, p is 0 and r is 1;
when Q is selected from the group consisting of O, S, Se, NR′″, CR′″R′″, SiR′″R′″, GeR′″R′″ and R′″C═CR′″, p is 1 and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₑ, R′″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“*” represents a position where Formula A is joined to Formula 4; and
adjacent substituents Rₑ, R′″, R_{q} can be optionally joined to form a ring.

23. The electroluminescent device of claim 22, wherein the first host compound is selected from the group consisting of:

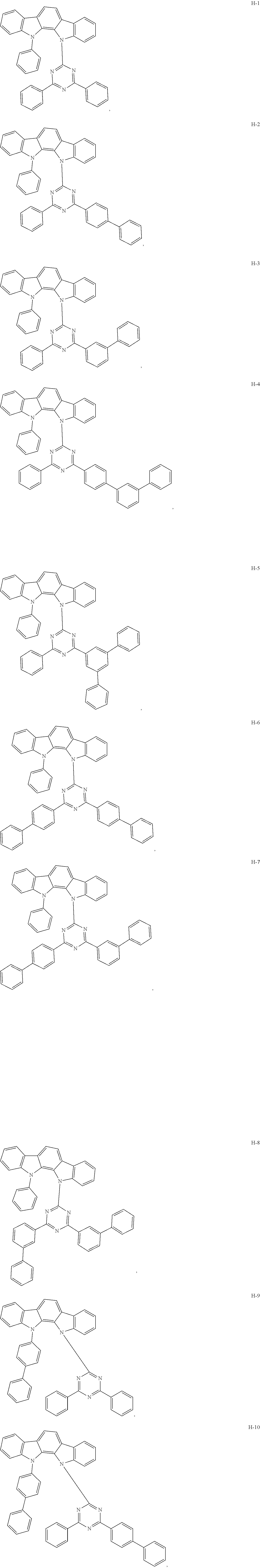

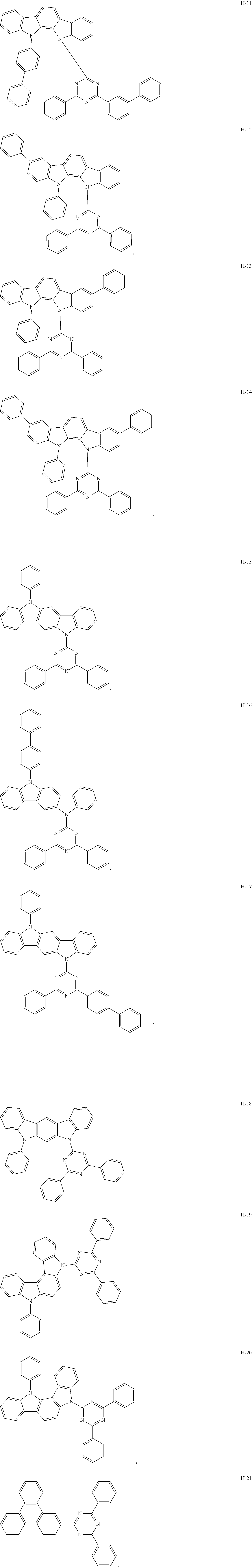

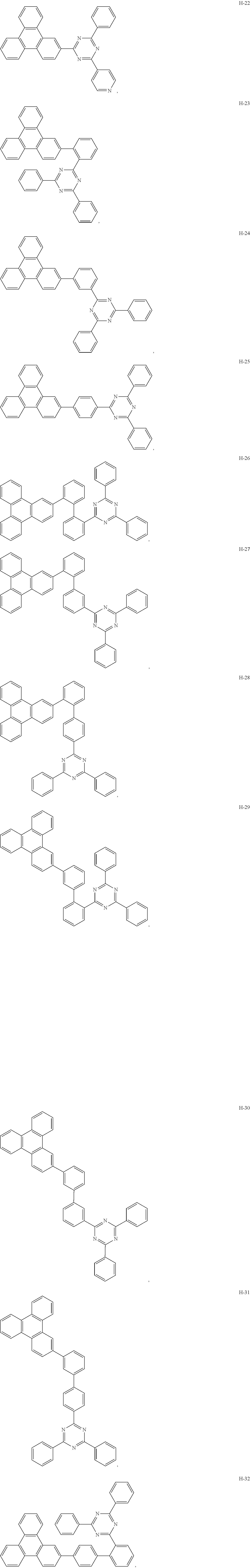

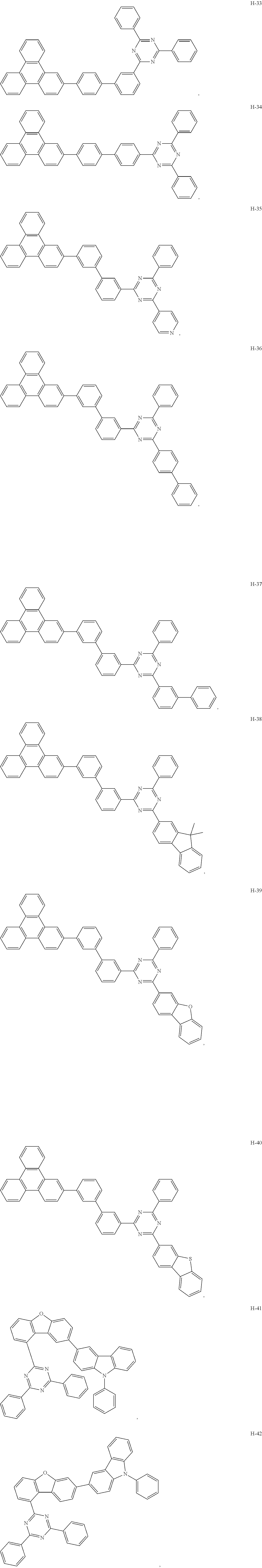

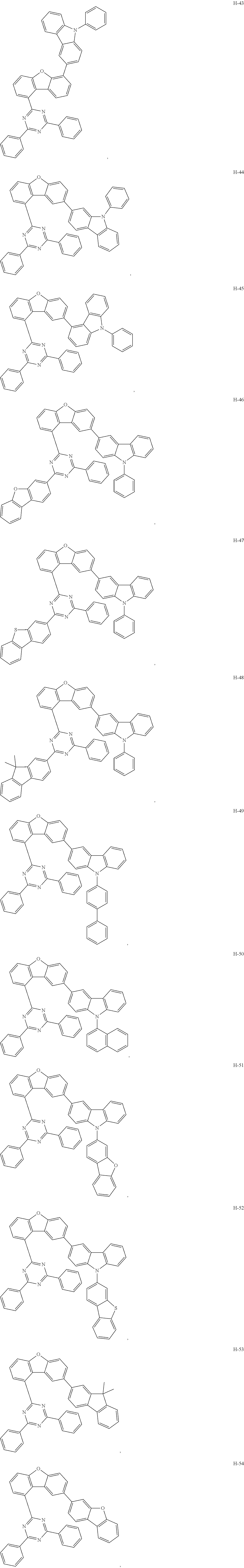

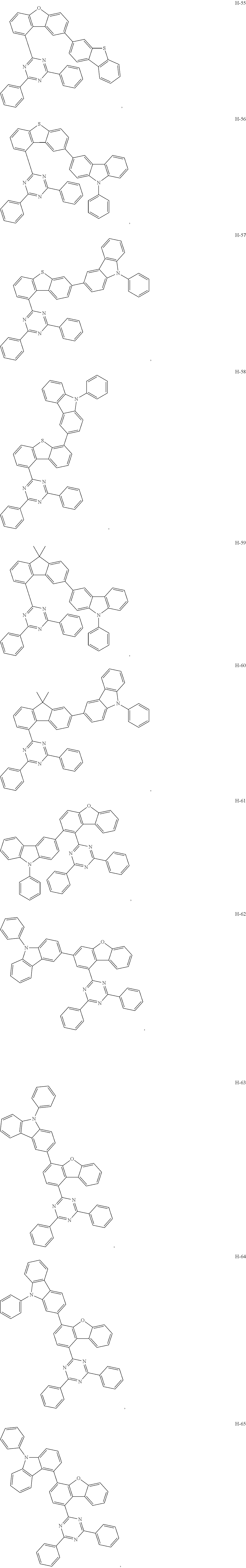

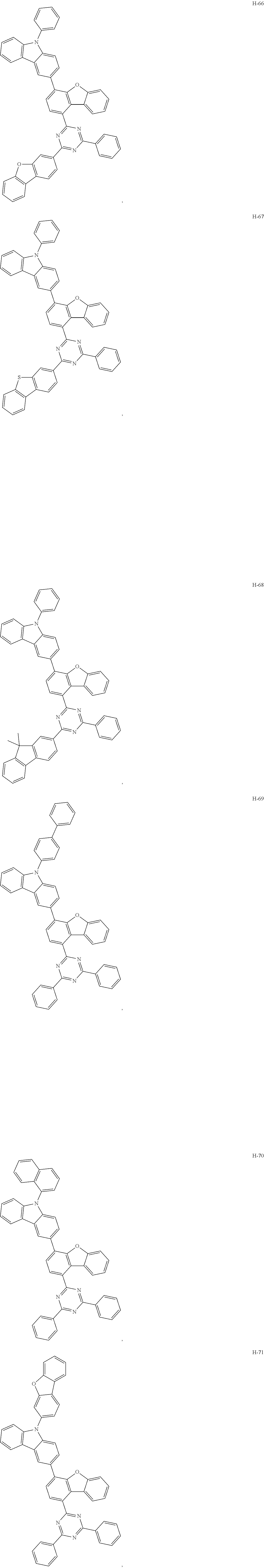

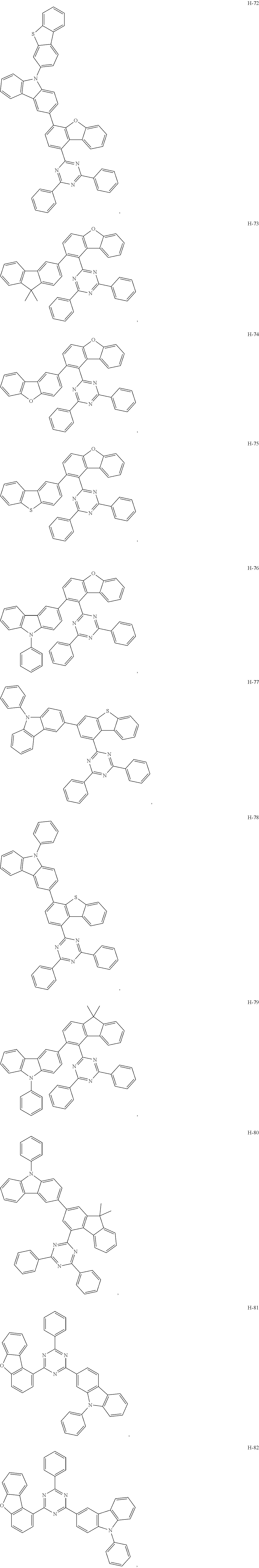

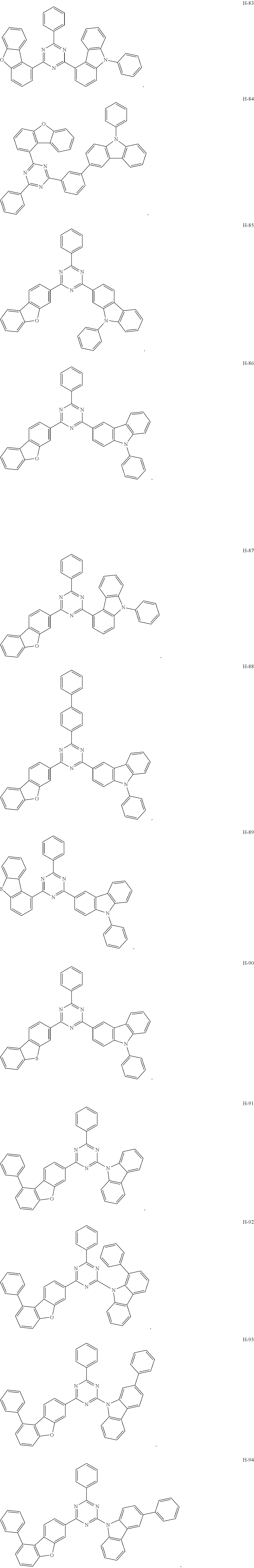

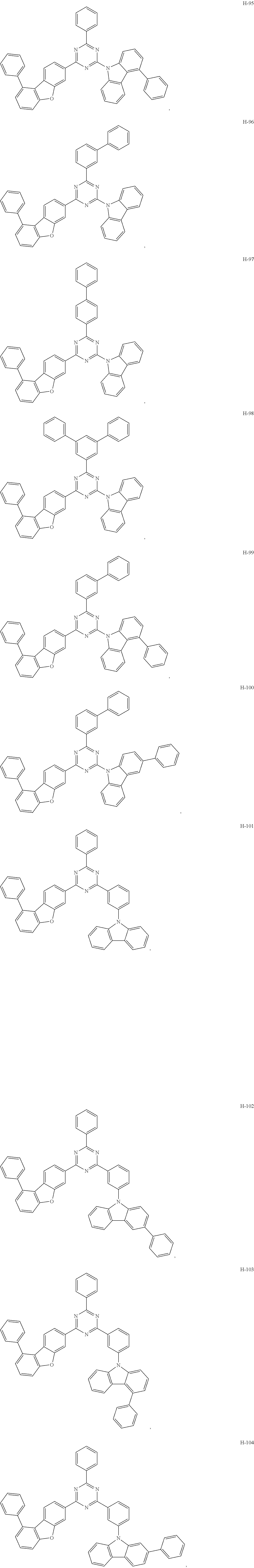

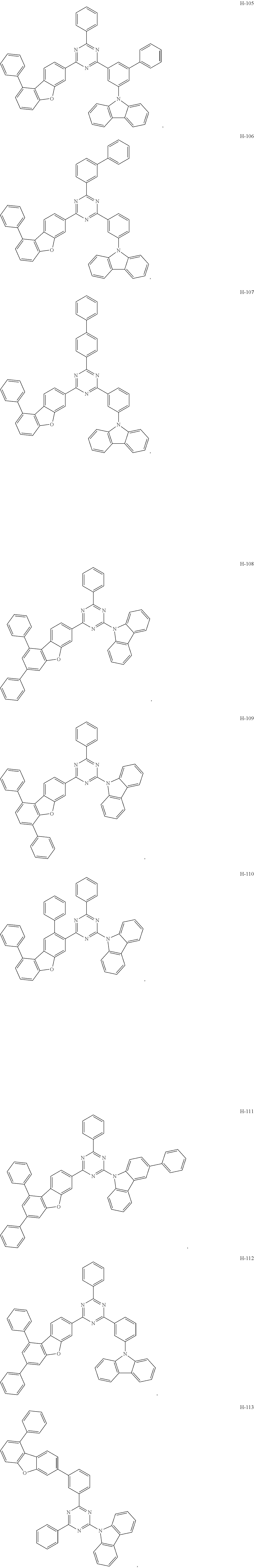

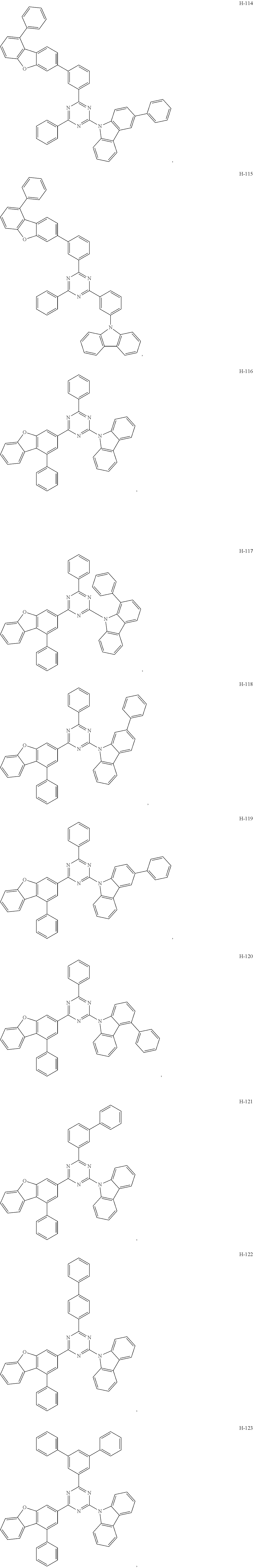

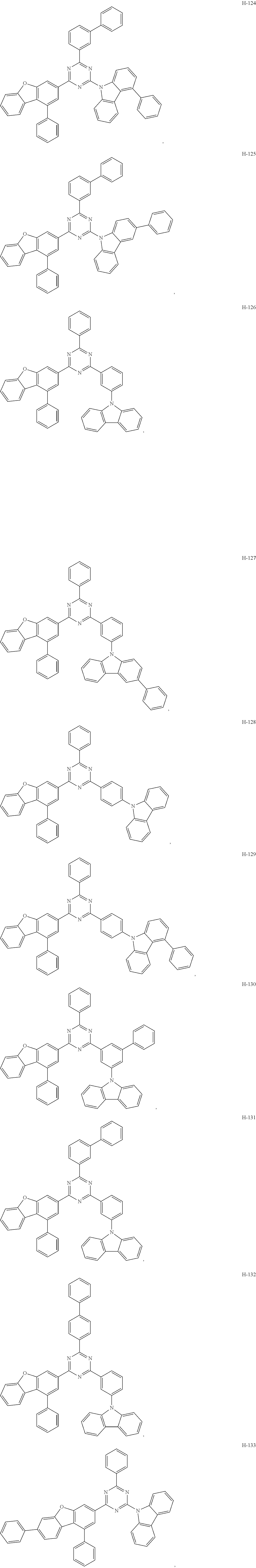

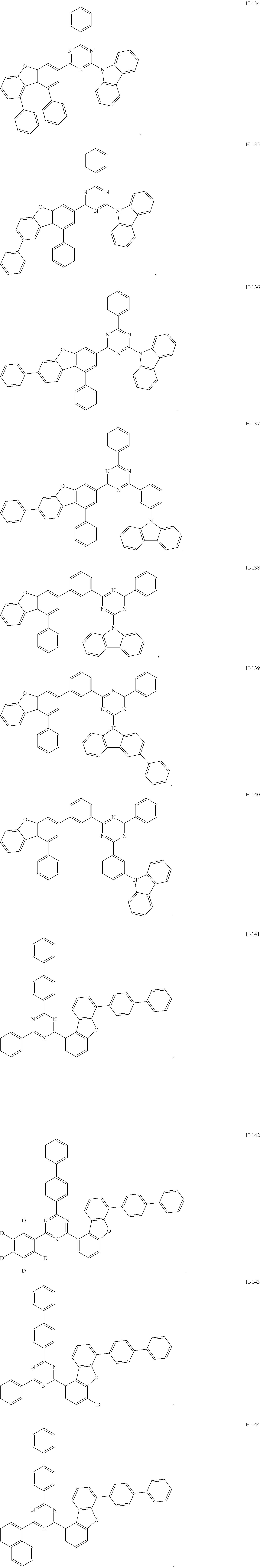

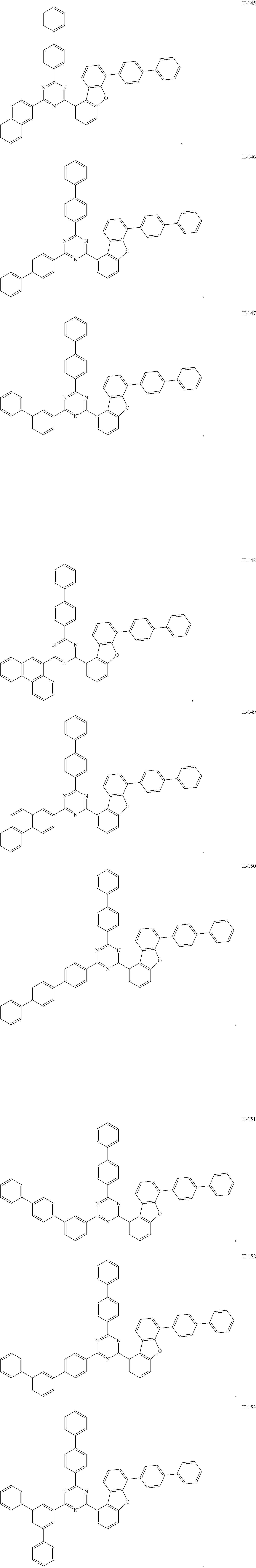

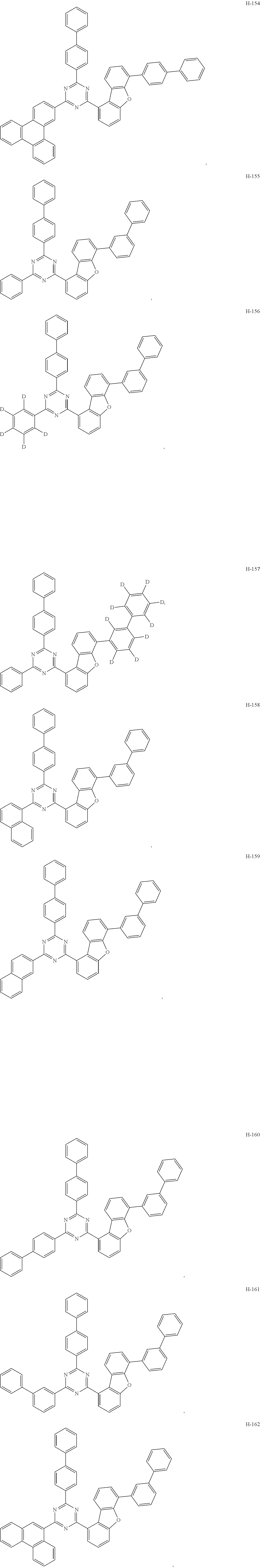

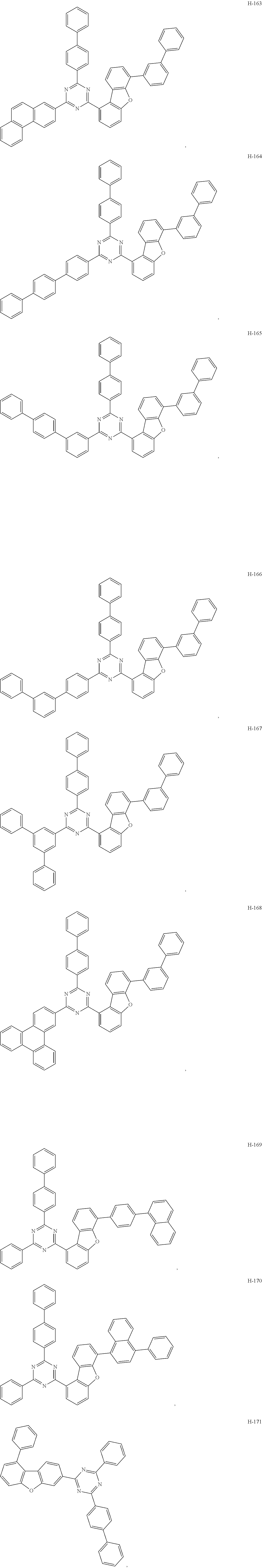

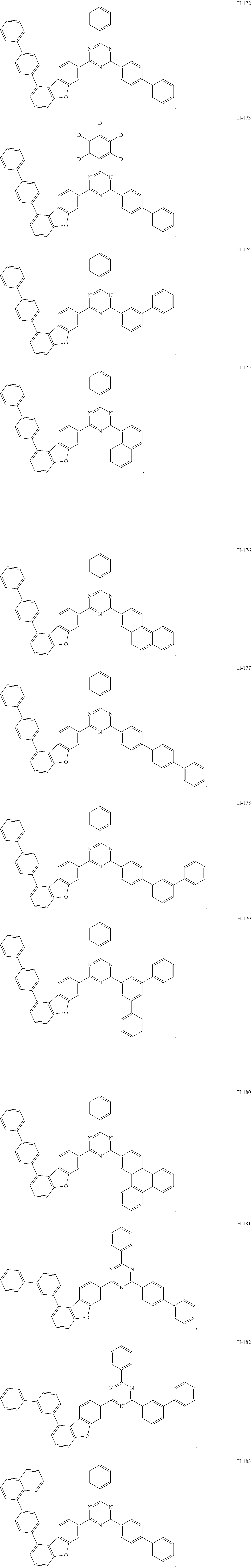

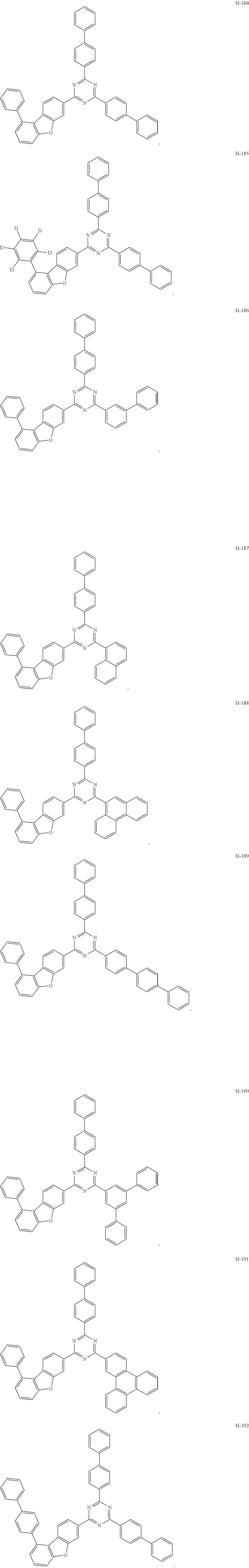

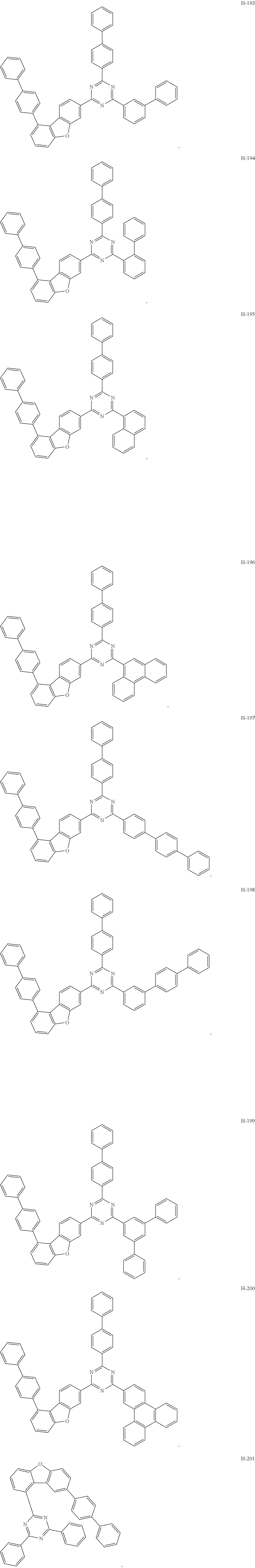

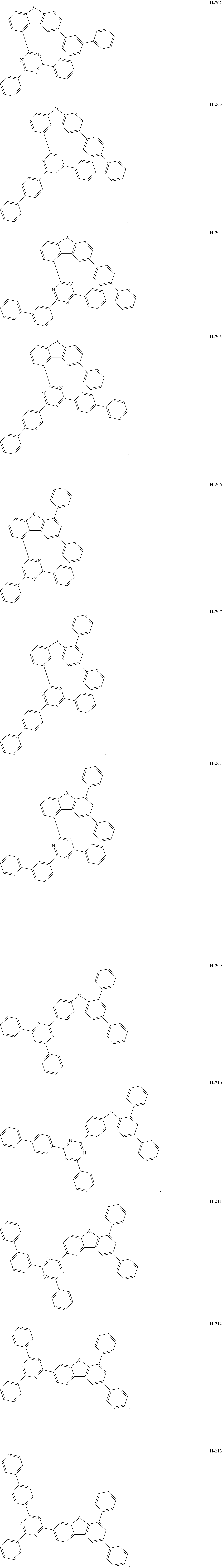

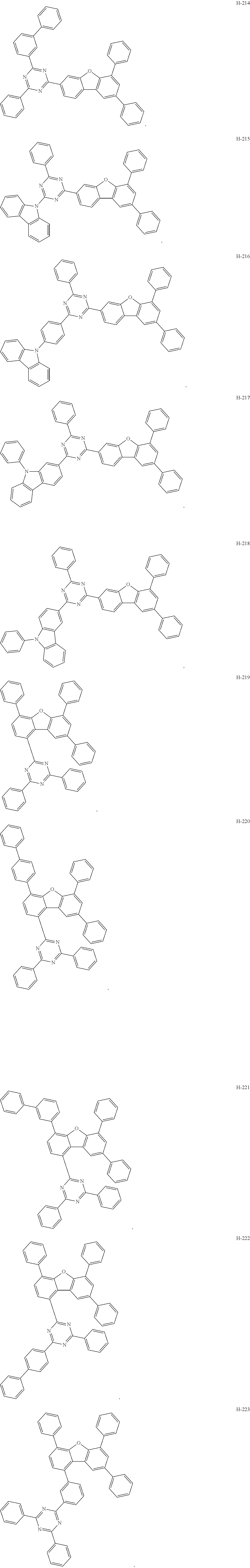

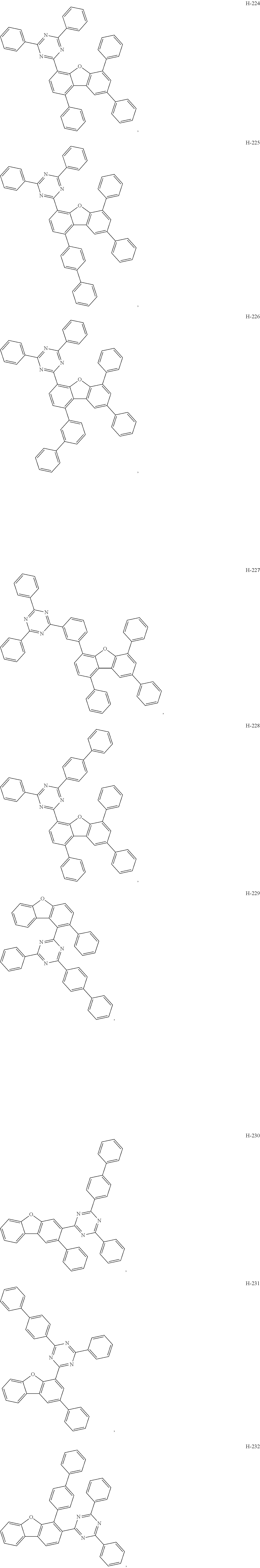

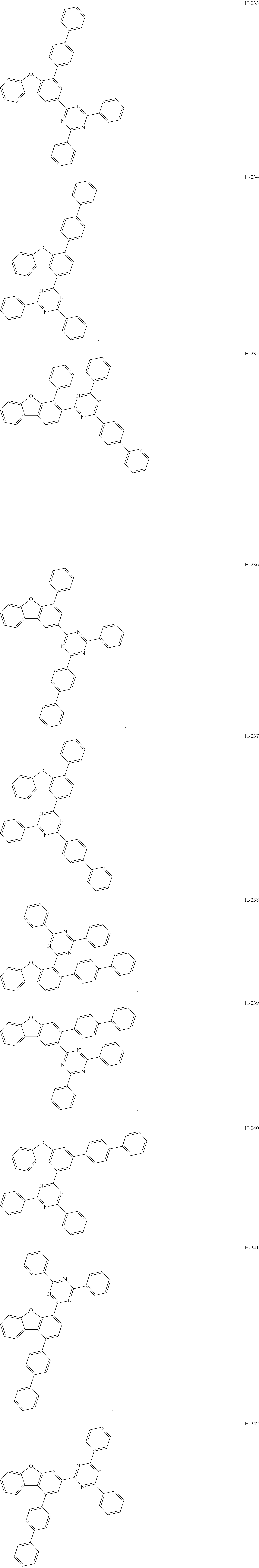

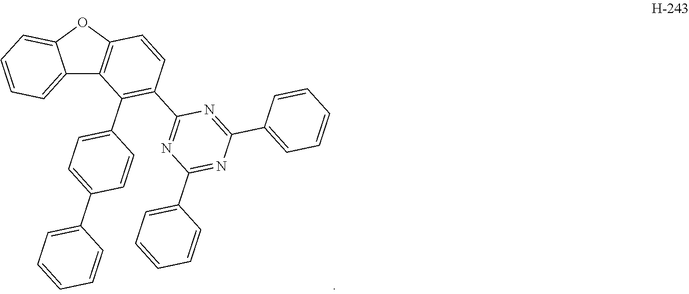 [SMILES: c1ccc(-c2ccc(-c3c(-c4nc(-c5ccccc5)nc(-c5ccccc5)n4)ccc4oc5ccccc5c34)cc2)cc1]

24. The electroluminescent device of claim 21, wherein the second host compound has a structure represented by Formula 5: 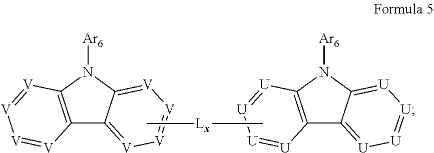
wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
V is, at each occurrence identically or differently, selected from C, CRᵥ or N, and at least one of V is C and joined to Lₓ;
U is, at each occurrence identically or differently, selected from C, CRᵤ or N, and at least one of U is C and joined to Lₓ;
Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₆ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents Rᵥ and Rᵤ can be optionally joined to form a ring;
preferably, the second host compound has a structure represented by one of Formula 5-a to Formula 5-j:

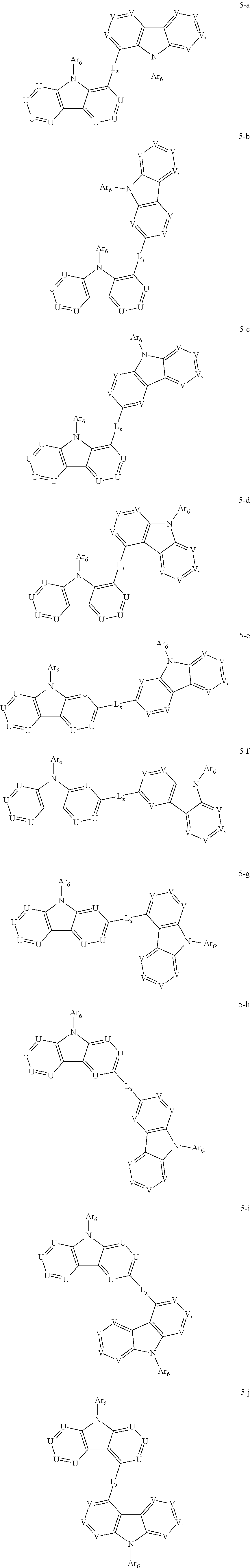

25. The electroluminescent device of claim 24, wherein the second host compound is selected from the group consisting of:

[chemical structure]

[chemical structure]

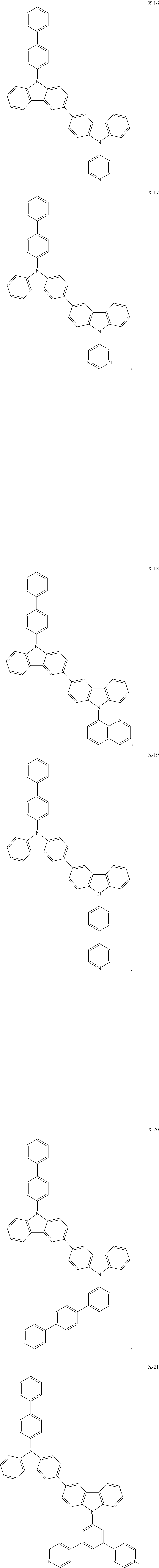

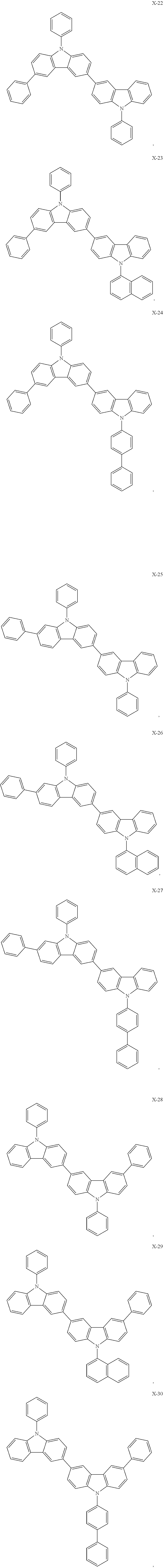

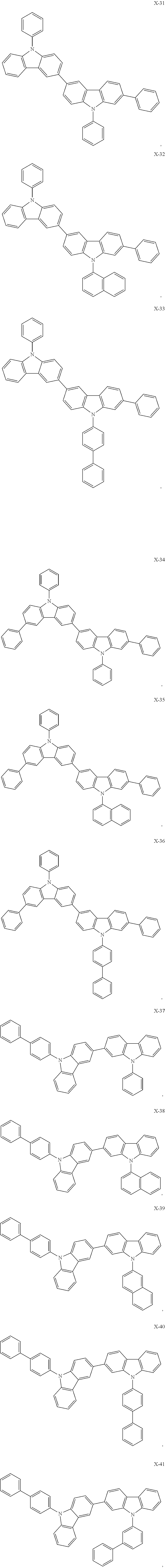

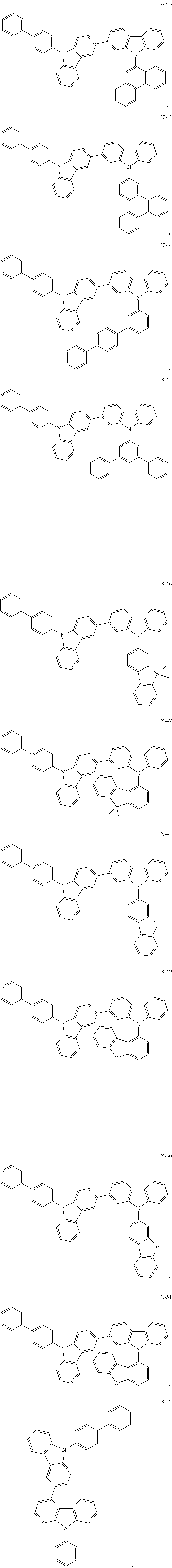

[chemical structure]

[chemical structure]

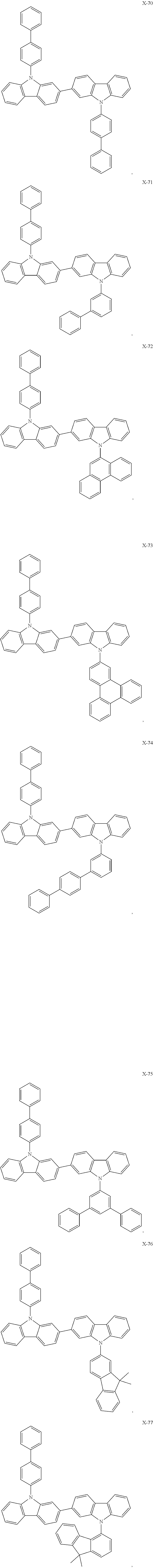

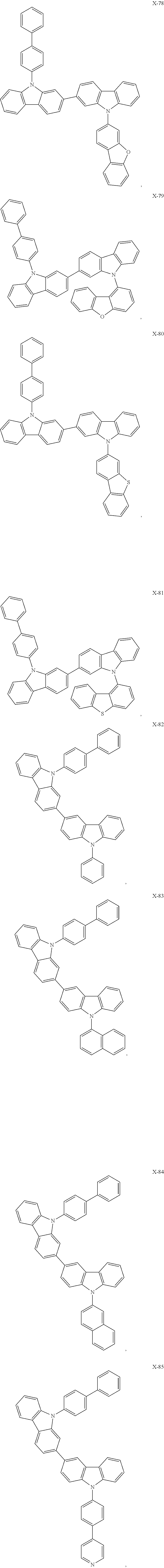

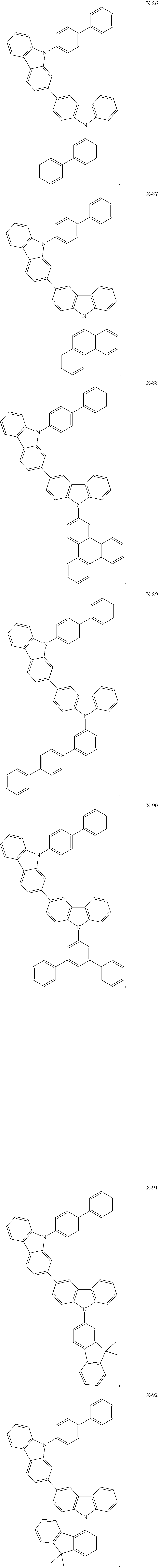

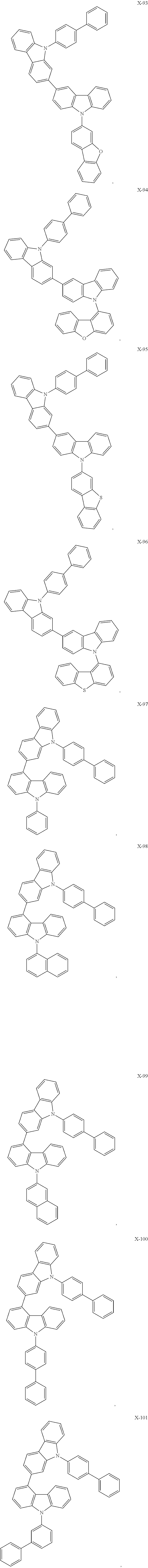

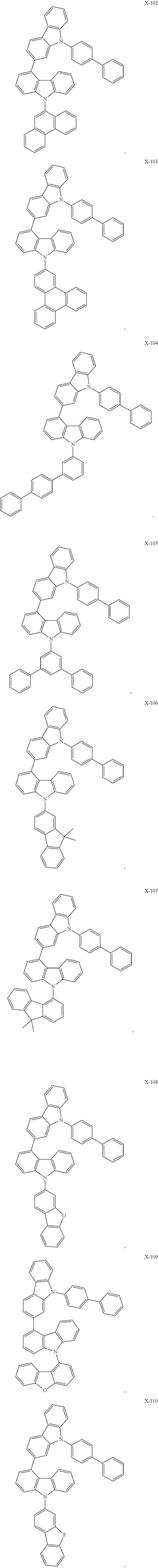

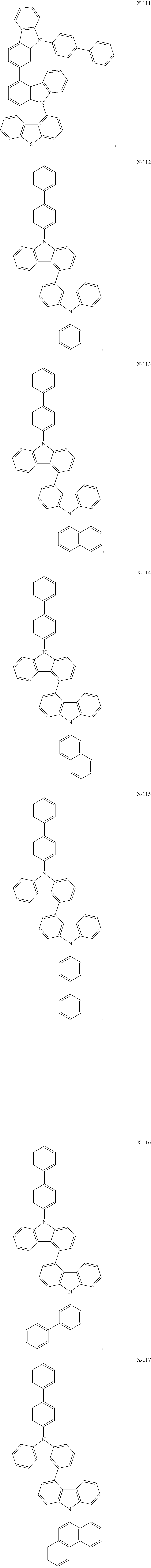

[chemical structure]

[chemical structure]

[chemical structure]

[chemical structure]

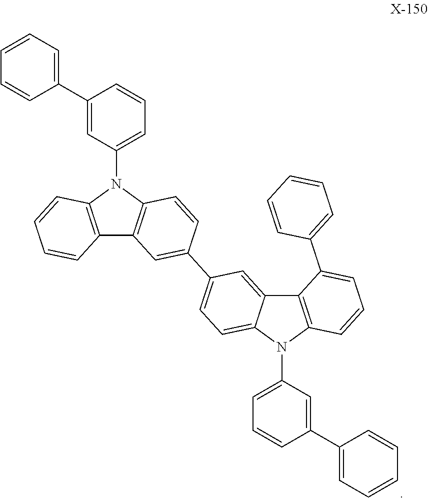 [SMILES: c1ccc(-c2cccc(-n3c4ccccc4c4cc(-c5ccc6c(c5)c5c(-c7ccccc7)cccc5n6-c5cccc(-c6ccccc6)c5)ccc43)c2)cc1]

26. The electroluminescent device of claim 21, wherein the metal complex is doped in the first host compound and the second host compound, and a weight of the metal complex accounts for 1% to 30% of a total weight of the light-emitting layer;
preferably, the weight of the metal complex accounts for 3% to 13% of the total weight of the light-emitting layer.

27. A compound combination, comprising the metal complex of claim 1.
